(19) United States
(12) Patent Application Publication
(10) Pub. No.: US 2018/0087010 A1
(43) Pub. Date: Mar. 29, 2018

(54) PRE-RINSING LIQUID, PRE-RINSING TREATMENT METHOD, AND PATTERN FORMING METHOD

(71) Applicant: FUJIFILM Corporation, Tokyo (JP)

(72) Inventors: Toshiya TAKAHASHI, Haibara-gun (JP); Yasushi TOYOSHIMA, Haibara-gun (JP); Junya ABE, Haibara-gun (JP); Hidehiro MOCHIZUKI, Haibara-gun (JP)

(73) Assignee: FUJIFILM Corporation, Tokyo (JP)

(21) Appl. No.: 15/810,134

(22) Filed: Nov. 12, 2017

Related U.S. Application Data
(63) Continuation of application No. PCT/JP2016/062047, filed on Apr. 14, 2016.

(30) Foreign Application Priority Data
May 13, 2015 (JP) 2015-098494
Mar. 25, 2016 (JP) 2016-061892

(51) Int. Cl. C11D 7/50; G03F 1/78; G03F 1/82; G03F 7/16; G03F 7/20; G03F 7/32; G03F 7/039; G03F 7/038; G03F 1/50; C11D 7/26; C11D 7/34

(52) U.S. Cl. CPC C11D 7/5022; G03F 1/78; G03F 1/82; G03F 7/16; G03F 7/168; C11D 7/34; G03F 7/322; G03F 7/039; G03F 7/038; G03F 1/50; C11D 7/265; G03F 7/2037

(57) ABSTRACT

Provided is a pre-rinsing liquid used in a method including forming a resist film including an actinic ray-sensitive or radiation-sensitive composition on a substrate, and irradiating the resist film with actinic rays or radiation to form a pattern on the substrate, and used for subjecting the substrate to a pre-rinsing treatment before applying the actinic ray-sensitive or radiation-sensitive composition onto the substrate. The pre-rinsing liquid satisfies the following conditions (1) and (2):
(1) the pre-rinsing liquid includes 80% by mass or more of an organic solvent with respect to the total mass of the pre-rinsing liquid, and
(2) the organic solvent is at least one organic solvent selected from the group consisting of alcohols, cyclic ethers, glycol ethers, glycol ether acetates, hydrocarbons, ketones, lactones, and esters.

### CROSS REFERENCE TO RELATED APPLICATIONS

This is a continuation of International Application No. PCT/JP2016/062047 filed on Apr. 14, 2016, and claims priorities from Japanese Patent Application No. 2015-098494 filed on May 13, 2015 and Japanese Patent Application No. 2016-061892 filed on Mar. 25, 2016, the entire disclosures of which are incorporated herein by reference.

### BACKGROUND OF THE INVENTION

### 1. Field of the Invention

The present invention relates to a pre-rinsing liquid which is suitably used for the ultramicrolithography process such as manufacture of a very-large-scale integrated circuit (ultra LSI) or a high-capacity microchip, or in other fabrication processes, and is particularly effective in a method for forming a high-precision pattern using electron beams or extreme ultraviolet rays; and a pre-rinsing treatment method and a pattern forming method, each using the same.

### 2. Description of the Related Art

In a fine processing using a resist composition, ultrafine patterns have been required to be formed as integrated circuits have been highly integrated. Accordingly, exposure wavelengths tend to be shortened, for example, from g-line to i-line and to excimer laser light, and furthermore, at present, development of lithography technology using electron beams, for example, is in progress.

Here, since it is extremely difficult to find an appropriate combination of a resin, a photoacid generator, a basic compound, an additive, a solvent, and the like to be used from the viewpoint of the comprehensive performance of a resist composition, a technique for forming a high-precision pattern by subjecting a substrate to a specific treatment before applying the resist composition onto the substrate is known, not from the viewpoint of selection of a resist composition.

For example, a method in which a mask blank is washed with a resist solvent in a resist application device, immediately before application of a resist (see JP1991-20744A (JP-H03-20744A)), or a method for forming a pattern of a chemical amplification-type negative tone resist is formed on a substrate, in which the surface of a substrate is treated with an acid or an acid generator before applying the resist (see JP1992-338959A (JP-H04-338959A)) is known.

### SUMMARY OF THE INVENTION

However, particularly, taking a recent demand for formation of an ultrafine pattern (for example, a pattern with a line width of 50 nm or less) with high performance into consideration, it cannot be said that the current situation is sufficient, yet.

In particular, in a case of patterning into a photomask blank, a light shielding film including a heavy atom such as chromium, molybdenum, and tantalum is present in the underlayer of a resist film, but the adhesiveness of the resist film to the light shielding film is not high.

Furthermore, particularly in the formation of a negative tone pattern, the cross-sectional shape of the pattern is likely to be an undercut shape (a narrow shape formed in the vicinity of a substrate), and thus, pattern collapse easily occurs. As a result, there has been a problem that it is difficult to obtain high resolution. In addition, particularly in the formation of a positive tone pattern, there has been a problem that residue defects easily occur. Further, such inconvenience has been remarkable, particularly in the formation of an ultrafine pattern.

The present invention has been made, taking the above problems into consideration, and has an object to provide a pre-rinsing liquid capable of forming a pattern excellent in a sensitivity, the cross-sectional shape of a pattern, a resolution, and residue defect performance, particularly in the formation of an ultrafine pattern (for example, a pattern with a line width of 50 nm or less); and a pre-rinsing treatment method and a pattern forming method, each using the same.

The present invention has the following configuration, whereby the above problems of the present invention are solved.

[1] A pre-rinsing liquid used in a method including forming a resist film including an actinic ray-sensitive or radiation-sensitive composition on a substrate, and irradiating the resist film with actinic rays or radiation to form a pattern on the substrate, and used for subjecting the substrate to a pre-rinsing treatment before applying the actinic ray-sensitive or radiation-sensitive composition onto the substrate, in which the pre-rinsing liquid satisfies the following conditions (1) and (2):

(1) the pre-rinsing liquid includes 80% by mass or more of an organic solvent with respect to the total mass of the pre-rinsing liquid, and

(2) the organic solvent is at least one organic solvent selected from the group consisting of alcohols, cyclic ethers, glycol ethers, glycol ether acetates, hydrocarbons, ketones, lactones, and esters.

[2] The pre-rinsing liquid as described in [1], for manufacturing a mask blank, in which the substrate is a mask blank.

[3] The pre-rinsing liquid as described in [1] or [2], comprising an organic solvent having a ClogP of −0.2 or more as the organic solvent.

[4] The pre-rinsing liquid as described in any one of [1] to [3], comprising an acid or a compound that produces an acid by heat.

[5] The pre-rinsing liquid as described in [4], in which the pKa of the acid, or an acid produced from the compound by heat is −5 or more.

[6] The pre-rinsing liquid as described in [4] or [5], in which the molecular weight of the acid, or an acid produced from the compound by heat is 1,000 or less.

[7] The pre-rinsing liquid as described in any one of [4] to [6], in which the content of the acid, or the compound that produces an acid by heat is from 0.01% by mass to 19.99% by mass with respect to the total mass of the pre-rinsing liquid.

[8] The pre-rinsing liquid as described in any one of [1] to [7], in which the pattern is a negative tone pattern.

[9] The pre-rinsing liquid as described in any one of [1] to [7], in which the pattern is a positive tone pattern.

[10] A pre-rinsing treatment method comprising washing and hydrophobizing the surface of a substrate before applying an actinic ray-sensitive or radiation-sensitive composition thereonto with the pre-rinsing liquid as described in any one of [1] to [9].

[11] A pattern forming method comprising the pre-rinsing treatment method as described in [10].

[12] The pattern forming method as described in [11], in which the substrate is a mask blank, and a pattern is formed on the mask blank.

[13] The pattern forming method as described in [11] or [12], in which a negative tone pattern is formed after carrying out the pre-rinsing treatment method as described in [10].

[14] The pattern forming method as described in [11] or [12], in which a positive tone pattern is formed after carrying out the pre-rinsing treatment method as described in [10].

According to the present invention, it is possible to provide a pre-rinsing liquid capable of forming a pattern excellent in a sensitivity, the cross-sectional shape of a pattern, a resolution, and residue defect performance, particularly in the formation of an ultrafine pattern (for example, a pattern with a line width of 50 nm or less); and a pre-rinsing treatment method and a pattern forming method, each using the same.

### DESCRIPTION OF THE PREFERRED EMBODIMENTS

Hereinafter, aspects for carrying out the present invention will be described in detail.

Furthermore, in citations for a group (atomic group) in the present specification, in a case where the group is denoted without specifying whether it is substituted or unsubstituted, the group includes both a group not having a substituent and a group having a substituent. For example, an “alkyl group” includes not only an alkyl group not having a substituent (unsubstituted alkyl group), but also an alkyl group having a substituent (substituted alkyl group).

In the present invention, “actinic rays” or “radiation” means, for example, a bright line spectrum of a mercury lamp, far ultraviolet rays represented by an excimer laser, extreme ultraviolet rays (EUV light), X-rays, electron beams, or the like. In addition, in the present invention, “light” means actinic rays or radiation. Unless otherwise specified, “exposure” in the present specification includes not only exposure by a mercury lamp, far ultraviolet rays represented by an excimer laser, X-rays, EUV light, or the like, but also writing by particle rays such as electron beams or ion beams.

The pre-rinsing liquid according to the present invention is a pre-rinsing liquid used in a method including forming a resist film including an actinic ray-sensitive or radiation-sensitive composition on a substrate, irradiating the resist film with actinic rays or radiation to form a pattern on the substrate, and used for subjecting the substrate to a pre-rinsing treatment before applying the actinic ray-sensitive or radiation-sensitive composition onto the substrate, in which the pre-rinsing liquid satisfies the following conditions (1) and (2):

(1) the pre-rinsing liquid includes 80% by mass or more of an organic solvent with respect to the total mass of the pre-rinsing liquid, and

(2) the organic solvent is at least one organic solvent selected from the group consisting of alcohols, cyclic ethers, glycol ethers, glycol ether acetates, hydrocarbons, ketones, lactones, and esters.

Here, the pre-rinsing liquid refers to a rinsing liquid provided for the purpose of washing and hydrophobizing the surface of a substrate before applying an actinic ray-sensitive or radiation-sensitive composition thereonto, and it is not required to use the rinsing liquid in later steps (development during pattern formation, and the like).

The reason why a pattern is excellent in a sensitivity, the cross-sectional shape of a pattern, a resolution, and residue defect performance, particularly in the formation of an ultrafine pattern (for example, a pattern with a line width of 50 nm or less) can be formed by the above-described pre-rinsing liquid of the present invention is not clear, but is presumed as follows.

First, since the surface of a substrate represented by a light shielding film or the like in a silicone substrate or a photomask blank has high hydrophilicity, particularly in order to form an ultrafine pattern favorably, there have been problems that a sufficient adhesiveness between a substrate and a resist film is not obtained, and the pattern is thus peeled. On the other hand, the present inventors have conducted extensive studies, and as a result, they have found that by reducing the hydrophilicity (increasing of the hydrophobicity) of a surface of the substrate, the adhesiveness between the substrate and the resist film is increased, and thus, generation of pattern collapse can be suppressed, that is, resolution can be improved.

Moreover, the present inventors have found that a lot of impurities (particularly an amine component) considered to be attached during a process for producing the substrate or the like are present on the surface of the substrate, and thus, due to the presence of the amine component, in the formation of a negative tone pattern, the cross-sectional shape of the obtained pattern is easily in an undercut shape, and in the formation of a positive tone pattern, residue defects easily occur. This phenomenon is presumed to be caused by the fact that in the bottom portion of an exposed area near to the surface of the substrate, an acid generated from an acid generator is easily inactivated by the amine component present on the surface of the substrate, and thus, it becomes difficult for desired reactions to proceed. Further, such phenomenon was found to be apparent, particularly in the formation of an ultrafine pattern. Moreover, since the amine component has an effect of reducing resist sensitivity, it is rather preferable to remove the amine component for high productivity in the formation of a pattern. In addition, in order to form a pattern with high reproductivity, it is preferable to maintain the amount of the amine component attached to the surface of the substrate to a certain amount, remove the amine component, neutralize the amine component, or the like.

Based on these findings, the present inventors have conducted studies on methods for solving the problems, and as a result, they have found that the problems are solved by a pre-rinsing liquid satisfying the conditions of (1) and (2).

This is thought to be due to the fact that first, by making the pre-rinsing liquid satisfy the condition (1), that is, by enhancing the purity of the organic solvent in the pre-rinsing liquid, a treatment for providing the pre-rinsing liquid onto the surface of the substrate suppresses undesired components from remaining on the surface of the substrate, and impurities on the surface of the substrate have been reliably removed.

In addition, it is thought to be due to the fact that by making the pre-rinsing liquid satisfy the condition (2), that is, by incorporating a specific organic solvent thereinto, a treatment for providing the pre-rinsing liquid onto the surface of the substrate provides the substrate with hydrophobicity, the adhesiveness between a substrate and a resist film has been improved.

Examples of the alcohols in the organic solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, cyclohexyl alcohol, n-heptyl alcohol, n-octyl alcohol, and n-decanol; and glycols such as ethylene glycol, diethylene glycol, triethylene glycol, and propylene glycol.

Examples of the cyclic ethers include dioxane, tetrahydrofuran, and phenetole.

Examples of the glycol ethers include ethylene glycol monomethyl ether, propylene glycol monomethyl ether (PGME, alternative name: 1-methoxy-2-propanol), propylene glycol dimethyl ether, ethylene glycol monoethyl ether, ethylene glycol dibutyl ether, propylene glycol monoethyl ether, diethylene glycol monomethyl ether, triethylene glycol monoethyl ether, and methoxymethylbutanol.

Examples of the glycol ether acetates include propylene glycol monomethyl ether acetate (PGMEA, alternative name: 1-methoxy-2-acetoxypropane), ethylene glycol monoethyl ether acetate, diethylene glycol monobutyl ether acetate, and diethylene glycol monoethyl ether acetate.

Examples of the hydrocarbons include aromatic hydrocarbons such as toluene and xylene, and aliphatic hydrocarbons such as pentane, hexane, heptane, octane, nonane, decane, and undecane.

Examples of the ketones include 1-octanone, 2-octanone, 1-nonanone, 2-nonanone, acetone, 3-pentanone, 2-heptanone (methyl amyl ketone), 4-heptanone, 1-hexanone, 2-hexanone, diisobutyl ketone, cyclohexanone, methylcyclohexanone, cyclopentanone, ethyl cyclopentanone-2-carboxylate, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the lactones include γ-butyrolactone, α-acetyl-γ-butyrolactone, α-hydroxy-γ-butyrolactone, and D-glucuronolactone.

Examples of the esters include methyl acetate, butyl acetate, ethyl acetate, propyl acetate, isopropyl acetate, pentyl acetate, isopentyl acetate, amyl acetate, hexyl butyrate, cyclohexyl acetate, isobutyl isobutyrate, ethyl-3-ethoxypropionate, 3-methoxybutylacetate, 3-methyl-3-methoxybutyl acetate, methyl formate, ethyl formate, butyl formate, propyl formate, ethyl lactate, butyl lactate, propyl lactate, propyl carbonate, dimethyl carbonate, diethyl carbonate, ethyl pyruvate, and 2-ethoxyethyl acetate, 2-(2-ethoxyethoxy)ethyl acetate.

Suitable examples of the organic solvent in the pre-rinsing liquid include propylene glycol monomethyl ether acetate, propylene glycol monomethyl ether, ethylene glycol monoethyl ether acetate, cyclohexanone, cyclopentanone, lactic acid ethyl, γ-butyrolactone, propylene glycol dimethyl ether, ethylene glycol dibutyl ether, sec-butyl alcohol, n-hexyl alcohol, cyclohexyl alcohol, propylene glycol, 3-pentanone, 2-heptanone, 4-heptanone, ethyl cyclopentanone-2-carboxylate, propyl acetate, butyl acetate, pentyl acetate, hexyl butyrate, heptane, nonane, undecane, propyl carbonate, dimethyl carbonate, diethyl carbonate, ethyl 3-ethoxypropionate, ethyl pyruvate, 2-ethoxyethyl acetate, and 2-(2-ethoxyethoxy)ethyl acetate.

The pre-rinsing liquid preferably contains an organic solvent having a ClogP of −0.2 or more as the organic solvent. The organic solvent preferably has a ClogP of 0.1 or more, and preferably 0.5 or more. The ClogP is usually 7.00 or less.

Here, the ClogP value is a value calculated by ChemDraw Ultra ver. 12.0. 2. 1076 (Cambridge corporation) with regard to a compound representing an organic solvent.

Examples of the organic solvent having a ClogP of −0.2 or more include propylene glycol monomethyl ether acetate, lactic acid ethyl, cyclohexanone, ethylene glycol monoethyl ether acetate, cyclopentanone, propylene glycol dimethyl ether, ethylene glycol dibutyl ether, 3-pentanone, 2-heptanone, 4-heptanone, ethyl cyclopentanone-2-carboxylate, propyl acetate, butyl acetate, pentyl acetate, hexyl butyrate, heptane, nonane, undecane, dimethyl carbonate, diethyl carbonate, and ethyl 3-ethoxypropionate.

The content of the organic solvent having a ClogP of −0.2 or more is preferably 20% by mass or more, more preferably 50% by mass or more, and still more preferably 80% by mass or more, with respect to the total amount of the pre-rinsing liquid.

The solvents may be used singly or in mixture of a plurality thereof, or may also be used in a mixture with another solvent or water.

Here, the pre-rinsing liquid includes an organic solvent in an amount of 80% by mass or more with respect to the total mass of the pre-rinsing liquid, as described in the condition (1). If the pre-rinsing liquid includes the organic solvent in an amount of less than 80% by mass or more with respect to the total mass of the pre-rinsing liquid, undesired components easily remain on the surface of the substrate after washing the substrate, and thus, in particular, desired reactions hardly proceed in the bottom portion of an exposed area near to the substrate, which thus tends to have an influence on the formation of a pattern. Accordingly, in order to sufficiently obtain the effect of the present invention, it is necessary for the pre-rinsing liquid to include the organic solvent in the amount of 80% by mass or more with respect to the total mass of the pre-rinsing liquid.

The pre-rinsing liquid includes the organic solvent in the amount of preferably from 80% by mass to 100% by mass, and more preferably from 90% by mass to 100% by mass or less, with respect to the total mass of the pre-rinsing liquid.

In a case where the pre-rinsing liquid contains components other than organic solvents such as an acid, and a compound that produces an acid by heat which will be described later, the pre-rinsing liquid includes the organic solvent in the amount of preferably from 80% by mass to 99.99% by mass, and more preferably from 90% by mass to 99.7% by mass, with respect to the total mass of the pre-rinsing liquid.

The moisture content of the pre-rinsing liquid is preferably 10% by mass or less, more preferably 5% by mass or less, and particularly preferably 3% by mass or less, with respect to the total mass of the pre-rinsing liquid. By setting the moisture content to 10% by mass or less, good development characteristics can be obtained by, for example, reliably providing adhesiveness between a substrate and a resist film.

The pre-rinsing liquid preferably contains an acid or a compound that produces an acid by heat. By the incorporation of the compound, the amine component remaining on the surface of the substrate is neutralized, and thus, a problem in an “undercut shape” in the formation of the negative tone pattern, and a problem in “residue defects” in the formation of the positive tone pattern, as described above, can further be reduced, and the resolution and the residue defect performance can further be improved.

The acid that can be contained in the pre-rinsing liquid is not particularly limited, and preferably has a property of being uniformly dissolved in the organic solvent contained in the pre-rinsing liquid.

Suitable examples of such an acid include an inorganic acid, amino acid, and sulfonic acid.

Examples of the inorganic acid include hydrochloric acid, sulfuric acid, nitric acid, carbonic acid, and phosphoric acid.

Examples of the amino acid include glycine, L-alanine, β-alanine, L-2-aminobutyric acid, L-norvaline, L-valine, L-leucine, L-norleucine, L-isoleucine, L-alloisoleucine, L-phenylalanine, L-proline, sarcosine, L-ornithine, L-lysine, taurine, L-serine, L-threonine, L-allothreonine, L-homoserine, L-tyrosine, 3,5-diodo-L-tyrosine, β-(3,4-dihydroxyphenyl)-L-alanine, L-thyroxine, 4-hydroxy-L-proline, L-cysteine, L-methionine, L-ethionine, L-lanthionine, L-cystathionine, L-cystine, L-cysteic acid, L-aspartic acid, L-glutamic acid, S-(carboxymethyl)-L-cysteine, 4-aminobutyric acid, L-asparagine, L-glutamine, azaserine, L-alginine, L-canavanine, L-aitrulline, δ-hydroxy-L-lysine, creatine, L-kynurenine, L-histidine, 1-methyl-L-histidine, 3-methyl-L-histidine, ergothioneine, L-tryptophan, actinomycin C1, apamine, angiotensin I, angiotensin II, and antipain.

Examples of the sulfonic acid include fluoroalkylsulfonic acids such as trifluoromethanesulfonic acid, pentafluoroethanesulfonic acid, heptafluoropropanesulfonic acid, nonafluorobutanesulfonic acid, dodecafluoropentanesulfonic acid, tridecafluorohexanesulfonic acid, pentadecafluoroheptanesulfonic acid, heptadecafluorooctanesulfonic acid, octadecafluorononanesulfonic acid, fluoromethanesulfonic acid, difluoromethanesulfonic acid, 1,1-difluoroethanesulfonic acid, 2,2,2-trifluoroethanesulfonic acid, 1,1-difluoropropanesulfonic acid, 1,1,2,2-tetrafluoropropanesulfonic acid, 3,3,3-trifluoropropanesulfonic acid, 2,2,3,3,4,4,4-heptafluorobutanesulfonic acid, and 3,3,4,4,4-pentafluorobutanesulfonic acid, alkylsulfonic acids such as methanesulfonic acid, ethanesulfonic acid, propanesulfonic acid, isopropanesulfonic acid, butanesulfonic acid, isobutanesulfonic acid, 1,1-dimethylethanesulfonic acid, pentanesulfonic acid, 1-methylbutanesulfonic acid, 2-methylbutanesulfonic acid, 3-methylbutanesulfonic acid, neopentanesulfonic acid, hexanesulfonic acid, heptanesulfonic acid, octanesulfonic acid, nonanesulfonic acid, and decanesulfonic acid, arylsulfonic acids such as benzenesulfonic acid, 2-toluenesulfonic acid, 3-toluenesulfonic acid, 4-toluenesulfonic acid, 4-ethylbenzenesulfonic acid, 4-propylbenzenesulfonic acid, 4-butylbenzenesulfonic acid, 4-(t-butyl)benzenesulfonic acid, 2,5-dimethylbenzenesulfonic acid, 2-mesithylenesulfonic acid, 2,4-dinitrobenzenesulfonic acid, 4-chlorobenzenesulfonic acid, 4-bromobenzenesulfonic acid, 4-fluorobenzenesulfonic acid, 2,3,4,5,6-pentafluorobenzenesulfonic acid, 4-hydroxybenzenesulfonic acid, 4-sulfobenzoic acid, and 4-sulfoaniline, aralkylsulfonic acids such as benzylsulfonic acid and phenethylsulfonic acid, and cyclic sulfonic acids such as camphorsulfonic acid.

The acid which may be contained in the pre-rinsing liquid may be an organic acid other than the above-described acids, and examples of such the organic acid include formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, hydroxyethyliminodiacetic acid, iminodiacetic acid, acetamidoiminodiacetic acid, nitrilotripropanoic acid, nitrilotrimethylphosphonic acid, dihydroxyethylglycine, tricine, and salts thereof such as ammonium salts and alkali metal salts of these acids, or a mixture thereof.

As the compound that produces an acid by heat, which may be contained in the pre-rinsing liquid, any of known thermal acid generators may be adopted and used, and the compound is preferably a thermal acid generator that generates the above-described acid.

The pKa (acid dissociation constant) of the acid, or an acid produced from the compound (thermal acid generator) by heat is preferably −5 or more, more preferably −1 or more, and preferably 2 or more. With this pKa, a reaction due to the action of the acid can be suppressed from proceeding extremely, particularly in the bottom portion of the resist film, near to the surface of the substrate, and the effect of the present invention can be more reliably shown.

Furthermore, there is a possibility that the acid, the compound that produces an acid by heat, or the like which is contained in the pre-rinsing liquid may remain on the surface of the substrate after the pre-rinsing treatment. There is a possibility that the remaining acid or the like, if it is in a state of not being neutralized, may give an effect on the resist film to be applied thereinafter, that is, may cause a reaction such as a deprotection reaction or a crosslinking reaction in the resist film. Accordingly, the remaining acid or the like may be removed by further carrying out a heating treatment and a pre-rinsing treatment with a pre-rinsing liquid not containing an acid or the like after the pre-rinsing treatment. Taking this into consideration, the pKa of the acid, or an acid produced from the compound (thermal acid generator) by heat, which may be contained in the pre-rinsing liquid, is preferably rather high.

On the other hand, if the pKa is extremely high, there is a possibility that the effect from the pre-rinsing treatment may not be sufficiently obtained. Accordingly, the pKa is usually 10 or less.

Here, acid dissociation constant pKa indicates an acid dissociation constant pKa in an aqueous solution, and is described in, for example, Chemical Handbook (II) (Revised 4^{th} Edition, 1993, compiled by the Chemical Society of Japan, Maruzen Inc.), and a lower value thereof indicates higher acid strength. Specifically, the acid dissociation constant pKa in an aqueous solution may be measured by using an infinite-dilution aqueous solution and measuring the acid dissociation constant at 25° C., or a value based on the Hammett substituent constants and the database of publicly known literature value data can also be obtained by computation using the following software package 1. All the values of pKa described in the present specification indicate values determined by computation using this software package.

Software package 1: Advanced Chemistry Development (ACD/Labs) Software V8.14 for Solaris (1994 to 2007 ACD/Labs)

Preferred examples of the acid having a pKa of −5 or more include acetic acid, propionic acid, butyric acid, benzoic acid, carbonic acid, camphorsulfonic acid, and 3-toluenesulfonic acid.

Furthermore, the molecular weight of the acid, or an acid produced from the compound (thermal acid generator) by heat is preferably 1,000 or less, more preferably 500 or less, and still more preferably 300 or less.

The content of the acid, or the compound that produces an acid by heat is preferably from 0.01% by mass to 19.99% by mass, more preferably from 0.05% by mass to 14.99% by mass or less, and still more preferably from 0.2% by mass to 9.99% by mass, with respect to the total mass of the pre-rinsing liquid.

The pre-rinsing liquid may be a surfactant, as desired.

The surfactant is not particularly limited, and for example, an ionic or nonionic, fluorine- and/or silicon-based surfactant can be used. Examples of such a fluorine- and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, with the nonionic surfactant being preferable. The nonionic surfactant is not particularly limited, but the fluorine-based surfactant or the silicon-based surfactant is more preferably used.

The amount of the surfactant to be used is usually 0.001% to 5% by mass, preferably 0.005% to 2% by mass, and more preferably 0.01% to 0.5% by mass, with respect to the total amount of the pre-rinsing liquid.

The present invention also relates to a pre-rinsing treatment method in which the surface of a substrate before applying an actinic ray-sensitive or radiation-sensitive composition thereonto is washed and hydrophobized with the above-described pre-rinsing liquid.

If the surface of the substrate is extremely hydrophobized, problems in cissing of the resist composition during the application of the resist composition, and the like easily occur. Accordingly, the hydrophobization of the surface of the substrate in the present specification typically refers to hydrophobization at a suitable degree in a lithography process (a pattern forming method using a resist composition). That is, the hydrophobization refers to provision of hydrophobicity suitable for coatability, adhesiveness, resolution, or defect performance of the resist composition. For the hydrophobized substrate, the preferred range varies depending on the type of a substrate, the type of a resist, an exposure/drawing mode, a baking condition, or a developing condition, but generally, the contact angle for water is 20° to 80°, and more preferably 30° to 70°.

The pre-rinsing treatment method, that is, the method in which the surface of a substrate is washed and hydrophobized with a pre-rinsing liquid is not particularly limited, but it is possible to apply, for example, a method of continuously discharging a rinsing liquid onto a substrate spinning at a constant speed (a spin coating method), a method of dipping a substrate in a bath filled with a pre-rinsing liquid for a certain period of time (a dip method), a method of spraying a pre-rinsing liquid on the surface of a substrate (a spray method), or the like.

In a case of carrying out the pre-rinsing treatment by the spin coating method, it is preferable that the pre-rinsing liquid is removed from the substrate by rotating the substrate at a rotation speed of 500 rpm to 4,000 rpm after the treatment.

The pre-rinsing treatment time, that is, the time for which the pre-rinsing liquid is provided on the surface of the substrate is appropriately adjusted depending on the type of the above-described method, or the like, and is, for example, but not limited to, within a range of 5 seconds to 3 minutes.

Furthermore, in one aspect, the pre-rinsing treatment method also preferably involves subjecting the substrate to a pre-rinsing treatment with the pre-rinsing liquid of the present invention, and then sufficiently drying the substrate. Examples of the method for drying the substrate include a method in which the substrate is subjected to a pre-rinsing treatment, and then rotated for a certain period of time (for example, 1 minute or longer), a method in which the substrate is rotated (a method in which the substrate is continuously rotated for removing the pre-rinsing liquid), and a method in which the substrate is left to stand.

Moreover, in the pre-rinsing treatment method, a heating treatment may be carried out after washing and hydrophobizing the surface of the substrate with the pre-rinsing liquid. The heating treatment is carried out at usually 40° C. to 250° C., and preferably 70° C. to 200° C., for usually 10 seconds to 20 minutes, and preferably for 30 seconds to 10 minutes.

In a case where the pre-rinsing liquid contains the above-mentioned thermal acid generator, it is preferable to carry out the heating treatment.

In addition, this heating treatment can also be carried out by the above-mentioned method for drying the substrate.

As a substrate provided for the pre-rinsing treatment method, and a material constituting the outermost surface layer, in a case of semiconductor wafers, for example, a silicon wafer may be used, and examples of the material constituting the outermost surface layer include Si, SiO₂, SiN, SiON, TiN, WSi, BPSG, SOG, and an organic antireflection film.

Moreover, the substrate is preferably a mask blank. That is, the pre-rinsing liquid of the present invention is preferably a pre-rinsing liquid for manufacturing a mask blank.

In this case, examples of the mask blank include those in which a light shielding film or the like is laminated on a transparent substrate. More specifically, necessary functional films such as a light shielding film, an antireflection film, and a phase shift film, and additionally, an etching stopper film and an etching mask film are generally laminated on a transparent substrate of quartz, calcium fluoride, or the like. As the material of the functional film, a film containing silicon, or transition metals such as chromium, molybdenum, zirconium, tantalum, tungsten, titanium, and niobium is laminated. Further, examples of the material used in the outermost surface layer include those including a material containing silicon or silicon and oxygen and/or nitrogen as a main constituent material, a silicon compound material including a material containing a transition metal in addition to the foregoing materials as a main constituent material, and a transition metal compound material including a material containing a transition metal, in particular, at least one selected from chromium, molybdenum, zirconium, tantalum, tungsten, titanium, and niobium, and optionally at least one selected from oxygen, nitrogen, and carbon as a main constituent material.

The light shielding film may be a single layer, but is more preferably a multiple layered structure formed by recoating a plurality of materials, one on another. In a case of the multiple layered structure, the layer thickness per one layer is not particularly limited, but is preferably 5 nm to 100 nm, and more preferably 10 nm to 80 nm. The thickness of the entire light shielding material is particularly limited, but is preferably 5 nm to 200 nm, and more preferably 10 nm to 150 nm.

Generally, in a case where a resist film is formed by an actinic ray-sensitive or radiation-sensitive composition on a photomask blank having the outermost surface layer of a mask blank (for example, a photomask blank having a material generally containing oxygen and nitrogen in chromium on the outermost surface layer), and the resist film is exposed to form a pattern, a problem of an undercut shape tends to be remarkable, but in a case of using the pre-rinsing liquid of the present invention, the problem of an undercut shape can be solved as described above.

The pre-rinsing liquid treatment method of the present invention is to hydrophobize the surface of the substrate, and for example, the contact angle for water in the surface of the substrate can be set to 28.00 or more.

The contact angle is more preferably 35.0° or more, and still more preferably 40.0° or more. Further, the contact angle is usually 80.0° or less.

Here, the contact angle for water in the present specification refers to a contact angle at a temperature of 23° C. and a relative humidity of 45%.

Furthermore, the pre-rinsing liquid treatment method of the present invention is to wash the surface of the substrate. Here, basically, a basic material which can remain on the surface of the substrate, that is, the amine component and the like can be a factor of the problem of the present invention, irrespective of the structure or configuration thereof. However, according to the present invention, various basic substances (typically an amine component) which can be a factor of the problem can be removed, and typically, on the surface of the substrate, the secondary ion strength of C₄H₁₂N⁺ in a case of being normalized to the entire ion strength can be set to 0.15 or less.

Moreover, the secondary ion strength of C₄H₁₂N⁺ is more preferably 0.10 or less, and still more preferably 0.05 or less. Further, the secondary ion strength of C₄H₁₂N⁺ is usually 0.001 or more.

Here, it is rather preferable that the amount of the amine component remaining on the surface of the substrate onto which the resist is applied is as small as possible. Particularly, in the task of the present invention, even the amount of the amine component which is no more than the detection limit can give an effect on a general quantitative analysis method.

Quantitative detection of the amine component to be a subject for the task of the present invention is highly difficult, but the present inventors have found that the type of the amine component can be identified by means of TOF-SIMS, and further, the dimension of the amount can be detected with the secondary ion strength.

Accordingly, the secondary ion strength of C₄H₁₂N⁺ of the amine component becomes the secondary ion strength of C₄H₁₂N⁺ normalized to the entire ion strength, as detected with TOF-SIMS.

Such the substrate is suitably obtained by subjecting the substrate to the pre-rinsing treatment method of the present invention as mentioned above.

Furthermore, in one aspect, the substrate is preferably one obtained by subjecting the substrate to the pre-rinsing treatment method of the present invention, followed by sufficiently drying (sufficiently volatilizing the organic solvent in the pre-rinsing liquid). The substrate thus dried is one suitably obtained by subjecting the substrate to the pre-rinsing treatment method of the present invention, followed by leaving it to stand for a certain period of time (for example, 1 minute or ore), carrying out the above-mentioned heating treatment, or the like.

In a view that by this substrate, hydrophobicity suitable for the surface is provided, while the residual amount of the amine component is small, particularly in a case where the substrate is used as a substrate for forming a resist film, it is possible to form a pattern excellent in a sensitivity, the cross-sectional shape of a pattern, a resolution, and residue defect performance, particularly in the formation of an ultrafine pattern (for example, a pattern with a line width of 50 nm or less).

The substrate of the present invention is preferably a substrate for a mask blank.

The pattern forming method of the present invention includes the pre-rinsing treatment method of the present invention as described above.

In the pattern forming method of the present invention, first, the pre-rinsing treatment method is typically carried out, and then an actinic ray-sensitive or radiation-sensitive composition is applied onto the substrate to form a resist film.

The thickness of this resist film is preferably 0.02 to 0.5 μm, more preferably 0.02 to 0.3 μm, and particularly preferably 0.02 to 0.1 μm. The thickness of the resist film can be suitably adjusted for the purpose of adjusting all the performance of the resist, such as dry etching resistance. For the purpose of enhancing the dry etching resistance, the film thickness is preferably high, and is also preferably 0.05 to 0.3 μm.

With regard to a method for applying the actinic ray-sensitive or radiation-sensitive composition onto the substrate, a suitable coating method such as spin coating, roll coating, flow coat, dip coat, spray coat, and doctor coat is used for the application onto a substrate, with the spin coating being preferable. Here, the rotation speed is preferably 1,000 to 3,000 rpm. The coating film is prebaked at 60° C. to 150° C. for 1 to 20 minutes, and preferably at 80° C. to 120° C. for 1 to 10 minutes to form a thin film.

Subsequently, the resist film is irradiated with actinic rays or radiation (electron beams and the like), and preferably baked (at usually 80° C. to 150° C., and preferably 90° C. to 130° C. for usually 1 to 20 minutes, and preferably 1 to 10 minutes), and then developed, thereby obtaining a good pattern. Further, a semiconductor fine circuit, a mold structure for imprinting, a photomask, or the like is manufactured by using the pattern as a mask and properly performing an etching treatment, ion injection, or the like.

Moreover, a process of a case of manufacturing the mold for imprinting, using the composition of the present invention, is described in, for example, JP4109085B, JP2008-162101A, and “Fundamentals of Nanoimprint and Technical Development/Application Deployment-Substrate Technique of Nanoimprint and Latest Application Deployment, edited by Yoshihiko Hirai (Frontier Publishing)”.

The pattern forming method of the present invention is typically a pattern forming method including (i) a step of forming the resist film, (ii) a step of exposing the resist film, and (iii) a step of developing the exposed resist film using a developer to form a pattern, and in one preferred aspect, the pattern forming method in which the substrate is a mask blank and a pattern is formed on the mask blank. In this case, the pattern forming method of the present invention typically has a step of exposing a mask blank (resist-applied mask blank) including the resist film, and a step of developing the exposed resist-applied mask blank using a developer to form a pattern.

In the exposure, the wavelength of a light source used for the exposure device is not limited, but examples thereof include infrared light, visible light, ultraviolet light, far ultraviolet light, extreme ultraviolet light (EUV light), X-rays, and electron beams, preferably far ultraviolet light having a wavelength of 250 nm or less, and more preferably far ultraviolet light having a wavelength of 220 nm or less, and particularly preferably 1 to 200 nm, and specifically, KrF excimer laser (248 nm), ArF excimer laser (193 nm), F₂ excimer laser (157 nm), X-rays, EUV light (13 nm), and electron beams, examples of which include KrF excimer laser, ArF excimer laser, EUV light, and electron beams.

In the present invention, the exposure is preferably carried out using X-rays, electron beams, or EUV light.

In the manufacture of a precise integrated circuit element, or the like, patternwise exposure onto a resist film (a pattern forming step) is preferably carried out in the first place with electron beams or extreme ultraviolet light on the resist film of the present invention. Exposure is carried out so that the exposure dose reaches usually 0.1 to 20 μC/cm² or so, and preferably 3 to 10 μC/cm² or so, in a case of electron beams, usually 0.1 to 20 mJ/cm² or so, and preferably 3 to 15 mJ/cm² or so, in a case of extreme ultraviolet light. Then, post-exposure heating (post-exposure baking) is carried out on a hot plate at 60° C. to 150° C. for 1 to 20 minutes, and preferably at 80° C. to 120° C. for 1 to 10 minutes, and then development, rinsing, and drying were carried out to form a resist pattern.

The exposure is preferably carried out via a mask, and particularly, for the mask, a light shielding band that suppresses undesired reflection of EUV light may be disposed in the pattern periphery, and fine convex and concave may be provided on the engraved bottom of the light shielding band. By using such the mask, “out-of-band light” can be suppressed to form a circuit pattern.

As the developer, an alkali developer, or a developer including an organic solvent (hereinafter also referred to as an organic developer) can be used.

Examples of the alkali developer include an alkaline aqueous solution including inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide, tetraethylammonium hydroxide, or cyclic amines such as pyrrole and piperidine.

An appropriate amount of alcohols and/or surfactants may be added to the alkali developer.

The concentration of the alkali developer is usually 0.1% to 20% by mass. The pH of the alkali developer is usually 10.0 to 15.0.

The developer is an alkali aqueous solution of tetramethylammonium hydroxide (TMAH), tetrabutylammonium hydroxide (TBAH), or the like at a concentration of preferably 0.1% to 5% by mass, more preferably 2% to 3% by mass, and is developed according to an ordinary method such as a dip method, a puddle method, and a spray method for preferably 0.1 to 3 minutes, and more preferably 0.5 to 2 minutes. An appropriate amount of alcohols and/or surfactants may be added to the alkali developer. The pH of the alkali developer is usually 10.0 to 15.0. In particular, a 2.38%-by-mass aqueous solution of tetramethylammoniumhydroxide is preferable.

As the organic developer, a polar solvent such as a ketone-based solvent, an ester-based solvent, an alcohol-based solvent, an amide-based solvent, and an ether-based solvent, and a hydrocarbon-based solvent can be used.

In the present invention, the ester-based solvent is a solvent having an ester group in the molecule thereof, the ketone-based solvent is a solvent having a ketone group in the molecule thereof, the alcohol-based solvent is a solvent having an alcoholic hydroxyl group in the molecule thereof, the amide-based solvent is a solvent having an amido group in the molecule thereof, and the ether-based solvent is a solvent having an ether bond in the molecule thereof. Among these, a solvent having a plurality of functional groups described above in one molecule may also be present, but in this case, it is assumed that the solvent also corresponds to any solvent type including the functional group which the solvent has. For example, it is assumed that diethylene glycol monomethyl ether also corresponds to any of the alcohol-based solvent, or the ether-based solvent, in the above classification. In addition, the hydrocarbon-based solvent is a hydrocarbon solvent having no substituent.

In particular, a developer containing at least one kind of solvent selected from a ketone-based solvent, an ester-based solvent, an alcohol-based solvent, and an ether-based solvent is preferable.

Examples of these solvents include the solvents described in paragraphs [0025] to [0048] of JP2013-80004A.

In a case of using extreme ultraviolet light (EUV light) or electron beams (EB) in the exposing step, the developer preferably uses an ester-based solvent having 7 or more carbon atoms (preferably 7 to 14 carbon atoms, more preferably 7 to 12 carbon atoms, and still more preferably 7 to 10 carbon atoms) and 2 or less heteroatoms in a view that swelling of the resist film can be suppressed.

Examples of the heteroatom of the ester-based solvent include an oxygen atom, a nitrogen atom, and a sulfur atom as an atom other than a carbon atom and a hydrogen atom. The number of heteroatoms is preferably 2 or less.

Examples of the ester-based solvent having 7 or more carbon atoms and 2 or less heteroatoms include amyl acetate, isoamyl acetate, 2-methylbutyl acetate, 1-methylbutyl acetate, hexyl acetate, pentyl propionate, hexyl propionate, butyl propionate, isobutyl isobutyrate, heptyl propionate, and butyl butanoate, and isoamyl acetate is particularly preferably used.

In a case of using extreme ultraviolet light or electron beams in the exposing step, the developer may use a mixed solvent of the ester-based solvent and the hydrocarbon-based solvent, or a mixed solvent of the ketone-based solvent and the hydrocarbon solvent, instead of the above-mentioned ester-based solvent having 7 or more carbon atoms and 2 or less heteroatoms. Also, this case is effective for suppression of the swelling of the resist film.

In a case of the ester-based solvent and the hydrocarbon-based solvent in combination, isoamyl acetate is preferably used as the ester-based solvent. Further, from the viewpoint of adjusting the solubility of the resist film, a saturated hydrocarbon solvent (for example, octane, nonane, decane, dodecane, undecane, and hexadecane) is preferably used as the hydrocarbon-based solvent.

In a case of the ketone-based solvent and the hydrocarbon-based solvent in combination, 2-heptanone is preferably used as the ketone-based solvent. Further, from the viewpoint of adjusting the solubility of the resist film, a saturated hydrocarbon solvent (for example, octane, nonane, decane, dodecane, undecane, and hexadecane) is preferably used as the hydrocarbon-based solvent.

In a case of using the above mixed solvents, the content of the hydrocarbon-based solvent depends on the solubility of the resist film in the solvent, and thus, it is not particularly limited and the required amount thereof may be determined by appropriate adjustment.

The organic developer may include a basic compound. Specific examples and preferred examples of the basic compound which can be included in the developer used in the present invention are the same as the basic compounds which can be used in the actinic ray-sensitive or radiation-sensitive composition which will be described later.

The moisture content of the entirety of the developer is preferably less than 10% by mass, and more preferably the developer substantially does not contain moisture.

That is, the amount of the organic solvent to be used with respect to the organic developer is preferably from 90% by mass to 100% by mass, and more preferably from 95% by mass to 100% by mass, with respect to the total amount of the developer.

An appropriate amount of alcohols and/or surfactants may be added to the developer, as desired.

The surfactant is not particularly limited, and for example, an ionic or nonionic, fluorine- and/or silicon-based surfactant can be used. Examples of such a fluorine- and/or silicon-based surfactant include surfactants described in JP 1987-36663A (JP-S62-36663A), JP1986-226746A (JP-S61-226746A), JP1986-226745A (JP-S61-226745A), JP1987-170950A (JP-S62-170950A), JP 1988-34540A (JP-S63-34540A), JP 1995-230165A (JP-H07-230165A), JP 1996-62834A (JP-H08-62834A), JP1997-54432A (JP-H09-54432A), JP1997-5988A (JP-H09-5988A), and U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A, with the nonionic surfactant being preferable. The nonionic surfactant is not particularly limited, but the fluorine-based surfactant or the silicon-based surfactant is more preferably used.

The amount of the surfactant to be used is usually 0.001% to 5% by mass, preferably 0.005% to 2% by mass, and more preferably 0.01% to 0.5% by mass, with respect to the total amount of the developer.

Examples of the developing method include a method in which a substrate is immersed in a tank filled with a developer for a certain period of time (a dip method), a method in which a developer is heaped up to the surface of a substrate by surface tension and developed by stopping for a certain period of time (a paddle method), a method in which a developer is sprayed on the surface of a substrate (a spray method), and a method in which a developer is continuously discharged on a substrate rotated at a constant rate while scanning a developer discharging nozzle at a constant rate (a dynamic dispense method).

In a case where the various developing methods include a step of discharging a developer toward a resist film from a developing nozzle of a developing device, the discharge pressure (flow rate per unit area of the developer to be discharged) of the developer to be discharged is preferably 2 mL/sec/mm² or less, more preferably 1.5 mL/sec/mm² or less, and still more preferably 1 mL/sec/mm² or less. The lower limit of the flow rate is not particularly limited, but is preferably 0.2 mL/sec/mm² or more, taking a throughput into consideration.

By setting the discharge pressure of the developer to be discharged to the above range, the defects of the pattern resulting from resist residues after development can be significantly reduced.

Details of the mechanism are not clear, but it is considered that this is probably due to the fact that the pressure applied to the resist film by the developer decreases by setting the discharge pressure within the above range, or unexpected scraping or collapsing of the resist film and/or the pattern is suppressed.

In addition, the discharge pressure (mL/sec/mm²) of a developer is a value at the developing nozzle exit in the developing device.

Examples of the method of adjusting the discharge pressure of a developer include a method of adjusting the discharge pressure using a pump and a method of adjusting the pressure by supply from a pressure tank.

In addition, after the step of carrying out development using a developer, a step of stopping the development with replacement with another solvent may be carried out.

With regard to the rinsing liquid in the rinsing treatment performed after the alkali development, pure water is used, and the pure water may be also used after adding an appropriate amount of a surfactant thereto.

In a case where the developer is an organic developer, as the rinsing liquid, a rinsing liquid containing at least one kind of organic solvent selected from the group consisting of a ketone-based solvent, an ester-based solvent, an alcohol-based solvent, an amide-based solvent, and a hydrocarbon solvent.

The vapor pressure (total vapor pressure in a case of a mixed solvent) of the rinsing liquid is preferably from 0.05 kPa to 5 kPa, more preferably from 0.1 kPa to 5 kPa, and most preferably from 0.12 kPa to 3 kPa, at 20° C. By setting the vapor pressure of the rinsing liquid to from 0.05 kPa to 5 kPa, the temperature evenness within a wafer plane is enhanced and the swelling due to the permeation of the rinsing liquid is suppressed, whereby the dimensional evenness within a wafer plane is improved.

Examples of the rinsing liquid include the solvents described in [0049] to [0058] of JP2013-80004A.

In a case of using extreme ultraviolet light (EUV light) or electron beams (EB) in the exposing step, as the organic solvent included in the rinsing liquid, a hydrocarbon-based solvent is preferably used among the above organic solvents, and an aliphatic hydrocarbon-based solvent is more preferably used. As the aliphatic hydrocarbon-based solvent used in the rinsing liquid, an aliphatic hydrocarbon-based solvent having 5 or more carbon atoms (for example, pentane, hexane, octane, decane, undecane, dodecane, and hexadecane) is preferable, an aliphatic hydrocarbon-based solvent having 8 or more carbon atoms is preferable, and an aliphatic hydrocarbon-based solvent having 10 or more carbon atoms is more preferable, from the viewpoint that the effect is more improved.

Furthermore, the upper limit value of the number of carbon atoms of the aliphatic hydrocarbon-based solvent is not particularly limited, but it may be, for example, 16 or less, is preferably 14 or less, and more preferably 12 or less.

Among the aliphatic hydrocarbon-based solvents, decane, undecane, or dodecane is particularly preferable, and undecane is most preferable.

By using the hydrocarbon-based solvent (particularly an aliphatic hydrocarbon-based solvent) as the organic solvent included in the rinsing liquid as above, an effect in which the developer slightly soaked into the resist film is washed away after the development, the swelling is further suppressed, and the pattern collapse is suppressed is further exhibited.

A plurality of the organic solvents may be used in mixture or the organic solvent may be used in combination with a solvent other than the solvent described above. The solvents described above may be mixed with water, and the moisture content in the rinsing liquid is usually 60% by mass or less, preferably 30% by mass or less, more preferably 10% by mass or less, and most preferably 5% by mass or less. By setting the moisture content to 60% by mass or less, good rinsing characteristics can be obtained.

The rinsing liquid preferably contains a surfactant. Thus, the wettability for the resist film is improved, and thus, the washing effect tends to be further improved.

As the surfactant, the same surfactant as that used in the actinic ray-sensitive or radiation-sensitive composition can be used.

The content of the surfactant is usually 0.001% to 5% by mass, preferably 0.005% to 2% by mass, and more preferably 0.01% to 0.5% by mass, with respect to the total mass of the rinsing liquid.

In the pattern forming method of the present invention, a step of performing development using an alkali aqueous solution (alkali developing step) and a step of performing development using a developer including an organic solvent (organic solvent developing step) may be used in combination. By such the combined use, a finer pattern can be formed.

In the present invention, a portion having a weak exposure intensity is removed by development using an organic solvent, and a portion having a strong exposure intensity is also removed by carrying out development using an alkali developer. Since pattern formation is carried out without dissolving only a region having an intermediate exposure intensity by a multiple development process in which such development is carried out plural times in this manner, a finer pattern than usual can be formed (the same mechanism as that in paragraph [0077] of JP2008-292975A).

In the pattern forming method of the present invention, the sequence of the alkali developing step and the organic solvent developing step is not particularly limited, but it is more preferable that alkali development is carried out before the organic solvent developing step.

Furthermore, for the pattern forming method in the present invention, a topcoat may be formed on the upper layer of the resist film. The topcoat is preferably one that is not mixed with the resist film and can be uniformly coated on the upper layer of the resist film.

The topcoat is not particularly limited, a topcoat known in the related art can be formed by a method known in the related art, and can be formed according to, for example, the description in paragraphs [0072] to [0082] of JP2014-059543A.

In a case of using a developer containing an organic solvent, it is preferable that a topcoat containing the basic compound described in JP2013-61648A is formed on a resist film.

The pattern forming method of the present invention may be either a method in which a pre-rinsing treatment method is carried out, and then a negative tone pattern is formed, or a method in which a pre-rinsing treatment method is carried out, and then a positive tone pattern is formed. Either of the negative tone pattern and the positive tone pattern is to be formed can be selected by appropriately combining the actinic ray-sensitive or radiation-sensitive composition with the developer.

Accordingly, the present invention further relates to a pre-rinsing liquid for forming a negative tone pattern, in which the pattern formed by the pattern forming method is a negative tone pattern.

Furthermore, the present invention still further relates to a pre-rinsing liquid for forming a negative tone pattern, in which the pattern formed by the pattern forming method is a positive tone pattern.

As the organic solvent (hereinafter also referred to as an “organic treatment liquid”) which can be used in the pre-rinsing liquid, the developer, and the rinsing liquid, an organic solvent preserved in a housing container of an organic treatment liquid for patterning of a chemical amplification-type resist film, having the housing section is preferably used. The housing container is preferably for example, a housing container of an organic treatment liquid for patterning of a chemical amplification-type resist film, in which the inner wall in contact with an organic treatment liquid of the housing section is formed from a resin different from a polyethylene resin, a polypropylene resin, and a polyethylene-polypropylene resin, or a metal which has been subjected to a rust-preventing/metal elution-preventing treatment. An organic solvent that is supposed to be used as an organic treatment liquid for patterning of a chemical amplification-type resist film is contained in the housing section of the housing container, and then discharged from the housing section upon the patterning of the chemical amplification-type resist film can be used.

In a case where the housing container further has a sealing portion for sealing the housing section, the sealing portion is preferably formed of a resin different from at least one resin selected from the group consisting of a polyethylene resin, a polypropylene resin, and a polyethylene-polypropylene resin, or a metal which has been subjected to a rust-preventing/metal elution-preventing treatment.

Here, the sealing portion means a member capable of shielding the housing section from an outside air, and suitable examples thereof include a packing and an O-ring.

The resin different from at least one resin selected from a polyethylene resin, a polypropylene resin, and a polyethylene-polypropylene resin is preferably a perfluoro resin.

Examples of the perfluoro resin include a tetrafluoroethylene resin (PTFE), a tetrafluoroethylene-perfluoroalkylvinyl ether copolymer (PFA), a tetrafluoroethylene-hexafluoropropylene copolymer resin (FEP), a tetrafluoroethylene-ethylene copolymer resin (ETFE), a chlorotrifluoroethylene-ethylene copolymer resin (ECTFE), a polyvinylidene resin (PVDF), a polychlorotrifluoroethylene copolymer resin (PCTFE), and a polyvinyl fluoride resin (PVF).

Particularly preferred examples of the perfluoro resin include a tetrafluoroethylene resin, a tetrafluoroethylene-perfluoroalkylvinyl ether copolymer, and a tetrafluoroethylene-hexafluoropropylene copolymer resin.

Examples of the metal which has been subjected to the rust-preventing/metal elution-preventing treatment include carbon steel, alloy steel, nickel-chrome steel, nickel chrome molybdenum steel, chrome steel, chrome molybdenum steel, and manganese steel.

As the rust-preventing/metal elution-preventing treatment, a coating technique is preferably applied.

The coating technique is largely divided into three kinds of coatings such as metal coating (various platings), inorganic coating (various chemical conversion treatments, glass, concrete, ceramics, and the like) and organic coating (rust preventive oil, paint, rubber, and plastics).

Preferred examples of the coating technique include a surface treatment using a rust-preventing oil, a rust inhibitor, a corrosion inhibitor, a chelate compound, a peelable plastic, or a lining agent.

Among those, various corrosion inhibitors such as chromate, nitrite, silicate, phosphate, carboxylic acids such as oleic acid, dimer acid, and naphthalenic acid, a carboxylic acid metallic soap, sulfonate, an amine salt, esters (a glycerin ester or a phosphate ester of a higher fatty acid), chelate compounds such as ethylenediaminetetraacetic acid, gluconic acid, nitrilotriacetic acid, hydroxyethylethylenediaminetriacetic acid, and diethylenetriaminepentaacetic acid, and a fluorine resin lining are preferable. The phosphate treatment and the fluorine resin lining are particularly preferable.

Furthermore, a “pre-treatment” which is at a pre-stage for the rust-preventing treatment is also preferably employed as a treatment method which leads to extension of an anti-rust period through a coating treatment although not directly preventing rust, as compared with a direct coating treatment.

Suitable specific examples of such a pre-treatment include a treatment for removing various corrosive factors, such as chloride and sulfate, present on a metal surface through washing or polishing.

Specific examples of the housing container include the following ones.
FluoroPurePFA complex drum manufactured by Entegris Inc. (liquid contact inner surface; PFA resin lining)
Steel-made drum manufactured by JFE (liquid contact inner surface; zinc phosphate film)

A semiconductor fine circuit, a mold structure for imprinting, a photomask, or the like can be manufactured by using a pattern obtained by the pattern forming method of the present invention as the mask, and appropriately performing an etching treatment, ion injection, or the like.

The pattern forming method of the present invention can also be used in guide pattern formation (see, for example, ACS Nano Vol. 4 No. 8 Pages 4815-4823) in a directed self-assembly (DSA).

In addition, a resist pattern formed by the above-described method can be used as a core in a so-called spacer process disclosed in, for example, JP1991-270227A (JP-H03-270227A) and JP2013-164509A).

It is preferable that various materials (for example, a resist solvent, a developer, a rinsing liquid, a composition for forming an antireflection film, and a composition for forming a topcoat) used in the composition and the pattern forming method of the present invention include no impurities such as a metal. The content of the impurities included in these materials is preferably 1 ppm or less, more preferably 10 ppb or less, still more preferably 100 ppt or less, particularly preferably 10 ppt or less, and most preferably 1 ppt or less. Here, examples of the metal impurities include Na, K, Ca, Fe, Cu, Mg, Al, Li, Cr, Ni, Sn, Ag, As, Au, Ba, Cd, Co, Pb, Ti, V, W, and Zn.

Examples of a method for removing impurities such as metals from various materials include a purification process by filtration using a filter and distillation (in particular, thin-film distillation and molecular distillation). Examples of the purification process by distillation include those described in “<Factory Operation Series> Enlarged and revised edition, published on Jul. 31, 1992, published by Kagaku Kogyo-sha, and “Chemical Engineering Handbook, published on Sep. 30, 2004, Asakura Shoten, pages 95-102.

In the production of the actinic ray-sensitive or radiation-sensitive composition, it is preferable that the respective components such as a resin and a photoacid generator are dissolved in a resist solvent, and then circulation filtration is performed using a plurality of filters having different materials. For example, it is preferable that a polyethylene-made filter having a pore diameter of 50 nm, a nylon-made filter having a pore diameter 10 nm, and a polyethylene-made filter having a pore diameter of 3 nm are connected in series, and then circulation filtration is performed ten times or more. A smaller difference in the pressure among the filters is more favorable, and is generally 0.1 MPa or less, preferably 0.05 MPa or less, or more preferably 0.01 MPa or less. A smaller in the pressure between the filter and the charge nozzle is more favorable, and is generally 0.5 MPa or less, preferably 0.2 MPa or less and more preferably 0.1 MPa or less.

The inside of a device for producing the actinic ray-sensitive or radiation-sensitive composition is preferably subjected gas replacement using inert gases such as nitrogen. Thus, an active gas such as oxygen is suppressed from being dissolved in the composition.

After being filtered with a filter, the actinic ray-sensitive or radiation-sensitive composition is charged in a clean container. The composition charged in the container is preferably refrigerated. Thus, the temporal performance deterioration is suppressed. A shorter time taken from completing the charging of the composition into the container to starting the refrigeration is more favorable, and the time is generally within 24 hours, preferably within 16 hours, more within 12 hours, and still more preferably within 10 hours. The preservation temperature is preferably 0° C. to 15° C., more preferably 0° C. to 10° C., and still more preferably 0° C. to 5° C.

Moreover, examples of the method for reducing the impurities such as metals included in the various materials include a method of selecting raw materials having a small content of metals as raw materials constituting various materials, a method of subjecting raw materials constituting various materials to filtration using a filter, and a method of performing distillation under the condition for suppressing the contamination as much as possible by, for example, lining the inside of a device with Teflon (registered trademark).

In addition to filtration using a filter, the removal of impurities by an adsorbing material may be carried out, or a combination of filtration using a filter and an adsorbing material may be used. As the adsorbing material, known adsorbing materials may be used, and for example, inorganic adsorbing materials such as silica gel and zeolite, and organic adsorbing materials such as activated carbon can be used. In order to reduce impurities such as metals included in the various materials include, it is necessary to prevent incorporation of metal impurities in the production step. Whether the metal impurities are sufficiently removed from the production device can be found by measuring the content of the metal components included in a washing liquid used for the washing of the production device. The content of the metal components included in the washing liquid after the use thereof is preferably 100 parts per trillion (ppt) or less, more preferably 10 ppt or less, and still more preferably 1 ppt or less.

In addition, the present invention further relates to a photomask for lithography, more specifically, a photomask obtained by developing the resist-applied mask blank through exposure and development, each of which is manufactured using the pre-rinsing liquid of the present invention. For the exposure and the development, the above-described steps are applied. The photomask is suitably used for production of a semiconductor.

The photomask in the present invention may be a light transmission type mask for use in an ArF excimer laser or the like, or may be a light reflection type mask for use in reflection type lithography having EUV light as a light source.

Moreover, the present invention also relates to a method for manufacturing an electronic device, including the above-described pattern forming method of the present invention, and an electronic device manufactured by this manufacturing method.

The electronic device of the present invention is suitably mounted in electrical or electronic equipments (household electronic appliance, OA/media-related equipment, optical equipment, telecommunication equipment, and the like).

The actinic ray-sensitive or radiation-sensitive composition in the present invention is typically a resist composition, and may be of a chemical amplification type or a non-chemical amplification type.

Hereinafter, the actinic ray-sensitive or radiation-sensitive composition in the present invention will be described in detail.

### First Embodiment

[Compound (A) Whose Dissolution Rate in Developer Decreases by Action of Acid]

The actinic ray-sensitive or radiation-sensitive composition according to the first embodiment of the present invention suitably contains a compound (A) whose dissolution rate in a developer decreases by the action of an acid (also referred to as a “compound (A)”). In this case, in the pattern forming method of the present invention, a negative tone pattern is suitably formed.

The compound (A) may be a high-molecular-weight compound (resin) or a low-molecular-weight compound.

From the viewpoints of reactivity and developability, the compound (A) is preferably a phenol derivative.

[N-A] Resin Whose Dissolution Rate in Developer Decreases by Action of Acid

A resin whose dissolution rate decreases in a developer by the action of an acid (also referred to as a “resin [N-A]”) is not particularly limited, but is preferably a resin whose dissolution rate decreases in a developer by the action of an acid generated from an acid generator which will be described later.

As the resin [N-A], a resin having a group which is polymerized by the action of an acid or an active species may be mentioned, and the resin [N-A] is preferably a resin having at least one of a repeating unit represented by General Formula (L-1) or a repeating unit represented by General Formula (L-2).

As the resin having the repeating unit represented by General Formula (L-1), the compound described in [0030] to [0047] of JP2012-242556A can be suitably used, and as the resin having the repeating unit represented by General Formula (L-2), the compound described in [0004] to [0048] of JP2014-24999A, and [0020] to [0031] of JP2013-164588A can be suitably used.

In the present invention, at least one of the repeating unit represented by General Formula (L-1) or the repeating unit represented by General Formula (L-2) may be included in a part of the resin (C) which will be described later or may be included in a resin other than the resin (C).

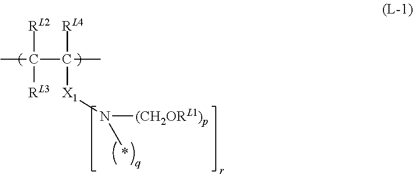

R^{L1} represents a hydrogen atom, an alkyl group, or a cycloalkyl group. p represents 1 or 2. q represents an integer represented by (2−p). * represents a bonding arm with other atoms constituting the repeating unit (L-1). In a case where p is 2 or r is 2 or more, a plurality of R^{L1}'s may be the same as or different from each other. R^{L2}, R^{L3}, and R^{L4} each independently represent a hydrogen atom, an alkyl group, a cycloalkyl group, a halogen atom, a cyano group, or an alkoxycarbonyl group. X₁ represents a single bond, or an (r+1)-valent group selected from the group consisting of a linear or branched hydrocarbon group, a cyclic hydrocarbon group which may contain a heteroatom as a ring member, —O—, —S—, —CO—, —SO₂—, —NR—, and a group formed by a combination thereof. R represents a hydrogen atom, an alkyl group, or a group represented by —CH₂OR^{L1}. Further, R^{L1} in the group represented by —CH₂OR^{L1} has the same definition as R^{L1} above. r represents an integer of 1 to 5, provided that in a case where X₁ is a single bond, r is 1.

The alkyl group in R^{L1} may be any one of a linear alkyl group or a branched alkyl group, and examples thereof include an alkyl group having 1 to 20 carbon atoms (for example, a methyl group, an ethyl group, a propyl group, an isopropyl group, a butyl group, an isobutyl group, a t-butyl group, an n-pentyl group, an n-hexyl group, an n-octyl group, and an n-dodecyl group). An alkyl group having 1 to 8 carbon atoms is preferable, an alkyl group having 1 to 6 carbon atoms is more preferable, and an alkyl group having 1 to 4 carbon atoms is particularly preferable.

The cycloalkyl group represented by R^{L1} may be any one of a monocyclic type or a polycyclic type, and examples thereof include a cycloalkyl group having 3 to 17 carbon atoms (for example, a cyclopentyl group, a cyclohexyl group, a norbomanyl group, and an adamantyl group). A cycloalkyl group having 5 to 12 carbon atoms is preferable, a cycloalkyl group having 5 to 10 carbon atoms is more preferable, and a cycloalkyl group having 5 or 6 carbon atoms is particularly preferable.

As R^{L1} in General Formula (L-1), a hydrogen atom or an alkyl group having 1 to 8 carbon atoms is preferable, a hydrogen atom or an alkyl group having 1 to 6 carbon atoms is more preferable, and a hydrogen atom or an alkyl group having 1 to 4 carbon atoms is particularly preferable.

R^{L2}, R^{L3}, and R^{L4} each independently represent a hydrogen atom, an alkyl group, a cycloalkyl group, a halogen atom, a cyano group, or an alkoxycarbonyl group.

X₁ a single bond, or an (r+1)-valent group selected from the group consisting of a linear or branched hydrocarbon group, a cyclic hydrocarbon group which may contain a heteroatom as a ring member, —O—, —S—, —CO—, —SO₂—, —NR—, and a group formed by a combination thereof. R represents a hydrogen atom, an alkyl group, or a group represented by —CH₂OR^{L1}. Further, R^{L1} in the group represented by —CH₂OR^{L1} has the same definition as R^{L1} in General Formula (L-1).

r represents an integer of 1 to 5, provided that in a case where X₁ is a single bond, r is 1.

Specific examples of repeating unit represented by General Formula (L-1) are shown below, but are not limited thereto. R and R′ represents a hydrogen atom or a methyl group.

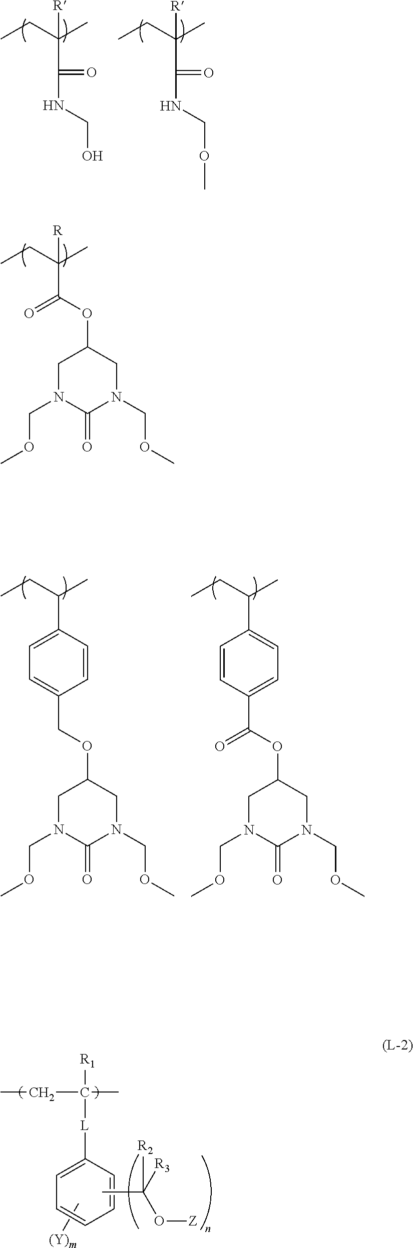

In General Formula (L-2), R₁ represents a hydrogen atom, a methyl group, or a halogen atom; R₂ and R₃ each independently represent a hydrogen atom, an alkyl group, or a cycloalkyl group; L represents a divalent linking group or a single bond; Y represents a monovalent substituent other than a methylol group; Z represents a hydrogen atom or a monovalent substituent; m represents an integer of 0 to 4; n represents an integer of 1 to 5; m+n is 5 or less; in a case where m is 2 or more, a plurality of Y's may be the same as or different from each other, and the plurality of Y's may be bonded to each other to form a ring structure; and in a case where n is 2 or more, a plurality of R₂'s, R₃'s, and Z's may be the same as or different from each other.

L preferably includes a divalent aromatic ring group, or a linking group represented by —COO—.

Specific examples of the repeating unit represented by General Formula (L-2) are shown below, but are not limited thereto.

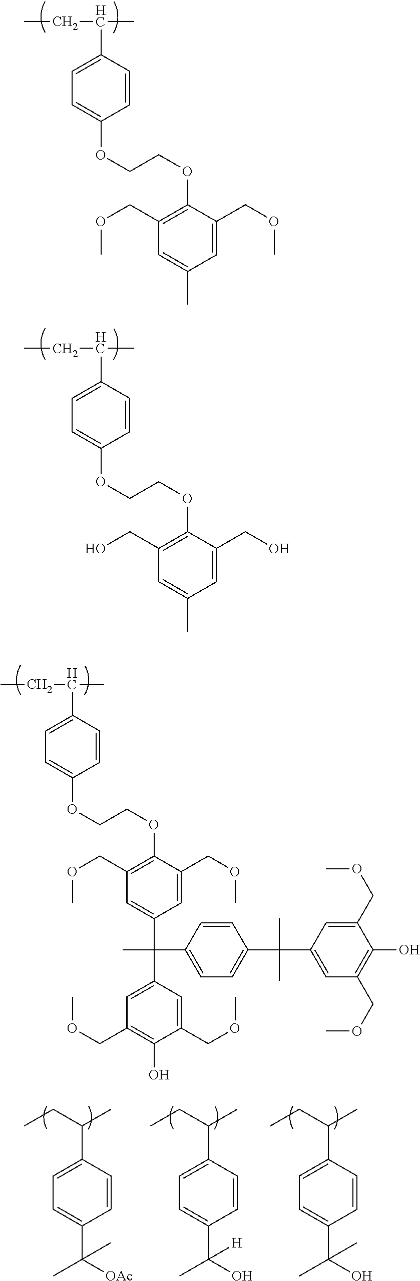

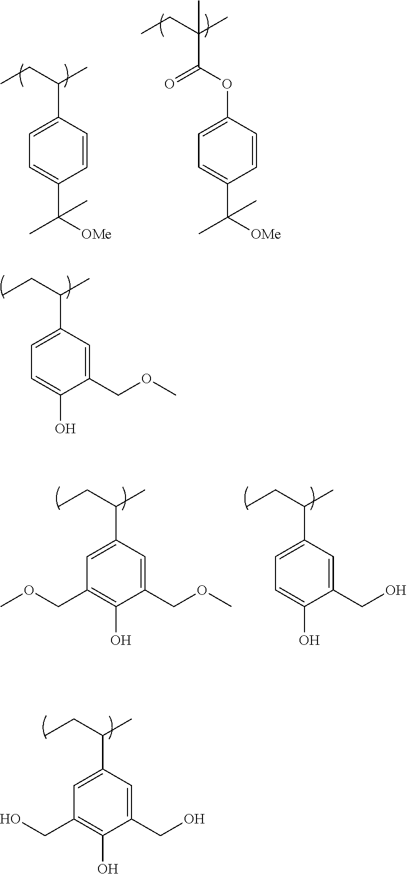

Furthermore, as the resin [N-A], a repeating unit having an epoxy structure or an oxetane structure may be included, and specifically, reference can be made to paragraphs [0076] to [0080] of JP2013-122569A, the contents of which are incorporated in the present specification.

In a case of forming a negative tone image (that is, in a case where the actinic ray-sensitive or radiation-sensitive composition is a negative-tone actinic ray-sensitive or radiation-sensitive composition), the content of at least one of the repeating unit represented by General Formula (L-1) or the repeating unit represented by General Formula (L-2) is preferably 5% to 50% by mole, and more preferably 10% to 40% by mole, with respect to all the repeating units included in the resin [N-A].

The resin [N-A] may contain other repeating units, in addition to the repeating unit represented by General Formula (L-1) and the repeating unit represented by General Formula (L-2), and may contain, for example, the repeating units mentioned for the resin (C) which will be described later.

The resin [N-A] can be synthesized by a known radical polymerization method, anionic polymerization method or living radical polymerization method (an iniferter method or the like). For example, in the anionic polymerization method, vinyl monomers are dissolved in an appropriate organic solvent, and reacted usually under a cooling condition by using a metal compound (butyllithium or the like) as the initiator, whereby the polymer can be obtained.

The weight-average molecular weight of the polymer resin [N-A] is preferably 1,000 to 50,000, more preferably 2,000 to 20,000, as a value in terms of polystyerene determined by a GPC method.

The resin [N-A] can be used singly or in combination of two or more kinds thereof. The content of the resin [N-A] is preferably 20% to 99% by mass, more preferably 30% to 99% by mass, and still more preferably 40% to 99% by mass, based on the total solid contents in the actinic ray-sensitive or radiation-sensitive composition.

[N-C] Low-Molecular-Weight Compound Whose Dissolution Rate in Developer Decreases by Action of Acid

The low-molecular-weight compound whose dissolution rate in a developer decreases by the action of an acid (also referred to as a “low-molecular-weight compound [N-C]”) is not particularly limited, and examples thereof include a compound whose dissolution rate decreases in an alkali developer by the action of an acid generated from the acid generator which will be described later.

The molecular weight range of the low-molecular-weight compound [N-C] is preferably from 100 to 1,000, more preferably from 200 to 900, and particularly preferably 300 to 800.

Here, the low-molecular-weight compound in the present invention is a compound having a given molecular weight (a compound substantially not having a molecular weight distribution), not a so-called polymer or oligomer, which is obtained by subjecting a compound having an unsaturated bond (a so-called polymerizable monomer) to cleavage of the unsaturated bond, using an initiator, and successive growth of the bond.

Examples of the low-molecular-weight compound [N-C] include an addition-polymerizable compound having a double bond. In this case, the low-molecular-weight compound [N-C] is selected from compounds having at least one terminal ethylenically unsaturated bond, and preferably two or more terminal ethylenically unsaturated bonds. Such the compound group is widely known in the field of the related art, and can be used in the present invention with particular limitation.

As the addition-polymerizable compound having a double bond, the monomers described in [0108] to [0113] of JP2014-104631A can be suitably used.

Suitable examples of the low-molecular-weight compound [N-C] include a compound that crosslinks the resin (C) having a phenolic hydroxyl group, which will be described later (hereinafter also referred to as a “crosslinking agent”). Here, a known crosslinking agent can be effectively used.

The crosslinking agent is, for example, a compound having a crosslinkable group which can crosslink the resin (C) having a phenolic hydroxyl group, and is preferably a compound having two or more hydroxymethyl groups, alkoxymethyl groups, acyloxymethyl groups, or alkoxymethyl ether groups as the crosslinkable group, or an epoxy compound.

More preferred examples thereof include an alkoxymethylated or acyloxymethylated melamine compound, an alkoxymethylated or acyloxymethylated urea compound, a hydroxymethylated or alkoxymethylated phenol compound, and an alkoxymethyl-etherified phenol compound.

In addition, with regard to the compound [N-C], reference can be made to the epoxy compound in paragraphs [0196] to [0200] of JP2013-64998A ([0271] to [0277] of the corresponding US2014/0178634A), or the oxetane compound described in paragraph [0065] of JP2013-258332A, the contents of which are incorporated in the present specification.

The crosslinking agent preferably has a structure represented by General Formula (1).

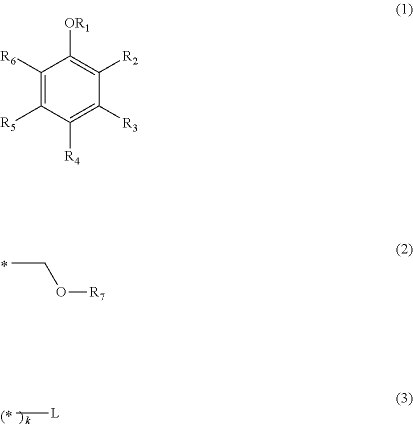

In General Formula (1), R₁ to R₆ each independently represent a hydrogen atom, an organic group having 1 to 50 carbon atoms, or a bonding site with the linking group or a single bond represented by L in General Formula (3), provided that at least one of R₂, . . . , or R₆ is the structure represented by General Formula (2).

In General Formula (2), R₇ represents a hydrogen atom, or an organic group having 1 to 30 carbon atoms, and * represents a bonding site in any one of R₂, . . . , or R₆.

In General Formula (3), L represents a linking group or a single bond, * represents a bonding site in any one of R₁, . . . , or R₆, and k represents an integer of 2 to 5.

In the case where the crosslinking agent is a compound represented by General Formula (1), R₁ to R₆ each independently represent a hydrogen atom or an organic group having 1 to 50 carbon atoms. Examples of the organic group having 1 to 50 carbon atoms include an alkyl group, a cycloalkyl group or an aryl group, or a group formed by the linkage of these groups with an alkylene group, an arylene group, a carboxylic acid ester bond, a carbonate ester bond, an ether bond, a thioether bond, a sulfo group, a sulfone group, a urethane bond, a urea bond, or a group formed by a combination thereof.

Furthermore, at least one of R₂, . . . , or R₆ is the structure represented by General Formula (2). Examples of the organic group having 1 to 30 carbon atoms, represented by R₇ in General Formula (2), include the same specific examples of the organic groups represented by R₁ to R₆, as described above. The organic groups having two or more structures represented by General Formula (2) in one molecule are preferable.

In another aspect of the present invention, the crosslinking agent (C) may be a compound in which 1 to 5 structures represented by General Formula (1) are connected via a linking group or a single bond represented by L in General Formula (3). In this case, at least one of R₁, . . . , or R₆ in General Formula (1) represents a bonding site with a linking group or a single bond represented by General Formula (3).

Examples of the linking group represented by L in General Formula (3) include an alkylene group, an arylene group, a carboxylic acid ester bond, a carbonate ester bond, an ether bond, a thioether bond, a sulfo group, a sulfone group, a urethane bond, a urea bond, or a group formed by a combination of two or more of these groups, and preferably an alkylene group, an arylene group, and a carboxylic ester bond.

k preferably represents 2 or 3.

In one aspect of the present invention, the crosslinking agent is, for example, the compound represented by General Formula (1) as mentioned above, and is preferably a compound having the structure represented by General Formula (4) as mentioned above as a polarity conversion group or a compound in which 2 or 3 of the compounds are linked via a linking group or a single bond represented by L in General Formula (3a).

(*ₖ_{₁}L (3a)

In General Formula (3a), L has the same definition as L in General Formula (3) as mentioned above, and k₁ represents 2 or 3.

Specific examples of L are shown below, but the present invention is not limited thereto.

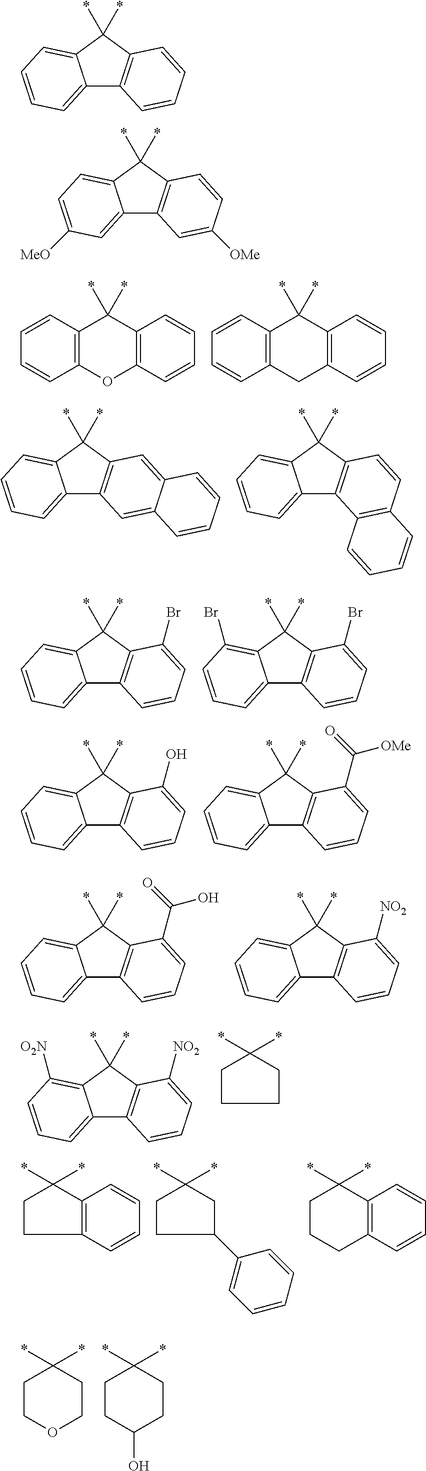

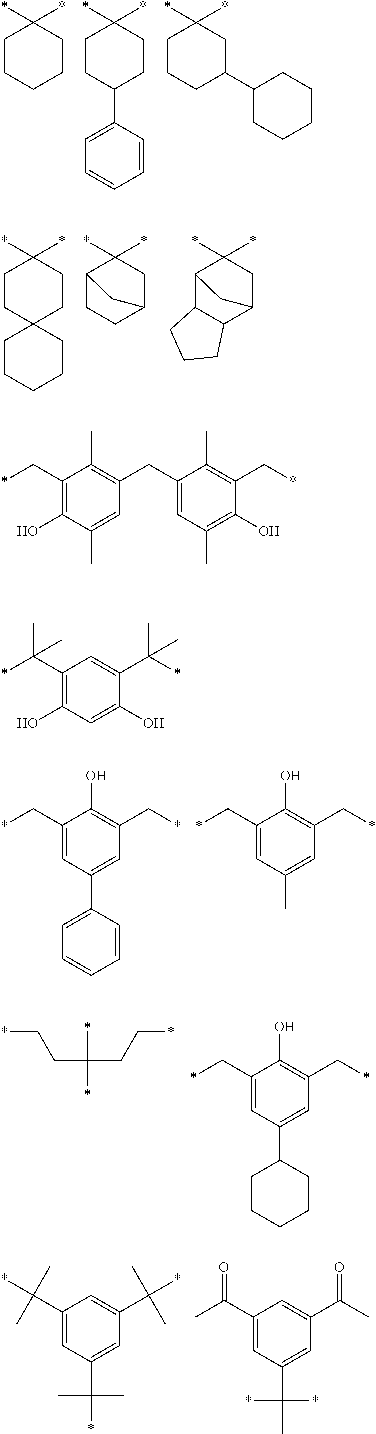

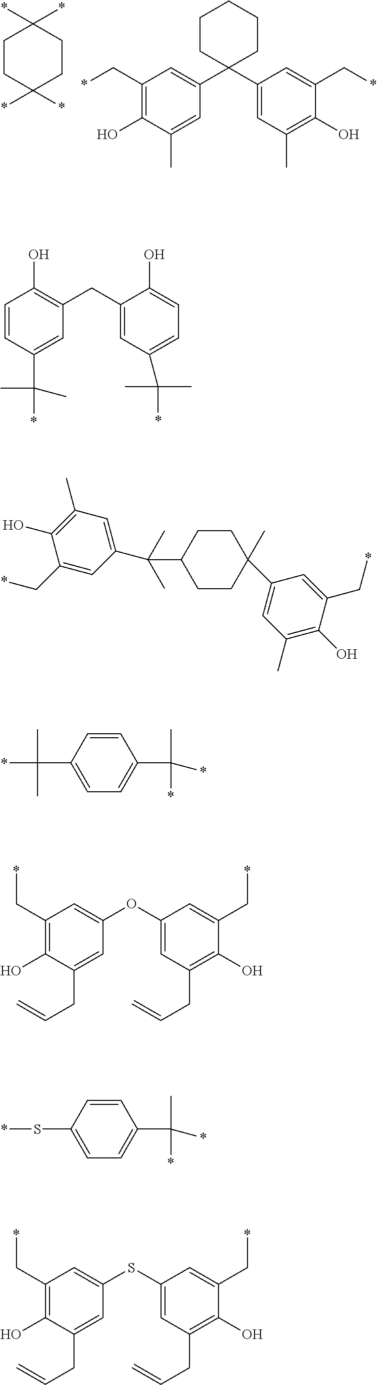

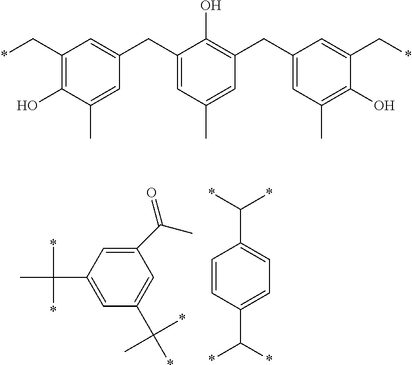

Specific examples of the crosslinking agent of the present invention are shown below, but the present invention is not limited thereto.

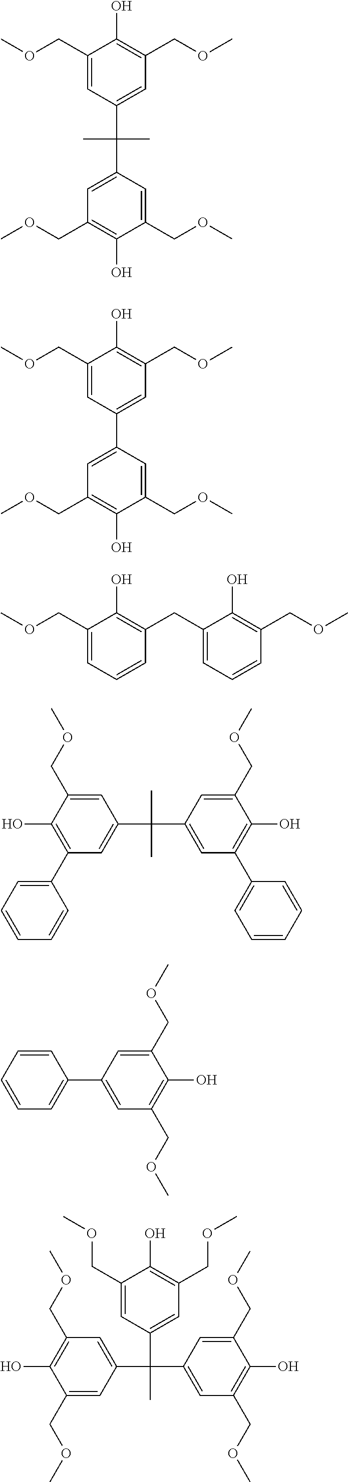

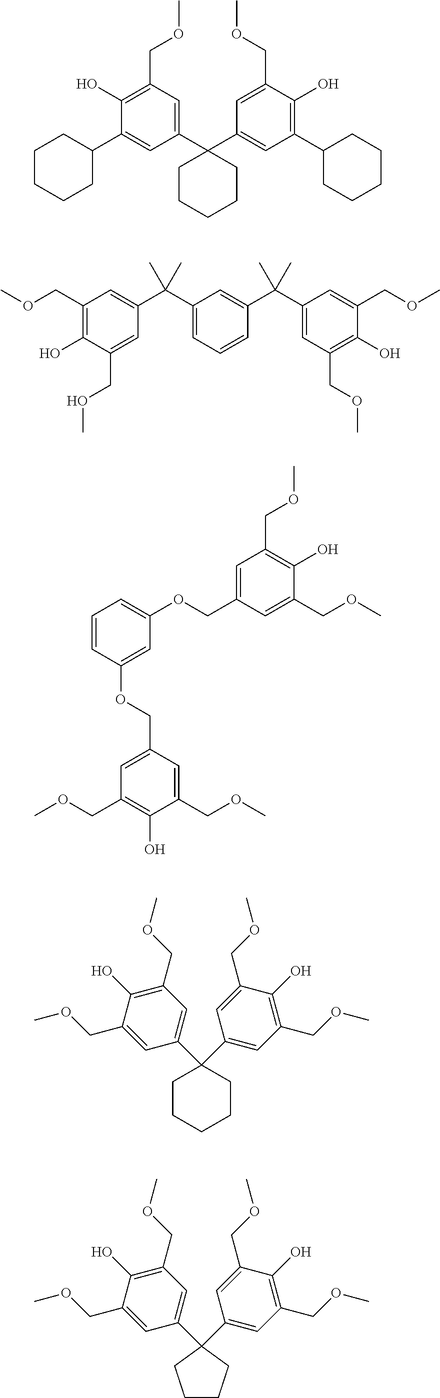

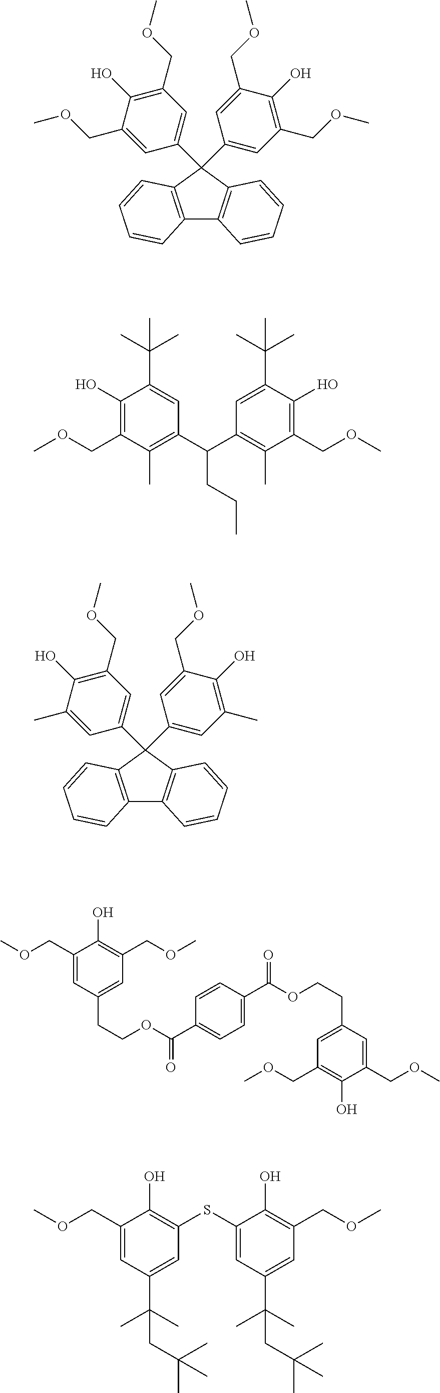

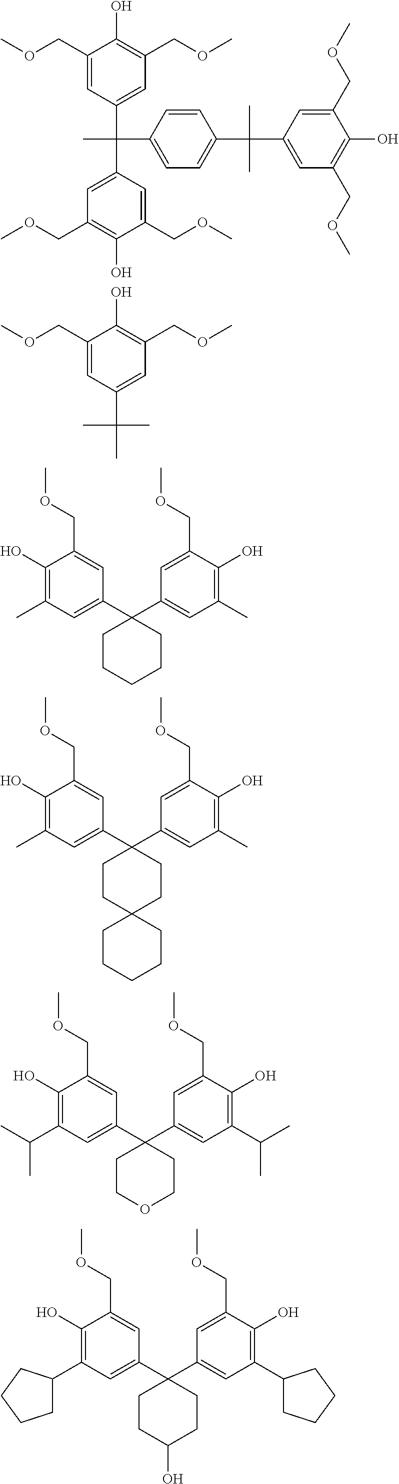

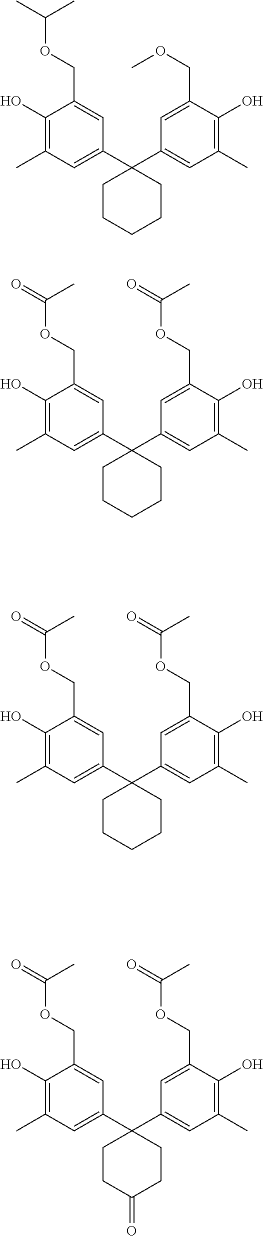 [SMILES: COCc1cc(C2(c3cc(C)c(O)c(COC(C)C)c3)CCCCC2)cc(C)c1O ; CC(=O)OCc1cc(C2(c3cc(C)c(O)c(COC(C)=O)c3)CCCCC2)cc(C)c1O ; CC(=O)OCc1cc(C2(c3cc(C)c(O)c(COC(C)=O)c3)CCCCC2)cc(C)c1O ; CC(=O)OCc1cc(C2(c3cc(C)c(O)c(COC(C)=O)c3)CCC(=O)CC2)cc(C)c1O]

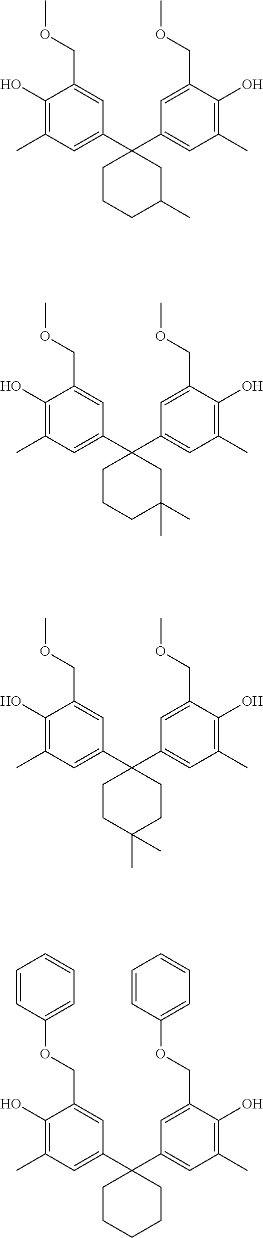 [SMILES: COCc1cc(C2(c3cc(C)c(O)c(COC)c3)CCCC(C)C2)cc(C)c1O ; COCc1cc(C2(c3cc(C)c(O)c(COC)c3)CCCC(C)(C)C2)cc(C)c1O ; COCc1cc(C2(c3cc(C)c(O)c(COC)c3)CCC(C)(C)CC2)cc(C)c1O ; Cc1cc(C2(c3cc(C)c(O)c(COc4ccccc4)c3)CCCCC2)cc(COc2ccccc2)c1O]

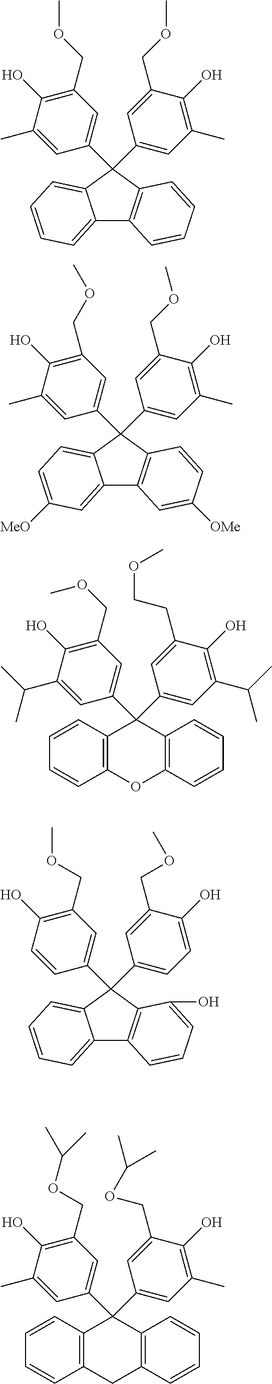

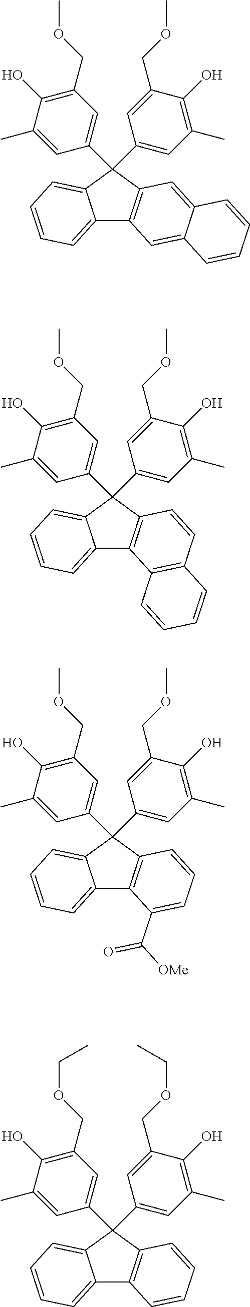

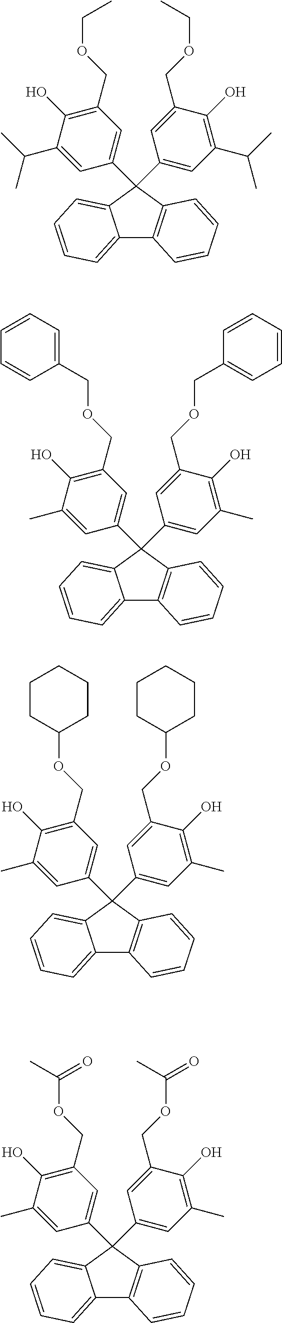

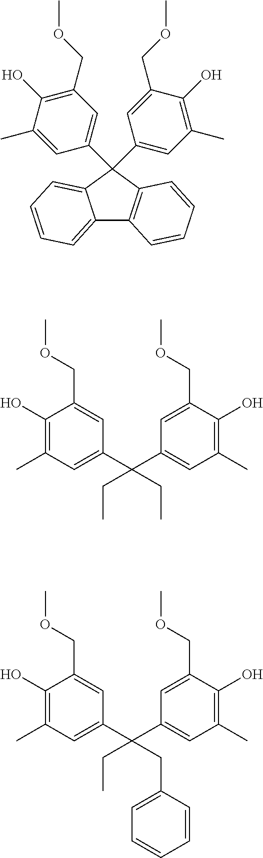

A synthesis method for the crosslinking agent can be appropriately selected depending on a desired compound, and is not limited to specific synthesis methods. One example thereof may be a method in which a compound having both a crosslinking group and a nucleophilic group (for example, a hydroxyl group), and a compound having a polarity conversion group and a leaving group (for example, a halogen atom such as bromine) are obtained as a raw material by a substitution reaction.

The content of the crosslinking agent is preferably 3% to 65% by mass, and more preferably 5% to 50% by mass, based on the solid content of the actinic ray-sensitive or radiation-sensitive composition of the present invention.

Furthermore, in the present invention, the crosslinking agents may be used singly or in combination of two or more kinds thereof.

As the crosslinking agent, a commercially available product can be used, or the crosslinking agent can also be synthesized by a known method. For example, a phenol derivative having a hydroxymethyl group can be obtained by reacting the corresponding phenol compound having no hydroxymethyl group with formaldehyde in the presence of a base catalyst. In this case, the reaction is preferably carried out at a temperature of 60° C. or lower in order to prevent resinification and gelation. Specifically, the crosslinking agent can be synthesized by the methods described in JP1994-282067A (JP-H06-282067A), JP1997-64285A (JP-H07-64285A), and the like.

The phenol derivative having an alkoxymethyl group can be obtained by reacting the corresponding phenol derivative having a hydroxymethyl group with an alcohol in the presence of an acid catalyst. In this case, the reaction is preferably carried out at a temperature of 100° C. or lower in order to prevent resinification and gelation. Specifically, the phenol derivative can be synthesized by the method described in EP632003A1. The phenol derivatives having a hydroxymethyl group or an alkoxymethyl group, thus synthesized, are preferable from the viewpoint of stability during preservation, and the phenol derivative having an alkoxymethyl group is particularly preferable from the viewpoint of stability during preservation. The phenol derivatives each having two or more of hydroxymethyl groups or alkoxymethyl groups in total, in which the hydroxymethyl groups or alkoxymethyl groups are bonded collectively to any one of the benzene rings or divisionally to the benzene rings, may be used singly or in combination of two or more kinds thereof.

Furthermore, examples of the crosslinking agent include (i) a compound having an N-hydroxymethyl group, an N-alkoxymethyl group, or an N-acyloxymethyl group, and (ii) an epoxy compound, each of which will be described below. Specifically, the compounds represented by General Formulae described in [0294] to [0315] of JP2012-242556A can be suitably used. In particular, as (i) the compound having an N-hydroxymethyl group, an N-alkoxymethyl group, or an N-acyloxymethyl group, a compound having two or more (more preferably 2 to 8) partial structures represented by General Formula (CLNM-1) is preferable.

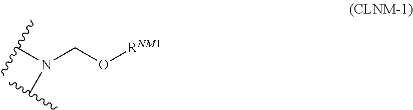

In General Formula (CLNM-1),

R^{NM1} represents a hydrogen atom, an alkyl group, a cycloalkyl group, or an oxoalkyl group.

Examples of a more preferred aspect of the compounds having two or more partial structures represented by General Formula (CLNM-1) include a urea-based crosslinking agent represented by General Formula (CLNM-2), an alkylene urea-based crosslinking agent represented by General Formula (CLNM-3), a glycoluril-based crosslinking agent represented by General Formula (CLNM-4), and a melamine-based crosslinking agent represented by General Formula (CLNM-5).

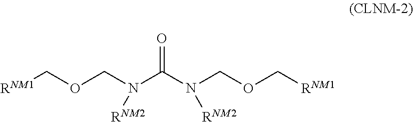

In General Formula (CLNM-2),

R^{NM1}'s are each independently the same as R^{NM1}'s in General Formula (CLNM-1).

R^{NM2}'s each independently represent a hydrogen atom, an alkyl group (preferably having 1 to 6 carbon atoms), or a cycloalkyl group (preferably having 5 or 6 carbon atoms).

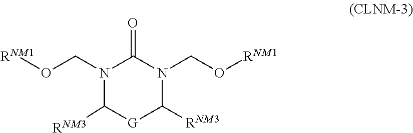

In General Formula (CLNM-3),

R^{NM1}'s are each independently the same as R^{NM1} in General Formula (CLNM-1).

R^{NM3}'s each independently represent a hydrogen atom, a hydroxyl group, a linear or branched alkyl group (preferably having 1 to 6 carbon atoms), a cycloalkyl group (preferably having 5 or 6 carbon atoms), an oxoalkyl group (preferably having 1 to 6 carbon atoms), an alkoxy group (preferably having 1 to 6 carbon atoms) or an oxoalkoxy group (preferably having 1 to 6 carbon atoms).

G represents a single bond, an oxygen atom, an alkylene group (preferably having 1 to 3 carbon atoms), or a carbonyl group

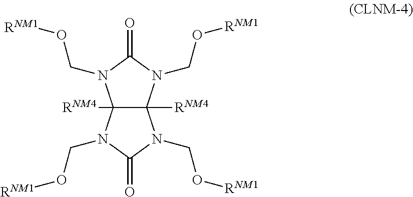

In General Formula (CLNM-4),

R^{NM1}'s each independently have the same definitions as R^{NM1}'s in General Formula (CLNM-1).

R^{NM4}'s each independently represent a hydrogen atom, hydroxyl group, an alkyl group, a cycloalkyl group, or an alkoxy group.

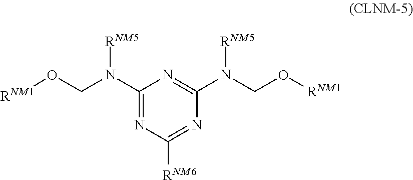

In General Formula (CLNM-5),

R^{NM1}'s are each independently the same as R^{NM1}'s in General Formula (CLNM-1).

R^{NM1}'s each independently represent a hydrogen atom, an alkyl group, a cycloalkyl group, an aryl group, or an atomic group represented by General Formula (CLNM-5′).

R^{NM6} represents a hydrogen atom, an alkyl group, a cycloalkyl group, an aryl group, or an atomic group represented by General Formula (CLNM-5″).

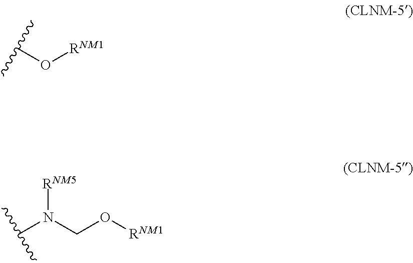

In General Formula (CLNM-5′),

R^{NM1}'s are each independently the same as R^{NM1}'s in General Formula (CLNM-1).

In General Formula (CLNM-5″),

R^{NM1}'s are each independently the same as R^{NM1}'s in General Formula (CLNM-1), and R^{NM5}'s are each independently the same as R^{NM5}'s in General Formula (CLNM-5).

As the alkyl group of each of R^{NM5} and R^{NM6}, an alkyl group having 1 to 6 carbon atoms is preferable, a cycloalkyl group having 5 or 6 carbon atoms is more preferable, and as an aryl group of each of R^{NM5} and R^{NM6}, an aryl group having 6 to 10 carbon atoms is preferable.

The groups represented by R^{NM1} to R^{NM6} in General Formulae (CLNM-1) to (CLNM-5) may each further have a substituent.

Specific examples of the compound with two or more partial structures represented by General Formula (CLNM-1) are shown below, but are not limited thereto.

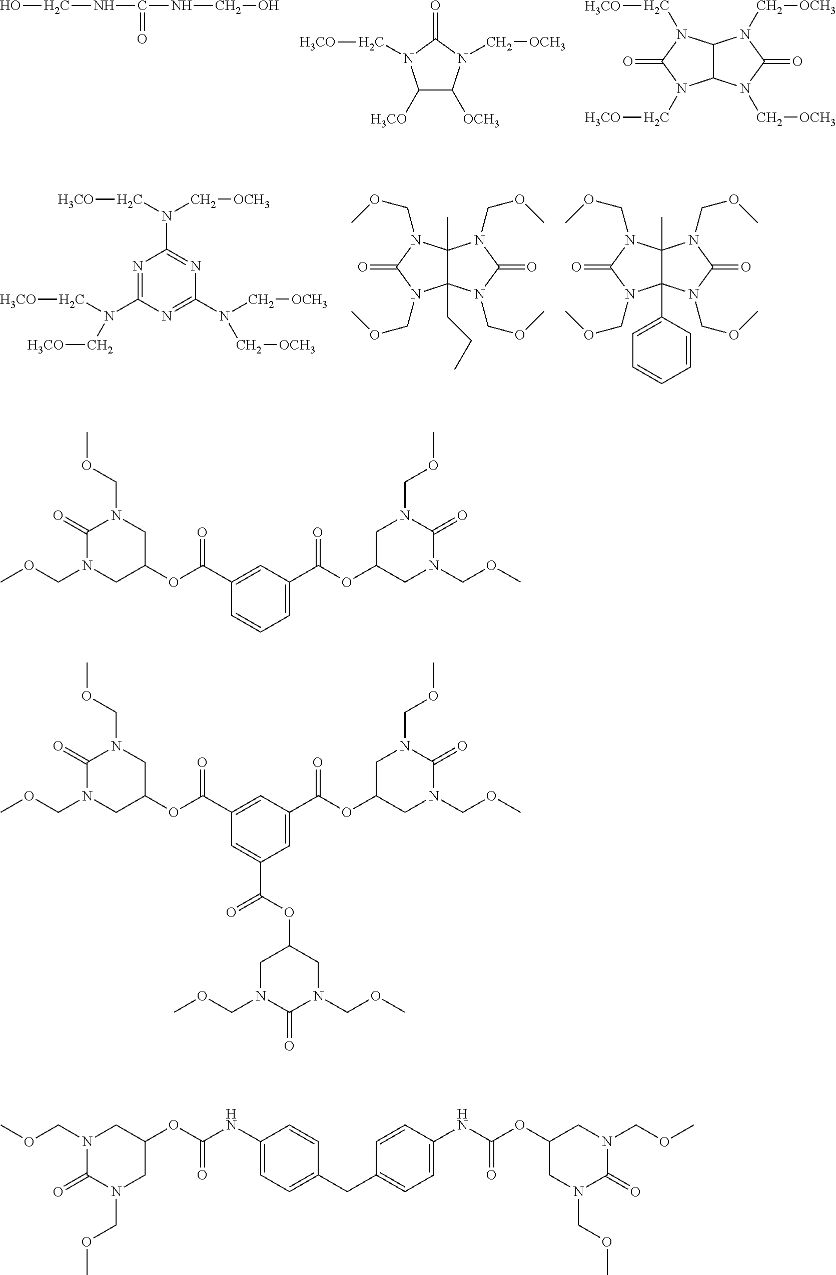

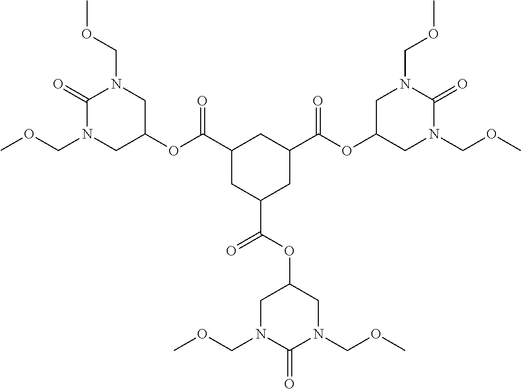

As the low-molecular-weight compound [N-C], a tertiary alcohol having a hydroxyl group on carbon directed bonded to an aromatic ring shown below can be used. The compounds described in JP1997-197672A (JP-H09-197672A), JP2001-324811A, and JP2000-31020A can be suitably used.

As the low-molecular-weight compound [N-C], a compound represented by General Formula (X) is preferable.

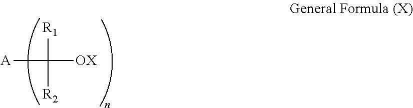

X represents a hydrogen atom, an alkyl group, a cycloalkyl group, an aryl group, or an acyl group.

A represents an aromatic hydrocarbon group, an aromatic heterocyclic group, or an alicyclic group.

R₁ and R₂ each independently represent a hydrogen atom, an alkyl group, a cycloalkyl group, or an aryl group, provided that all of R₁'s and all of R₂'s are not hydrogen atoms at the same time.

n's each independently represent an integer of 2 or more.

The compound represented by General Formula (X) is preferably a compound represented by General Formula (1), (2), (3), (4), or (I).

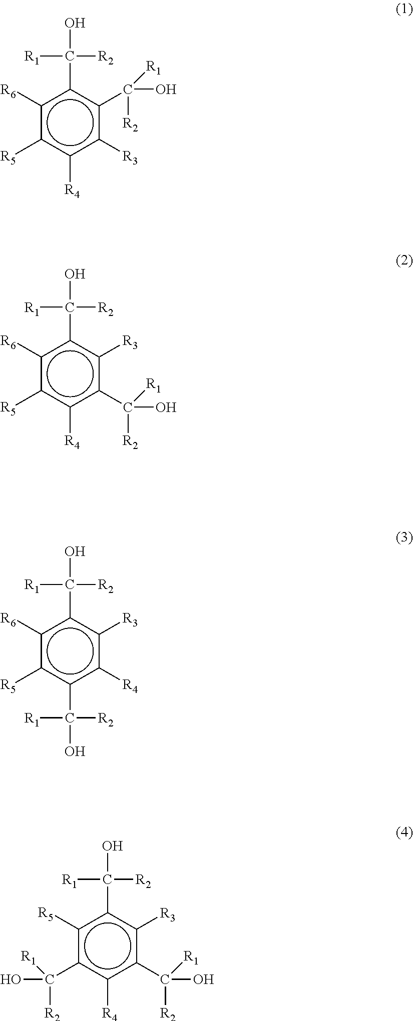

Here, R₁ and R₂ each represent a hydrogen atom or a substituted or unsubstituted alkyl group having 1 to 4 carbon atoms. R₃, R₄, R₅, and R₆ each independently represent an atom or atomic group selected from a hydrogen atom, a halogen atom, a substituted or unsubstituted alkyl group having 1 to 4 carbon atoms, a substituted or unsubstituted alkoxy group having 1 to 4 carbon atoms, a phenyl group, a methoxy group, and a cyclopropyl group. R₁ and R₂ may be the same as or different from each other. Further, R₃, R₄, R₅, and R₆ may be the same as or different from each other.

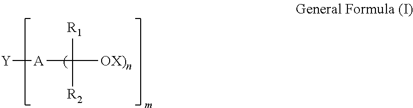

In the formula,

X represents a hydrogen atom, an alkyl group, a cycloalkyl group, an aryl group, or an acyl group.

A represents an aromatic hydrocarbon group, an aromatic heterocyclic group, or an alicyclic group.

R₁ and R₂ each independently represent a hydrogen atom, an alkyl group, a cycloalkyl group, or an aryl group, provided that all of R₁'s and all of R₂'s are not hydrogen atoms at the same time.

m's and n's each independently represent an integer of 1 or more.

In a case where at least one of m and n represents an integer of 2 or more, a plurality of R₁'s, a plurality of R₂'s, and a plurality of X's may be each the same as or different from each other.

In a case where m represents an integer of 2 or more, a plurality of A's may be the same as or different from each other.

Y represents an m-valent group. Y is preferably an m-valent group having a heteroatom.

A and at least one of R₁ or R₂ may be bonded to each other to form a ring.

R₁ and R₂ may be bonded to each other to form a ring, together with the carbon atom to which they are bonded.

In a case where A represents an aromatic ring group, the aromatic ring group is preferably a group formed by removing n+1 hydrogen atoms from a monocyclic or polycyclic aromatic ring (n represents an integer of 1 or more).

Examples of the aromatic hydrocarbon include an aromatic hydrocarbon ring (preferably having 6 to 18 carbon atoms) such as a benzene ring, a naphthalene ring, an anthracene ring, a fluorene ring, and a phenanthrene ring. Among these, a benzene ring and a naphthalene ring are preferable from the viewpoint of resolution, and a benzene ring is the most preferable.

In a case where A represents an alicyclic group, the alicyclic group may be monocyclic or polycyclic, and specifically, a group formed by removing n+1 hydrogen atoms (n represents an integer of 1 or more) from a monocyclic or polycyclic alicycle (preferably an alicycle having 3 to 18 carbon atoms) is preferable, and a group corresponding to a monocyclic or polycyclic monovalent alicyclic group (a group formed by removing n hydrogen atoms from a monovalent alicyclic group) is more preferable.

Examples of the monocyclic alicyclic group include groups corresponding to cycloalkyl groups such as a cyclopropyl group, a cyclobutyl group, a cycloheptyl group, a cyclohexyl group, a cyclopentyl group, a cyclooctyl group, a cyclononyl group, a cyclodecyl group, a cycloundecyl group, a cyclododecanyl group, a cyclohexenyl group, a cyclohexadienyl group, a cyclopentenyl group, and a cyclopentadienyl group, with a group corresponding to a cyclohexyl group or a cyclopentyl group being preferable.

Examples of the polycyclic alicyclic group include groups having a bicyclic, tricyclic, or tetracyclic structure, or the like, for example, a group corresponding to a bicyclobutyl group, a bicyclooctyl group, a bicyclononyl group, a bicyclooctyl group, a bicycloundecyl group, a bicyclooctenyl group, a bicyclotridecenyl group, an adamantyl group, an isobornyl group, a norbomyl group, an isobornyl group a camphanyl group, an α-pinen group, a tricyclodecanyl group, a tetracyclododecyl group, or an androstanyl group. More preferred examples thereof include groups corresponding to an adamantyl group, a decalin group, a norbomyl group, a cedrol group, a cyclohexyl group, a cycloheptyl group, a cyclooctyl group, a cyclodecanyl group, a cyclododecanyl group, and a tricyclodecanyl group, with a group corresponding to an adamantyl group being most preferable from the viewpoint of dry etching resistance.

In addition, some of carbon atoms in the monocyclic or polycyclic alicyclic group may be substituted with heteroatoms such as an oxygen atom, a nitrogen atom, and a sulfur atom, and specific examples of such the monocyclic or polycyclic alicyclic group include a thiophene ring, a furan ring, and a pyrrole ring.

In a case where A represents an aromatic heterocyclic group, an aromatic heterocyclic group containing an oxygen atom, a nitrogen atom, or a sulfur atom is preferable. Further, A is preferably an aromatic heterocyclic group having 3 to 18 carbon atoms, and specific examples thereof include a group having a heterocyclic structure, such as pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxthine ring, a phenothiazine ring, and a phenazine ring, but are not limited thereto.

Moreover, A and at least one of R₁ or R₂ may be bonded to each other to form a ring.

The aromatic hydrocarbon group, the aromatic heterocyclic group, or the alicyclic group of A may have a substituent, and examples of the substituent include an alkyl group, a halogen atom, hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

R₁ and R₂ each independently represent an alkyl group, a cycloalkyl group, or an aryl group. R₁ and R₂ may be bonded to each other to form a ring, together with the carbon atom to which they are bonded.

R₁ and R₂ each independently preferably represent an alkyl group or a cycloalkyl group, more preferably represent an alkyl group having 1 to 10 carbon atoms, or a cycloalkyl group having 3 to 10 carbon atoms, and still more preferably represent an alkyl group having 1 to 5 carbon atoms.

R₁ and R₂ each may have a substituent, and examples of the substituent include an alkyl group, a halogen atom, hydroxyl group, an alkoxy group, a carboxyl group, an alkoxycarbonyl group, an alkylcarbonyl group, an alkylcarbonyloxy group, an alkylsulfonyloxy group, and an arylcarbonyl group.

Examples of R₁ and R₂ in a case where they have the substituent include a benzyl group and a cyclohexylmethyl group.

All of R₁'s and all of R₂'s are not hydrogen atoms at the same time. When all of R₁'s and all of R₂'s are not hydrogen atoms at the same time, the reaction efficiency is enhanced, and the sensitivity is improved.

X represents a hydrogen atom, an alkyl group, a cycloalkyl group, an aryl group, or an acyl group. X is preferably a hydrogen atom, an alkyl group, or an acyl group, and more preferably a hydrogen atom, an alkyl group having 1 to 5 carbon atoms, or an acyl group having 2 to 5 carbon atoms.

Examples of the m-valent group containing a heteroatom of Y include —S—, —O—, —CO—, —SO₂—, —N(R₀)—, —SO₂—, an m-valent group formed by a combination of a plurality of these groups, an m-valent group formed by a combination of these groups with a hydrocarbon group, and an m-valent heterocyclic group. R₀ represents a hydrogen atom or an alkyl group (for example, an alkyl group having 1 to 8 carbon atoms, and specifically, a methyl group, an ethyl group, a propyl group, an n-butyl group, a sec-butyl group, a hexyl group, and an octyl group). Examples of the hydrocarbon group include an alkylene group (for example, a methylene group, an ethylene group, a propylene group, a butylene group, a hexylene group, an octylene group), a cycloalkylene group (for example, a cyclopentylene group and a cyclohexylene group), an alkenylene group (for example, an ethylene group, a propenylene group, and a butenylene group), and an arylene group (for example, a phenylene group, a tolylene group, and a naphthylene group).

As the m-valent group containing a heteroatom of Y, from the viewpoints of the interaction with a polymer, resolution, and etching resistance, an m-valent group having a heteroatom and a ring structure is more preferable, and an m-valent having —O—, —CO—, —SO₂—, and a group formed by a combination of a plurality of these groups with an aryl group is the most preferable.

m and n each independently represent an integer of 1 or more. m is preferably an integer of 1 to 3, and from the viewpoints of reaction efficiency and developer solubility, m is most preferably 2. n is preferably an integer of 1 to 3, and more preferably an integer of 1 or 2.

General Formula (X) is preferably General Formula (I-1).

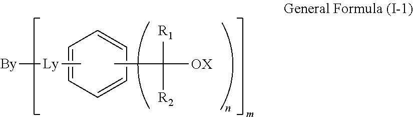

In General Formula (I-1),

X represents a hydrogen atom, an alkyl group, a cycloalkyl group, an aryl group, or an acyl group.

R₁ and R₂ each independently represent a hydrogen atom, an alkyl group, a cycloalkyl group, or an aryl group, provided that all of R₁'s and all of R₂'s are not hydrogen atoms at the same time.

Ly represents —S—, —O—, —CO—, —SO₂—, —N(R₀)—, —SO₂—, alkylene group, or a divalent group formed by a combination of a plurality of these groups.

m and n each independently represent an integer of 1 or more.

In a case where at least one of m or n represents an integer of 2 or more, a plurality of R₁'s, a plurality of R₂'s, and a plurality of X's may be the same as or different from each other.

In a case where m represents an integer of 2 or more, a plurality of Ly's may be the same as or different from each other.

R₁ and R₂ may be bonded to each other to form a ring, together with the carbon atom to which they are bonded.

By represents an m-valent group having at least one structure selected from the following six structures.

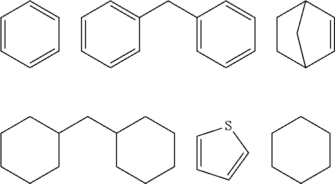

Specific examples and preferred ranges of X, R₁, R₂, R₀, m, and n in General Formula (I-1) are the same as the specific examples and the preferred ranges of X, R₁, R₂, R₀, m, and n in General Formula (I), respectively.

Ly represents —S—, —O—, —CO—, —SO₂—, —N(R₀)—, —SO₂—, an alkylene group, or a divalent group formed by a combination of a plurality of these groups. As the alkylene group, an alkylene group having 1 to 5 carbon atoms is preferable.

The compound represented by the compound (X) can be synthesized, for example, based on the same method as the synthesis of 2,2′-(5-hydroxy-1,3-phenylene) dipropan-2-ol in Journal of Photopolymer Science and Technology Volume 26, Number 5(2013) 665-671.

Examples of the secondary or tertiary alcohol having a hydroxyl group on carbon directly bonded to an aromatic ring, used in the present invention, include α,α′-dimethyl-1,2-benzenedimethanol, α,α′-diethyl-1,2-benzenedimethanol, 4-methoxy-α,α′-dimethyl-1,2-benzenedimethanol, 4,5-dichloro-α,α′-dimethyl-1,2-benzenedimethanol, 4,5,α,α′-tetramethyl-1,2-benzenedimethanol, α,α′-dimethyl-1,3-benzenedimethanol, α,α′-diethyl-1,3-benzenedimethanol, 5-methoxy-α,α′-dimethyl-1,3-benzenedimethanol, 5-chloro-α,α′-dimethyl-1,3-benzenedimethanol, 5-bromo-α,α′-dimethyl-1,3-benzenedimethanol, α,α′-dimethyl-1,4-benzenedimethanol, α,α′-diethyl-1,4-benzenedimethanol, 2,3,5,6,α,α′-hexamethyl-1,4-benzenedimethanol, 2-chloro-α,α′-dimethyl-1,4-benzenedimethanol, 2-bromo-α,α′-dimethyl-1,4-benzenedimethanol, α,α′,α″-trimethyl-1,3,5-benzenetrimethanol, α,α′,α″-triethyl-1,3,5-benzenetrimethanol, α,α′,α″-trihydroxy-1,3,5-triisopropylbenzene, α,α′-dimethyl-1,5-naphthalenedimethanol, α,α′-dimethyl-1,4-naphthalenedimethanol, and α,α′-dimethyl-9, 10-anthracenedimethanol.

Among the secondary or tertiary alcohols having a hydroxyl group on carbon directly bonded to an aromatic ring, the tertiary alcohols are dehydrated with high efficiency even in the presence of a small amount of an acid, and thus, they are more preferable as a high-sensitivity pattern forming material. In addition, the tertiary alcohols having 3 or more 2-hydroxyisopropyl groups on the same aromatic ring are less volatilized during the pre-exposure baking, and thus, they are more preferable as an alcohol compound for use in the pattern forming material of the present invention.

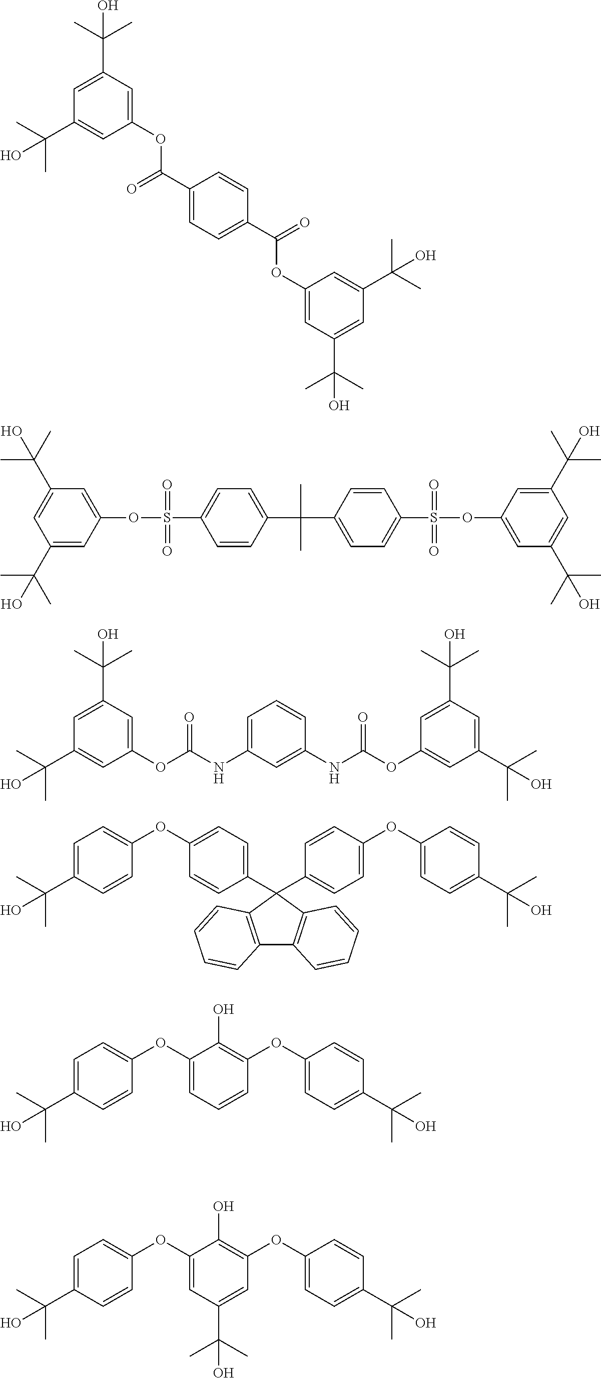

In addition, the actinic ray-sensitive or radiation-sensitive composition according to the first embodiment of the present invention preferably contains a compound having a molecular weight of 500 or more as the low-molecular-weight compound [N-C], and thus, can be suppressed from being volatilized from the film under vacuum during the pre-heating step, the post-heating step, and the exposure.

[Resin (C) Having Phenolic Hydroxyl Group]

The actinic ray-sensitive or radiation-sensitive composition according to the first embodiment of the present invention preferably contains a resin (C) having a phenolic hydroxyl group (also referred to as a “resin (C)”).

The phenolic hydroxyl group in the present invention is a group resulting from the substitution of a hydrogen atom in an aromatic ring group with a hydroxy group. The aromatic ring of the aromatic ring group is a monocyclic or polycyclic aromatic ring, and examples thereof include a benzene ring and a naphthalene ring.

The resin (C) is preferably a resin having a repeating unit containing a phenolic hydroxyl group, and more preferably a resin having a repeating unit represented by General Formula (30).

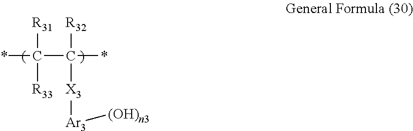

In General Formula (30),

R₃₁, R₃₂, and R₃₃ each independently represent a hydrogen atom, an alkyl group, a cycloalkyl group, a halogen atom, a cyano group, or an alkoxycarbonyl group. R₃₃ may be bonded to Ar₃ to form a ring, and in this case, R₃₃ represents an alkylene group.

X₃ represents a single bond or a divalent linking group.

Ar₃ represents an (n3+1)-valent aromatic ring group, and in a case where Ar₃ is bonded to R₃₃ to form a ring, it represents an (n3+2)-valent aromatic ring group.

n3 represents an integer of 1 to 4.

Specific examples of the alkyl group, the cycloalkyl group, the halogen atom, the alkoxycarbonyl group, and the substituent which can be contained in these groups of R₃₁, R₃₂, and R₃₃ in Formula (30) include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group, and the number of carbon atoms of the substituent is preferably 8 or less.

Ar₃ represents an (n3+1)-valent aromatic cyclic group. The divalent aromatic cyclic group in a case where n3 is 1 may have a substituent, and preferred examples of the divalent aromatic cyclic group include an arylene group having 6 to 18 carbon atoms, such as a phenylene group, a tolylene group, a naphthylene group, and an anthracenylene group, and aromatic cyclic groups containing a heterocycle, such as thiophene, furan, pyrrole, benzothiophene, benzofuran, benzopyrrole, triazine, imidazole, benzimidazole, triazole, thiadiazole, and thiazole.

Specific suitable examples of the (n3+1)-valent aromatic cyclic group in a case where n3 is an integer of 2 or more include the groups formed by removing arbitrary (n3-1) hydrogen atoms from the above-described specific examples of the divalent aromatic cyclic group.

The (n3+1)-valent aromatic cyclic group may further have a substituent.

Examples of the substituent which can be contained in the alkylene group and the (n3+1)-valent aromatic ring group as mentioned above include an alkyl group, an alkoxy group such as a methoxy group, an ethoxy group, a hydroxyethoxy group, a propoxy group, a hydroxypropoxy group, and a butoxy group, and an aryl group such as a phenyl group.

Examples of the divalent linking group of X₃ include —COO— and —CONR₆₄—.

Examples of the alkyl group of R₃₄ in —CONR₃₄— (R₃₄ represents a hydrogen atom or an alkyl group) represented by X₃ include the same groups as the alkyl group of each of R₃₁ to R₃₃.

X₃ is preferably a single bond, —COO—, or —CONH—, and more preferably a single bond or —COO—.

In a case where the resin (C) has a repeating unit corresponding to (meth)acrylate in addition to the repeating unit containing a phenolic hydroxyl group, X₃ is also preferably —COO— from the viewpoint of copolymerizability of a monomer corresponding to the repeating unit containing a phenolic hydroxyl group with (meth)acrylate.

Ar₃ is more preferably an aromatic ring group having 6 to 18 carbon atoms, may have a substituent, and particularly preferably a benzene ring group, a naphthalene ring group, or a biphenylene ring group.

The repeating unit (b) preferably includes a hydroxystyrene structure. That is, Ar₃ is a benzene ring group.

n3 represents an integer of 1 to 4, preferably represents 1 or 2, and more preferably represents 1.

The monomer corresponding to the repeating unit represented by General Formula (30) is preferably hydroxystyrene, 2-hydroxyphenyl methacrylate, 3-hydroxyphenyl methacrylate, or 4-hydroxyphenyl methacrylate, and more preferably hydroxystyrene or 4-hydroxyphenyl methacrylate.

The resin (C) may be only formed of such the repeating unit containing a phenolic hydroxyl group. The resin (C) may have the repeating unit which will be described later, in addition to the repeating unit containing a phenolic hydroxyl group, as described above. In such a case, the content of the repeating unit containing a phenolic hydroxyl group is preferably 10% to 98% by mole, more preferably 30% to 97% by mole, and still more preferably 40% to 95% by mole, with respect to all the repeating units of the resin (C). With such the content, particularly in a case where the resist film is a thin film (for example, in a case where the thickness of the resist film is 10 to 150 nm), the dissolution rate of the exposed area in the resist film in a developer can be more reliably reduced (that is, the dissolution rate of the resist film can be more reliably controlled to optimum). As a result, the sensitivity can be more reliably improved.

Specific examples of the repeating unit containing a phenolic hydroxyl group are shown below, but are not limited thereto.

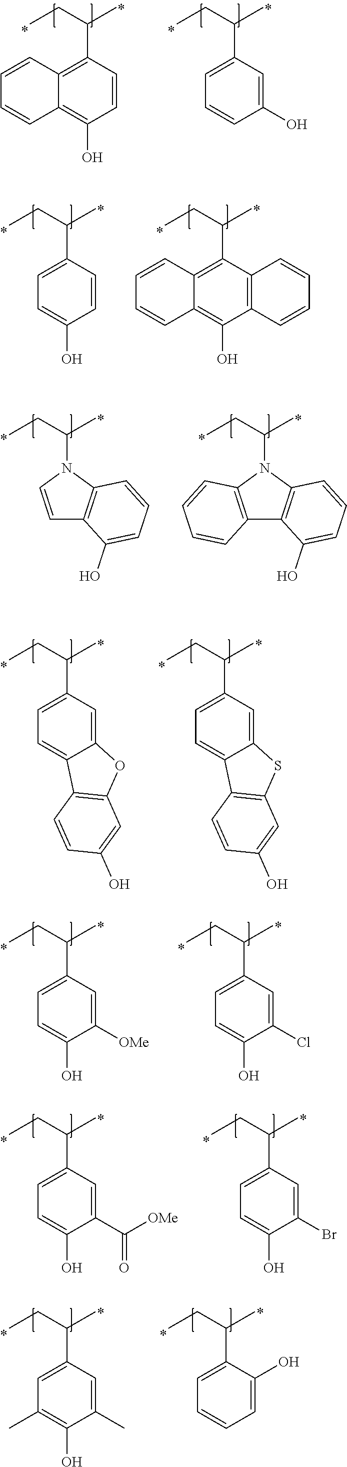

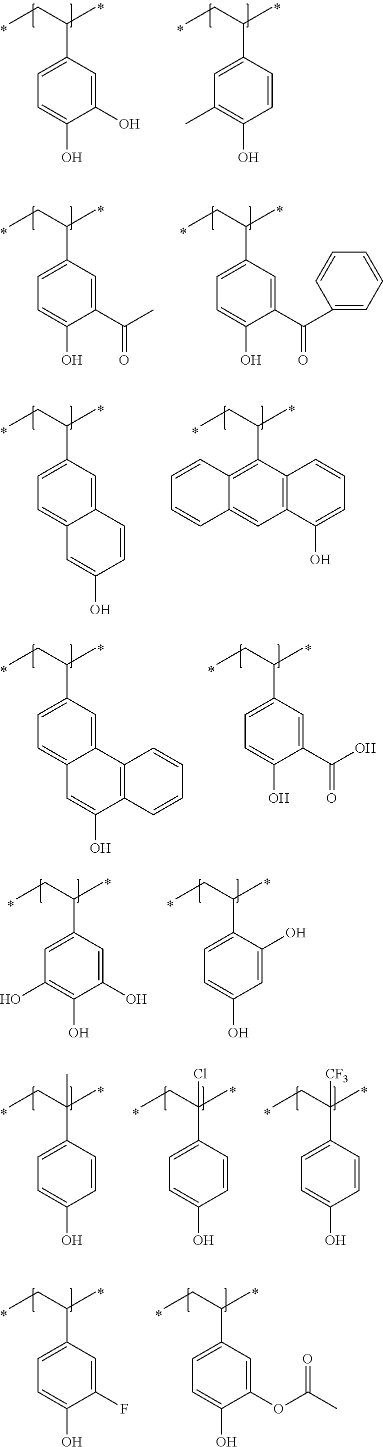

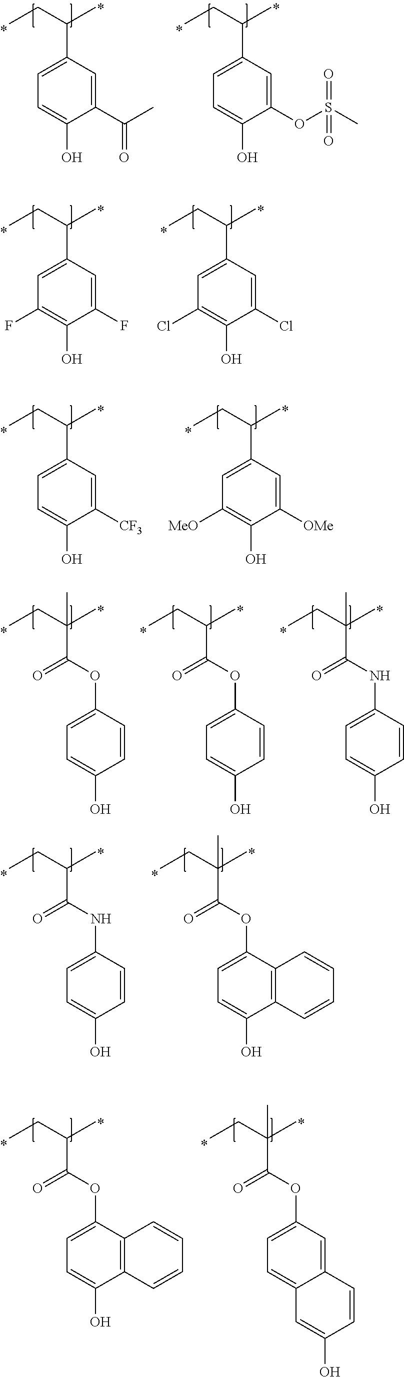

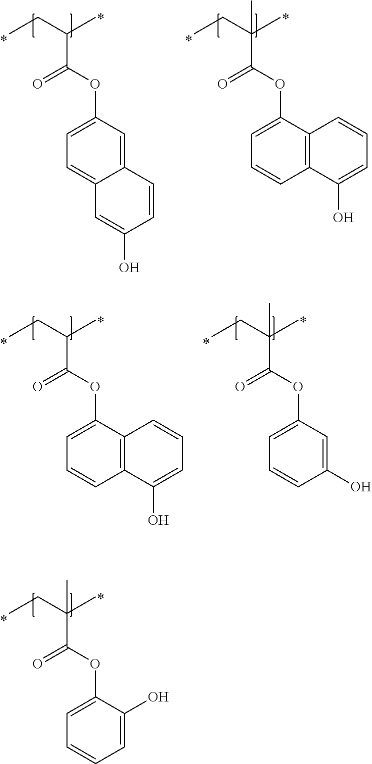

It is preferable that the resin (C) has a structure in which a hydrogen atom of the phenolic hydroxyl group is substituted with a group having a non-acid-decomposable polycyclic alicyclic hydrocarbon structure, in the views that a high glass transition temperature (Tg) is obtained and dry etching resistance is improved.

When the resin (C) has the above-mentioned specific structure, the glass transition temperature (Tg) of the resin (C) is high, so that a very hard resist film can be formed and the acid diffusion or dry etching resistance can be controlled. Accordingly, an acid is highly constrained from diffusion in the area exposed to actinic rays or radiation such as electron beams and extreme ultraviolet rays, and thus, the effects in terms of resolving power, pattern profile, and LER performance in a fine pattern are more excellent. Further, it is considered that the resin (C) has a non-acid-decomposable polycyclic alicyclic hydrocarbon structure, and this contributes to further improvement of dry etching resistance. In addition, although details are unclear, it is presumed that the polycyclic alicyclic hydrocarbon structure has a high hydrogen radical-donating property and works out to a hydrogen source when decomposing a photoacid generator, and as a result, the decomposition efficiency of the photoacid generator is further improved, and in turn, the acid generation efficiency is further enhanced. This is considered to contribute to excellent sensitivity.

In the above-mentioned specific structure which may be contained in the resin (C), an aromatic ring such as a benzene ring, and a group having a non-acid-decomposable polycyclic alicyclic hydrocarbon structure are linked via an oxygen atom derived from a phenolic hydroxyl group. As described above, this structure not only contributes to high dry etching resistance but also enables raising the glass transition temperature (Tg) of the resin (C), such that a combination of these effects provides higher resolving power.

In the present invention, the “non-acid-decomposability” means a property of not causing a decomposition reaction by an acid generated from a photoacid generator.

More specifically, the group having a non-acid-decomposable polycyclic alicyclic hydrocarbon structure is preferably a group which is stable against an acid and an alkali. The group which is stable against an acid and an alkali means a group which does not exhibit acid-decomposability and alkali decomposability. Here, acid decomposability means a property of causing a decomposition reaction by an acid generated from a photoacid generator.

Furthermore, being alkali-decomposable means a property of causing a decomposition reaction by an alkali developer, and examples of the group exhibiting alkali decomposability include a group (for example, a group having a lactone structure) whose dissolution rate in an alkali developer increases by decomposition by an action of an alkali developer known in the art, included in the resin suitably used in a positive tone chemical amplification-type resist composition.

The group having a polycyclic alicyclic hydrocarbon structure is not particularly limited as long as it is a monovalent group having a polycyclic alicyclic hydrocarbon structure, but the total number of carbon atoms thereof is preferably 5 to 40, and more preferably from 7 to 30. The polycyclic alicyclic hydrocarbon structure may have an unsaturated bond in the ring.

The polycyclic alicyclic hydrocarbon structure in the group having a polycyclic alicyclic hydrocarbon structure means a structure having a plurality of monocyclic alicyclic hydrocarbon groups, or a polycyclic alicyclic hydrocarbon structure, and may be bridged. The monocyclic alicyclic hydrocarbon group is preferably a cycloalkyl group having 3 to 8 carbon atoms, and examples thereof include a cyclopropyl group, a cyclopentyl group, a cyclohexyl group, a cyclobutyl group and a cyclooctyl group. The structure having a plurality of monocyclic alicyclic hydrocarbon groups has a plurality of such groups. The structure having a plurality of monocyclic alicyclic hydrocarbon groups preferably has 2 to 4 monocyclic alicyclic hydrocarbon groups, and more preferably has 2 monocyclic alicyclic hydrocarbon groups.

Examples of the polycyclic alicyclic hydrocarbon structure include a bicyclo-, tricyclo-, and tetracyclo-structures having 5 or more carbon atoms, and the polycyclic alicyclic hydrocarbon structure is preferably a polycyclic cyclo-structure having 6 to 30 carbon atoms, and examples thereof include an adamantane structure, a decalin structure, a norbornane structure, a norbornane structure, a cedrol structure, an isobornane structure, a bornane structure, a dicyclopentane structure, an α-pinene structure, a tricyclodecane structure, a tetracyclododecane structure, and an androstane structure. Incidentally, some of carbon atoms in the monocyclic or polycyclic cycloalkyl group may be substituted with a heteroatom such as an oxygen atom.

Preferred examples of the polycyclic alicyclic hydrocarbon structure include an adamantane structure, a decalin structure, a norbornane structure, a norbornane structure, a cedrol structure, a structure having a plurality of cyclohexyl groups a structure having a plurality of cycloheptyl groups, a structure having a plurality of cyclooctyl groups, a structure having a plurality of cyclodecanyl groups, a structure having a plurality of cyclododecanyl groups, and a tricyclodecane structure, and most preferably an adamantane structure from the viewpoint of dry etching resistance (that is, the group having a non-acid-decomposable polycyclic alicyclic hydrocarbon structure is most preferably a group having a non-acid-decomposable adamantane structure).

The chemical formulae of these polycyclic alicyclic hydrocarbon structures (with respect to the structure having a plurality of monocyclic alicyclic hydrocarbon groups, the monocyclic alicyclic hydrocarbon structure corresponding to the monocyclic alicyclic hydrocarbon group (specifically, structures of Formulae (47) to (50))) are shown below.

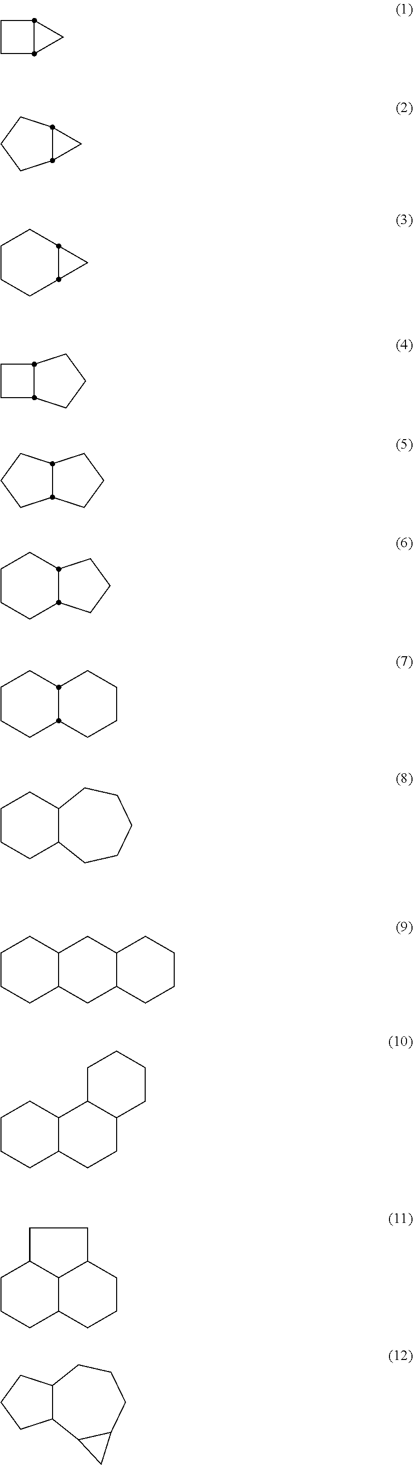

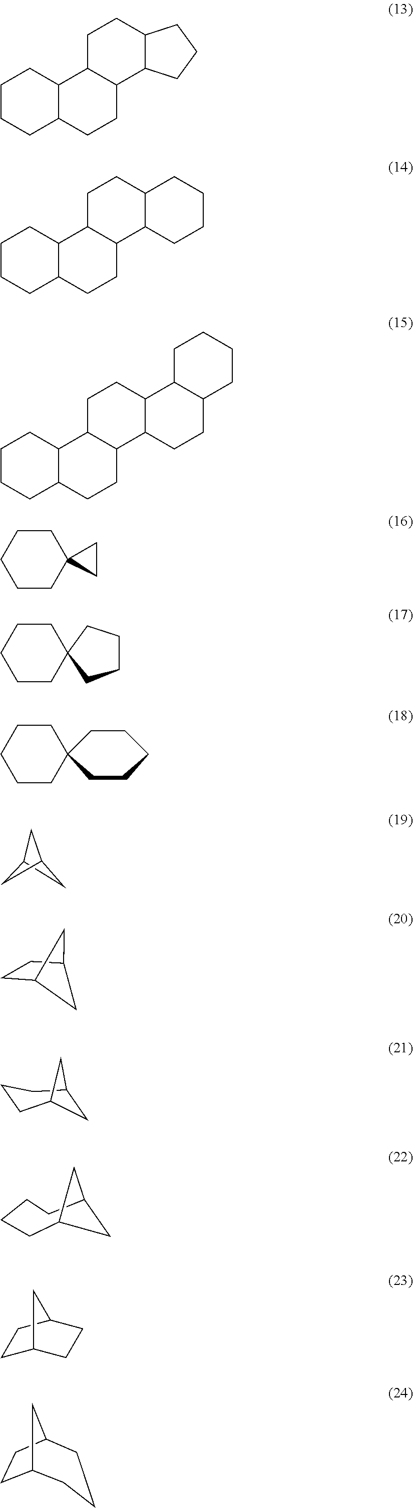

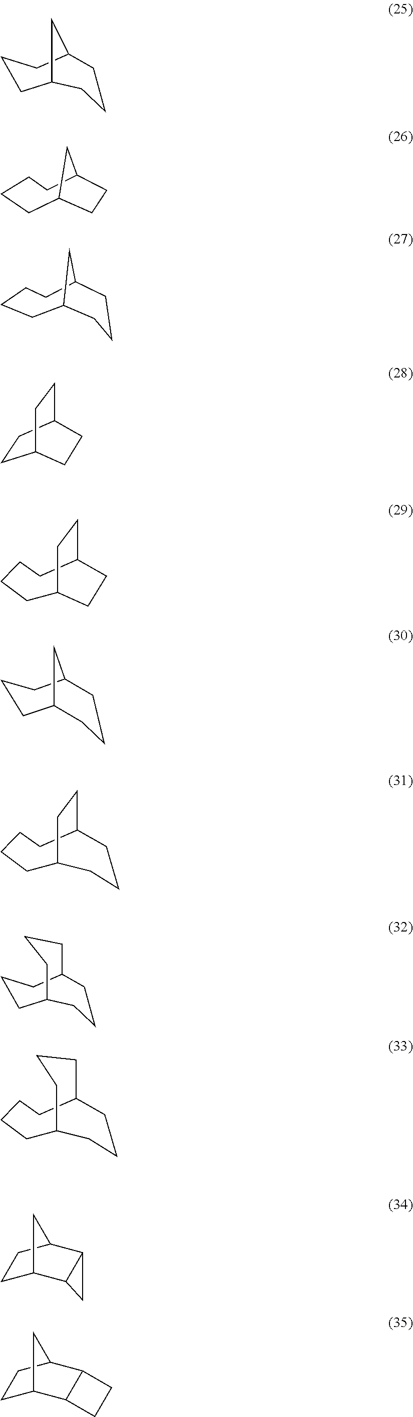

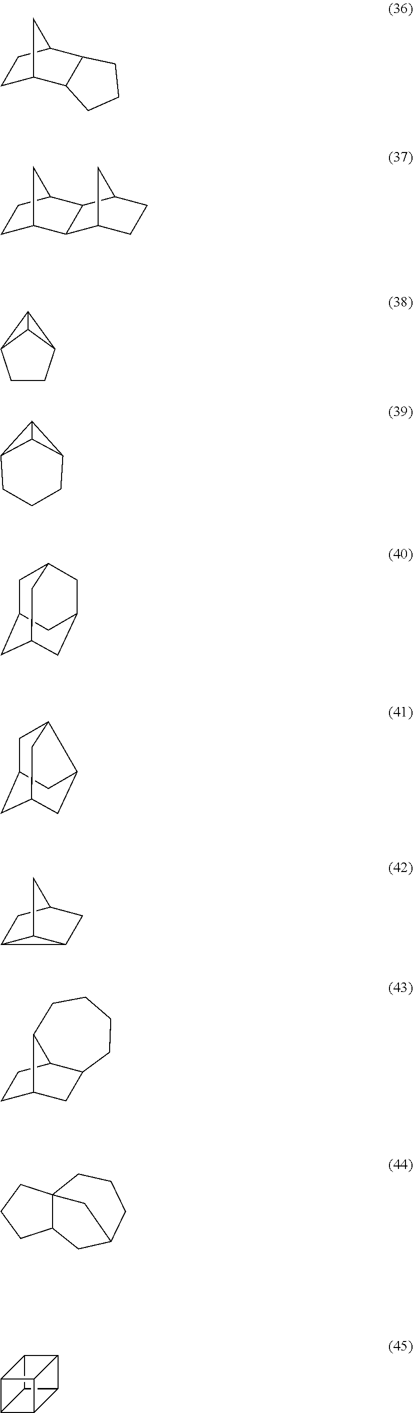

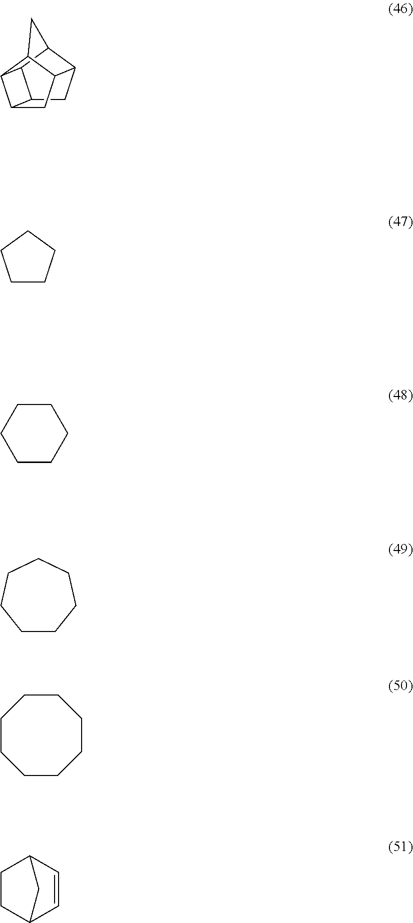 [SMILES: C1C2C3CC4C5CC3C1C5C24 ; C1CCCC1 ; C1CCCCC1 ; C1CCCCCC1 ; C1CCCCCCC1 ; C1=CC2CCC1C2]

Moreover, the polycyclic alicyclic hydrocarbon structure may have a substituent, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, a carbonyl group, a thiocarbonyl group, an alkoxycarbonyl group (preferably having 2 to 7 carbon atoms), and a group formed by a combination of these groups (preferably having 1 to 30 carbon atoms in total, and more preferably having 1 to 15 carbon atoms in total).

The polycyclic alicyclic hydrocarbon structure is preferably a structure represented by any one of Formulae (7), (23), (40), (41), and (51), or a structure of Formula (48) which has two monovalent groups having one arbitrary hydrogen atom as a bonding arm, more preferably a structure represented by any one of Formulae (23), (40), and (51), or a structure of Formula (48) which has two monovalent groups having one arbitrary hydrogen atom as a bonding arm, and most preferably a structure represented by Formula (40).

The group having the polycyclic alicyclic hydrocarbon structure is preferably a monovalent group in which one arbitrary hydrogen atom of the polycyclic alicyclic hydrocarbon structure is used as a bonding arm.

The above-mentioned group having a non-acid-decomposable polycyclic alicyclic hydrocarbon structure, in which a hydrogen atom in the phenolic hydroxyl group is substituted, is preferably contained as a repeating unit having the above-mentioned group having a non-acid-decomposable polycyclic alicyclic hydrocarbon structure, in which a hydrogen atom in the phenolic hydroxyl group is substituted, in the resin (C), and more preferably contained as a repeating unit represented by General Formula (3A) in the resin (C).

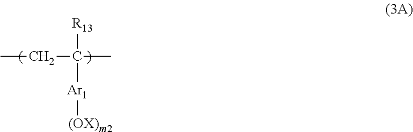

In General Formula (3A), R₁₃ represents a hydrogen atom or a methyl group.

X represents a group having a non-acid-decomposable polycyclic alicyclic hydrocarbon structure.

Ar₁ represents an aromatic ring.

m2 represents an integer of 1 or more.

R₁₃ in General Formula (3A) represents a hydrogen atom or a methyl group, with a hydrogen atom being particularly preferable.

Examples of the aromatic ring of Ar₁ of General Formula (3A) include an aromatic hydrocarbon ring having 6 to 18 carbon atoms, which may have a substituent, such as a benzene ring, a naphthalene ring, an anthracene ring, a fluorene ring, and a phenanthrene ring, or an aromatic ring heterocycle including a hetero ring such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among these, a benzene ring and a naphthalene ring are preferable from the viewpoint of resolution, and a benzene ring is the most preferable.

The aromatic ring of Ar₁ may have a substituent, in addition to the group represented by —OX, and examples of the substituent include an alkyl group (preferably having 1 to 6 carbon atoms), a cycloalkyl group (preferably having 3 to 10 carbon atoms), an aryl group (preferably having 6 to 15 carbon atoms), a halogen atom, a hydroxyl group, an alkoxy group (preferably having 1 to 6 carbon atoms), a carboxyl group, and an alkoxycarbonyl group (preferably having 2 to 7) carbon atoms, with an alkyl group, an alkoxy group, and an alkoxycarbonyl group being preferable, and an alkoxy group being more preferable.

X represents a group having a non-acid-decomposable polycyclic alicyclic hydrocarbon structure. Specific examples and preferred ranges of the group having a non-acid-decomposable polycyclic alicyclic hydrocarbon structure represented by X are the same as those described above. X is more preferably a group represented by —Y—X₂ in General Formula (4A), which will be described later.

m2 is preferably an integer of 1 to 5 and most preferably 1. When m2 is 1 and Ar₁ is a benzene ring, the substitution position of —OX may be a para-position, a meta-position, or an ortho-position with respect to the bonding position of the benzene ring to the polymer main chain but is preferably a para-position or a meta-position, and more preferably a para-position.

In the present invention, the repeating unit represented by General Formula (3A) is preferably a repeating unit represented by General Formula (4A).

If the resin (C) having the repeating unit represented by General Formula (4A) is used, Tg of the resin (C) is high and a very hard resist film is formed, so that the acid diffusion or the dry etching resistance can be more reliably controlled.

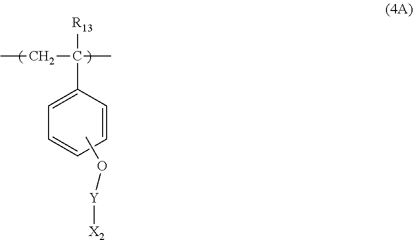

In General Formula (4A), R₁₃ represents a hydrogen atom or a methyl group.

Y represents a single bond or a divalent linking group.

X₂ represents a non-acid-decomposable polycyclic alicyclic hydrocarbon group.

Preferred examples of the repeating unit represented by General Formula (4A), used in the present invention, will be described below.

R₁₃ in General Formula (4A) represents a hydrogen atom or a methyl group, with a hydrogen atom being particularly preferable.

In General Formula (4A), Y is preferably a divalent linking group. The divalent linking group of Y is preferably a carbonyl group, a thiocarbonyl group, an alkylene group (preferably having 1 to 10 carbon atoms, and more preferably having 1 to 5 carbon atoms), a sulfonyl group, —COCH₂—, —NH—, or a divalent linking group formed of a combination thereof (preferably having 1 to 20 carbon atoms in total, more preferably a carbonyl group, —COCH₂—, a sulfonyl group, —CONH—, or —CSNH—, and more preferably 1 to 10 carbon atoms in total), still more preferably a carbonyl group or COCH₂—, and particularly preferably a carbonyl group.

X₂ represents a polycyclic alicyclic hydrocarbon group and is non-acid-decomposable. The total number of carbon atoms of the polycyclic alicyclic hydrocarbon group is preferably 5 to 40, and more preferably 7 to 30. The polycyclic alicyclic hydrocarbon group may have an unsaturated bond in the ring.

Such the polycyclic alicyclic hydrocarbon group is a group having a plurality of monocyclic alicyclic hydrocarbon groups, or a polycyclic alicyclic hydrocarbon group, and may be bridged. The monocyclic alicyclic hydrocarbon group is preferably a cycloalkyl group having 3 to 8, and examples thereof include a cyclopropyl group, a cyclopentyl group, a cyclohexyl group, a cyclobutyl group, and a cyclooctyl group. The group has a plurality of such groups. The group having a plurality of monocyclic alicyclic hydrocarbon groups preferably has 2 to 4 monocyclic alicyclic hydrocarbon groups, more preferably has 2 monocyclic alicyclic hydrocarbon groups.

Examples of the polycyclic alicyclic hydrocarbon group includes a group containing, for example, a bicyclo-, tricyclo-, or tetracyclo-structure, or the like, having 5 or more carbon atoms, and is preferably a group containing a polycyclic cyclo-structure having 6 to 30 carbon atoms, and examples thereof include an adamantyl group, a norbomyl group, an isoboronyl group, a camphanyl group, a dicyclopentyl group, an α-pinen group, a tricyclodecanyl group, a tetracyclododecyl group, and an androstanyl group. Incidentally, some of carbon atoms in the monocyclic or polycyclic cycloalkyl group may be substituted with a heteroatom such as an oxygen atom.

The polycyclic alicyclic hydrocarbon group of X₂ is preferably a group having a plurality of adamantyl groups, decalin groups, norbomyl groups, norbomanyl groups, cedrol groups, or cyclohexyl groups, a group having a plurality of cycloheptyl groups, a group having a plurality of a cyclooctyl groups, a group having a plurality of cyclodecanyl groups, a group having a plurality of cyclododecanyl groups, or a tricyclodecanyl group, and most preferably an adamantyl group from the viewpoint of dry etching resistance. Examples of the chemical formulae of the polycyclic alicyclic hydrocarbon structure in the polycyclic alicyclic hydrocarbon group of X₂ include the same ones as the chemical formulae of the polycyclic alicyclic hydrocarbon structure in the above-mentioned group having a polycyclic alicyclic hydrocarbon structure, and preferred ranges thereof are also the same. Examples of the polycyclic alicyclic hydrocarbon group of X₂ include a monovalent group in one arbitrary hydrogen atom in the above-mentioned polycyclic alicyclic hydrocarbon structure is used as a bonding arm.

Furthermore, the alicyclic hydrocarbon group may have a substituent, and examples of the substituent include the same ones as those mentioned above as the substituent which may be contained in the polycyclic alicyclic hydrocarbon structure.

The substitution position of —O—Y—X₂ in General Formula (4A) may be a para-position, a meta-position, or an ortho-position with respect to the bonding position of the benzene ring, but is preferably a para-position.

In the present invention, the repeating unit represented by General Formula (3A) is most preferably a repeating unit represented by General Formula (4′).

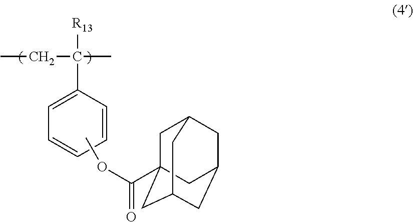

In General Formula (4′), R₁₃ represents a hydrogen atom or a methyl group.

R₁₃ in General Formula (4′) represents a hydrogen atom or a methyl group, with a hydrogen atom being particularly preferable.

The substitution position of the adamantyl ester group in General Formula (4′) may be a para-position, a meta-position, or an ortho-position with respect to the bonding position of the benzene ring to the polymer main chain, but is preferably a para-position.

Specific examples of the repeating unit represented by General Formula (3A) include the following ones.

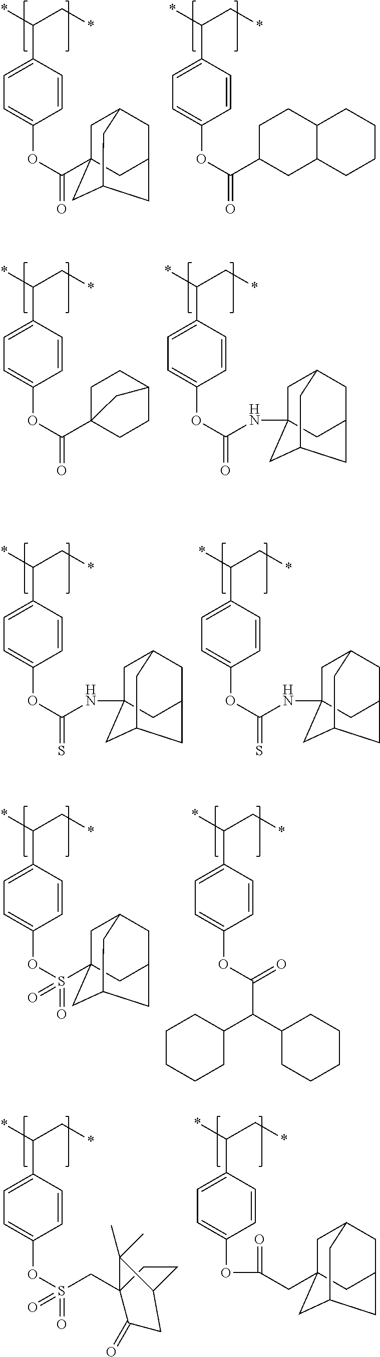

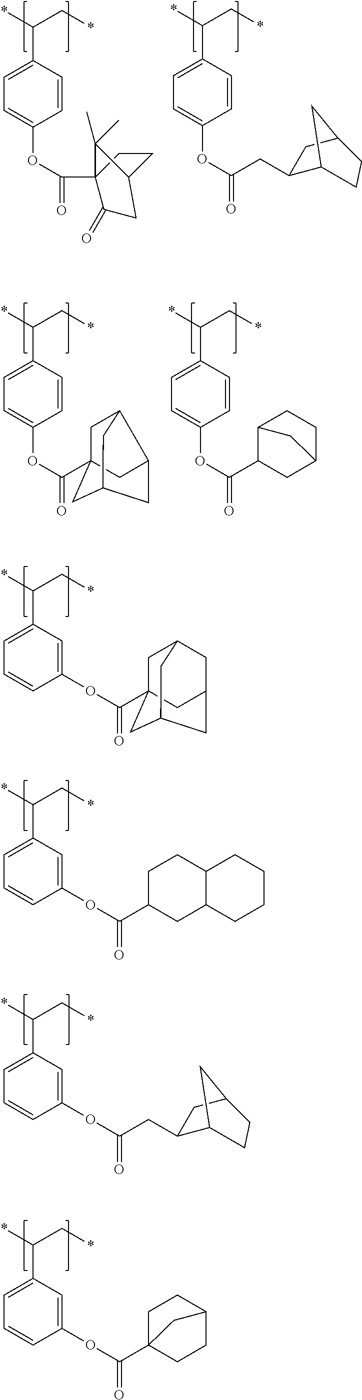

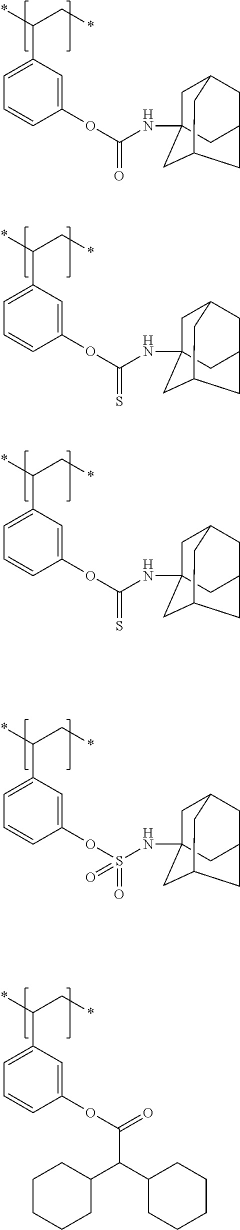

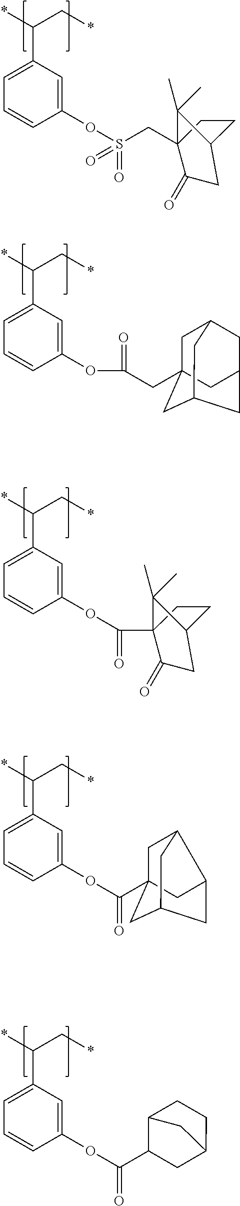

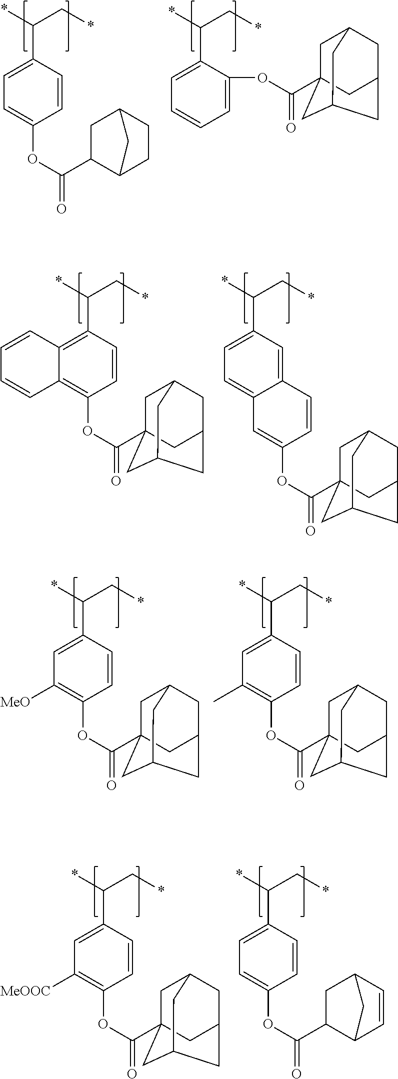

In a case where the resin (C) contains a repeating unit having the above-mentioned group having a non-acid-decomposable polycyclic alicyclic hydrocarbon structure, in which a hydrogen atom in the phenolic hydroxyl group is substituted, the content of the repeating unit is preferably 1% to 40% by mole, and more preferably 2% to 30% by mole, with respect to all the repeating units of the resin (C).

The resin (C) may further include a repeating unit having a structural site which generates upon irradiation with actinic rays or radiation to generate an acid in the side chain.

It is also preferable that the resin (C) further has repeating units below (hereinafter also referred to as “other repeating units”) as repeating units other than the above repeating units.

Examples of polymerizable monomers for forming other repeating units include styrene, alkyl-substituted styrene, alkoxy-substituted styrene, halogen-substituted styrene, O-alkylated styrene, O-acylated styrene, hydrogenated hydroxystyrene, maleic acid anhydride, acrylic acid derivatives (acrylic acid, acrylic ester, and the like), methacrylic acid derivatives (methacrylic acid, methacrylic ester, and the like), N-substituted maleimide, acrylonitrile, methacrylonitrile, vinyl naphthalene, vinyl anthracene, and indene, which may have a substituent.

The resin (C) may or may not contain these other repeating units, but in a case where these other repeating units are contained, the content of these other repeating units in the resin (C) is generally 1% to 30% by mole, preferably 1% to 20% by mole, and more preferably 2% to 10% by mole, with respect to all the repeating units constituting the resin (C).

The resin (C) may contain a repeating unit represented by General Formula (IV) or General Formula (V).

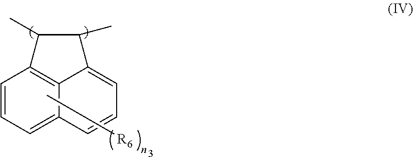

In the formula,

R₆ represents a hydrogen atom, a hydroxy group, a linear, branched, or cyclic alkyl group having 1 to 10 carbon atoms, an alkoxy group or acyloxy group, a cyano group, a nitro group, an amino group, a halogen atom, an ester group (—OCOR or —COOR: R is an alkyl or fluorinated alkyl group having 1 to 6 carbon atoms), or a carboxyl group.

n3 represents an integer of 0 to 6.

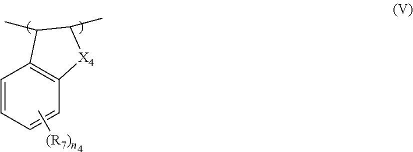

In the formula,

R₇ represents a hydrogen atom, a hydroxy group, a linear, branched, or cyclic alkyl group having 1 to 10 carbon atoms, an alkoxy group or acyloxy group, a cyano group, a nitro group, an amino group, a halogen atom, an ester group (—OCOR or —COOR: R is an alkyl group or fluorinated alkyl group, having 1 to 6 carbon atoms), or a carboxyl group.

n4 represents an integer of 0 to 4.

X₄ represents a methylene group, an oxygen atom, or a sulfur atom.

Specific examples of a repeating unit represented by General Formula (IV) or General Formula (V) are shown below, but are not limited thereto.

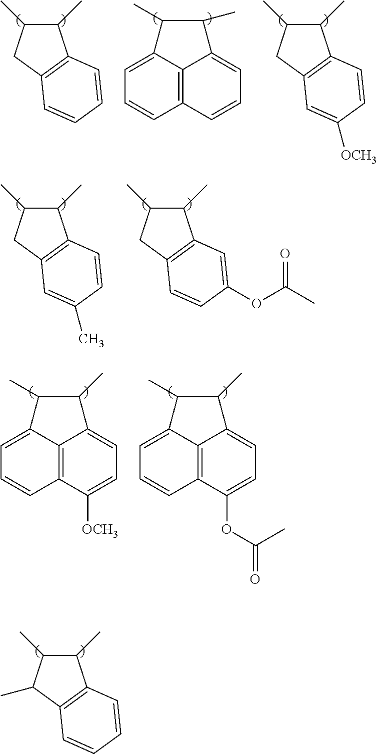

Furthermore, the resin (C) may contain a repeating unit having a silicon atom in the side chain.

The repeating unit having a silicon atom in the side chain is not particularly limited as long as it has a silicon atom in the side chain, and examples thereof include a (meth)acrylate-based repeating unit having a silicon atom, and a vinyl-based repeating unit having a silicon atom.

The repeating unit having a silicon atom in the side chain is preferably a repeating unit which does not have a structure (acid-decomposable group) protected with a leaving group that leaves by the decomposition of a polar group by the action of an acid.

The repeating unit having a silicon atom in the side chain is typically a repeating unit having a group having a silicon atom in the side chain, and examples of the group having a silicon atom include a trimethylsilyl group, a triethylsilyl group, a triphenylsilyl group, a tricyclohexylsilyl group, a tristrimethylsiloxysilyl group, a tristrimethylsilylsilyl group, a methylbistrimethylsilylsilyl group, a methylbistrimethylsiloxysilyl group, dimethyltrimethylsilylsilyl group, dimethyltrimethylsiloxysilyl group, a cyclic or linear polysiloxane as described below, and a cage-type, ladder-type, or random-type silsesquioxane structure. In the formulae, R and R¹ each independently represent a monovalent substituent. * represents a bonding arm.

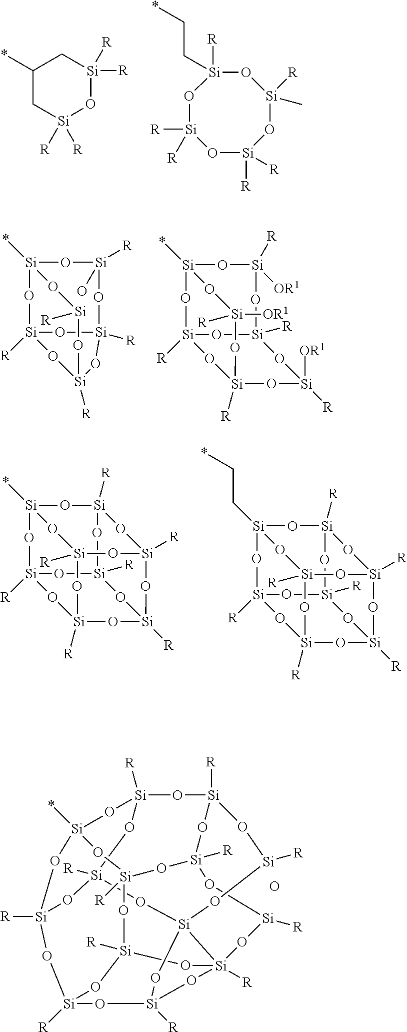

Suitable examples of the repeating unit having the above-mentioned group include a repeating unit derived from an acrylate or methacrylate compound having the above-mentioned group, and a repeating unit derived from a compound having the above-mentioned group and a vinyl group.

The repeating unit having a silicon atom is preferably a repeating unit having a silsesquioxane structure, and thus, it is ultrafine (for example, a line width of 50 nm or less), further, in the formation of a pattern having a cross-sectional shape with a high aspect ratio (for example, a film thickness/line width of 2 or more), highly excellent collapse performance can be expressed.

Examples of the silsesquioxane structure include a cage-type silsesquioxane structure, a ladder-type silsesquioxane structure, and a random-type silsesquioxane structure. Among these, a cage-type silsesquioxane structure is preferable.

Here, the cage-type silsesquioxane structure is a silsesquioxane structure having a case-shaped skeleton. The cage-type silsesquioxane structure may be a complete cage-type silsesquioxane structure or an incomplete cage-type silsesquioxane structure, and is preferably a complete cage-type silsesquioxane structure.

Furthermore, the ladder-type silsesquioxane structure is a silsesquioxane structure having a ladder-shaped skeleton.

Furthermore, the random-type silsesquioxane structure is a silsesquioxane structure having a random skeleton.

The cage-type silsesquioxane structure is preferably a siloxane structure represented by Formula (S).

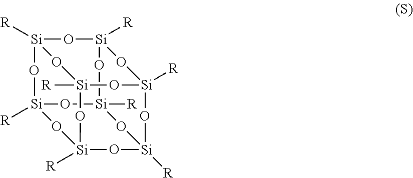

In Formula (S), R represents a monovalent substituent. R's which are present in plural numbers may be the same as or different from each other.

The monovalent substituent is not particularly limited, and specific examples thereof include a halogen atom, a hydroxy group, a nitro group, a carboxy group, an alkoxy group, an amino group, a mercapto group, a blocked mercapto group (for example, a mercapto group blocked with an acyl group), an acyl group, an imido group, a phosphino group, a phosphinyl group, a silyl group, a vinyl group, a hydrocarbon group which may have a heteroatom, a (meth)acryl group-containing group, and an epoxy group-containing group.

Examples of the halogen atom include a fluorine atom, a chlorine atom, a bromine atom, and an iodine atom.

Examples of the heteroatom of the hydrocarbon group which may have a heteroatom include an oxygen atom, a nitrogen atom, a sulfur atom, and a phosphorus atom.

Examples of the hydrocarbon group which may have a heteroatom include an aliphatic hydrocarbon group, an aromatic hydrocarbon group, and a group formed by a combination thereof.

The aliphatic hydrocarbon group may be any one of a linear type, a branched type, and a cyclic type. Specific examples of the aliphatic hydrocarbon group include a linear or branched alkyl group (particularly, having 1 to 30 carbon atoms), a linear or branched alkenyl group (particularly, having 2 to 30 carbon atoms), and a linear or branched alkanyl group (particularly, having 2 to 30 carbon atoms).

Examples of the aromatic hydrocarbon group include an aromatic hydrocarbon group having 6 to 18 carbon atoms, such as a phenyl group, a tolyl group, a xylyl group, and a naphthyl group.

The repeating unit having a silicon atom is preferably represented by Formula (I).

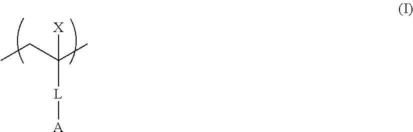

In Formula (I), L represents a single bond or a divalent linking group.

Examples of the divalent linking group include an alkylene group, a —COO-Rt- group, and an —O-Rt- group. In the formulae, Rt represents an alkylene group or a cycloalkylene group.

L is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

In Formula (I), X represents a hydrogen atom or an organic group.

Examples of the organic group include a fluorine atom, an alkyl group which may have a substituent such as a hydroxyl group, with a hydrogen atom, a methyl group, a trifluoromethyl group, or a hydroxymethyl group being preferable.

In Formula (I), A represents a silicon atom-containing group. Among these, a group represented by Formula (a) or (b) is preferable.

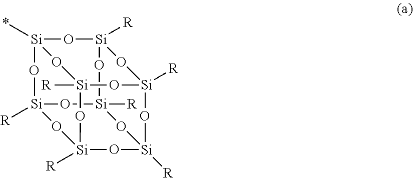

In Formula (a), R represents a monovalent substituent. R's which are present in plural numbers may be the same as or different from each other. Specific examples and suitable aspect of R are the same as in Formula (S). Further, in a case where A in Formula (I) is a group represented by Formula (a), Formula (I) is represented by Formula (I-a).

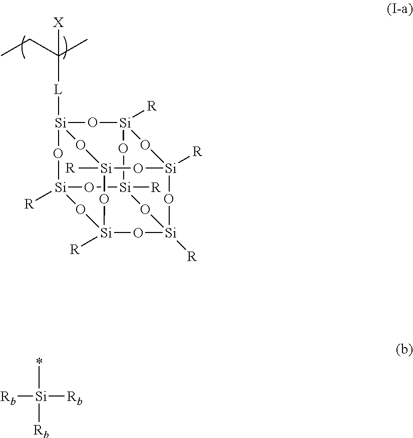

In Formula (b), R_{b} represents a hydrocarbon group which may have a heteroatom. Specific examples and suitable aspect of the hydrocarbon group which may have a heteroatom are the same as for R in Formula (S).

The resin (C) may one kind or two or more kinds of repeating unit having a silicon atom in the side chain.

The content of the repeating unit having a silicon atom in the side chain is preferably 1% to 30% by mole, more preferably 1% to 20% by mole, and still more preferably 1% to 10% by mole, with respect to all the repeating units of the resin (C).

The resin (C) can be synthesized by a known radical polymerization method, anion polymerization method or a living radical polymerization method (an iniferter method or the like). For example, in the anion polymerization method, a polymer can be obtained by dissolving a vinyl monomer in an appropriate organic solvent, and causing the vinyl monomer to react, usually under cooling conditions, by using a metal compound (butyllithium or the like) as an initiator.

As the resin (C), a polyphenol compound produced by a condensation reaction between an aromatic ketone or an aromatic aldehyde, and a compound containing 1 to 3 phenolic hydroxyl groups (for example, JP2008-145539A), a calixarene derivative (for example, JP2004-18421A), a Noria derivative (for example, JP2009-222920A), a polyphenol derivative (for example, JP2008-94782A) can also be applied, and the resin (C) may also be synthesized by modifying these compounds by polymer reactions.

Furthermore, it is preferable that the resin (C) is produced by modifying a polymer synthesized by a radical polymerization method or an anion polymerization method by a polymer reaction.

The weight-average molecular weight of the resin (C) is preferably 1,000 to 200,000, more preferably 2,000 to 50,000, and still more preferably 2,000 to 15,000, as a value in terms of polystyrene by means of a GPC method.

The dispersity (molecular weight distribution) (Mw/Mn) of the resin (C) is preferably 2.0 or less, and from the standpoint of improving the sensitivity and the resolution, preferably 1.0 to 1.80, more preferably 1.0 to 1.60, and most preferably 1.0 to 1.20. By employing living polymerization such as living anionic polymerization, the high-molecular-weight compound thus obtained can have a uniform dispersity (molecular weight distribution), which is thus preferable. The weight-average molecular weight and the dispersity of the resin (C) are measured by the above-mentioned method.

The content of the resin (C) with respect to the composition of the present invention is preferably 30% to 95% by mass, more preferably 40% to 90% by mass, and still more preferably 50% to 85% by mass, with respect to the total solid contents of the composition.

Specific examples of the resin (C) are shown below, but the present invention is not limited thereto.

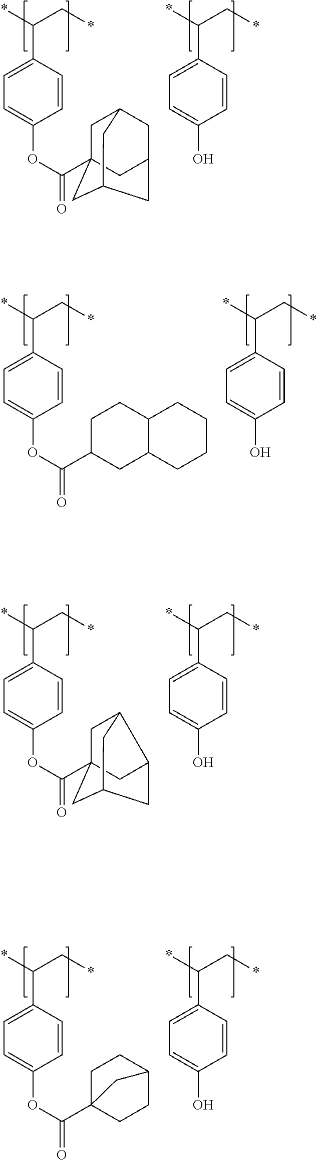

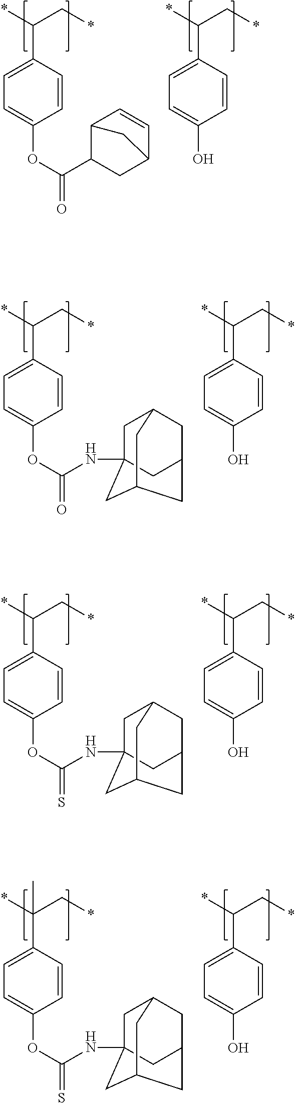

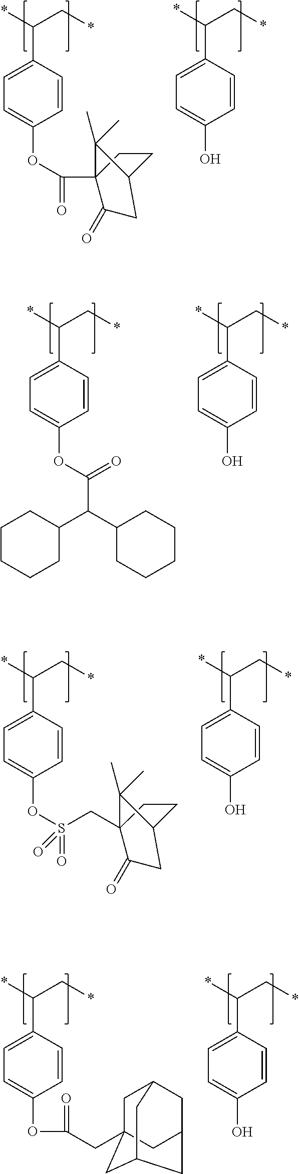

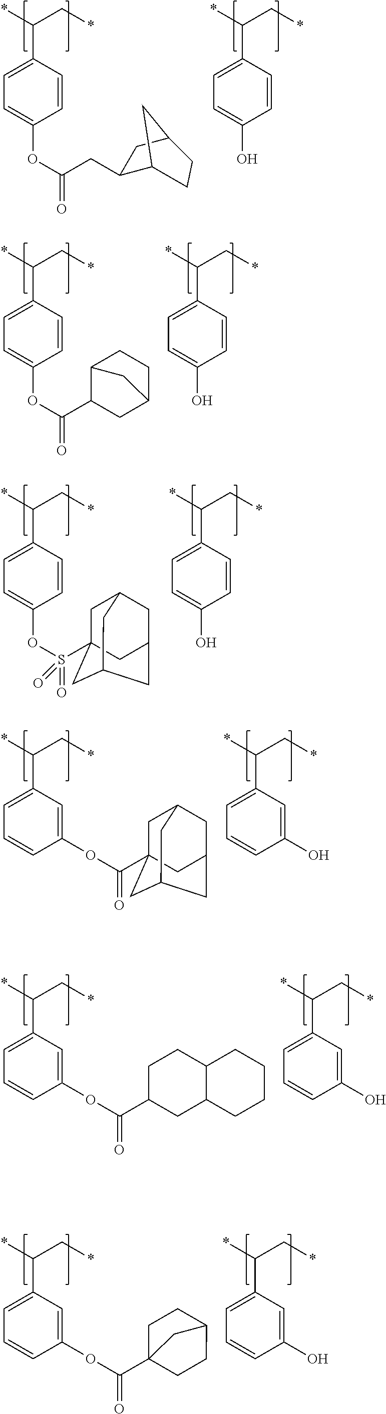

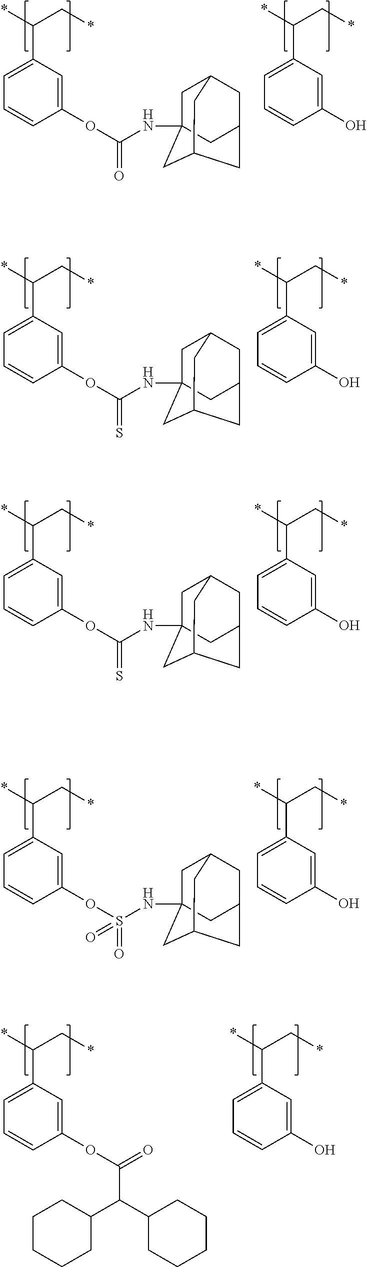

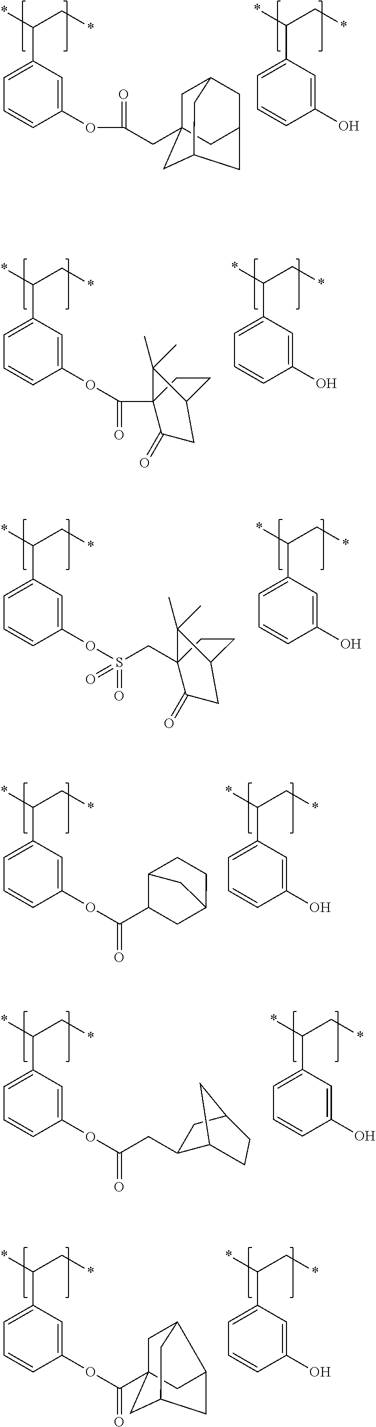

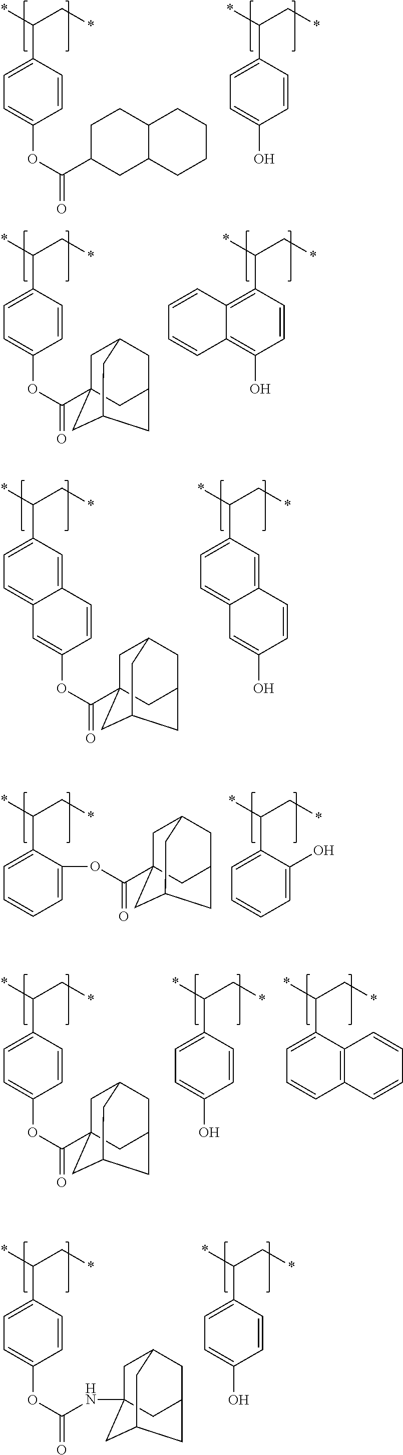

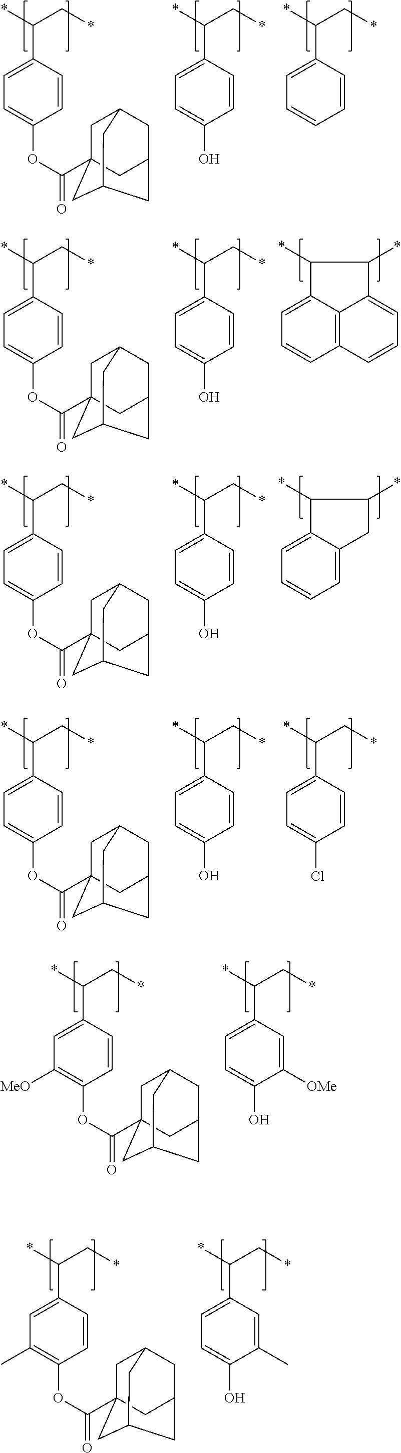

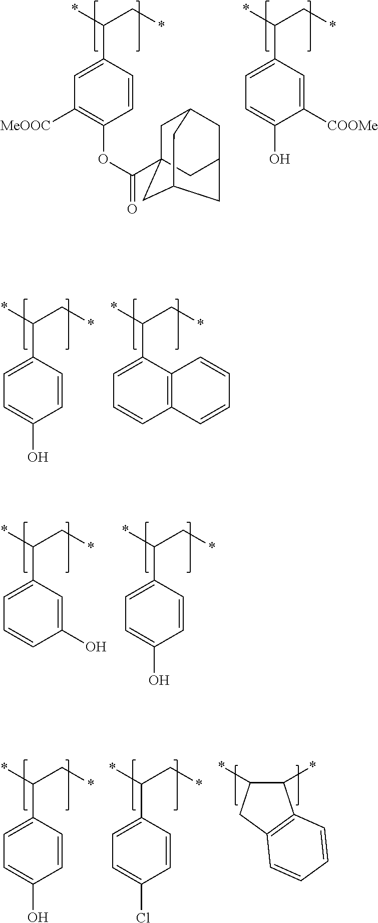

[Compound (D) that Generates Acid Upon Irradiation with Actinic Rays or Radiation]

The actinic ray-sensitive or radiation-sensitive composition according to the first embodiment of the present invention preferably contains a compound (D) that generates an acid upon irradiation with actinic rays or radiation (hereinafter also referred to as a “compound (D)”, an “acid generator”, or a “photoacid generator”).

The compound (D) that generates an acid upon irradiation with actinic rays or radiation may be in a form of a low-molecular-weight compound or in a form introduced into a part of a polymer. Further, a combination of the form of a low-molecular-weight compound and the form introduced into a part of a polymer may also be used.

In a case where the compound (D) that generates an acid upon irradiation with actinic rays or radiation is in the form of a low-molecular-weight compound, the molecular weight thereof is preferably 3,000 or less, more preferably 2,000 or less, and still more preferably 1,000 or less.

In a case where the compound (D) that generates an acid upon irradiation with actinic rays or radiation is in the form introduced into a part of a polymer, it may be introduced into a part of the above-mentioned resin (C) or into a resin other than the above-mentioned resin (C).

A preferred embodiment of the acid generator is an onium compound. Examples of the onium compound include a sulfonium salt, an iodonium salt, and a phosphonium salt, with a sulfonium salt being preferable.

In addition, another preferred embodiment of the acid generator may be a compound that generates a sulfonic acid, an imide acid or a methide acid upon irradiation with actinic rays or radiation. Examples of the acid generator in this embodiment include a sulfonium salt, an iodonium salt, a phosphonium salt, oxime sulfonate, and imidosulfonate.

The acid generator is preferably a compound that generates an acid upon irradiation with electron beams or extreme ultraviolet rays.

In the present invention, preferred examples of the salt onium compound include a sulfonium compound represented by General Formula (7) and an iodonium compound represented by General Formula (8).

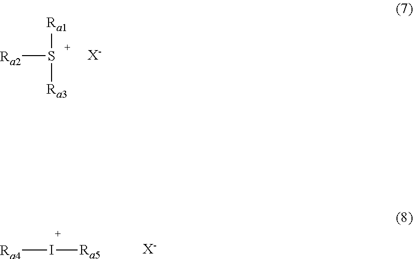

In General Formula (7) and General Formula (8),

Rₐ₁, Rₐ₂, Rₐ₃, Rₐ₄, and Rₐ₅ each independently represent an organic group.

X⁻ represents an organic anion.

The sulfonium compound represented by General Formula (7) and the iodonium compound represented by General Formula (8) will be described in more detail below.

Rₐ₁, Rₐ₂, and Rₐ₃ in General Formula (7), and Rₐ₄ and Rₐ₅ in General Formula (8) each independently represent an organic group, as described above, and preferably at least one Rₐ₁, Rₐ₂, or Rₐ₃, and at least one of Rₐ₄ or Rₐ₅ are each an aryl group. The aryl group is preferably a phenyl group or a naphthyl group, and more preferably a phenyl group.

Examples of the organic anion of X⁻ in General Formulae (7) and (8) include a sulfonate anion, a carboxylate anion, a bis(alkylsulfonyl)imide anion, and a tris(alkylsulfonyl)methide anion. The organic anion is preferably an organic anion represented by General Formula (9), (10), or (11), and more preferably an organic anion represented by General Formula (9).

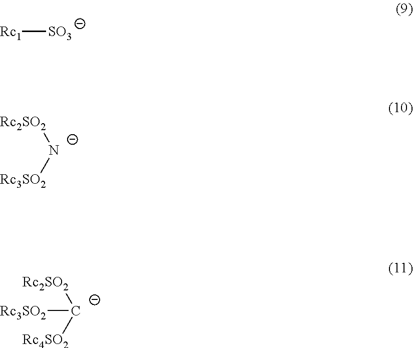

In General Formulae (9), (10), and (11), R_{c1}, R_{c2}, R_{c3}, and R_{c4} each independently represent an organic group.

The organic anion of X⁻ corresponds to a sulfonic acid, an imide acid, or a methide acid which is an acid generated upon irradiation with actinic rays or radiation such as electron beams and extreme ultraviolet rays.

Examples of the organic group of R_{c1}, R_{c2}, R_{c3}, and R_{c4} include an alkyl group, a cycloalkyl group, an aryl group, and a group formed by a combination of a plurality of such groups. Among these organic groups, an alkyl group substituted with a fluorine atom or a fluoroalkyl group at the 1-position, a cycloalkyl group substituted with a fluorine atom or a fluoroalkyl group, and a phenyl group substituted with a fluorine atom or a fluoroalkyl group are more preferable. By having a fluorine atom or a fluoroalkyl group, the acidity of the acid generated upon irradiation with light is increased, and the sensitivity is enhanced. Here, it is preferable that the terminal group contains no fluorine atom as a substituent.

Particularly preferred examples of the organic anion represented by General Formula (9), (10), or (11) include the following ones. In the following examples, A represents a cyclic organic group.

⁻SO₃—CF₂—CH₂—OCO-A, ⁻SO₃—CF₂—CHF—CH₂—OCO-A, ⁻SO₃—CF₂—COO-A, ⁻SO₃—CF₂—CF₂—CH₂-A, ⁻SO₃—CF₂—CH(CF₃)—OCO-A

For the purpose of adjusting the cross-sectional shape of a pattern, the number of fluorine atoms contained in the acid generator is appropriately adjusted. By adjusting the fluorine atoms, it is possible to control the uneven localization on the surface of the acid generator. As the number of fluorine atoms contained in the acid generator is larger, there is tendency of uneven localization on the surface.

Moreover, in the present invention, from the viewpoint of suppressing the acid generated by exposure from diffusing to the unexposed area and improving the resolution or the pattern profile, the compound (D) is preferably a compound that generates an acid in a size with a volume of 130 Å³ or more (more preferably a sulfonic acid), more preferably a compound that generates an acid in a size with a volume of 190 Å³ or more (more preferably a sulfonic acid), still more preferably a compound that generates an acid in a size with a volume of 270 Å³ or more (more preferably sulfonic acid), and particularly preferably a compound that generates an acid in a size with a volume of 400 Å³ or more (more preferably sulfonic acid), upon irradiation with electron beams or extreme ultraviolet rays. Here, from the viewpoint of the sensitivity or the solubility in the coating solvent, the volume above is preferably 2,000 Å³ or less, and more preferably 1,500 Å³ or less. Here, 1 Å³ corresponds to 0.1 nm. The value of the volume above was determined using “WinMOPAC” manufactured by Fujitsu Limited. That is, first, the chemical structure of the acid in each compound is input, next, using this structure as an initial structure, the most stable steric conformation of each acid is determined by molecular force field calculation according to an MM3 method, and then, molecular orbital calculation using a PM3 method is performed with respect to the most stable steric conformation, whereby the “accessible volume” of each acid can be calculated.

With regard to the compound (D), reference can be made to paragraphs [0368] to [0377] of JP2014-41328A, and paragraphs [0240] to [0262] of JP2013-228681A ([0339] of the corresponding US2015/004533A), the contents of which are incorporated in the present specification. Further, specific preferred examples thereof include the following compounds, but are not limited thereto.

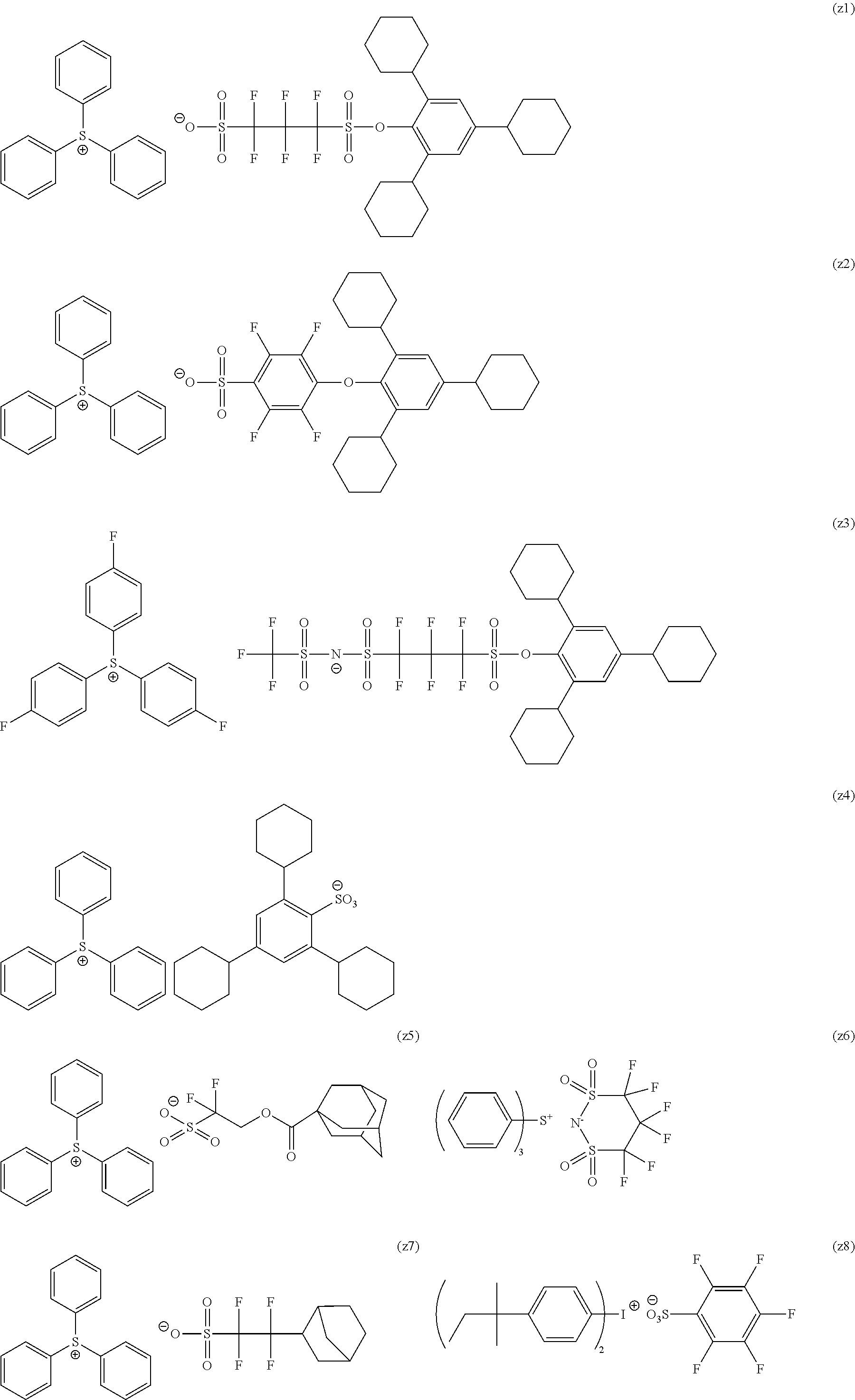

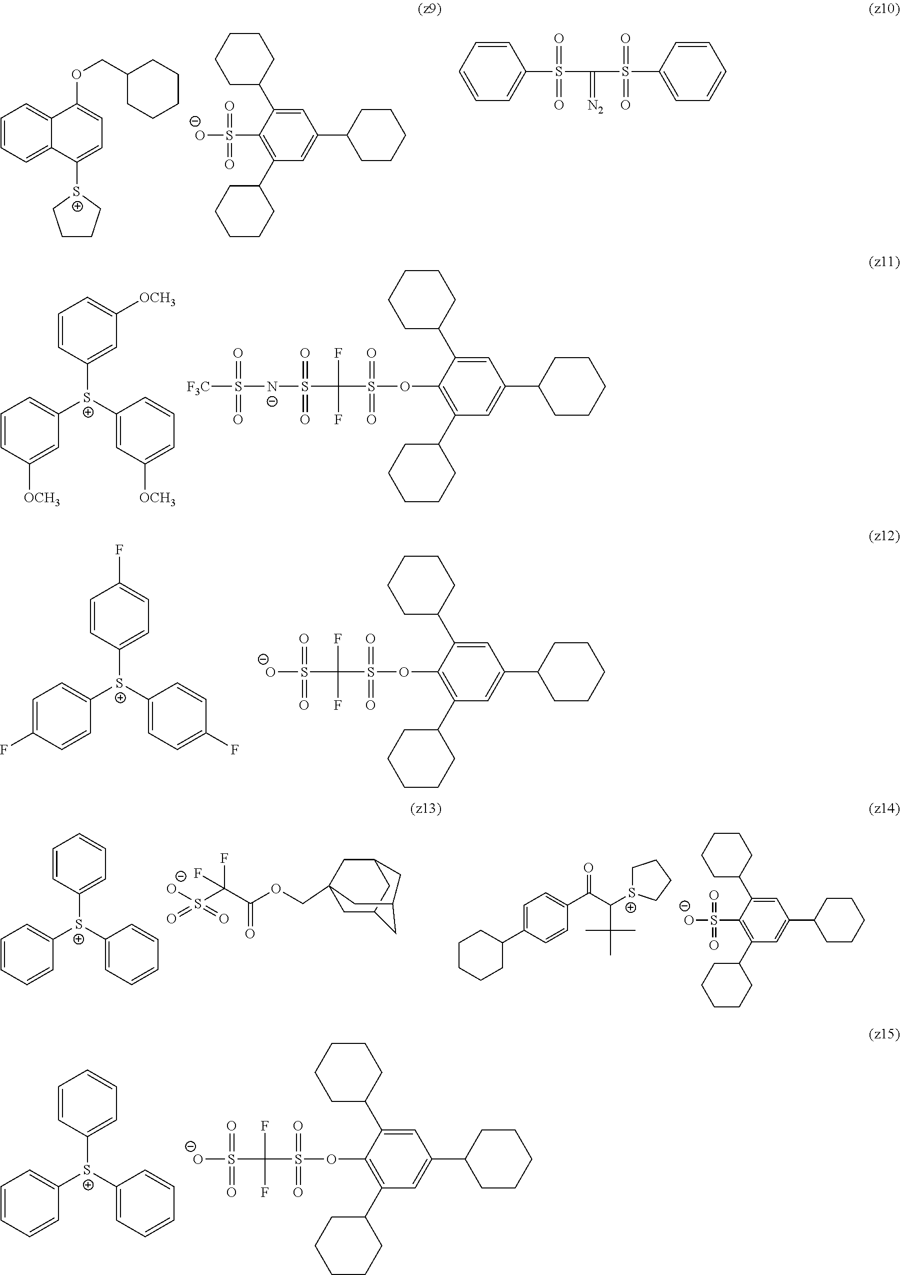

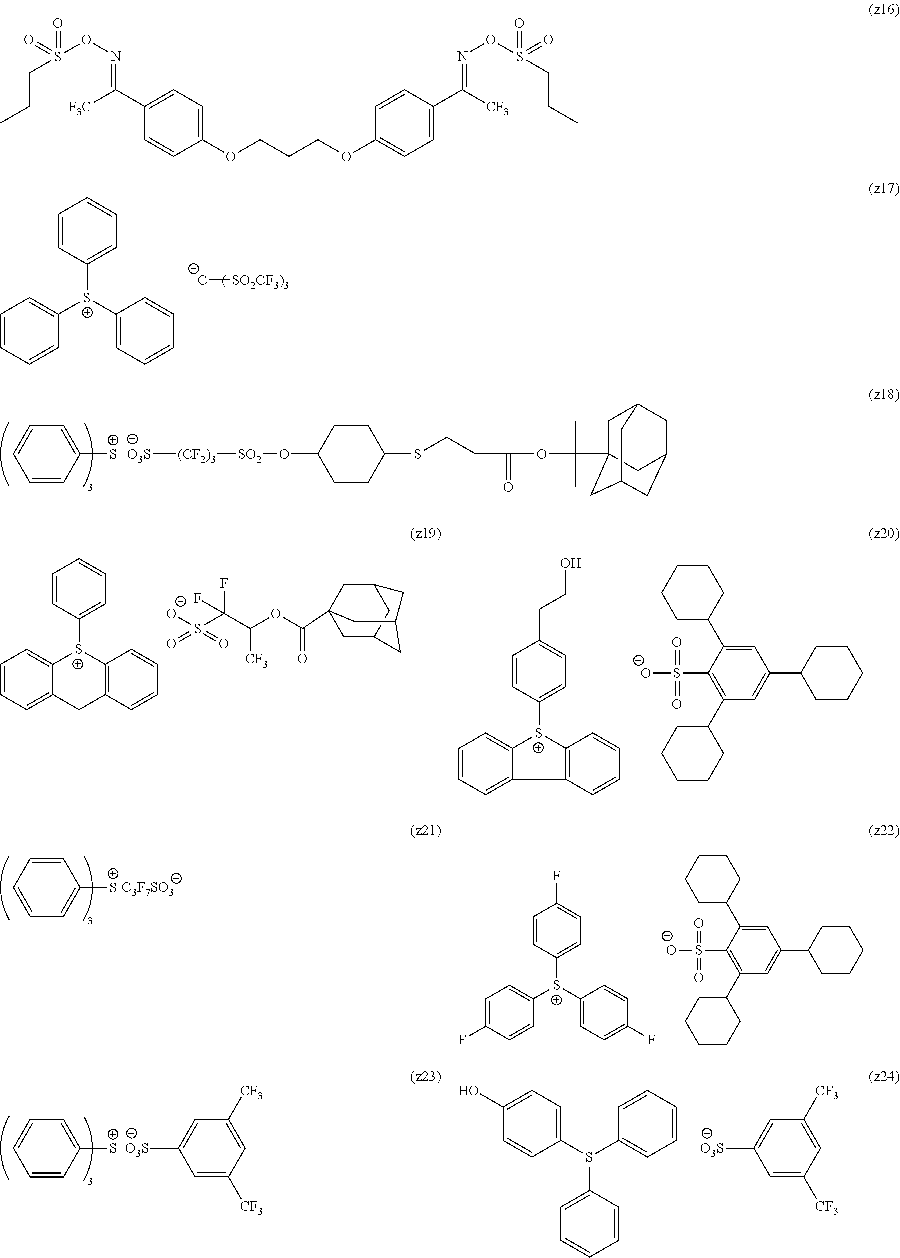

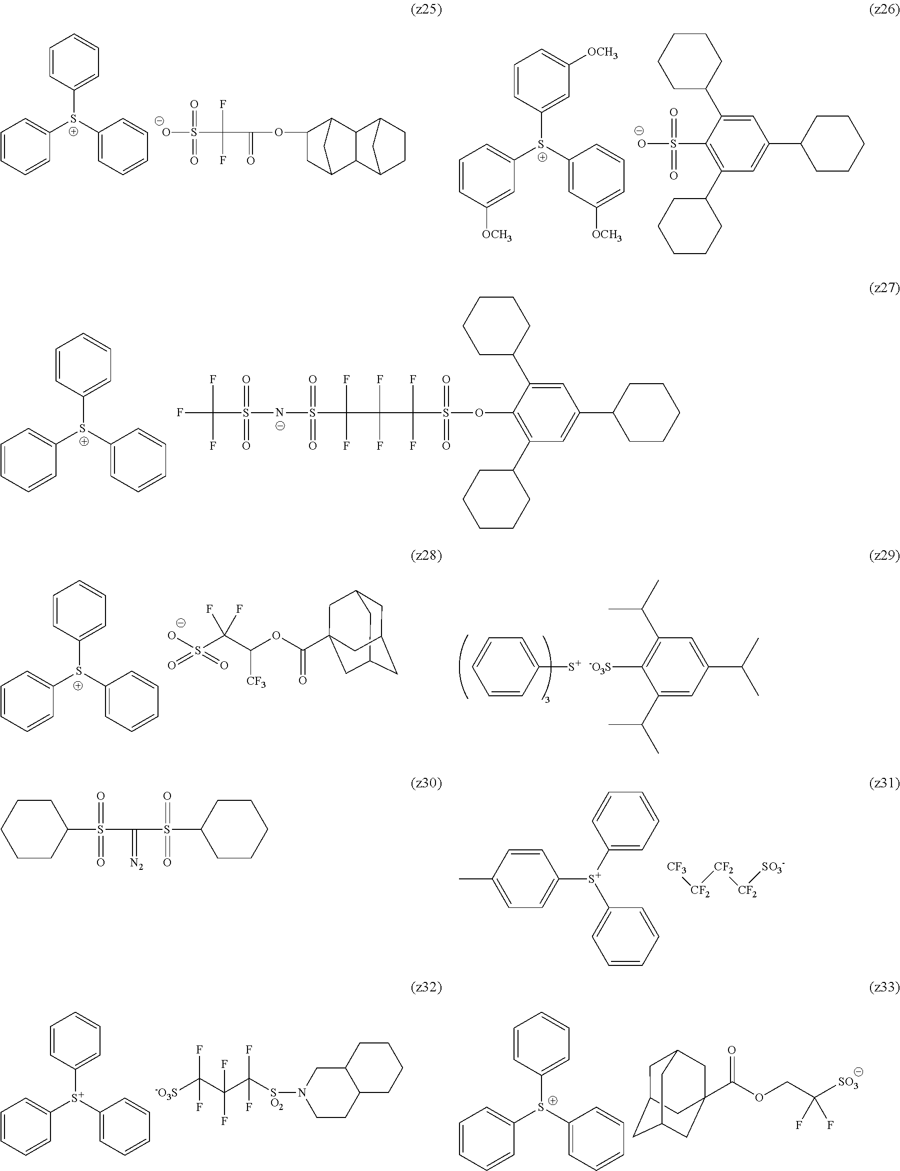

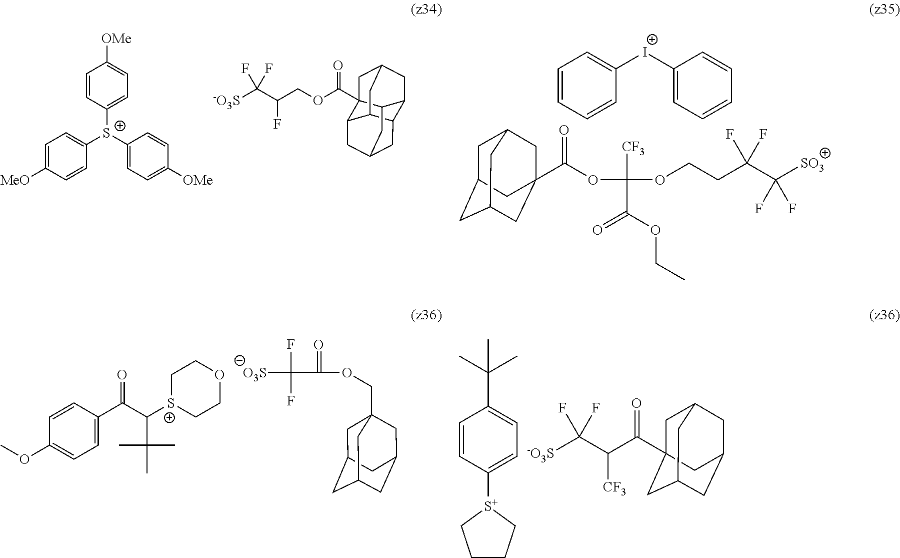

The content of the acid generator is preferably 0.1% to 40% by mass, more preferably 0.5% to 20% by mass, and still preferably 1% to 18% by mass, based on the total solid contents of the composition.

The acid generator may be used singly or in combination of two or more kinds thereof.

[Basic Compound (E)]

The actinic ray-sensitive or radiation-sensitive composition according to the first embodiment of the present invention preferably contains abasic compound as an acid scavenger.

In one aspect, the composition preferably contains, as the basic compound, a basic compound or ammonium salt whose basicity is reduced upon irradiation with actinic rays or radiation (hereinafter also referred to as a “compound (N)”).

The compound (N) is preferably a compound (N−1) having a basic functional group or ammonium group, and a group that generates an acidic functional group upon irradiation with actinic rays or radiation. That is, the compound (N) is preferably a basic compound having a basic functional group and a group that generates an acidic functional group upon irradiation with actinic rays or radiation, or an ammonium salt compound having an ammonium group and a group that generates an acidic functional group upon irradiation with actinic rays or radiation.

Specific examples of the compound (N) include the following compounds. Further, in addition to the compounds mentioned below, as the compound (N), for example, the compounds of (A-1) to (A-44) described in US2010/0233629A and the compounds of (A-1) to (A-23) described in 2012/0156617A can also be preferably used in the present invention.

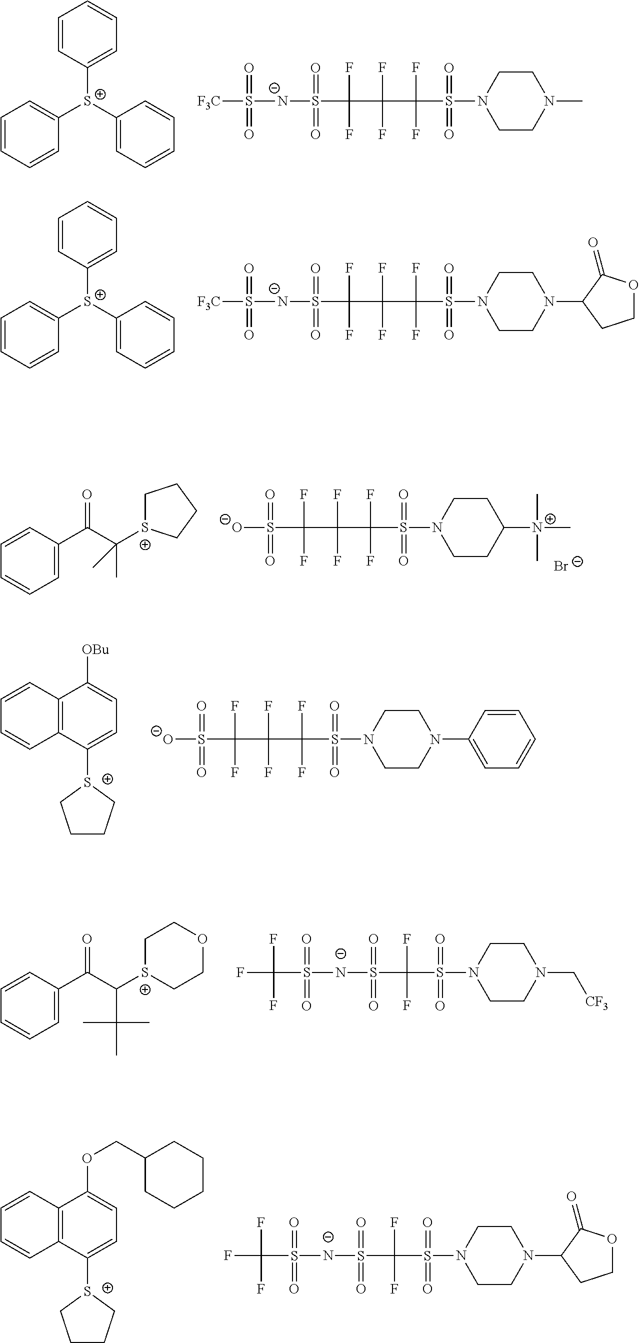

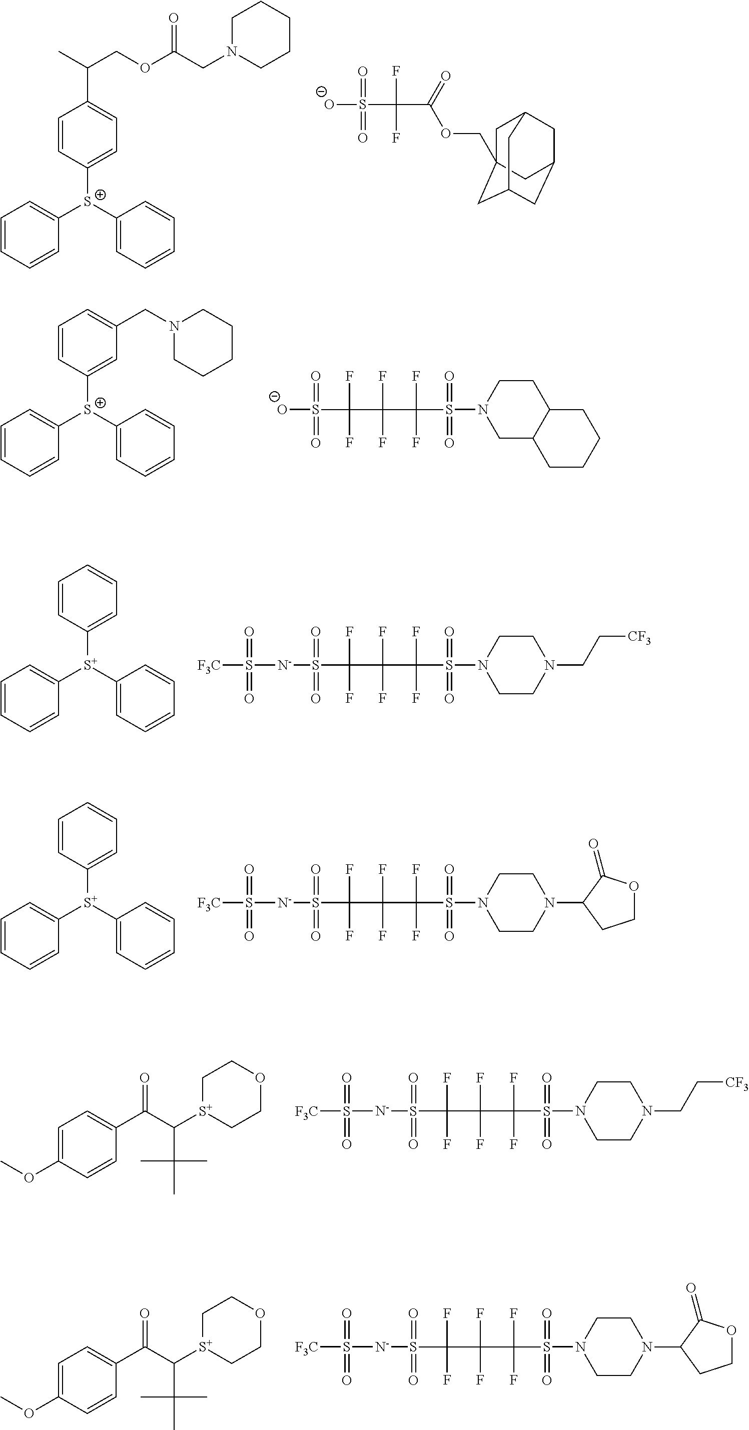

Furthermore, with regard to the compound (N), reference can be made to, for example, paragraphs 0421 to 0428 of JP2014-41328A, and paragraphs 0108 to 0116 of JP2014-134686, the contents of which are incorporated in the present specification. Further, the following compounds can be included as the specific preferred.

These compounds can be synthesized in accordance with Synthesis Examples described in JP2006-330098A.

The molecular weight of the compound (N) is preferably 500 to 1,000.

The composition may or may not contain the compound (N), but in a case where the composition contains the compound (N), the content ratio of the compound (N) is preferably 0.1% to 20% by mass, and more preferably 0.1% to 10% by mass, based on the solid content of the composition.

The composition may contain a basic compound (N′) other than the compound (N) as the basic compound in order to decrease a performance change over time from exposure to heating.

Preferred examples of the basic compound (N′) include compounds having structures represented by Formulae (A′) to (E′).

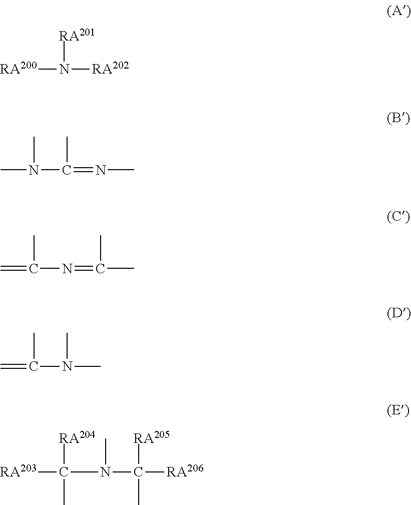

In General Formulae (A′) and (E′),

RA²⁰⁰, RA²⁰¹, and RA²⁰² may be the same as or different from each other, and each represent a hydrogen atom, an alkyl group (preferably having 1 to 20 carbon atoms), a cycloalkyl group (preferably having 3 to 20 carbon atoms), or an aryl group (having 6 to 20 carbon atoms). RA²⁰¹ and RA²⁰² may be bonded to each other to form a ring. RA²⁰³, RA²⁰⁴, RA²⁰⁵, and RA²⁰⁶ may be the same as or different from each other, and each represent an alkyl group (having 1 to 20 carbon atoms).

The alkyl group may have a substituent, and the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in General Formulae (A′) and (E′) is more preferably unsubstituted.

Preferred specific examples of the basic compound (N′) include guanidine, aminopyrrolidine, pyrazole, pyrazoline, piperazine, aminomorpholine, aminoalkylmorpholine, and piperidine. Further preferred specific examples thereof include a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond.

Examples of the compounds having an imidazole structure include imidazole, 2,4,5-triphenylimidazole, and benzimidazole. Examples of the compounds having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compounds having an onium hydroxide structure include triarylsulfonium hydroxide, phenacylsulfonium hydroxide, and sulfonium hydroxides having a 2-oxoalkyl group, specifically triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide. Examples of the compounds having an onium carboxylate structure include those having a carboxylate at the anion moiety of the compounds with an onium hydroxide structure, for example, acetate, adamantane-1-carboxylate, and perfluoroalkyl carboxylate. Examples of the compounds having a trialkylamine structure include tri(n-butyl)amine and tri(n-octyl)amine. Examples of the compounds having an aniline structure include 2,6-diisopropylaniline, N,N-dimethylaniline, N,N-dibutylaniline, and N,N-dihexylaniline. Examples of the alkylamine derivatives having a hydroxyl group and/or an ether bond include ethanolamine, diethanolamine, triethanolamine, and tris(methoxyethoxyethyl)amine. Examples of the aniline derivatives having a hydroxyl group and/or an ether bond include N,N-bis(hydroxyethyl)aniline.

Preferred examples of the basic compound include an amine compound having a phenoxy group, an ammonium salt compound having a phenoxy group, an amine compound having a sulfonic ester group and an ammonium salt compound having a sulfonic ester group. Specific examples thereof include the compounds (C1-1) to (C3-3) exemplified in [0066] of US2007/0224539A, but are not limited thereto.

The composition may or may not contain the compound (N′), but in a case where the composition contains the compound (N′), the content of the compound (N′) is preferably 0.001% to 10% by mass, and more preferably 0.01% to 5% by mass, based on the solid content of the composition.

In another aspect, the composition may also contain a nitrogen-containing organic compound having a group that leaves by the action of an acid (hereinafter also referred to as a “basic compound (N″)”) as one kind of basic compound. As the examples of the compound, for example, specific examples thereof are shown below.

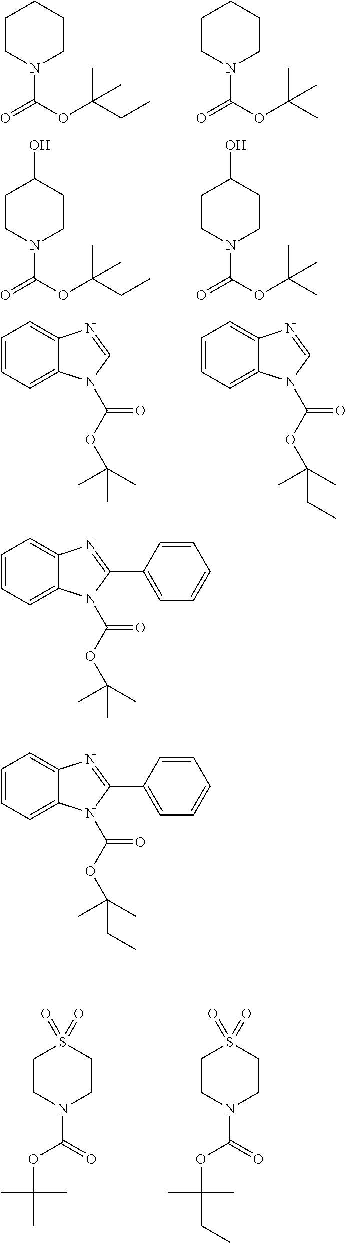

The compound can be synthesized in accordance with the method described, for example, in JP2009-199021A.

Furthermore, as the basic compound (N″), a compound having an amine oxide structure can also be used. Specific examples of the compound include triethylamine N-oxide, pyridine N-oxide, tributylamine N-oxide, triethanolamine N-oxide, tris(methoxyethyl)amine N-oxide, tris(2-(methoxymethoxy)ethyl)amine N-oxide, 2,2′,2″-nitrilotriethyl propionate N-oxide, and N-2-(2-methoxyethoxy)methoxyethylmorpholine N-oxide. In addition, the amine oxide compounds exemplified in JP2008-102383A can also be used.

The molecular weight of the basic compound (N″) is preferably 250 to 2,000, and more preferably 400 to 1,000. From the viewpoints of more reduction of LWR and uniformity of local pattern dimension, the molecular weight of the basic compound is preferably 400 or more, more preferably 500 or more, and still more preferably 600 or more.

Such a basic compound (N″) may be used in combination with the compound (N), and may be used singly or in combination of two or more kinds thereof.

The composition in the present invention may or may not contain the basic compound (N″), but in the case where the composition contains the basic compound (N″), the amount of the basic compound (N″) to be used is usually 0.001% to 10% by mass, and preferably 0.01% to 5% by mass, based on the solid content of the composition.

In another aspect, the composition may include an onium salt represented by General Formula (6A) or (6B) as the basic compound. This onium salt is expected to control the diffusion of the generated acid in the resist system, in the relationship with the acid strength of the photoacid generator usually used in the resist composition.

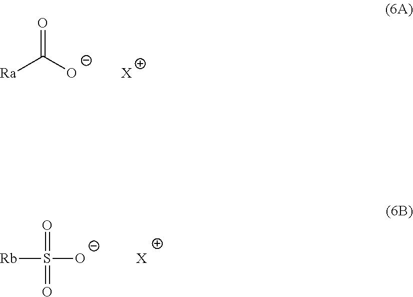

In General Formula (6A),

Ra represents an organic group, provided that a case where a carbon atom directly bonded to the carboxyl acid group in the formula is substituted with a fluorine atom is excluded.

X⁺ represents an onium cation.

In General Formula (6B),

Rb represents an organic group, provided that a case where a carbon atom directly bonded to a carboxyl acid group in the formula is substituted with a fluorine atom is excluded.

X⁺ represents an onium cation.

For the organic group represented by Ra and Rb, the atom directly bonded to a carboxylic acid group or sulfonic acid group in the formula is preferably a carbon atom. Here, in this case, in order to make a relatively weaker acid than the acid generated from the above-mentioned photoacid generator, a carbon atom directly bonded to a sulfonic acid group or a carboxyl acid group in the formula is not substituted with a fluorine atom in any case.

Examples of the organic acid represented by Ra and Rb include an alkyl group having 1 to 20 carbon atoms, a cycloalkyl group having 3 to 20 carbon atoms, an aryl group having 6 to 30 carbon atoms, an aralkyl group having 7 to 30 carbon atoms, and a heterocyclic group having 3 to 30 carbon atoms. A part or all of hydrogen atoms of these groups may be substituted.

Examples of the substituent which may be contained in the alkyl group, the cycloalkyl group, the aryl group, the aralkyl group, and the heterocyclic group include a hydroxyl group, a halogen atom, an alkoxy group, a lactone group, and an alkylcarbonyl group.

Examples of the onium cation represented by X⁺ in General Formula (6A) and (6B) include a sulfonium cation, an ammonium cation, an iodonium cation, a phosphonium cation, a diazonium cation, and among these, a sulfonium cation is more preferable.

The sulfonium cation is preferably for example, an arylsulfonium cation having at least one aryl group, and more preferably a triarylsulfonium cation. The aryl group may have a substituent, and the aryl group is preferably a phenyl group.

Preferred examples of the sulfonium cation and the iodonium cation also include the structures described for the compound (B).

The specific structures of the onium salt represented by General Formula (6A) or (6B) are shown below.

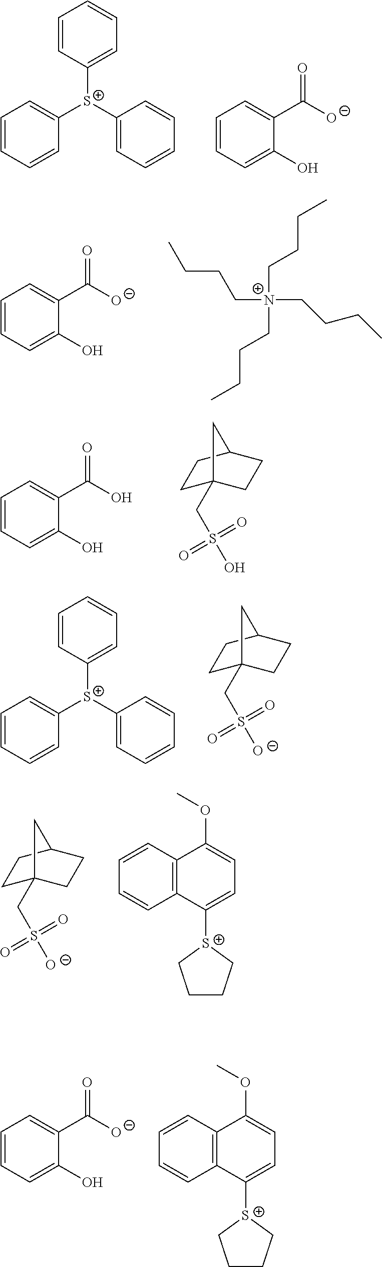

The composition may or may not contain the onium salt, but in a case where the composition contains the onium salt, the content ratio of the onium salt is usually 0.001% to 20% by mass, and more preferably 0.01% to 10% by mass, based on the solid content of the composition.

In another aspect, the composition may contain a compound (hereinafter also referred to as a betaine compound) having both an onium salt structure and an acid anion structure in one molecule thereof, such as a compound included in Formula (I) of JP2012-189977A, a compound represented by Formula (I) of JP2013-6827A, a compound represented by Formula (I) of JP2013-8020A, and a compound represented by Formula (I) of JP2012-252124A, as the basic compound. Examples of the onium salt structure may include sulfonium, iodonium, and ammonium structures, with a sulfonium or iodonium salt structure being preferable. Further, the acid anion structure is preferably a sulfonic acid anion or a carboxylic acid anion. Examples of the compound may be described as follows.

[Betaine Compound]

The actinic ray-sensitive or radiation-sensitive composition according to the first embodiment of the present invention may contain a betaine compound. The betaine compound is preferably an ionic compound represented by General Formula (I).

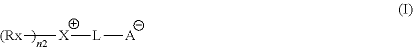

In General Formula (I),

A⁻ represents an organic acid anion, L represents a single bond or a divalent linking group, X⁺ represents a nitrogen cation or a sulfur cation, and Rx's each independently represent an alkyl group or an aryl group. A plurality of Rx's may be bonded to each other to form a ring, and the ring thus formed may have a nitrogen atom, an oxygen atom, or a sulfur atom as a ring member.

n2 represents 3 when X⁺ is a nitrogen cation, and represents 2 when X⁺ is a sulfur cation.

With regard to the ionic compound represented by General Formula (I), reference can be made to, for example, the contents described in paragraphs 0167 to 0177 of JP2014-199273A, the contents of which are incorporated in the present specification.

The composition of the present invention may or may not contain a betaine compound, but in a case where the composition contains the betaine compound, the content of the betaine compound is usually 0.001% to 20% by mass, preferably 0.001% to 10% by mass, and more preferably 0.01 to 5% by mass, based on the total solid contents of the composition, combined with the above-mentioned basic compound.

Moreover, in a case where the composition of the present invention contains an acid generator, the ratio of the acid generator to the betaine compound to be used in the composition is preferably the acid generator/[betaine compound+basic compound below] (molar ratio) of 2.5 to 300. That is, in views of sensitivity and resolution, the molar ratio is preferably 2.5 or more, and in a view of suppression of a reduction in resolving power due to an increase of the thickness of the resist pattern over time from exposure to a heating treatment, is preferably 300 or less. The acid generator/[betaine compound+the basic compound] (molar ratio) is more preferably 5.0 to 200, and more preferably 7.0 to 150.

In addition, examples of those usable in the composition according to the present invention include the compounds synthesized in Examples of JP2002-363146A and the compounds described in paragraph 0108 of JP2007-298569A.

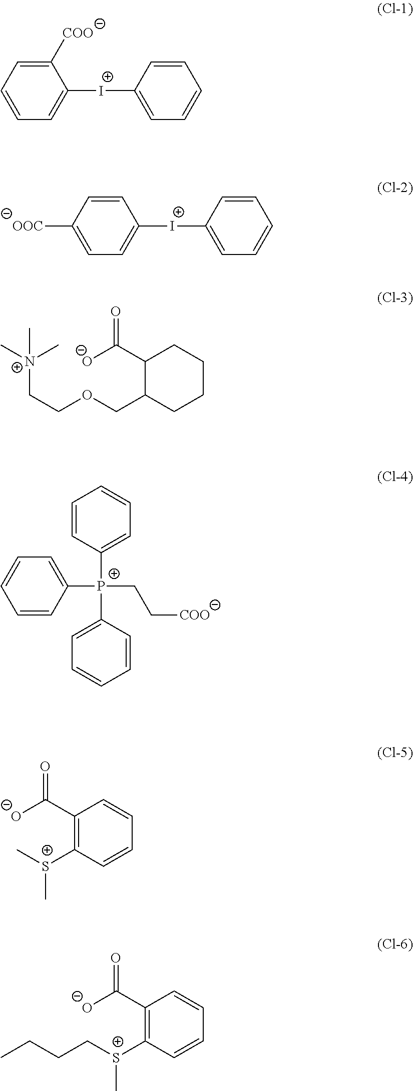

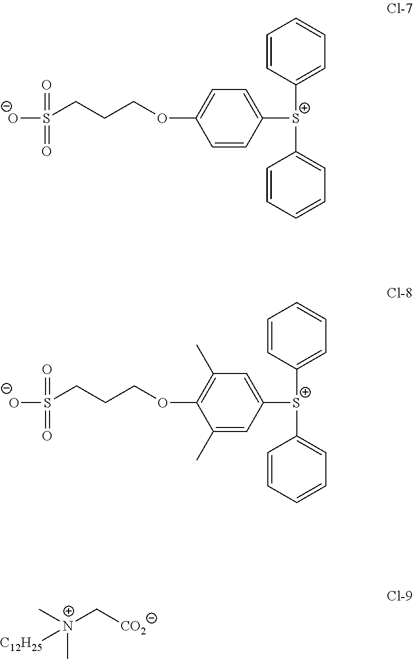

The composition may or may not contain the betaine compound, but in a case where the composition contains the betaine compound, the content ratio of the betaine compound is preferably 0.001% to 20% by mass, and more preferably 0.01% to 10% by mass, based on the solid content of the composition.

[Hydrophobic Resin]

The actinic ray-sensitive or radiation-sensitive composition according to the first embodiment of the present invention may contain a hydrophobic resin (hereinafter also referred to as a “hydrophobic resin (HR)”) having at least one of a fluorine atom or a silicon atom.

It is presumed that incorporation of a hydrophobic resin containing at least one of a fluorine atom or silicon atom into the actinic ray-sensitive or radiation-sensitive composition of the present invention, the hydrophobic resin is unevenly localized on the surface layer of a film formed from the actinic ray-sensitive or radiation-sensitive composition, formation of sparingly soluble materials is suppressed, and thus, scum is reduced. Thus, it is considered that generation of scum can be suppressed while all the characteristics such as collapse performance of a pattern are maintained.

In addition, in a case where the liquid immersion medium for the liquid immersion exposure is water, the receding contact angle of the film surface with respect to water can be enhanced, thereby enhancing the immersion liquid tracking properties.

Although the hydrophobic resin (HR) is unevenly localized on the surface layer of the film as mentioned above, as different from surfactants, it does not necessarily have to have a hydrophilic group in a molecule thereof and does not need to contribute to uniform mixing of polar/nonpolar materials.

The hydrophobic resin typically contains a fluorine atom and/or a silicon atom. The fluorine atom and/or silicon atom in the hydrophobic resin (HR) may be contained in the main chain or the side chain of the resin.

In a case where the hydrophobic resin contains a fluorine atom, it is preferable that the resin has an alkyl group containing a fluorine atom, a cycloalkyl group containing a fluorine atom, or an aryl group containing a fluorine atom, as a partial structure containing a fluorine atom.

The alkyl group having a fluorine atom is a linear or branched alkyl group having at least one hydrogen atom thereof substituted with a fluorine atom. The alkyl group preferably has 1 to 10 carbon atoms, and more preferably has 1 to 4 carbon atoms, and may further have another substituent.

The cycloalkyl group having a fluorine atom is a mono- or polycycloalkyl group having at least one hydrogen atom thereof substituted with a fluorine atom, and may further have another substituent.

As the aryl group having a fluorine atom, an aryl group having at least one hydrogen atom thereof substituted with a fluorine atom may be mentioned. As the aryl group, there can be mentioned, and the aryl group may further have another substituent.

Preferred examples of the alkyl group having a fluorine atom, the cycloalkyl group having a fluorine atom, and the aryl group having a fluorine atom include a group represented by any one of General Formulae (F2) to (F4), but the present invention is not limited thereto.

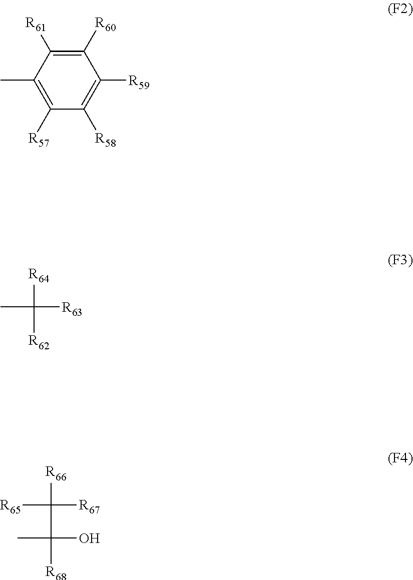

In General Formulae (F2) to (F4),

R₅₇ to R₆₈ each independently represent a hydrogen atom, a fluorine atom or an (linear or branched) alkyl group, provided that at least one of R₅₇, . . . , or R₆₁, at least one of R₆₂, . . . , or R₆₄, and at least one of R₆₅, . . . , or R₆₈ represent a fluorine atom or an alkyl group (preferably having 1 to 4 carbon atoms) having at least one hydrogen atom substituted with a fluorine atom.

It is preferable that all of R₅₇ to R₆₁ and R₆₅ to R₆₇ are fluorine atoms. R₆₂, R₆₃ and R₆₈ are each preferably a fluoroalkyl group (especially having 1 to 4 carbon atoms), and more preferably a perfluoroalkyl group having 1 to 4 carbon atoms. When R₆₂ and R₆₃ are each a perfluoroalkyl group, R₆₄ is preferably a hydrogen atom. R₆₂ and R₆₃ may be bonded to each other to form a ring.

Specific examples of the group represented by General Formula (F2) include a p-fluorophenyl group, a pentafluorophenyl group, and a 3,5-di(trifluoromethyl)phenyl group.

Specific examples of the group represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, and a perfluorocyclohexyl group. Among these, a hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable. A hexafluoroisopropyl group and a heptafluoroisopropyl group are more preferable.

Specific examples of the group represented by General Formula (F4) include —C(CF₃)₂OH, —C(C2F5)₂OH, —C(CF₃)(CH₃)OH, and —CH(CF₃)OH, with —C(CF₃)₂OH being preferable.

The partial structure containing a fluorine atom may be directly bonded to the main chain, or may be bonded to the main chain via a group selected from the group consisting of an alkylene group, a phenylene group, an ether group, a thioether group, a carbonyl group, an ester group, an amido group, a urethane group, and a ureylene group, or via a group formed of a combination of two or more of these groups.

Suitable examples of the repeating unit having a fluorine atom include ones shown below.

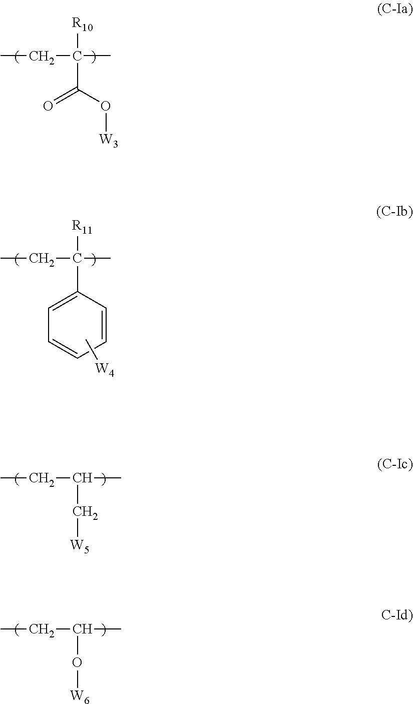

In Formulae (C-Ia) to (C-Id), R₁₀ and R₁₁ each independently represent a hydrogen atom, a fluorine atom, or an alkyl group. The alkyl group is preferably a linear or branched alkyl group having 1 to 4 carbon atoms. The alkyl group may have a substituent. As a substituted alkyl group, in particular, a fluorinated alkyl group can be mentioned.

W₃ to W₆ each independently represent an organic group containing at least one fluorine atom. Specific examples thereof include the atomic groups of (F2) to (F4).

In addition, in addition to these, the hydrophobic resin may also have the repeating units shown below as a repeating unit containing a fluorine atom.

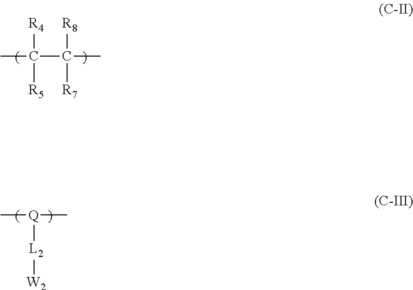

In Formulae (C-II) and (C-III), R₄ to R₇ each independently represent a hydrogen atom, a fluorine atom, or an alkyl group. The alkyl group is preferably a linear or branched alkyl group having 1 to 4 carbon atoms. The alkyl group may have a substituent. As a substituted alkyl group, in particular, a fluorinated alkyl group can be mentioned.

Here, at least one of R₄, . . . , or R₇ represents a fluorine atom. R₄ and R₅ or R₆ and R₇ may be combined to form a ring.

W₂ represents an organic group containing at least one fluorine atom. Specific examples thereof include the atomic groups of (F2) to (F4).

L₂ represents a single bond or a divalent linking group. The divalent linking group represents a substituted or unsubstituted arylene group, a substituted or unsubstituted alkylene group, a substituted or unsubstituted cycloalkylene group, —O—, —SO₂—, —CO—, —N(R)-(in the formula, R represents a hydrogen atom or an alkyl group), —NHSO₂—, or a divalent linking group formed by a combination of a plurality of these groups.

Q represents an alicyclic structure. The alicyclic structure may have a substituent, and may be monocyclic or polycyclic. In a case where the alicyclic structure is polycyclic, it may be bridged. The alicyclic structure which is monocyclic is preferably a cycloalkyl group having 3 to 8 carbon atoms, and examples thereof include a cyclopentyl group, a cyclohexyl group, a cyclobutyl group, and a cyclooctyl group. Examples of the alicyclic structure which is polycyclic include a group with a bicyclo, tricyclo, or tetracyclo structure having 5 or more carbon atoms, or the like. Such the alicyclic structure is preferably a cycloalkyl group having 6 to 20 carbon atoms is preferable, and examples thereof include an adamantyl group, a norbomyl group, a dicyclopentyl group, a tricyclodecanyl group, and a tetracyclododecyl group. Further, at least one carbon atom in the cycloalkyl group may be substituted with a heteroatom such as an oxygen atom. Particularly preferred examples of Q include a norbomyl group, a tricyclodecanyl group, and a tetracyclododecyl group.

The hydrophobic resin may contain a silicon atom.

It is preferable for the hydrophobic resin to have an alkylsilyl structure (preferably a trialkylsilyl group) or a cyclosiloxane structure as a partial structure having a silicon atom.

Specific examples of the alkylsilyl structure or cyclosiloxane structure include groups represented by General Formulae (CS-1) to (CS-3).

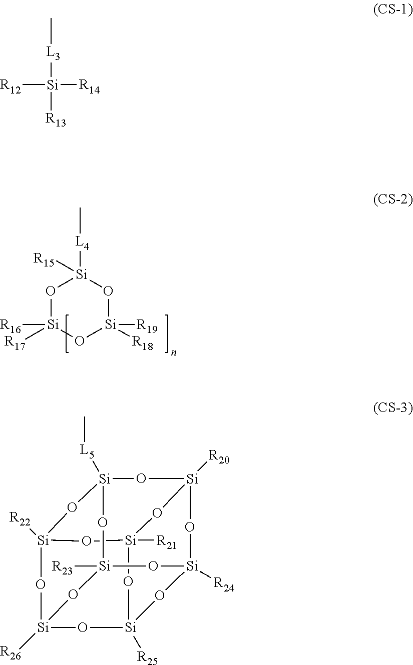

In General Formulae (CS-1) to (CS-3),

R₁₂ to R₂₆ each independently represent a linear or branched alkyl group (preferably having 1 to 20 carbon atoms) or a cycloalkyl group (preferably having 3 to 20 carbon atoms).

L₃ to L₅ each represent a single bond or a divalent linking group. Examples of the divalent linking group include any one or a combination of two or more groups selected from the group consisting of an alkylene group, a phenylene group, an ether bond, a thioether bond, a carbonyl group, an ester bond, an amido bond, a urethane bond, and a ureylene bond.

n is an integer of 1 to 5. n is preferably an integer of 2 to 4.

The repeating unit having at least one of a fluorine atom or a silicon atom is preferably a (meth)acrylate-based repeating unit.

Specific examples of the repeating units each having at least one of a fluorine atom or a silicon atom include the repeating units disclosed in paragraph 0576 of US2012/0135348A, but the present invention is not limited thereto.

It is preferable that the hydrophobic resin has a repeating unit (b) having at least one group selected from the group consisting of the following (x) to (z):

(x) an alkali-soluble group,

(y) a group which decomposes by action of an alkali developer to increase its solubility in the alkali developer (hereinafter also referred to as a polarity conversion group), and

(z) a group which decomposes by action of an acid to increase its solubility in an alkali developer.

Examples of the repeating unit (b) include the following types.

A repeating unit (b′) having at least one of a fluorine atom or a silicon atom and at least one group selected from the group consisting of (x) to (z) introduced in one side chain thereof at the same time.

A repeating unit (b*) having at least one group selected from the group consisting of (x) to (z) but containing neither a fluorine atom nor a silicon atom.

A repeating unit (b″) having at least one group selected from the group consisting of (x) to (z) in one side chain thereof, and having at least one of a fluorine atom or a silicon atom in a side chain other than the above side chain within the same repeating unit.

It is preferable that the hydrophobic resin has the repeating unit (b′) as the repeating unit (b). That is, it is preferable that the repeating unit (b) having at least one group selected from the group consisting of (x) to (z) has at least one of a fluorine atom or a silicon atom.

Furthermore, in a case where the hydrophobic resin has the repeating unit (b*), it is preferable that the hydrophobic resin is a copolymer with a repeating unit (repeating unit other than the above-mentioned repeating units (b′) and (b″)) having at least one of a fluorine atom or a silicon atom. Further, in the repeating unit (b″), it is preferable that the side chain having at least one group selected from the group consisting of (x) to (z) and the side chain having at least one of a fluorine atom or a silicon atom are bonded to the same carbon atom in the main chain, that is, are in the positional relationship as shown in Formula (K1).

In the formula, B1 represents a partial structure having at least one group selected from the group consisting of (x) to (z), and B2 represents a partial structure having at least one of a fluorine atom or a silicon atom.

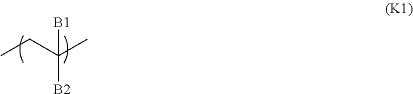

The group selected from the group consisting of (x) to (z) is preferably (x) an alkali-soluble group or (y) a polarity conversion group, and more preferably (y) a polarity conversion group.

Examples of the alkali-soluble group (x) include a phenolic hydroxyl group, a carboxylate group, a fluoroalcohol group, a sulfonate group, a sulfonamido group, a sulfonimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

Preferred examples of the alkali-soluble group include a fluoroalcohol group (preferably hexafluoroisopropanol group), a sulfonimido group, and a bis(alkylcarbonyl)methylene group.

Examples of the repeating unit (bx) having an alkali-soluble group (x) include a repeating unit resulting from direct bonding of an alkali-soluble group to the main chain of a resin like a repeating unit of an acrylic acid or a methacrylic acid, a repeating unit resulting from bonding, via a linking group, of an alkali-soluble group to the main chain of a resin and a repeating unit resulting from polymerization, and any of these cases are preferable in the a polymerization initiator or chain transfer agent having an alkali-soluble group in the polymerization can be introduced to the terminal of a polymer chain.

In a case where the repeating unit (bx) is a repeating unit having at least one of a fluorine atom or a silicon atom (that is, in a case of corresponding to the repeating unit (b′) or (b″)), examples of the partial structure containing a fluorine atom contained in the repeating unit (bx) include the same ones as set forth above with regard to the repeating unit having at least one of a fluorine atom or a silicon atom. Preferred examples thereof include the groups represented by General Formulae (F2) to (F4). Further, in this case, examples of the partial structure containing a silicon atom contained in the repeating unit (bx) include the same ones as set forth above with regard to the repeating unit having at least one of a fluorine atom or a silicon atom. Preferred examples thereof include the groups represented by General Formulae (CS-1) to (CS-3).

The content ratio of the repeating units (bx) having the alkali-soluble group (x) is preferably 1% to 50% by mole, more preferably 3% to 35% by mole, and still more preferably 5% to 20% by mole, with respect to all the repeating units of the hydrophobic resin.

Specific examples of the repeating units (bx) having the alkali-soluble group (x) include the repeating units disclosed in paragraph 0595 of US2012/0135348A, but the present invention is not limited thereto.

Examples of the polarity conversion group (y) include a lactone group, a carboxylic ester group (—COO—), an acid anhydride group (—C(O)OC(O)—), an acid imido group (—NHCONH—), a carboxylic thioester group (—COS—), a carbonic ester group (—OC(O)O—), a sulfuric ester group (—OSO₂O—), and a sulfonic ester group (—SO₂O—), with a lactone group being preferable.

The polarity conversion group (y) is preferable in two modes, that is, one mode in which the polarity conversion group (y) is contained in a repeating unit of an acrylic ester or a methacrylic ester and introduced in a side chain of a resin, and the other mode in which the polarity conversion group (y) is introduced into a terminal of a polymer chain by using a polymerization initiator or chain transfer agent containing the polarity conversion group (y) during polymerization.

Specific examples of the repeating units (by) having the polarity conversion group (y) include units having lactone structures represented by Formulae (KA-1-1) to (KA-1-17) which will be described hereinafter.

In addition, it is preferable that the repeating unit (by) having the polarity conversion group (y) is a repeating unit having at least one of a fluorine atom or a silicon atom (that is, corresponding to the above-mentioned repeating unit (b′) or repeating unit (b″)). The resin having the repeating unit (by) is hydrophobic, and is particularly preferable from the viewpoint of a reduction in development defects.

Examples of the repeating unit (by) include a repeating unit represented by Formula (K0).

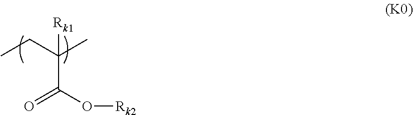

In the formula, Rₖ₁ represents a hydrogen atom, a halogen atom, a hydroxyl group, an alkyl group, a cycloalkyl group, an aryl group, or a group containing a polarity conversion group. Rₖ₂ represents an alkyl group, a cycloalkyl group, an aryl group, or a group containing a polarity conversion group.

Here, at least one of Rₖ₁ or Rₖ₂ is a group containing a polarity conversion group.

The polarity conversion group refers to a group which decomposes by the action of an alkali developer to increase its solubility in the alkali developer, as mentioned above. It is preferable that the polarity conversion group is a group represented by X in the partial structure represented by General Formula (KA-1) or (KB-1).

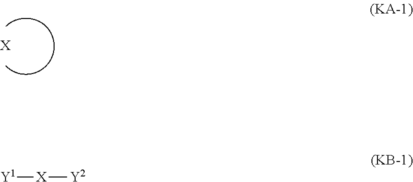

In General Formula (KA-1) or (KB-1), X represents a carboxylic ester group: —COO—, an acid anhydride group: —C(O)OC(O)—, an acid imido group: —NHCONH—, a carboxylic thioester group: —COS—, a carbonic ester group: —OC(O)O—, a sulfuric ester group: —OSO₂O—, or a sulfonic ester group: —SO₂O—

Y¹ and Y² may be the same as or different from each other, and each represent an electron withdrawing group.

Moreover, the repeating unit (by) has a preferred group whose solubility in an alkali developer increases by incorporation of a group having the partial structure represented by General Formula (KA-1) or (KB-1). However, in a case where the partial structure has no bonding arm as in the case of the partial structure represented by General Formula (KA-1) or the partial structure represented by General Formula (KB-1) in which Y¹ and Y² are monovalent, the above group having the partial structure refers to a group containing a monovalent or more-valent group resulting from deletion of at least one arbitrary hydrogen atom from the partial structure.

The partial structure represented by General Formula (KA-1) or (KB-1) is linked at its arbitrary position to the main chain of the hydrophobic resin via a substituent.

The partial structure represented by General Formula (KA-1) is a structure in which a ring structure is formed in cooperation with a group represented by X.

In General Formula (KA-1), X is preferably a carboxylic ester group (that is, in the case of the formation of a lactone ring structure as KA-1), an acid anhydride group or a carbonic ester group. More preferably X is a carboxylic ester group.

The ring structure represented by General Formula (KA-1) may have a substituent, and for example, may also have nka substituents Zₖₐₗ.

In a case where a plurality of Zₖₐₗ's are present, they each independently represent a halogen atom, an alkyl group, a cycloalkyl group, an ether group, a hydroxyl group, an amido group, an aryl group, a lactone ring group, or an electron withdrawing group.

Zₖₐₗ's may be linked to each other to form a ring. Examples of the ring formed by the mutual linkage of Zₖₐₗ's include a cycloalkyl ring and a heterocycle (for example, a cycloether ring and a lactone ring).

The nka represents an integer of 0 to 10, preferably an integer of 0 to 8, more preferably an integer of 0 to 5, still more preferably an integer of 1 to 4, and most preferably an integer of 1 to 3.

The electron withdrawing groups as Zₖₐₗ are the same as those represented by Y¹ and Y² which will be described later. Further, these electron withdrawing groups may be substituted with other electron withdrawing groups.

Zₖₐₗ is preferably an alkyl group, a cycloalkyl group, an ether group, a hydroxyl group, or an electron withdrawing group. Zₖₐₗ is more preferably an alkyl group, a cycloalkyl group, or an electron withdrawing group. Further, the ether group is preferably one substituted with an alkyl group, a cycloalkyl group, or the like, that is, an alkyl ether group or the like. The electron withdrawing group has the same definition as above.

Examples of the halogen atom as Zₖₐₗ include a fluorine atom, a chlorine atom, a bromine atom, and an iodine atom, with a fluorine atom being preferable.

The alkyl group as Zₖₐₗ may have a substituent, and may be linear or branched. The linear alkyl group preferably has 1 to 30 carbon atoms, and more preferably 1 to 20 carbon atoms, and examples of the linear alkyl group include a methyl group, an ethyl group, an n-propyl group, an n-butyl group, a sec-butyl group, a t-butyl group, an n-pentyl group, an n-hexyl group, an n-heptyl group, an n-octyl group, an n-nonyl group, and an n-decanyl group. The branched alkyl group preferably has 3 to 30 carbon atoms, and more preferably 3 to 20 carbon atoms, and examples thereof include an i-propyl group, an i-butyl group, a t-butyl group, an i-pentyl group, a t-pentyl group, an i-hexyl group, a t-hexyl group, an i-heptyl group, a t-heptyl group, an i-octyl group, a t-octyl group, an i-nonyl group, and a t-decanoyl group, with the alkyl groups having 1 to 4 carbon atoms, such as a methyl group, an ethyl group, an n-propyl group, an i-propyl group, an n-butyl group, an i-butyl group, and a t-butyl group, being preferable.

The cycloalkyl group as Zₖₐₗ may have a substituent and may be monocyclic or polycyclic. In a case where the cycloalkyl group is polycyclic, it may be bridged. That is, in that case, the cycloalkyl group may have a bridged structure. The monocycloalkyl group is preferably a cycloalkyl group having 3 to 8 carbon atoms. Examples of the cycloalkyl group include a cyclopropyl group, a cyclopentyl group, a cyclohexyl group, a cyclobutyl group, and a cyclooctyl group. Examples of the polycycloalkyl group include a group having a bicyclo, tricyclo, or tetracyclo structure having 5 or more carbon atoms, or the like. The polycycloalkyl group is preferably a cycloalkyl group having 6 to 20 carbon atoms, and examples thereof include an adamantyl group, a norbomyl group, an isobornyl group, a camphonyl group, a bicyclopentyl group, an α-pinen group, a tricyclodecanyl group, a tetracyclododecyl group, and an androstanyl group. As the cycloalkyl group, the structural formulae (1) to (50) disclosed in paragraph 0619 of US2012/0135348A are also preferable. In addition, at least one carbon atom in the cycloalkyl group may be substituted with a heteroatom such as an oxygen atom.

Preferred examples of the alicyclic moieties include an adamantyl group, a noradamantyl group, a decalin group, a tricyclodecanyl group, a tetracyclododecanyl group, a norbomyl group, a cedrol group, a cyclohexyl group, a cycloheptyl group, a cyclooctyl group, a cyclodecanyl group, and a cyclododecanyl group. More preferred examples of the alicyclic moieties include an adamantyl group, a decalin group, a norbomyl group, a cedrol group, a cyclohexyl group, a cycloheptyl group, a cyclooctyl group, a cyclodecanyl group, a cyclododecanyl group, and a tricyclodecanyl group.

Examples of the substituent having an alicyclic structure include an alkyl group, a halogen atom, a hydroxyl group, an alkoxy group, a carboxyl group, and an alkoxycarbonyl group. The alkyl group is preferably a lower alkyl group such as a methyl group, an ethyl group, a propyl group, an isopropyl group, and a butyl group, and more preferably a methyl group, an ethyl group, a propyl group, or an isopropyl group. Preferred examples of the alkoxy group include those having 1 to 4 carbon atoms, such as a methoxy group, an ethoxy group, a propoxy group, and a butoxy group. Examples of the substituent which may be contained in the alkyl group and the alkoxy group include a hydroxyl group, a halogen atom, and an alkoxy group (preferably having 1 to 4 carbon atoms).

Furthermore, the group may further have a substituent, and examples of further substituents include a hydroxyl group, a halogen atom (fluorine, chlorine, bromine, or iodine), a nitro group, a cyano group, the above-mentioned alkyl groups, an alkoxy group such as a methoxy group, an ethoxy group, a hydroxyethoxy group, a propoxy group, a hydroxypropoxy group, an n-butoxy group, an isobutoxy group, a sec-butoxy group, and a t-butoxy group, an alkoxycarbonyl group such as a methoxycarbonyl group and an ethoxycarbonyl group, an aralkyl group such as a benzyl group, a phenethyl group, and a cumyl group, an aralkyloxy group, an acyl group such as a formyl group, an acetyl group, a butyryl group, a benzoyl group, a cyanamyl group, and a valeryl group, an acyloxy group such as a butyryloxy group, the above-mentioned alkenyl groups, an alkenyloxy group such as a vinyloxy group, a propenyloxy group, an allyloxy group, and a butenyloxy group, the above-mentioned aryl groups, an aryloxy group such as a phenoxy group, and an aryloxycarbonyl group such as a benzoyloxy group.

It is preferable that X in General Formula (KA-1) is a carboxylic ester group and the partial structure represented by General Formula (KA-1) is a lactone ring, and a 5- to 7-membered lactone ring is preferable.

Furthermore, as in formulae (KA-1-1) to (KA-1-17), the 5- to 7-membered lactone ring as the partial structure represented by General Formula (KA-1) is preferably fused with another ring structure in such a fashion that a bicyclo structure or a spiro structure is formed.

The peripheral ring structures to which the ring structure represented by General Formula (KA-1) may be bonded can be, for example, those shown in formulae (KA-1-1) to (KA-1-17), or those similar to the same.

It is preferred for the structure containing the lactone ring structure represented by General Formula (KA-1) to be the structure represented by any one of Formulae (KA-1-1) to (KA-1-17). The lactone structure may be directly bonded to the main chain. Preferred structures thereof are (KA-1-1), (KA-1-4), (KA-1-5), (KA-1-6), (KA-1-13), (KA-1-14), and (KA-1-17).

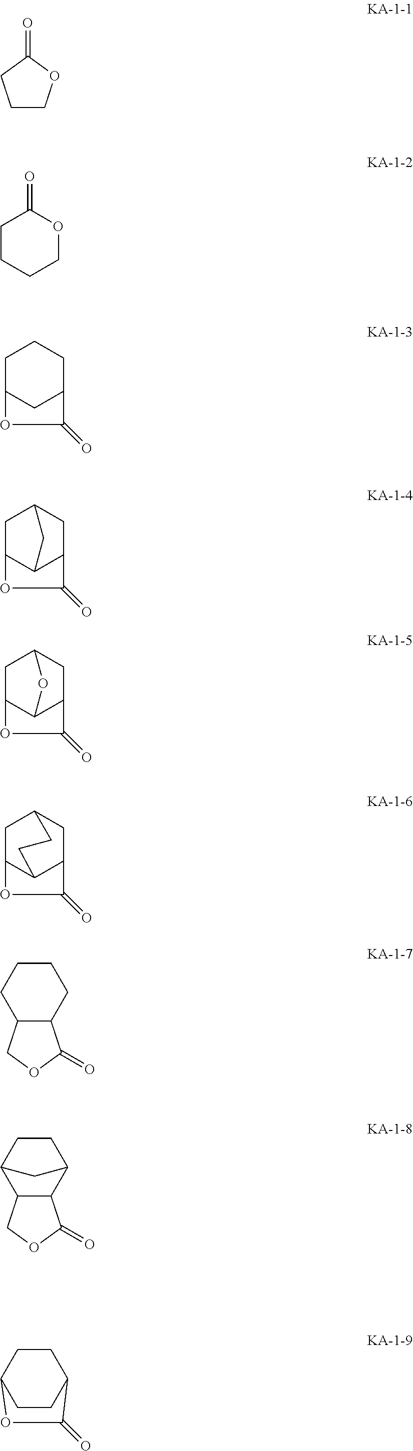

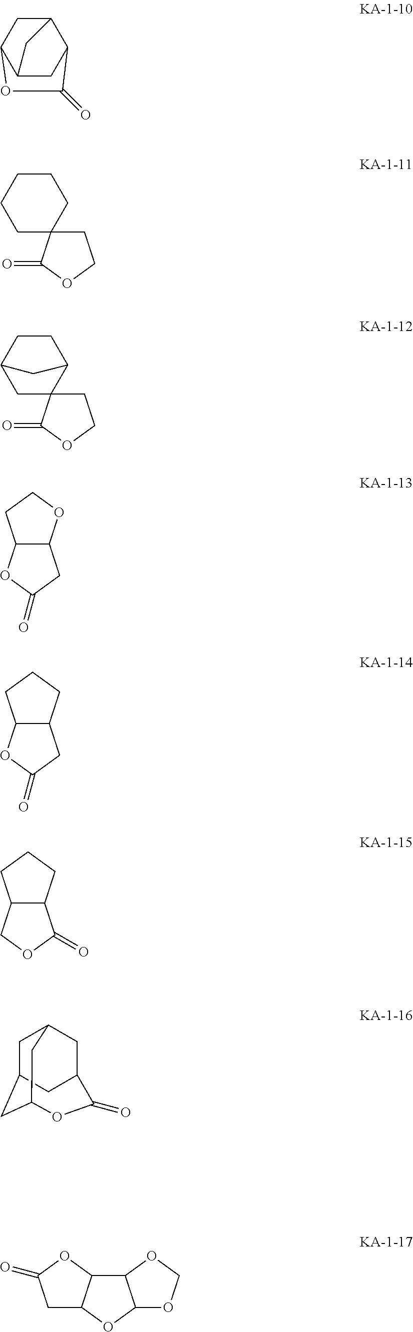

The structure containing the lactone ring structure may have a substituent. Preferred examples of the substituent include the same ones as the substituent Zₖₐₗ which may be contained in the ring structure of General Formula (KA-1).

In General Formula (KB-1), X is preferably a carboxylic ester group (—COO—).

In General Formula (KB-1), Y¹ and Y² each independently represent an electron withdrawing group.

The electron withdrawing group has a partial structure represented by Formula (EW). In formula (EW), * represents either a bonding arm directly connected with (KA-1) or a bonding arm directly bonded to X in (KB-1).

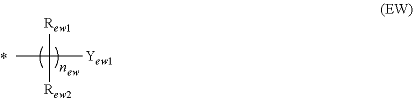

In Formula (EW),

R_{ew1} and R_{ew2} each independently represent an arbitrary substituent, and each represent, for example, a hydrogen atom, an alkyl group, a cycloalkyl group, or an aryl group.

n_{ew} is the number of repetitions of the linking group represented by —C(R_{ew1})(R_{ew2})—, and represents an integer of 0 or 1. In a case where n_{ew} is 0, it represents a single bond, indicating the direct bonding of Y_{ew1}.

Examples of Y_{ew1} include a halogen atom, a cyano group, a nitrile group, a nitro group, a halo(cyclo)alkyl or haloaryl group represented by —C(R_{f1})(R_{f2})—R_{f3}, an oxy group, a carbonyl group, a sulfonyl group, a sulfinyl group, and a combination thereof. The electron withdrawing groups may have, for example, the following structures. Further, the “halo(cyclo)alkyl group” refers to an at least partially halogenated alkyl group or cycloalkyl group, and the “haloaryl group” refers to an at least partially halogenated aryl group. In the following structural formulae, R_{ew3} and R_{ew4} each independently represent an arbitrary structure. Regardless of the types of the structures of R_{ew3} and R_{ew4}, the partial structures represented by Formula (EW) exhibit electron withdrawing properties, and may be linked to, for example, the main chain of the resin. Preferably R_{ew3} and R_{ew4} are each an alkyl group, a cycloalkyl group, or a fluoroalkyl group.

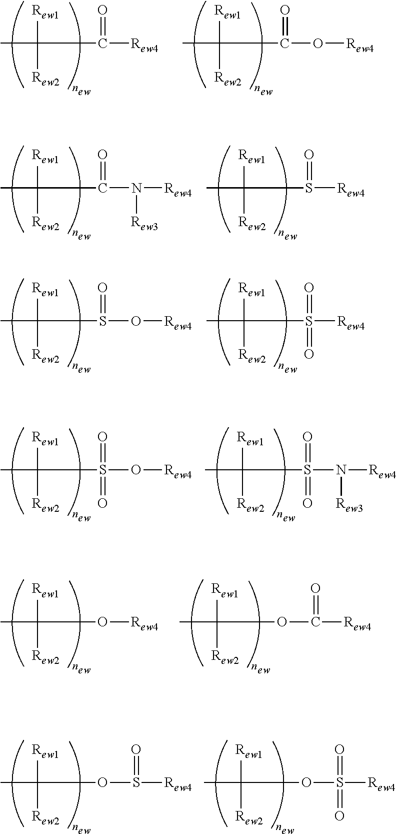

In a case where Y_{ew1} is a divalent or more-valent group, the remaining bonding arms form a bond with an arbitrary atom or substituent. At least one group of Y_{ew1}, R_{ew1}, or R_{ew2} may be linked to the main chain of the hydrophobic resin via a further substituent.

Y_{ew1} is preferably a halogen atom, or a halo(cyclo)alkyl groups or haloaryl group represented by —C(R_{f1})(R_{f2})—R_{f3}.

At least two of Y_{ew1}, R_{ew1}, or R_{ew2} may be linked to each other to form a ring.

Here, R_{f1} represents a halogen atom, a perhaloalkyl group, a perhalocycloalkyl group, or a perhaloaryl group. R_{f1} is preferably a fluorine atom, a perfluoroalkyl group, or a perfluorocycloalkyl group, and more preferably a fluorine atom or a trifluoromethyl group.

R_{f2} and R_{f3} each independently represent a hydrogen atom, a halogen atom, or an organic group, and R_{f2} and R_{f3} may be linked to each other to form a ring. The organic group represents, for example, an alkyl group, a cycloalkyl group, an alkoxy group, or the like. It is more preferable that R_{f2} represents the same group as R_{f1} or is linked to R_{f3} to form a ring.

R_{f1} to R_{f3} may be linked to each other to form a ring, and examples of the ring thus formed include a (halo)cycloalkyl ring and a (halo)aryl ring.

Examples of the (halo)alkyl groups in R_{f1} to R_{f3} include the above-mentioned alkyl groups in Zₖₐₗ, and structures resulting from halogenation thereof.

Examples of the (per)halocycloalkyl groups and (per)haloaryl groups in R_{f1} to R_{f3} or in the ring formed by the linkage of R_{f2} and R_{f3} include a structure resulting from halogenation of the cycloalkyl groups Zₖₐₗ mentioned above, preferably a fluorocycloalkyl group represented by —C(ₙ)F(₂ₙ₋₂)H, and a perfluoroaryl group represented by —C(ₙ)F(ₙ₋₁). Here, the number of carbon atoms, n, is not particularly limited, but is preferably 5 to 13, and more preferably 6.

Preferred examples of the ring which may be formed by the mutual linkage of at least two of R_{ew1}, R_{ew2}, or Y_{ew1} include a cycloalkyl group and a heterocyclic group. The heterocyclic group is preferably a lactone ring group. Examples of the lactone ring include the structures represented by Formulae (KA-1-1) to (KA-1-17).

Furthermore, the repeating unit (by) may contain a plurality of the partial structures represented by General Formula (KA-1), or a plurality of the partial structures represented by General Formula (KB-1), or both any one of the partial structures represented by General Formula (KA-1) and any one of the partial structures represented by General Formula (KB-1).

Moreover, a part or all of the partial structures of General Formula (KA-1) may double as the electron withdrawing group as Y¹ or Y² in General Formula (KB-1). For example, in a case where X of General Formula (KA-1) is a carboxylic ester group, the carboxylic ester group can function as the electron withdrawing group as Y¹ or Y² in General Formula (KB-1).

In addition, in a case where the repeating unit (by) corresponds to the above-mentioned repeating unit (b*) or repeating unit (b″) and contains the partial structures represented by General Formula (KA-1), it is preferable that the partial structures represented by General Formula (KA-1) is a partial structure in which the polarity conversion group is expressed by —COO— appearing in the structures represented by General Formula (KA-1).

The repeating unit (by) can be a repeating unit having a partial structure represented by General Formula (KY-0).

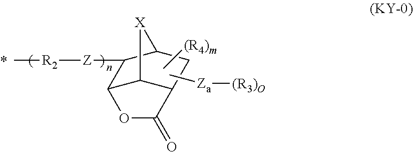

In General Formula (KY-0),

R₂ represents a chained or cyclic alkylene group, and in a case where a plurality of R₂'s are present, they may be the same as or different from each other.

R₃ represents a linear, branched, or cyclic hydrocarbon group whose hydrogen atoms on constituent carbons are partially or entirely replaced with fluorine atoms.

R₄ represents a halogen atom, a cyano group, a hydroxyl group, an amido group, an alkyl group, a cycloalkyl group, an alkoxy group, a phenyl group, an acyl group, an alkoxycarbonyl group, or a group represented by R—C(═O)— or R—C(═O)O— (R represents an alkyl group or a cycloalkyl group). In a case where a plurality of R₄'s are present, they may be the same as or different from each other, and two or more of R₄'s may be bonded to each other to form a ring.

X represents an alkylene group, a cycloalkylene group, an oxygen atom, or a sulfur atom.

Z and Za each represent a single bond, an ether bond, an ester bond, an amido bond, a urethane bond, or a urea bond, and in a case where a plurality of Z's and Za's, they may each be the same as or different from each other.

* represents a bonding arm to the main chain or the side chain of the resin.

o is the number of the substituents, and represents an integer of 1 to 7.

m is the number of the substituents, and represents an integer of 0 to 7.

n is the number of the substituents, and represents an integer of 0 to 5.

The structure of —R₂—Z— is preferably the structure represented by —(CH₂)ₗ—COO— (l represents an integer of 1 to 5).

The preferred range of number of carbon atoms and specific examples of the chained or cyclic alkylene group as R₂ are the same as described for the chained alkylene group and cyclic alkylene group in Z₂ of General Formula (bb).

The number of carbon atoms of the linear, branched, or cyclic hydrocarbon group as R₃ is preferably in the range of 1 to 30, and more preferably 1 to 20 in a case where the hydrocarbon group is linear; is preferably in the range of 3 to 30, and more preferably 3 to 20 in a case where the hydrocarbon group is branched; and is in the range of 6 to 20 in a case where the hydrocarbon group is cyclic. Specific examples of R₃ include the specific examples of the above-described alkyl groups and cycloalkyl groups as Zₖₐₗ.

The preferred range of number of carbon atoms and specific examples of the alkyl groups and cycloalkyl groups in R₄ or R are the same as described for the above-described alkyl groups and cycloalkyl groups as Zₖₐₗ.

The acyl group as R₄ preferably has 1 to 6 carbon atoms, and examples of the acyl group include a formyl group, an acetyl group, a propionyl group, a butyryl group, an isobutyryl group, a valeryl group, and a pivaloyl group.

Examples of the alkyl moiety in the alkoxy group and alkoxycarbonyl group as R₄ include a linear, branched, or cyclic alkyl moiety. The preferred range of number of carbon atoms and specific examples of the alkyl moiety are the same as described for the alkyl groups and cycloalkyl groups as Zₖₐₗ.

Examples of the alkylene group as X include a chained or cyclic alkylene group, and the preferred range of number of carbon atoms and specific examples thereof are the same as described for the alkylene groups and cycloalkylene groups as R₂.

In addition, examples of the specific structures of the repeating unit (by) also include repeating units having the partial structures shown below.

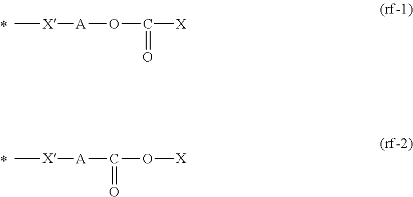

In General Formulae (rf-1) and (rf-2),

X′ represents an electron withdrawing substituent, preferably a carbonyloxy group, an oxycarbonyl group, an alkylene group substituted with a fluorine atom, or a cycloalkylene group substituted with a fluorine atom.

A represents a single bond or a divalent linking group represented by —C(Rx)(Ry)-. Here, Rx and Ry each independently represent a hydrogen atom, a fluorine atom, an alkyl group (preferably having 1 to 6 carbon atoms, optionally substituted with a fluorine atom) or a cycloalkyl group (preferably having 5 to 12 carbon atoms, optionally substituted with a fluorine atom). Rx and Ry are each preferably a hydrogen atom, an alkyl group, or an alkyl group substituted with a fluorine atom.

X represents an electron withdrawing group. Specific examples thereof include the above-mentioned electron withdrawing groups as Y¹ and Y². X is preferably a fluoroalkyl group, a fluorocycloalkyl group, an aryl group substituted with fluorine or a fluoroalkyl group, an aralkyl group substituted with fluorine or a fluoroalkyl group, a cyano group, or a nitro group.

* represents a bonding arm to the main chain or the side chain of the resin, that is, a bonding arm bonded to the main chain of the resin via a single bond or a linking group.

Furthermore, when X′ is a carbonyloxy group or an oxycarbonyl group, A is not a single bond.

The receding contact angle with water of the resist film after alkali development can be decreased by the polarity conversion effected by the decomposition of the polarity conversion group by the action of an alkali developer. The decrease of the receding contact angle with water of the film after alkali development is preferable from the viewpoint of suppression of development defects.

The receding contact angle with water of the resist film after alkali development is preferably 50° or less, more preferably 40° or less, further more preferably 35° or less, and most preferably 30° or less at a temperature of 23±3° C. and a humidity of 45±5%.

The receding contact angle refers to a contact angle determined when the contact line at a liquid droplet-substrate interface draws back. It is generally known that the receding contact angle is useful in the simulation of liquid droplet mobility in a dynamic condition. Simply, the receding contact angle can be defined as a contact angle at a time of recession of the interface of a liquid droplet when the liquid droplet discharged from a needle tip is deposited onto a substrate, and then the liquid droplet is sucked again into the needle. Generally, the receding contact angle can be measured according to a measurement method for a contact angle, known as the dilation/contraction method.

The hydrolysis rate of the hydrophobic resin in an alkali developer is preferably 0.001 nm/sec or more, more preferably 0.01 nm/sec or more, still more preferably 0.1 nm/sec or more, and most preferably 1 nm/sec or more.

Here, the rate of hydrolysis of the hydrophobic resin in an alkali developer refers to the rate of a decrease in the thickness of a resin film formed from only the hydrophobic resin in an aqueous tetramethylammonium hydroxide solution (TMAH) (2.38% by mass) at 23° C.

Furthermore, the repeating unit (by) is more preferably a repeating unit having at least two or more polarity conversion groups.

In a case where the repeating unit (by) has at least two polarity conversion groups, it is preferable that the repeating unit (by) has a group with a partial structure having two polarity conversion groups represented by General Formula (KY-1). In addition, in a case where the structure represented by General Formula (KY-1) has no bonding arm, it is a group with a monovalent or more-valent group resulting from deletion of at least one arbitrary hydrogen atom in the structure.

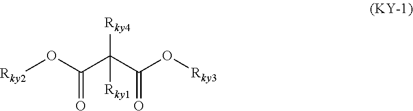

In General Formula (KY-1),

R_{ky1} and R_{ky4} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group. Alternatively, R_{ky1} and R_{ky4} each independently represent may be bonded to the same atom to form a double bond. For example, R_{ky1} and R_{ky4} may be each independently bonded to the same oxygen atom to form a part (═O) of a carbonyl group.

R_{ky2} and R_{ky3} each independently represent an electron withdrawing group.

Alternatively, R_{ky1} and R_{ky2} are linked to each other to form a lactone ring, while R_{ky3} is an electron withdrawing group. The lactone ring thus formed is preferably any of the structures of (KA-1-1) to (KA-1-17). Examples of the electron withdrawing group include the same groups as mentioned for Y₁ and Y₂ in Formula (KB-1). This electron withdrawing group is preferably a halogen atom, or a halo(cyclo)alkyl group or haloaryl group represented by —C(R_{f1})(R_{f2})—R_{f3}. Preferably R_{ky3} is a halogen atom, or a halo(cyclo)alkyl group or haloaryl group represented by —C(R_{f1})(R_{f2})—R_{f3}, while R_{ky2} is linked to R_{ky1} to form a lactone ring, or an electron withdrawing group containing no halogen atom.

R_{ky1}, R_{ky2}, and R_{ky4} may be linked to each other to form a monocyclic or polycyclic structure.

Specific examples of R_{ky1} and R_{ky4} include the same groups as for Zₖₐₗ in Formula (KA-1).

The lactone rings formed by the linkage of R_{ky1} and R_{ky2} preferably have the structures of (KA-1-1) to (KA-1-17). Examples of the electron withdrawing group include the same ones as for Y₁ and Y₂ in Formula (KB-1).

It is more preferable that the structure represented by General Formula (KY-1) is the structure represented by General Formula (KY-2) below. Further, the structure represented by General Formula (KY-2) is a group with a monovalent or higher-valent group resulting from removal of at least one arbitrary hydrogen atoms in the structure.

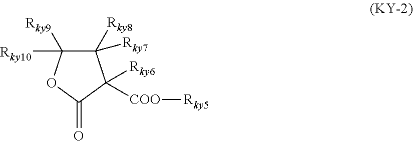

In Formula (KY-2),

R_{ky6} to R_{ky10} each independently represent a hydrogen atom, a halogen atom, an alkyl group, a cycloalkyl group, a carbonyl group, a carbonyloxy group, an oxycarbonyl group, an ether group, a hydroxyl group, a cyano group, an amido group, or an aryl group.

Two or more of R_{ky6} to R_{ky10} may be linked to each other to form a monocyclic or polycyclic structure.

R_{ky5} represents an electron withdrawing group. Examples of the electron withdrawing group include the same ones as for Y₁ and Y₂. This electron withdrawing group is preferably a halogen atom, or a halo(cyclo)alkyl group or haloaryl group represented by —C(R_{f1})(R_{f2})—R_{f3}.

Specific examples of R_{ky5} to R_{ky10} include the same groups as for Zₖₐₗ in Formula (KA-1).

The structure represented by Formula (KY-2) is more preferably a partial structure represented by General Formula (KY-3).

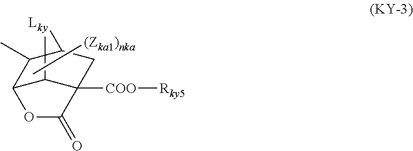

In Formula (KY-3), Zₖₐₗ and nka have the same definitions as in General Formula (KA-1). R_{ky5} has the same definition as in Formula (KY-2).

L_{ky} represents an alkylene group, a cycloalkylene group, an oxygen atom, or a sulfur atom. Examples of the alkylene group of L_{ky} include a methylene group and an ethylene group. L_{ky} is preferably an oxygen atom or a methylene group, and more preferably a methylene group.

The repeating unit (b) is not limited as long as it is derived by polymerization such as addition polymerization and condensation polymerization, but the repeating unit (b) is preferably a repeating unit obtained by the addition polymerization of a carbon to carbon double bond. Examples of such the repeating unit include acrylate-based repeating units (including the family having a substituent at the α- or β-position), styrene-based repeating units (including the family having a substituent at the α- or β-position), vinyl ether-based repeating units, norbornene-based repeating units, and repeating units of maleic acid derivatives (maleic acid anhydride, a derivative thereof, maleimide, and the like). Acrylate-based repeating units, styrene-based repeating units, vinyl ether-based repeating units, and norbornene-based repeating units are preferable, acrylate-based repeating units, vinyl ether-based repeating units, and norbornene-based repeating units are more preferable, and acrylate-based repeating units are the most preferable.

In a case where the repeating unit (by) is a repeating unit having at least one of a fluorine atom or a silicon atom (that is, in case of corresponding to the above repeating unit (b′) or (b″)), examples of the partial structure containing a fluorine atom within the repeating unit (by) include the same ones as mentioned for the repeating unit having at least one of a fluorine atom or a silicon atom, and preferably the groups represented by General Formulae (F2) to (F4). Further, in this case, examples of the partial structure containing a silicon atom in the repeating unit (by) include the same ones as mentioned for the repeating unit having at least one of a fluorine atom or a silicon atom, and preferably the groups represented by General Formulae (CS-1) to (CS-3).

The content of the repeating unit (by) in the hydrophobic resin is preferably 10% to 100% by mole, more preferably 20% to 99% by mole, still more preferably 30% to 97% by mole, and most preferably 40% to 95% by mole, with respect to all the repeating units of the hydrophobic resin.

Specific examples of the repeating units (by) containing a group whose solubility in an alkali developer increases include, but not limited to, the repeating units disclosed in paragraph 0725 of US2012/0135348A.

With regard to a method for synthesizing a monomer corresponding to the repeating unit (by) having the polarity conversion group (y) as described above, the monomer can be synthesized with reference to, for example, the method described in WO2010/067905A, WO2010/067905A, or the like.

Examples of the repeating unit (bz) having a group (z) that decomposes by the action of an acid in the hydrophobic resin include the same ones as the repeating units having the acid-decomposable group mentioned in the resin (B).

In a case where the repeating unit (bz) is a repeating unit having at least one of a fluorine atom or a silicon atom (that is, in a case of corresponding to the repeating unit (b′) or (b″)), examples of the partial structure having a fluorine atom in the repeating unit (bz) include the same ones as mentioned for the repeating unit having at least one of a fluorine atom or a silicon atom, and preferably the groups represented by General Formulae (F2) to (F4). Further, in this case, examples of the partial structure having a silicon atom in the repeating unit (by) include the same ones as mentioned for the repeating unit having at least one of a fluorine atom or a silicon atom, and preferably the groups represented by General Formulae (CS-1) to (CS-3).

The content of the repeating unit (bz) having a group (z) that decomposes by the action of an acid in the hydrophobic resin is preferably 1% to 80% by mole, more preferably 10% to 80% by mole, and still more preferably 20% to 60% by mole, with respect to all the repeating units in the hydrophobic resin.

The repeating unit (b) having at least one group selected from the group consisting of (x) to (z) has been described above, and the content of the repeating unit (b) in the hydrophobic resin is preferably 1% to 98% by mole, more preferably 3% to 98% by mole, still more preferably 5% to 97% by mole, and most preferably 10% to 95% by mole, with respect to all the repeating units in the hydrophobic resin.

The content of the repeating unit (b′) is preferably 1% to 100% by mole, more preferably 3% to 99% by mole, still more preferably 5% to 97% by mole, and most preferably 10% to 95% by mole, with respect to all the repeating units in the hydrophobic resin.

The content of the repeating unit (b*) is preferably 1% to 90% by mole, more preferably 3% to 80% by mole, still more preferably 5% to 70% by mole, and most preferably 10% to 60% by mole, with respect to all the repeating units in the hydrophobic resin. The content of the repeating unit having at least one of a fluorine atom or a silicon atom, used together with the repeating unit (b*), is preferably 10% to 99% by mole, more preferably 20% to 97% by mole, still more preferably 30% to 95% by mole, and most preferably 40% to 90% by mole, with respect to all the repeating units in the hydrophobic resin.

The content of the repeating unit (b″) is preferably 1% to 100% by mole, more preferably 3% to 99% by mole, still more preferably 5% to 97% by mole, and most preferably 10% to 95% by mole, with respect to all the repeating units in the hydrophobic resin.

The hydrophobic resin may further have a repeating unit represented by General Formula (CIII).

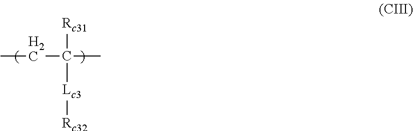

In General Formula (CIII),

R_{c31} represents a hydrogen atom, an alkyl group (which may be substituted with a fluorine atom or the like), a cyano group, or a —CH₂—O-Rac₂. In the formula, Rac₂ represents a hydrogen atom, an alkyl group, or an acyl group. R_{c31} is preferably a hydrogen atom, a methyl group, a hydroxymethyl group, or a trifluoromethyl group, and more preferably a hydrogen atom or a methyl group.

R_{c32} represents a group containing an alkyl group, a cycloalkyl group, an alkenyl group, a cycloalkenyl group, or an aryl group. These groups may be substituted with a group containing a fluorine atom, a silicon atom, or the like.

L_{c3} represents a single bond or a divalent linking group.

The alkyl group of R_{c32} in General Formula (CIII) is preferably a linear or branched alkyl group having 3 to 20 carbon atoms.

The cycloalkyl group is preferably a cycloalkyl group having 3 to 20 carbon atoms.

The alkenyl group is preferably an alkenyl group having 3 to 20 carbon atoms.

The cycloalkenyl group is preferably a cycloalkenyl group having 3 to 20 carbon atoms.

The aryl group is preferably a phenyl group or a naphthyl group, having 6 to 20 carbon atoms, and this group may have a substituent.

R_{c32} is preferably an unsubstituted alkyl group or an alkyl group substituted with a fluorine atom.

The divalent linking group of L_{c3} is preferably an alkylene group (preferably having 1 to 5 carbon atoms), an oxy group, a phenylene group, or an ester bond (a group represented by —COO—).

It is also preferable that the hydrophobic resin has a repeating unit represented by General Formula (BII-AB).

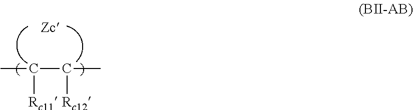

In Formula (BII-AB),

R_{c11}′ and R_{c12}′ each independently represent a hydrogen atom, a cyano group, a halogen atom, or an alkyl group.

Zc′ represents an atomic group for forming an alicyclic structure in cooperation with two carbon atoms (C—C) to which it is bonded.

In a case where each of the groups in the repeating unit represented by General Formulae (CIII) and (BII-AB) is substituted with a group containing a fluorine atom or a silicone atom, the repeating unit is also corresponding to the repeating unit having at least one of a fluorine atom or a silicon atom.

Specific examples of the repeating unit represented by General Formulae (CIII) or (BII-AB) are shown below, but the present invention is not limited thereto. In the formulae, Ra represents H, CH₃, CH₂OH, CF₃, or CN. Further, the repeating unit in a case where Ra is CF₃ also corresponds to the repeating unit having at least one of a fluorine atom or a silicon atom.

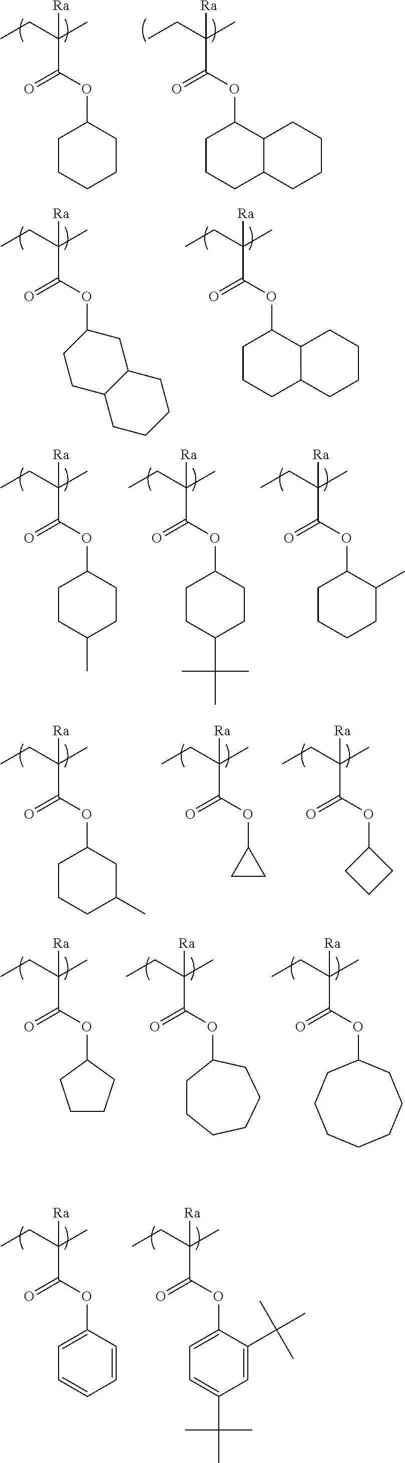

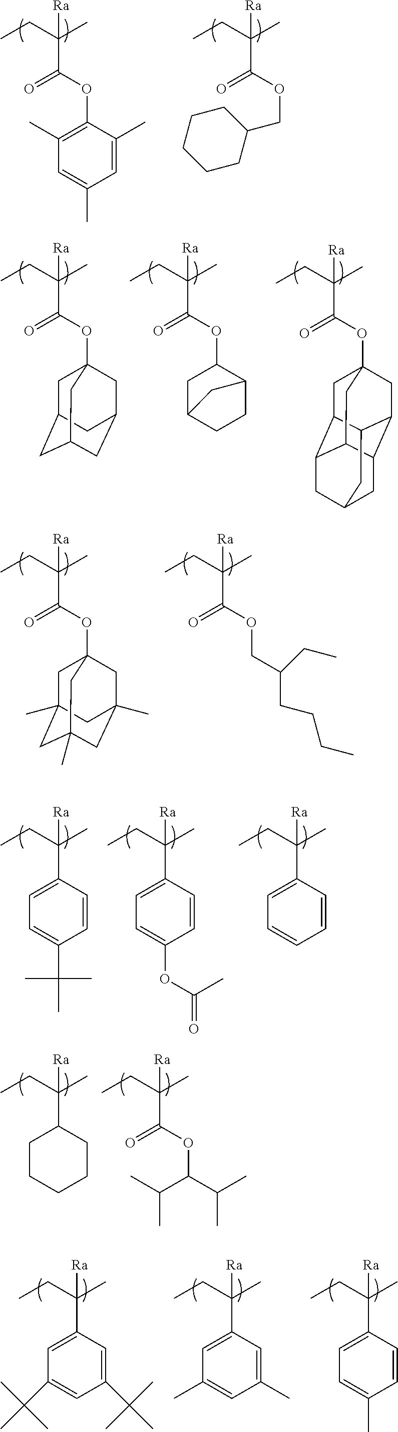

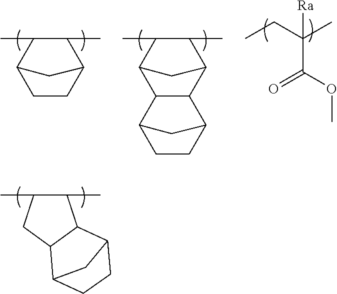

Impurities such as metals in the hydrophobic resin should naturally be of low quantity as in the above-mentioned resin (B). In addition, the content of residual monomers and oligomer components is preferably 0% to 10% by mass, more preferably 0% to 5% by mass, and still more preferably 0% to 1% by mass. Thus, a composition which is free from in-liquid foreign matters and a change in sensitivity or the like over time is obtained. From the viewpoints of resolving power, resist profile, the side wall of a resist pattern, roughness, and the like, the molecular weight distribution (Mw/Mn, also referred to as a dispersity) thereof is preferably in the range of 1 to 3, more preferably 1 to 2, still more preferably 1 to 1.8, and most preferably 1 to 1.5.

A variety of commercially available products can be used as the hydrophobic resin, and also the resin can be synthesized in accordance with conventional methods (for example, by radical polymerization). Examples of the general synthesizing methods include a batch polymerization method in which a monomer species and an initiator are dissolved in a solvent and heated to carry out polymerization, and a dropwise-addition polymerization method in which a solution of monomer species and initiator is dropped into a hot solvent over a period of 1 to 10 hours. Among these, the dropwise-addition polymerization method is preferable.

The reaction solvent, the polymerization initiator, the reaction conditions (a temperature, a concentration, and the like), and the purification method after a reaction are the same as described above for the above-mentioned resin (B).

Specific examples of the hydrophobic resin (HR) are shown below. Further, Table 1 shows the molar ratio of the repeating units (the position relationship of the respective resins shown in the specific examples corresponds to the position relationship of the compositional ratio in Table 1), the weight-average molecular weight, and the dispersity with respect to each of the resins.

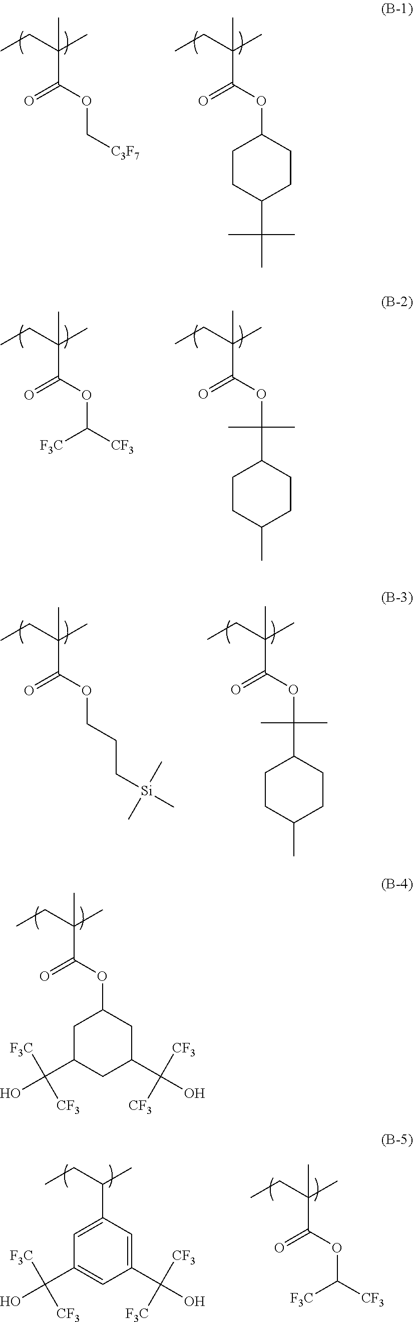

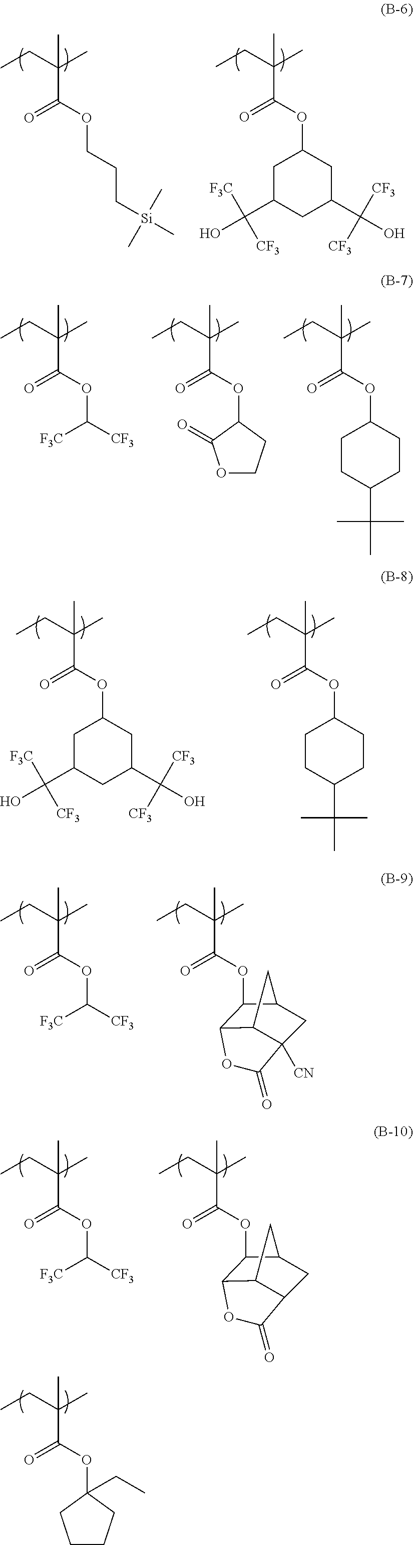

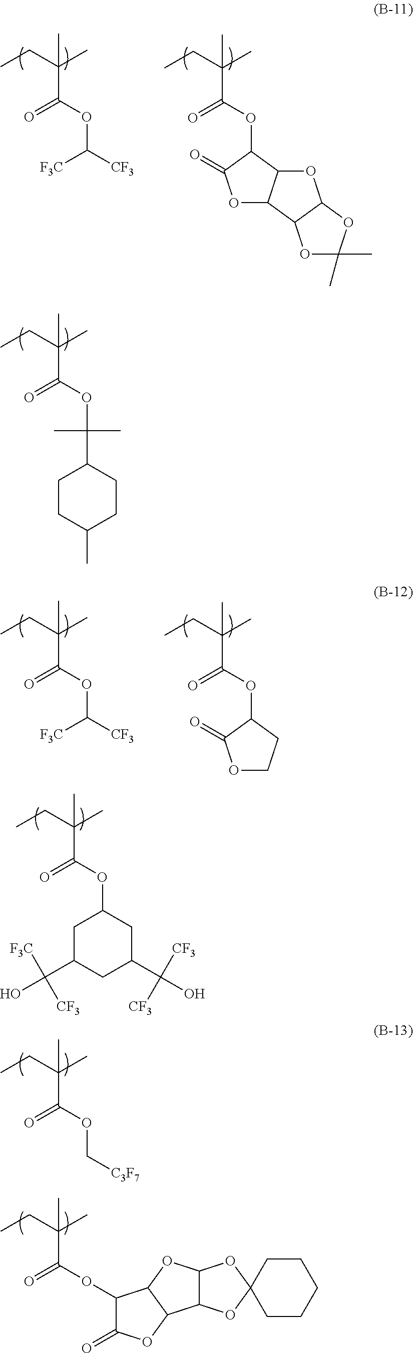

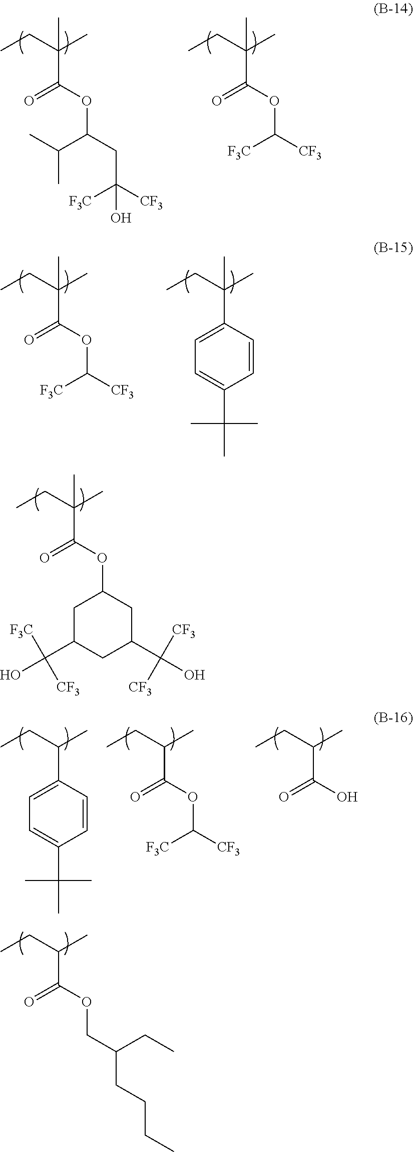

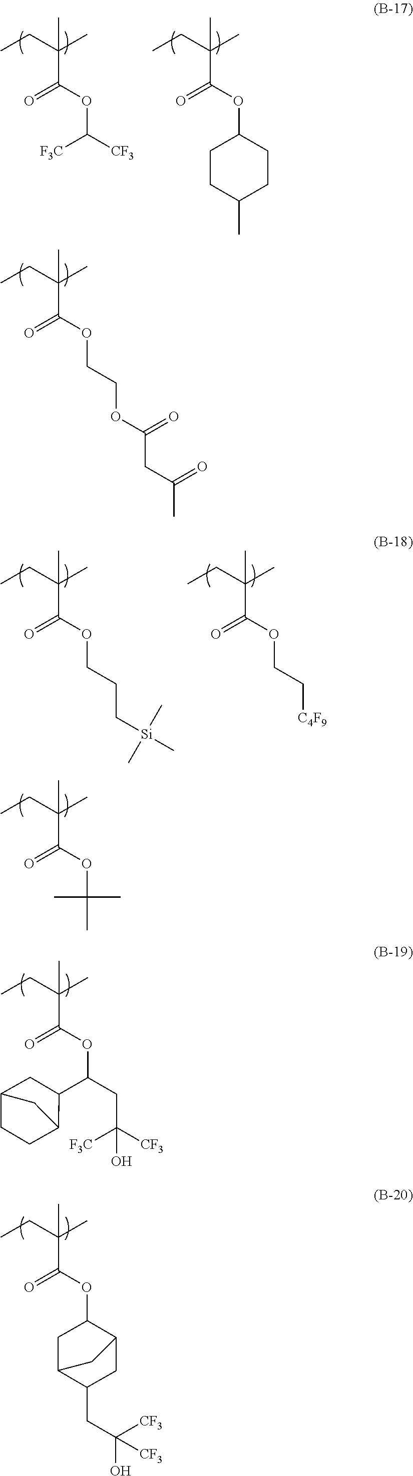

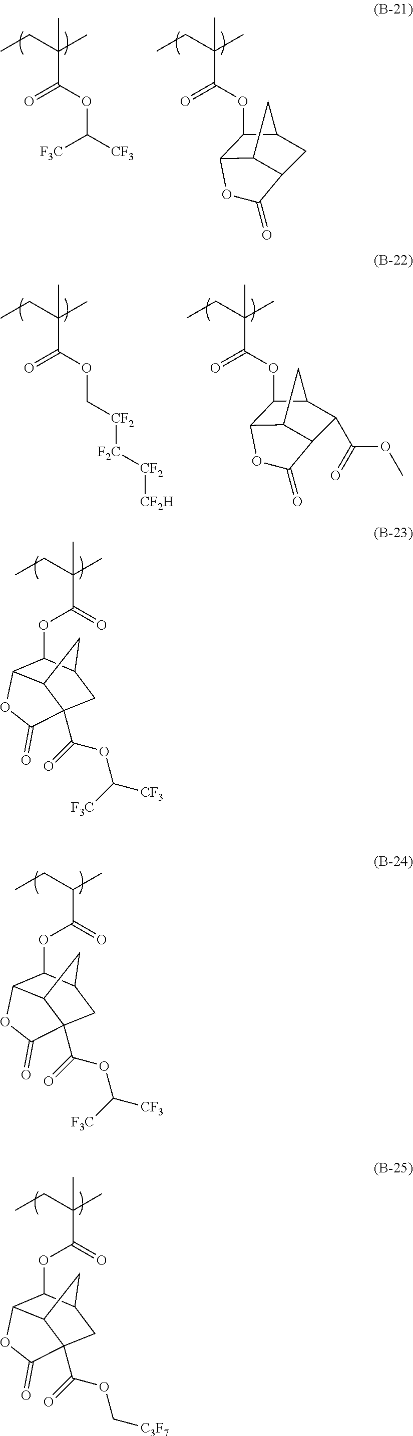

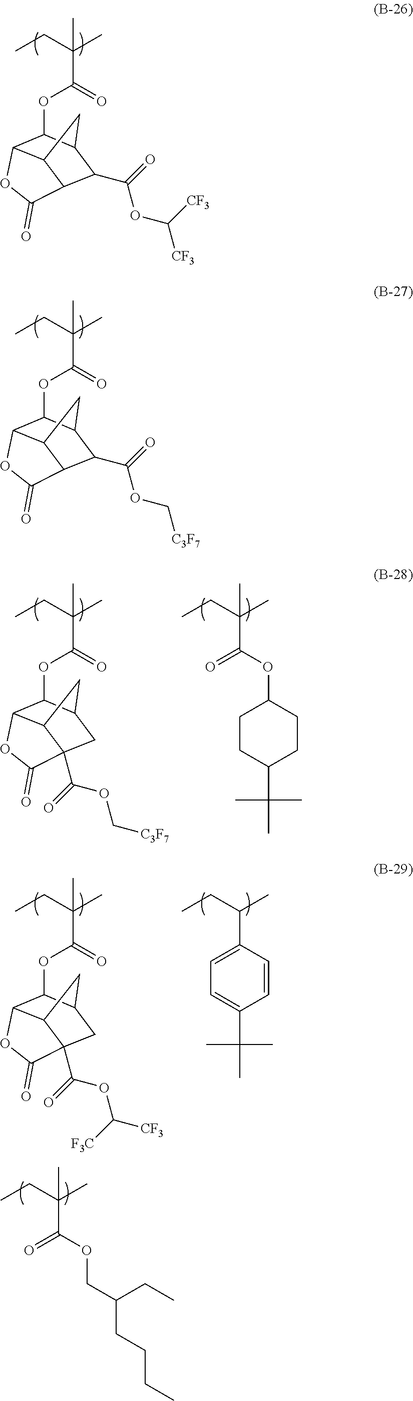

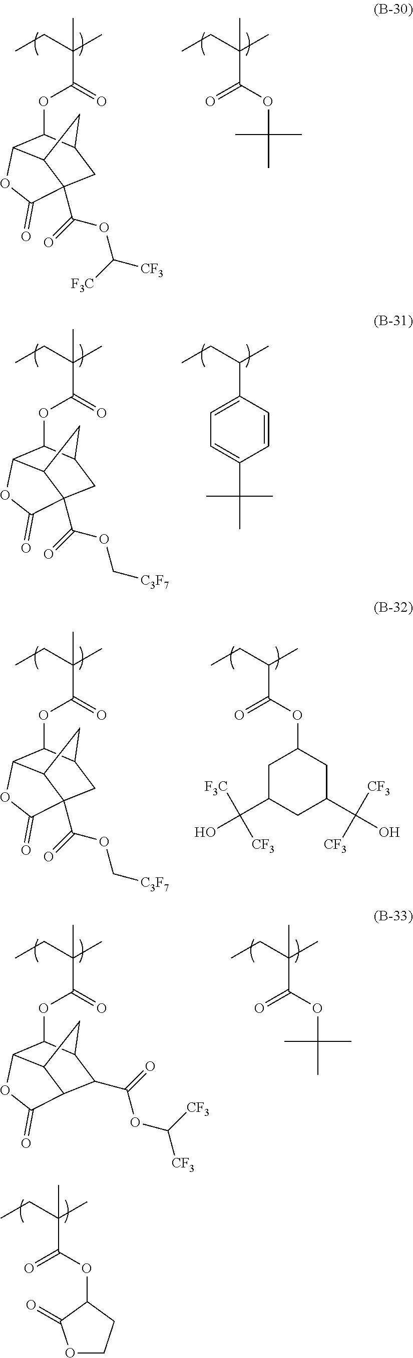

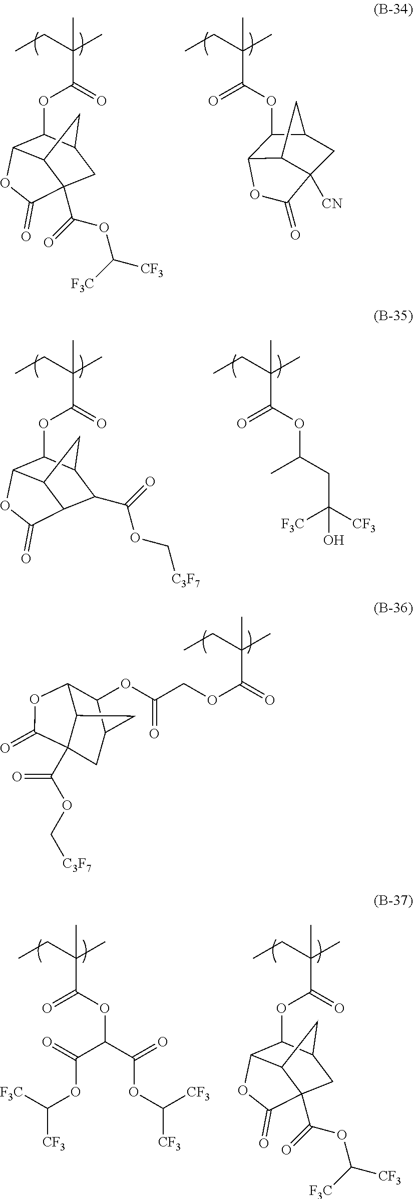

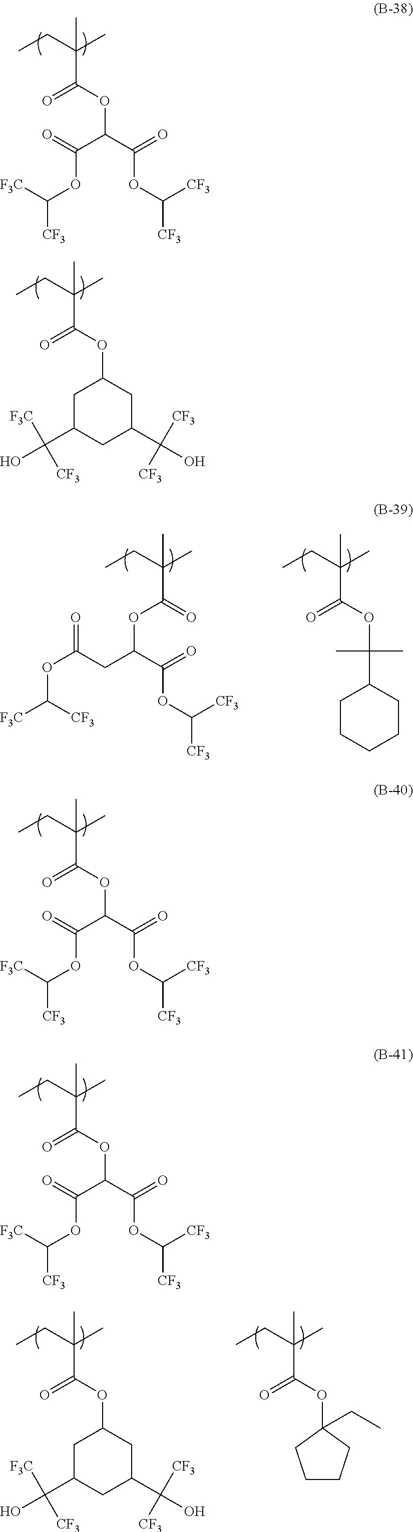

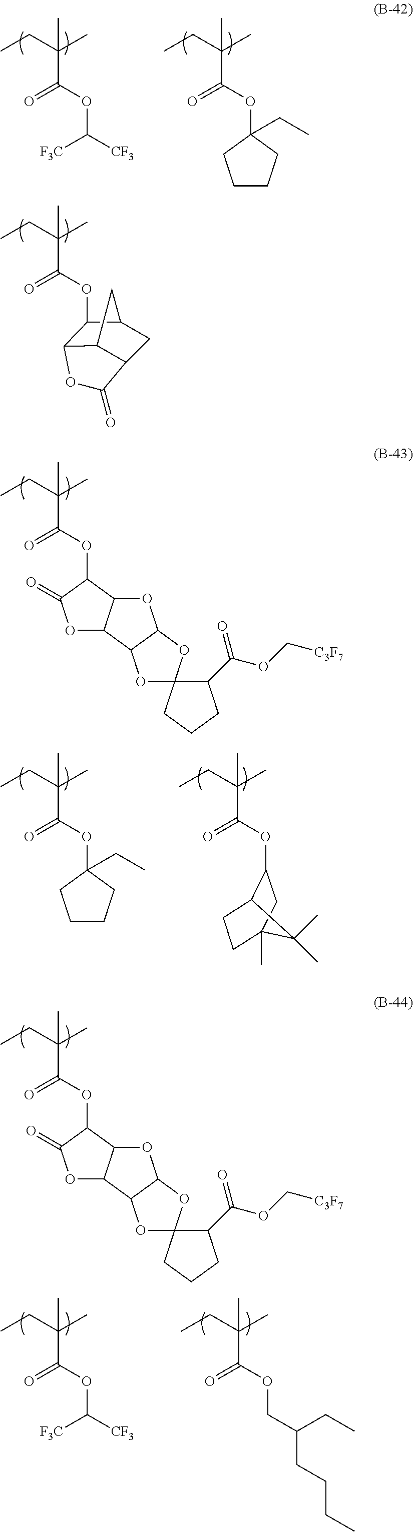

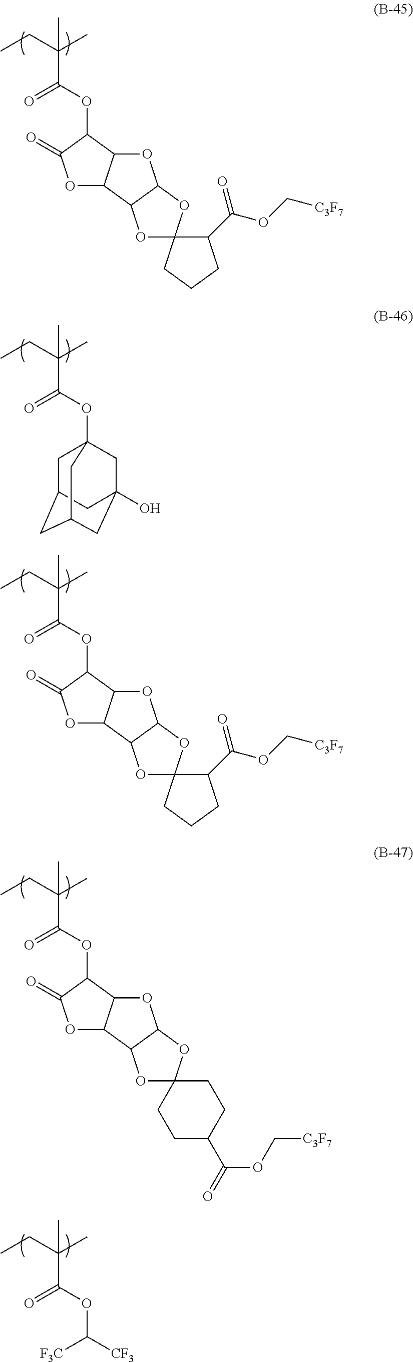

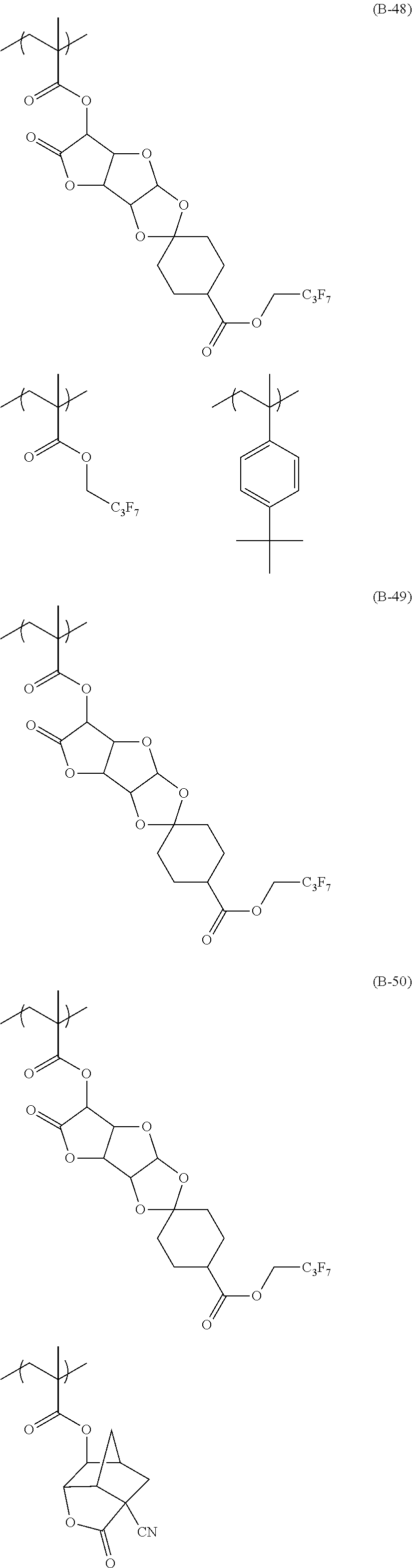

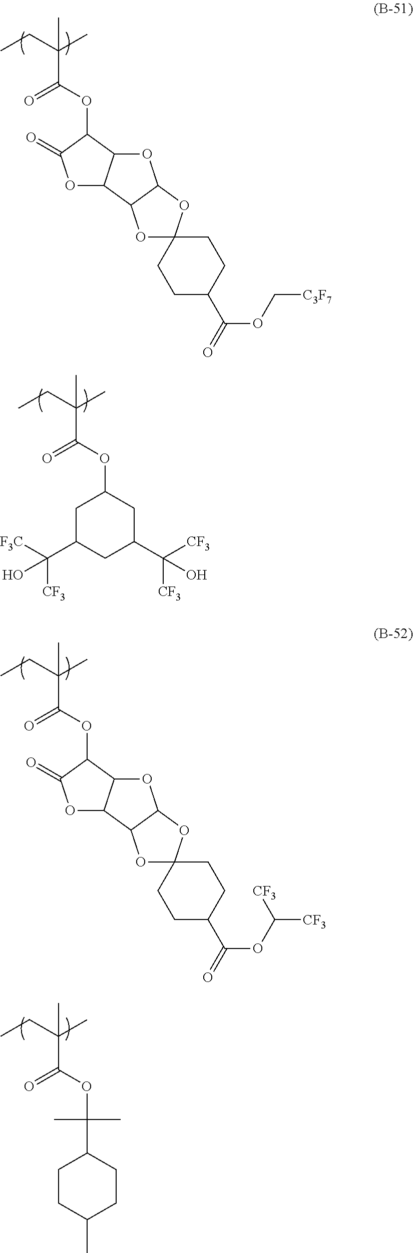

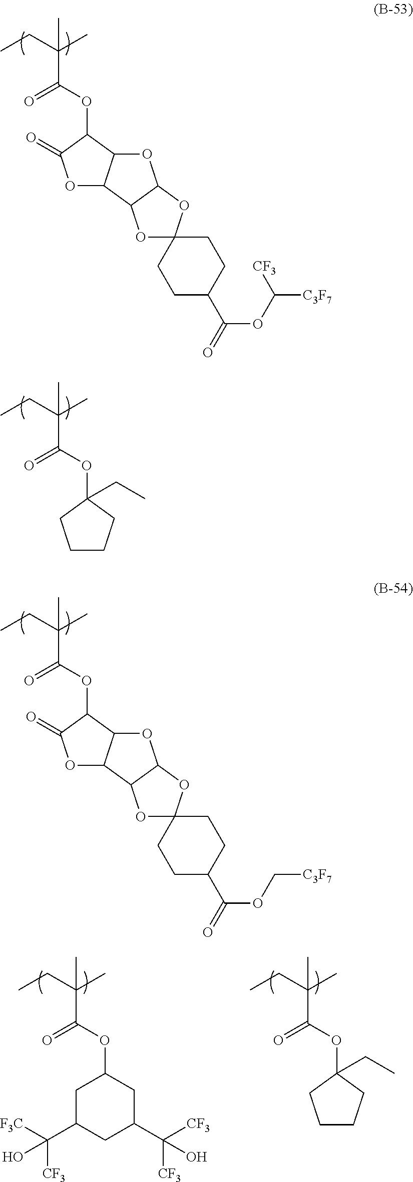

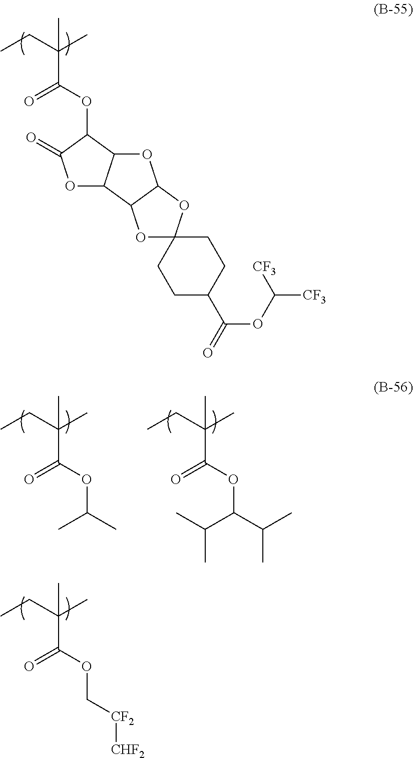

TABLE 1

| | Compositional | | |
|---|---|---|---|
| Polymer | ratio (% by mole) | Mw | Mw/Mn |
| B-1 | 50/50 | 6,000 | 1.5 |
| B-2 | 30/70 | 6,500 | 1.4 |
| B-3 | 45/55 | 8,000 | 1.4 |
| B-4 | 100 | 15,000 | 1.7 |
| B-5 | 60/40 | 6,000 | 1.4 |
| B-6 | 40/60 | 8,000 | 1.4 |
| B-7 | 30/40/30 | 8,000 | 1.4 |
| B-8 | 60/40 | 8,000 | 1.3 |
| B-9 | 50/50 | 6,000 | 1.4 |
| B-10 | 40/40/20 | 7,000 | 1.4 |
| B-11 | 40/30/30 | 9,000 | 1.6 |
| B-12 | 30/30/40 | 6,000 | 1.4 |
| B-13 | 60/40 | 9,500 | 1.4 |
| B-14 | 60/40 | 8,000 | 1.4 |
| B-15 | 35/35/30 | 7,000 | 1.4 |
| B-16 | 50/40/5/5 | 6,800 | 1.3 |
| B-17 | 20/30/50 | 8,000 | 1.4 |
| B-18 | 25/25/50 | 6,000 | 1.4 |
| B-19 | 100 | 9,500 | 1.5 |
| B-20 | 100 | 7,000 | 1.5 |
| B-21 | 50/50 | 6,000 | 1.6 |
| B-22 | 40/60 | 9,600 | 1.3 |
| B-23 | 100 | 20,000 | 1.7 |
| B-24 | 100 | 25,000 | 1.4 |
| B-25 | 100 | 15,000 | 1.7 |
| B-26 | 100 | 12,000 | 1.8 |
| B-27 | 100 | 18,000 | 1.3 |
| B-28 | 70/30 | 15,000 | 2.0 |
| B-29 | 80/15/5 | 18,000 | 1.8 |
| B-30 | 60/40 | 25,000 | 1.8 |
| B-31 | 90/10 | 19,000 | 1.6 |
| B-32 | 60/40 | 20,000 | 1.8 |
| B-33 | 50/30/20 | 11,000 | 1.6 |
| B-34 | 60/40 | 12,000 | 1.8 |
| B-35 | 60/40 | 15,000 | 1.6 |
| B-36 | 100 | 22,000 | 1.8 |
| B-37 | 20/80 | 35,000 | 1.6 |
| B-38 | 30/70 | 12,000 | 1.7 |
| B-39 | 30/70 | 9,000 | 1.5 |
| B-40 | 100 | 9,000 | 1.5 |
| B-41 | 40/15/45 | 12,000 | 1.9 |
| B-42 | 30/30/40 | 13,000 | 2.0 |
| B-43 | 40/40/20 | 23,000 | 2.1 |
| B-44 | 65/30/5 | 25,000 | 1.6 |
| B-45 | 100 | 15,000 | 1.7 |
| B-46 | 20/80 | 9,000 | 1.7 |
| B-47 | 70/30 | 18,000 | 1.5 |
| B-48 | 60/20/20 | 18,000 | 1.8 |
| B-49 | 100 | 12,000 | 1.4 |
| B-50 | 60/40 | 20,000 | 1.6 |
| B-51 | 70/30 | 33,000 | 2.0 |
| B-52 | 60/40 | 19,000 | 1.8 |
| B-53 | 50/50 | 15,000 | 1.5 |
| B-54 | 40/20/40 | 35,000 | 1.9 |
| B-55 | 100 | 16,000 | 1.4 |
| B-56 | 30/65/5 | 28,000 | 1.7 |

In a case where the hydrophobic resin has fluorine atoms, the content of the fluorine atoms is preferably 5% to 80% by mass, and more preferably 10% to 80% by mass, with respect to the molecular weight of the hydrophobic resin. Further, the repeating unit containing a fluorine atom is preferably in the amount of 10% to 100% by mass, and more preferably 30% to 100% by mass, with respect to all the repeating units in the hydrophobic resin.

In a case where the hydrophobic resin has silicon atoms, the content of the silicon atoms is preferably in the range of 2% to 50% by mass, and more preferably 2% to 30% by mass, with respect to the molecular weight of the hydrophobic resin. Further, the repeating unit containing silicon atoms is preferably in the amount of 10% to 90% by mass, and more preferably 20% to 80% by mass, with respect to all the repeating units in the hydrophobic resin.

The weight-average molecular weight of the hydrophobic resin is preferably 1,000 to 100,000, more preferably 2,000 to 50,000, and still more preferably 3,000 to 35,000. Here, the weight-average molecular weight of the resin refers to a polystyrene-equivalent molecular weight measured by GPC (carrier: tetrahydrofuran (THF)).

The content of hydrophobic resin in the actinic ray-sensitive or radiation-sensitive composition can be appropriately adjusted for use so that the receding contact angle of the actinic ray-sensitive or radiation-sensitive resin film falls within the above-mentioned range. The content of the hydrophobic resin is preferably 0.01% to 20% by mass, more preferably 0.1% to 15% by mass, still more preferably 0.1% to 10% by mass, and most preferably 0.2% to 8% by mass, based on the total solid contents of the composition.

The hydrophobic resins may be used singly or in combination of two or more kinds thereof.

[Surfactant]

The actinic ray-sensitive or radiation-sensitive composition according to the first embodiment of the present invention may further include a surfactant (F) in order to improve the coatability. Examples of the surfactant are not particularly limited, but include nonionic surfactants such as polyoxyethylene alkyl ethers, polyoxyethylene alkylaryl ethers, polyoxyethylene polyoxypropylene block copolymers, sorbitan fatty acid esters, and polyoxyethylene sorbitan fatty acid esters, fluorine-based surfactants such as MEGAFACE F171 and F176 (manufactured by Dainippon Ink & Chemicals, Inc.), FLORAD FC 430 (manufactured by Sumitomo 3M, Ltd.), SURFYNOL E1004 (manufactured by ASAHI GLASS CO., LTD.), and PF656 and PF6320 manufactured by OMNOVA Solutions Inc, and organosiloxane polymers such as Polysiloxane Polymer KP-341 (manufactured by Shin-Etsu Chemical Co., Ltd.).

In a case where the composition of the present invention contains a surfactant, the amount of the surfactant to be used is preferably 0.0001% to 2% by mass, and more preferably 0.0005% to 1% by mass, with respect to the total amount of the actinic ray-sensitive or radiation-sensitive composition (excluding the solvent).

[Organic Acid]

The actinic ray-sensitive or radiation-sensitive composition according to the first embodiment of the present invention may further contain an organic acid. The amount of the organic acid is preferably large from the viewpoint of temporal stability, and the content of the organic acid to be added is preferably more than 5% by mass with respect to the total solid contents of the actinic ray-sensitive or radiation-sensitive composition according to the first embodiment of the present invention. In one aspect of the present invention, the content of the organic acid is more preferably more than 5% by mass and less than 15% by mass, and still more preferably more than 5% by mass and less than 10% by mass, with respect to the total solid contents of the actinic ray-sensitive or radiation-sensitive composition according to the first embodiment of the present invention.

From the viewpoint of temporal stability, the pKa of the organic acid is preferably in the range of 0 to 10, more preferably in the range of 2 to 8, and still more preferably in the range of 3 to 7. Here, the pKa indicates a pKa in an aqueous solution, and is described, for example, in Chemical Handbook (II) (Revised 4^{th} Edition, 1993, compiled by the Chemical Society of Japan, Maruzen Inc.), and a lower value thereof indicates higher acid strength. Specifically, the pKa in an aqueous solution can be measured by using an infinite-dilution aqueous solution and measuring the acid dissociation constant at 25° C., or a value based on the Hammett substituent constants and the database of publicly known literature value data can also be determined by computation using the following Software Package 1. All the values of pKa described in the present specification indicate values determined by computation using this software package. Software Package 1: Advanced Chemistry Development (ACD/Labs) Software V 8.14 for Solaris (1994-2007 ACD/Labs).

As described above, from the viewpoint of suppression of side reactions occurring between the resin and the acid generator, the pKa of the organic acid is preferably lower than the pKa of the resin and higher than the pKa of the acid generated from the acid generator. In one aspect of the present invention, the pKa of the organic acid is preferably 3 or more lower, and more preferably 5 or more lower than the pKa of the (A) resin. In addition, in another aspect, the pKa of the organic acid is preferably 2 or more higher, and more preferably 3 or more lower than the pKa of the (B) resin.

Examples of the organic acid which can be used in the present invention include an organic carboxylic acid and an organic sulfonic acid, and among these, the organic carboxylic acid is preferable. Examples of the organic carboxylic acid include an aromatic organic carboxylic acid, an aliphatic carboxylic acid, an alicyclic carboxylic acid, an unsaturated aliphatic carboxylic acid, an oxycarboxylic acid, and an alkoxycarboxylic acid. In one aspect of the present invention, the aromatic organic carboxylic acid is preferable, and the organic acids represented shown below, and the like are particularly preferable.

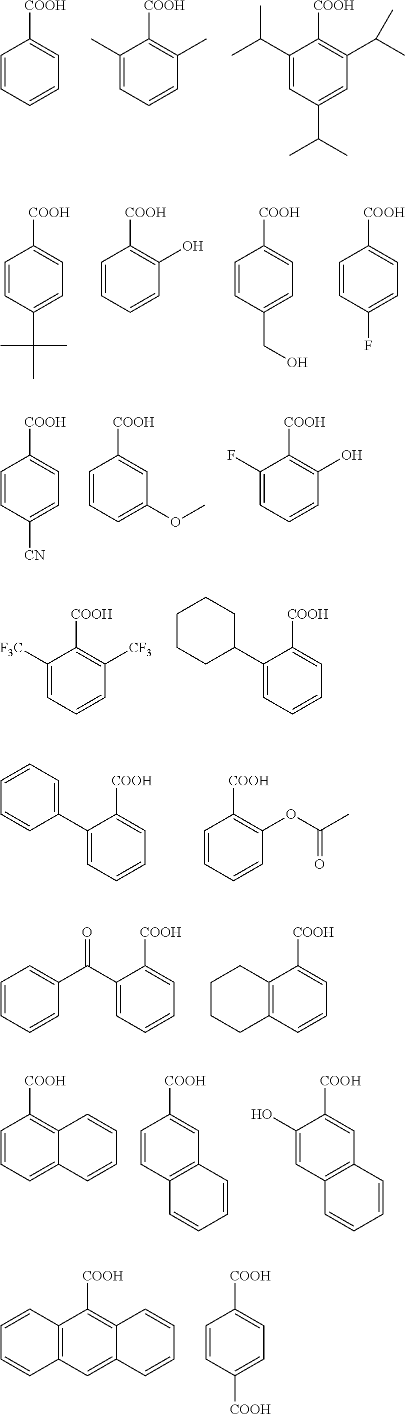

Moreover, the organic acid which may be contained in the actinic ray-sensitive or radiation-sensitive composition according to the first embodiment of the present invention can also be used as an acid which may be contained in the pre-rinsing liquid.

[Compound Having Two or More Functional Groups Which Forms Hydrogen Bond with Phenolic Hydroxyl Group]

For the actinic ray-sensitive or radiation-sensitive composition according to the first embodiment of the present invention, a compound having two or more functional groups which form a hydrogen bond with a phenolic hydroxyl group (in particular, a phenolic hydroxyl group in the resin (C)) may further be used. By using such the compound, the film hardness (hardness, density) of the resist film can be enhanced. Specific examples of the compound are shown below.

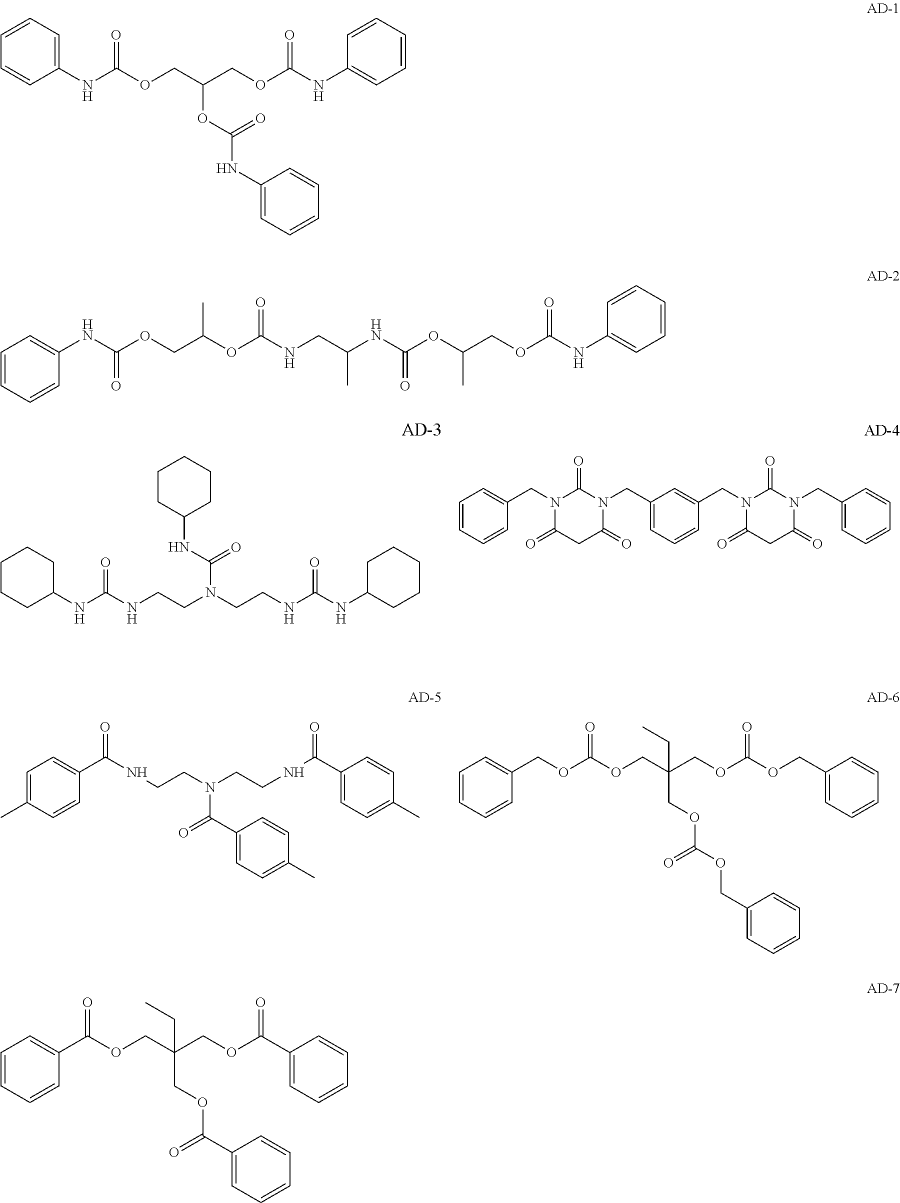

[Onium Carboxylate Salt]

The actinic ray-sensitive or radiation-sensitive composition according to the first embodiment of the present invention may contain an onium carboxylate salt. Examples of the onium carboxylate salt include a sulfonium carboxylate salt, an iodonium carboxylate salt, and an ammonium carboxylate salt. In particular, as the onium carboxylate salt, an iodonium salt and a sulfonium salt are preferable. Further, it is preferable that the carboxylate residue of the onium carboxylate salt does not contain an aromatic group and a carbon-carbon double bond. As a particularly preferred anionic moiety, a linear, branched, or cyclic (monocyclic or polycyclic) alkylcarboxylate anion having 1 to 30 carbon atoms is preferable. Further, a carboxylate anion in which a part or all of the alkyl groups are substituted with fluorine is more preferable. An oxygen atom may be contained in the alkyl chain, by which the transparency to the light at 220 nm or less is ensured, thus, sensitivity and resolving power are enhanced, and density dependency and exposure margin are improved.

The blending ratio of the onium carboxylate salt is preferably 1% to 15% by mass, and more preferably 2% to 10% by mass, with respect to the total solid contents of the composition.

[Acid Proliferation Agent]

The actinic ray-sensitive or radiation-sensitive composition according to the first embodiment of the present invention may further include one kind or two or more kinds of compound (hereinafter also referred to as an acid proliferation agent) that decomposes by the action of an acid to generate an acid. The acid generated by the acid proliferation agent is preferably sulfonic acid, methide acid, or imide acid. The content of the acid proliferation agent is preferably 0.1% to 50% by mass, more preferably 0.5% to 30% by mass, and still more preferably 1.0% to 20% by mass, based on the total solid contents of the composition.

The quantitative ratio of the acid proliferation agent to the acid generator (the solid fraction of the acid proliferation agent based on the total solid contents in the composition/the solid fraction of the acid generator based on the total solid contents in the composition) is not particularly limited, but is preferably 0.01 to 50, more preferably 0.1 to 20, and particularly preferably 0.2 to 1.0.

With regard to the acid proliferation agent, reference can be made to the description in [0381] of JP2014-41328A, the contents of which are incorporated in the present specification.

[Solvent]

The actinic ray-sensitive or radiation-sensitive composition according to the first embodiment of the present invention preferably contains a solvent. Examples of the solvent include ethylene glycol monoethyl ether acetate, cyclohexanone, 2-heptanone, propylene glycol monomethyl ether (PGME, alternative name: 1-methoxy-2-propanol), propylene glycol monomethyl ether acetate (PGMEA, alternative name: 1-methoxy-2-acetoxypropane), propylene glycol monomethyl ether propionate, propylene glycol monoethyl ether acetate, methyl 3-methoxypropionate, ethyl 3-ethoxypropionate, methyl β-methoxyisobutyrate, ethyl butyrate, propyl butyrate, methyl isobutyl ketone, ethyl acetate, isoamyl acetate, ethyl lactate, toluene, xylene, cyclohexyl acetate, diacetone alcohol, N-methylpyrrolidone, N,N-dimethylformamide, γ-butyrolactone, N,N-dimethylacetamide, propylene carbonate, and ethylene carbonate. These solvents are used singly or in combination.

The solvent may include isomers (compounds having the same atomic number but different structures). In addition, one kind or two or more kinds of the isomers may be included. The solid content of the composition of to the invention is preferably dissolved in the solvents at the concentration of the solid content of 1% to 40% by mass, more preferably 1% to 30% by mass, and still more preferably 3% to 20% by mass.

The content of the solid content of the composition of the present invention can be appropriately adjusted for the purpose of adjusting the thickness of a resist film to be manufactured.

### Second Embodiment

[Resin (B) Having Group that Decomposes by Action of Acid to Increase its Polarity]

The actinic ray-sensitive or radiation-sensitive composition according to the second embodiment of the present invention suitably includes a resin (B) (hereinafter also referred to as an “acid-decomposable resin” or a “resin (B)”) having a group (hereinafter also referred to as an “acid-decomposable group”) that decomposes by the action of an acid to increase its polarity. Here, in a case of employing an alkali developer as the developer in the pattern forming method of the present invention, a positive tone pattern is suitably formed, and in a case of adopting and using an organic developer as the developer, a negative tone pattern is suitably formed. However, formation of the positive tone pattern and the negative tone pattern with the resin (B) is not limited to the method, and the positive tone pattern and the negative tone pattern may also be formed by employing a developing method or the like, which might be newly invented later.

The resin (B) preferably includes a repeating unit having a group that decomposes by the action of an acid to increase its polarity (hereinafter also referred to as an “acid-decomposable group”). The repeating unit having a group that decomposes by the action of an acid to increase its polarity is preferably a repeating unit having a group that decomposes by the action of an acid to generate a polar group. In the resin (B) has a repeating unit having an acid-decomposable group, its solubility in an alkali developer increases by the action of an acid and its solubility in an organic solvent decreases. Thus, the resin (B) having the repeating unit having an acid-decomposable group can be suitably used for formation of a positive tone pattern using an alkali developer or formation of a negative tone pattern using an organic developer.

The acid-decomposable group is preferably a group resulting from substitution of a hydrogen atom of a polar group such as a —COOH group and an —OH group with a group that leaves by the action of an acid.

Examples of the polar group in the acid-decomposable group include a carboxyl group, an alcoholic hydroxyl group, a phenolic hydroxyl group, and a sulfonic acid group. Among these, the polar group is preferably a carboxyl group, an alcoholic hydroxyl group, or a phenolic hydroxyl group, and more preferably a carboxyl group or a phenolic hydroxyl group.

Examples of the group that leaves by decomposition by the action of an acid include groups represented by Formulae (Y1) to (Y4).

—C(Rₓ₁)(Rₓ₂)(Rₓ₃) Formula (Y1):

—C(═O)OC(Rₓ₁)(Rₓ₂)(Rₓ₃) Formula (Y2):

—C(R₃₆)(R₃₇)(OR₃₈) Formula (Y3):

—C(Rn)(H)(Ar) Formula (Y4):

In Formulae (Y1) and (Y2), Rₓ₁ to Rₓ₃ each independently represent an (linear or branched) alkyl group, or a (monocyclic or polycyclic) cycloalkyl group, provided that in a case where all of Rₓ₁ to Rₓ₃ are (linear or branched) alkyl groups, it is preferable that at least two of Rₓ₁, . . . , or Rₓ₃ are each a methyl group.

A repeating unit in which Rₓ₁ to Rₓ₃ each independently represent a linear or branched alkyl group is more preferable, and a repeating unit in which Rₓ₁ to Rₓ₃ each independently represent a linear alkyl group is still more preferable.

Two of Rₓ₁ to Rₓ₃ may be bonded to each other to form a monocycle or a polycycle.

The alkyl group of each of Rₓ₁ to Rₓ₃ is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group of each of Rₓ₁ to Rₓ₃ is preferably a monocyclic cycloalkyl group such as a cyclopentyl group and a cyclohexyl group, or a polycyclic cycloalkyl group such as a norbomyl group, a tetracyclodecanyl group, a tetracyclododecanyl group, and an adamantyl group.

The cycloalkyl group formed by the bonding of two of Rₓ₁ to Rₓ₃ is preferably a monocyclic cycloalkyl group such as a cyclopentyl group and a cyclohexyl group, or a polycyclic cycloalkyl group such as a norbomyl group, a tetracyclodecanyl group, a tetracyclododecanyl group, and an adamantyl group. A monocyclic cycloalkyl group having 5 or 6 carbon atoms is particularly preferable.

In the cycloalkyl group formed by the bonding of two of Rₓ₁ to Rₓ₃, for example, one of methylene groups constituting a ring may be substituted with a heteroatom such as an oxygen atom, or a group having a heteroatom, such as a carbonyl group.

In the repeating unit represented by General Formula (Y1) or (Y2), for example, Rₓ₁ is a methyl group or an ethyl group, and an aspect in which Rₓ₂ and Rₓ₃ are bonded to each other to form the above-mentioned cycloalkyl group is preferable.

In Formula (Y3), R₃₆ to R₃₈ each independently represent a hydrogen atom or a monovalent organic group. R₃₇ and R₃₈ may be bonded to each other to form a ring. Examples of the monovalent organic group include an alkyl group, a cycloalkyl group, an aryl group, an aralkyl group, and an alkenyl group. It is also preferable that R₃₆ is a hydrogen atom.

As the preferred Formula (Y3), a structure represented by General Formula (Y3-1) is more preferable.

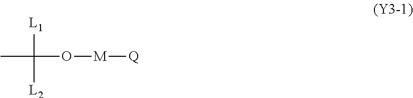

Here, L₁ and L₂ each independently represent a hydrogen atom, an alkyl group, a cycloalkyl group, an aryl group, or a group formed by a combination of an alkylene group with an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

It is preferable that at least one of L1 or L2 is a hydrogen atom, and at least one is an alkyl group, a cycloalkyl group, an aryl group, or a group formed by a combination of an alkylene group with an aryl group.

At least two of Q, M, or L₁ may be bonded to form a ring (preferably a 5- or 6-membered ring).

For the improvement of pattern collapse performance, L₂ is preferably a secondary or tertiary alkyl group, and more preferably a tertiary alkyl group. Examples of the secondary alkyl group include an isopropyl group, a cyclohexyl group, a norbomyl group, a tertiary alkyl group, a tert-butyl group, and an adamantane. In these aspects, Tg or activation energy increases, and therefore, it is possible to suppress fogging, while securing film hardness.

In Formula (Y4), Ar represents an aromatic ring group. Rn represents an alkyl group, a cycloalkyl group, or an aryl group. Rn and Ar may be bonded to each other to form a non-aromatic ring. Ar is more preferably an aryl group.

The group that leaves by the action of an acid is particularly preferably an acetal group or a tertiary ester group.

Examples of a base resin in a case where the acid-decomposable group is bonded as a side chain include a resin having an —OH or —COOH group. Examples of the resin having such a polar group include the resins which will be described later.

The alkali dissolution rate of these resins having a polar group is preferably 17 nm/sec or more, as measured in 0.261 N tetramethylammonium hydroxide (TMAH) (23° C.). The rate is particularly preferably 33 nm/sec or more.

From such a viewpoint, particularly preferred examples of the resin having a polar group include a resin including a hydroxystyrene structural unit, such as an o-, m- and p-poly(hydroxystyrene) as well as a copolymer thereof, hydrogenated poly(hydroxystyrene), halogen- or alkyl-substituted poly(hydroxystyrene), a partial O-alkylated or O-acylated poly(hydroxystyrene), a styrene hydroxystyrene copolymer, an α-methylstyrene hydroxystyrene copolymer and hydrogenated novolak resin; and a resin including a repeating unit containing a carboxyl group, such as (meth)acrylic acid and norbomenecarboxylic acid.

Preferred examples of the repeating unit having an acid-decomposable group include t-butoxycarbonyloxystyrene, 1-alkoxyethoxystyrene, and tertiary alkyl (meth)acrylate ester. As the repeating unit, 2-alkyl-2-adamantyl(meth)acrylate or dialkyl(1-adamantyl)methyl(meth)acrylate are more preferable.

The resin having a group that decomposes by the action of an acid to increase its polarity, as disclosed in EP254853B, JP1990-25850A (JP-H02-25850A), JP1991-223860A (JP-H03-223860A), and JP1992-251259A (JP-H04-251259A), or the like, is obtained by reacting a precursor of a group that leaves by the action of an acid with a resin, or by copolymerizing an alkali-soluble resin monomer having a polar group protected with a group that leaves by the action of an acid with various monomers.

In a case of irradiation with KrF excimer laser light, electron beams, X-rays, or high energy light beams at a wavelength of 50 nm or less (for example, EUV) in the actinic ray-sensitive or radiation-sensitive composition according to the second embodiment of the present invention, the resin (B) preferably includes a hydroxystyrene repeating unit. More preferably the resin (B) is a copolymer of hydroxystyrene and hydroxystyrene protected with a group that leaves by the action of an acid, or a copolymer of hydroxystyrene and tertiary alkyl (meth)acrylate ester.

As the repeating unit having an acid-decomposable group, a repeating unit represented by General Formula (AI) or (AII) is preferable.

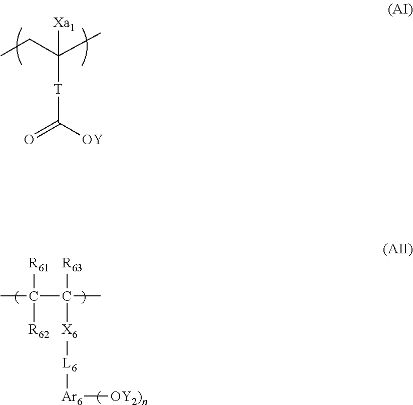

In General Formula (AI),

Xa₁ represents a hydrogen atom, or an alkyl group which may have a substituent.

T represents a single bond or a divalent linking group.

Y represents a group that leaves by an acid. Y is preferably represented by Formulae (Y1) to (Y4).

Examples of the alkyl group which may have a substituent, represented by Xₐ₁, include a methyl group or a group represented by —CH₂—R₁₁. R₁₁ represents a halogen atom (a fluorine atom or the like), a hydroxyl group, or a monovalent organic group, and examples thereof include an alkyl group having 5 or less carbon atoms and an acyl group having 5 or less carbon atoms. An alkyl group having 3 or less carbon atoms is preferable, and a methyl group is more preferable. In one aspect, Xa₁ is preferably a hydrogen atom, a methyl group, a trifluoromethyl group, or a hydroxymethyl group.

Examples of the divalent linking group of T include an alkylene group, a —COO-Rt- group, and an —O-Rt- group. In the formula, Rt represents an alkylene group or a cycloalkylene group.

T is preferably a single bond or a —COO-Rt- group. Rt is preferably an alkylene group having 1 to 5 carbon atoms, and more preferably a —CH₂— group, a —(CH₂)₂— group, or a —(CH₂)₃— group.

In General Formula (AII),

R₆₁, R₆₂, and R₆₃ each independently represent a hydrogen atom, an alkyl group, a cycloalkyl group, a halogen atom, a cyano group, or an alkoxycarbonyl group, provided that R₆₂ may be bonded to Ar₆ to form a ring, and R₆₂ in this case represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents a sing an (n+1)-valent aromatic ring group, and in a case where Ar₆ is bonded to R₆₂ to form a ring, it represents an (n+2)-valent aromatic ring group.

In a case of n>2, Y₂'s each independently represent a hydrogen atom or a group that leaves by the action of an acid, provided that at least one of Y₂'s represents a group that leaves by the action of an acid. The group that leaves by the action of an acid as Y₂ is preferably represented by each of Formulae (Y1) to (Y4).

n represents an integer of 1 to 4.

Each of the groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having carbon atoms 2 to 6), each of which preferably 8 or less carbon atoms.

The repeating unit represented by General Formula (AI) is preferably an acid-decomposable (meth)acrylic acid tertiary alkyl ester-based repeating unit (the repeating unit in which Xa₁ represents a hydrogen atom or a methyl group, and T represents a single bond).

More preferred examples of the resin (B) include a resin having a repeating unit represented by General Formula (A) as the repeating unit including an acid-decomposable group. By using a resin including the repeating unit, the dry etching resistance of the formed pattern is enhanced.

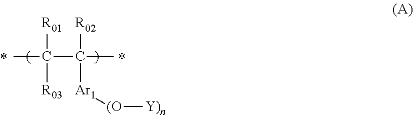

In the formula, R₀₁, R₀₂, and R₀₃ each independently represent, for example, a hydrogen atom, an alkyl group, a cycloalkyl group, a halogen atom, a cyano group, or an alkoxycarbonyl group. Ar₁ represents, for example, an aromatic ring group. Alternatively, R₀₃ and Ar₁ may each be an alkylene group, and they may bonded to each other to form a 5- or 6-membered ring, together with a —C—C— chain.

n Y's each independently represent a hydrogen atom or a group that leaves by the action of an acid, provided that at least one of Y's represents a group that leaves by the action of an acid.

n represents an integer of 1 to 4, and is preferably 1 to 2, and more preferably 1.

The alkyl group of each of R₀₁ to R₀₃ is, for example, an alkyl group having 20 or less carbon atoms, and preferably a methyl group, an ethyl group, a propyl group, an isopropyl group, an n-butyl group, a sec-butyl group, a hexyl group, a 2-ethylhexyl group, an octyl group, or a dodecyl group, and more preferably an alkyl group having 8 or less carbon atoms. Further, these alkyl groups may have a substituent.

Preferred examples of the alkyl group included in an alkoxycarbonyl group are the same ones as the alkyl group in R₀₁ to R₀₃.

The cycloalkyl group may be a monocyclic cycloalkyl group or a polycyclic cycloalkyl group. Preferred examples thereof include a monocyclic cycloalkyl group having 3 to 8 carbon atoms, such as a cyclopropyl group, a cyclopentyl group, and a cyclohexyl group. Further, these cycloalkyl groups may have a substituent.

Examples of the halogen atom include a fluorine atom, a chlorine atom, a bromine atom and an iodine atom, with the fluorine atom being more preferable.

In a case where R₀₃ represents an alkylene group, preferred examples of the alkylene group include an alkylene group having 1 to 8 carbon atoms, such as a methylene group, an ethylene group, a propylene group, a butylene group, a hexylene group, and an octylene group.

The aromatic ring group as Ar₁ preferably has 6 to 14 carbon atoms, and examples thereof include a benzene ring, a toluene ring, and a naphthalene ring. Further, these aromatic ring groups may have a substituent.

Examples of the group Y that leaves by the action of an acid include groups represented by —C(R³⁶)(R³⁷)(R³⁸), —C(═O)—O—C(R³⁶)(R³⁷)(R³⁸), —C(R⁰¹)(R⁰²)(OR³⁹), —C(R⁰¹)(R⁰²)—C(═O)—O—C(R³⁶)(R³⁷)(R³⁸), and —CH(R³⁶)(Ar).

In the formulae, R³⁶ to R³⁹ each independently represent an alkyl group, a cycloalkyl group, an aryl group, an aralkyl group, or an alkenyl group. R³⁶ and R³⁷ may be bonded to each other to form a ring structure.

R⁰¹ and R⁰² each independently represent a hydrogen atom, an alkyl group, a cycloalkyl group, an aryl group, an aralkyl group, or an alkenyl group.

Ar represents an aryl group.

The alkyl group as R³⁶ to R³⁹, R⁰¹, or R⁰² is preferably an alkyl group having 1 to 8 carbon atoms, and examples thereof include a methyl group, an ethyl group, a propyl group, an n-butyl group, a sec-butyl group, a hexyl group, and an octyl group.

The cycloalkyl group as R³⁶ to R³⁹, R⁰¹, or R⁰² may be a monocyclic cycloalkyl group or a polycyclic cycloalkyl group. The monocyclic cycloalkyl group is preferably a cycloalkyl group having 3 to 8 carbon atoms, and examples thereof include a cyclopropyl group, a cyclobutyl group, a cyclopentyl group, a cyclohexyl group, and a cyclooctyl group. The polycyclic cycloalkyl group is preferably a cycloalkyl group having 6 to 20 carbon atoms, and examples thereof include an adamantyl group, a norbomyl group, an isobornyl group, a camphanyl group, a dicyclopentyl group, an α-pinen group, a tricyclodecanyl group, a tetracyclododecyl group, and an androstanyl group. In addition, some of the carbon atoms in the cycloalkyl group may be substituted with heteroatoms such as an oxygen atom.

The aryl group as R³⁶ to R³⁹, R⁰¹, R⁰², or Ar is preferably an aryl group having 6 to 10 carbon atoms, and examples thereof include a phenyl group, a naphthyl group, and an anthryl group.

The aralkyl group as R³⁶ to R³⁹, R⁰¹, or R⁰² is preferably an aralkyl group having 7 to 12 carbon atoms, and examples thereof include a benzyl group, a phenethyl group, and a naphthylmethyl group.

The alkenyl group as R³⁶ to R³⁹, R⁰¹, or R⁰² is preferably an alkenyl group having 2 to 8 carbon atoms, and examples thereof include a vinyl group, an allyl group, a butenyl group, and a cyclohexenyl group.

A ring which can be formed by the mutual bonding of R³⁶ and R³⁷ may be a monocyclic type or a polycyclic type. The monocyclic type is preferably a cycloalkane structure having 3 to 8 carbon atoms, and examples thereof include a cyclopropane structure, a cyclobutane structure, a cyclopentane structure, a cyclo hexane structure, a cycloheptane structure, and a cyclooctane structure. The polycyclic type is preferably a cycloalkane structure having 6 to 20 carbon atoms, and examples thereof include an adamantane structure, a norbornane structure, a dicyclopentane structure, a tricyclodecane structure, and a tetracyclododecane structure. Moreover, some of carbon atoms in the ring structure may be substituted with heteroatoms such as oxygen atoms.

Each of the groups may have a substituent. Examples of the substituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxy carbonyl group, a cyano group, and a nitro group. These substituents preferably have 8 or less carbon atoms.

As the group Y that leaves by the action of an acid, a structure represented by General Formula (B) is more preferable.

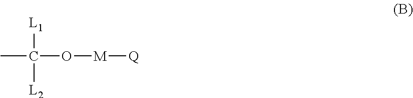

In the formula, Li and L₂ each independently represent a hydrogen atom, an alkyl group, a cycloalkyl group, an aryl group, or an aralkyl group.

M represents a single bond or a divalent linking group.

Q represents an alkyl group, a cycloalkyl group, a cyclic aliphatic group, an aromatic ring group, an amino group, ammonium group, a mercapto group, a cyano group, or an aldehyde group. Further, these cyclic aliphatic groups and aromatic ring groups may contain heteroatoms.

In addition, at least two of Q, M, or Li may be bonded to each other to form a 5- or 6-membered ring.

The alkyl group as each of Li and L₂ is, for example, an alkyl group having 1 to 8 carbon atoms, and specific examples thereof include a methyl group, an ethyl group, a propyl group, an isopropyl group, an n-butyl group, a sec-butyl group, a t-butyl group, a hexyl group, and an octyl group.

The cycloalkyl group as each of Li and L₂ is, for example, a cycloalkyl group having 3 to 15 carbon atoms, and specific examples thereof include a cyclopentyl group, a cyclohexyl group, a norbomyl group, and an adamantyl group.

The aryl group as each of Li and L₂ is, for example, an aryl group having 6 to 15 carbon atoms, and specific examples thereof include a phenyl group, a tolyl group, a naphthyl group, and an anthryl group.

The aralkyl group as each of Li and L₂ is, for example, an aralkyl group having 6 to 20 carbon atoms, and specific examples thereof include a benzyl group and a phenethyl group.

The divalent linking group as M is, for example, an alkylene group (for example, a methylene group, an ethylene group, a propylene group, a butylene group, a hexylene group, and an octylene group), a cycloalkylene group (for example, a cyclopentylene group and a cyclohexylene group), an alkenylene group (for example, an ethylene group, a propenylene group, and a butenylene group), an arylene group (for example, a phenylene group, a tolylene group, and a naphthylene group), —S—, —O—, —CO—, —SO₂—, —N(R₀)—, or a combination of two or more thereof. Here, R₀ is a hydrogen atom or an alkyl group. The alkyl group of R₀ is an alkyl group having 1 to 8 carbon atoms, and specific examples thereof include a methyl group, an ethyl group, a propyl group, an n-butyl group, a sec-butyl group, a hexyl group, and an octyl group.

The alkyl group and the cycloalkyl group as Q are the same as each of the above-mentioned groups as L₁ and L₂.

Examples of the cyclic aliphatic group or the aromatic ring group as Q include the above-mentioned cycloalkyl group and aryl group as L₁ and L₂. These cycloalkyl groups and aryl groups are each preferably groups having 3 to 15 carbon atoms.

Examples of the cyclic aliphatic group or aromatic ring group containing a heteroatom as Q include groups having a heterocyclic ring structure, such as thiirane, cyclothiorane, thiophene, furan, pyrrole, benzothiophene, benzofuran, benzopyrrole, triazine, imidazole, benzimidazole, triazole, thiadiazole, thiazole, and pyrrolidone, provided that if the ring is formed by carbon and a heteroatom or the ring is formed by a heteroatom singly, there is no limitation thereto.

Examples of a ring structure formed by the mutual bonding of at least two of Q, M, or Li include a 5- or 6-membered ring structures formed of a propylene group or a butylene group. In addition, the 5- or 6-membered ring structure contains an oxygen atom.

Each of the groups represented by L₁, L₂, M, and Q may have a substituent. Examples of the substituent include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. These substituents preferably have 8 or less carbon atoms.

The group represented by -(M-Q) is preferably a group having 1 to 30 carbon atoms, and more preferably a group having 5 to 20 carbon atoms. In particular, from the viewpoint of suppressing outgas, a group having 6 or more carbon atoms is preferable.

The acid-decomposable resin may be a resin having a repeating unit represented by General Formula (X) as the repeating unit having an acid-decomposable group.

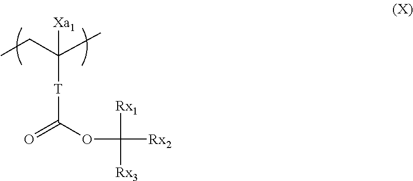

In General Formula (X),

Xa₁ represents a hydrogen atom, a methyl group, a trifluoromethyl group, or a hydroxymethyl group.

T represents a single bond or a divalent linking group.

Rₓ₁ to Rₓ₃ each independently represent a linear or branched alkyl group, or a monocyclic or polycyclic cycloalkyl group. Further, two of Rₓ₁ to Rₓ₃ may be bonded to each other to form a monocyclic or polycyclic cycloalkyl group.

Examples of the divalent linking group of T include an alkylene group, a —(COO-Rt)- group, and an —(O-Rt)- group. Here, Rt represents an alkylene group or a cycloalkylene group.

T is preferably a single bond or a —(COO-Rt)- group. Rt is preferably an alkylene group having 1 to 5 carbon atoms, and more preferably a —CH₂— group or a —(CH₂)₃— group.

The alkyl group as each of Rₓ₁ to Rₓ₃ is preferably an alkyl group having 1 to 4 carbon atoms, such as a methyl group, an ethyl group, an n-propyl group, an isopropyl group, an n-butyl group, an isobutyl group, and a t-butyl group.

The cycloalkyl group as each of Rₓ₁ to Rₓ₃ is preferably a monocyclic cycloalkyl group such as a cyclopentyl group and a cyclohexyl group, or a polycyclic cycloalkyl group such as a norbomyl group, a tetracyclodecanyl group, a tetracyclododecanyl group, and an adamantyl group.

The cycloalkyl group formed by the mutual bonding of two of Rₓ₁ to Rₓ₃ is preferably a monocyclic cycloalkyl group such as a cyclopentyl group and a cyclohexyl group, or a polycyclic cycloalkyl group such as a norbomyl group, a tetracyclodecanyl group, a tetracyclododecanyl group, and an adamantyl group.

In particular, an aspect, in which Rₓ₁ is a methyl group or an ethyl group, and Rₓ₂ and Rₓ₃ are bonded to each other to form the above-mentioned cycloalkyl group, is preferable.

Specific suitable examples of the repeating unit having an acid-decomposable group are shown below, but the present invention is not limited thereto.

In the specific examples, Rx represents a hydrogen atom, CH₃, CF₃, or CH₂OH. Rxa and Rxb each represent an alkyl group having 1 to 4 carbon atoms. Z represents a substituent containing a polar group, and in a case where a plurality of z's are present, they are each independent. p represents 0 or a positive integer. Examples of the substituent containing a polar group represented by Z include a linear or branched alkyl group and a cycloalkyl group, having a hydroxyl group, a cyano group, an amino group, an alkylamido group, or a sulfonamido group, and the substituent is preferably an alkyl group having a hydroxyl group. As the branched alkyl group, an isopropyl group is particularly preferable.

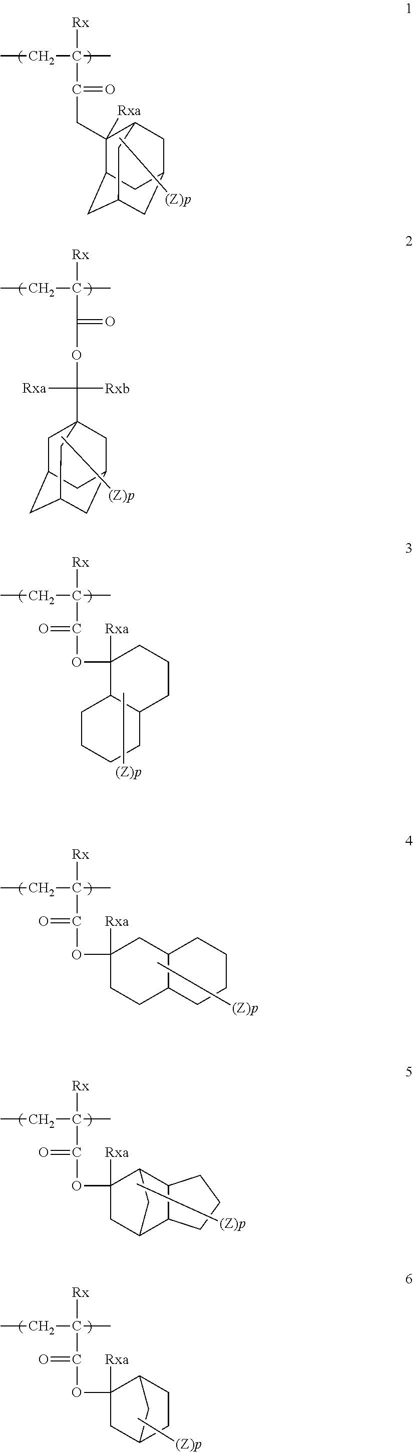

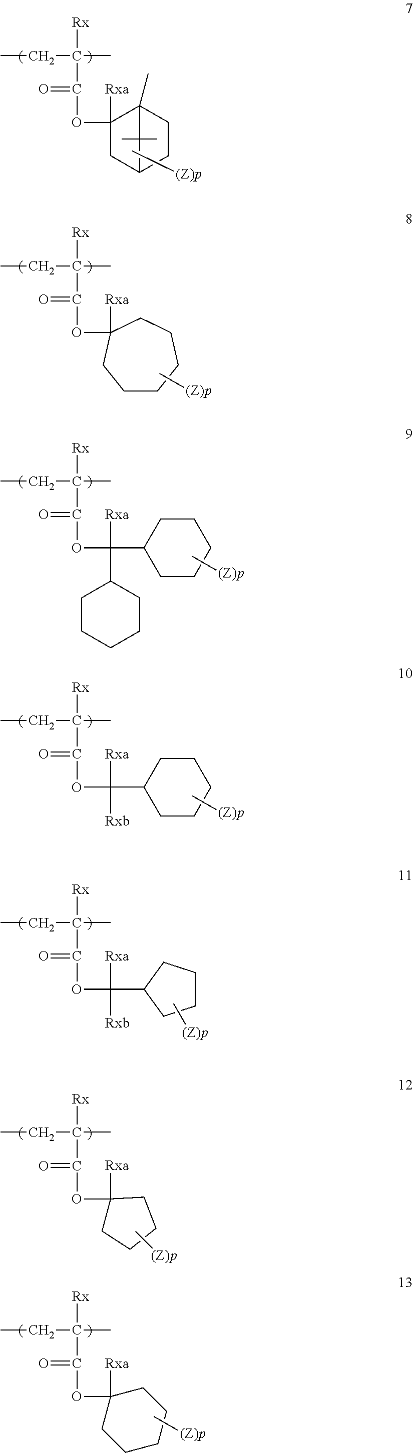

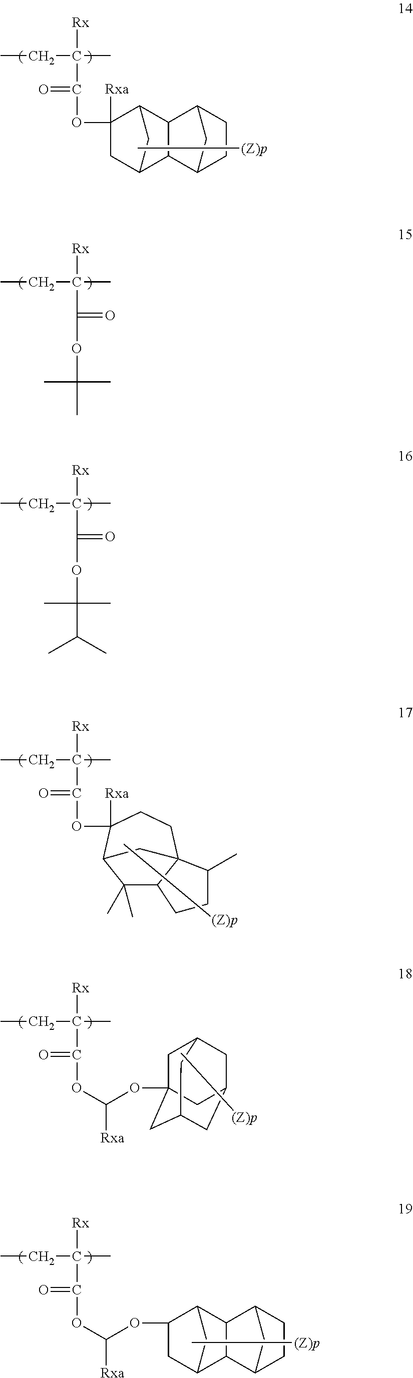

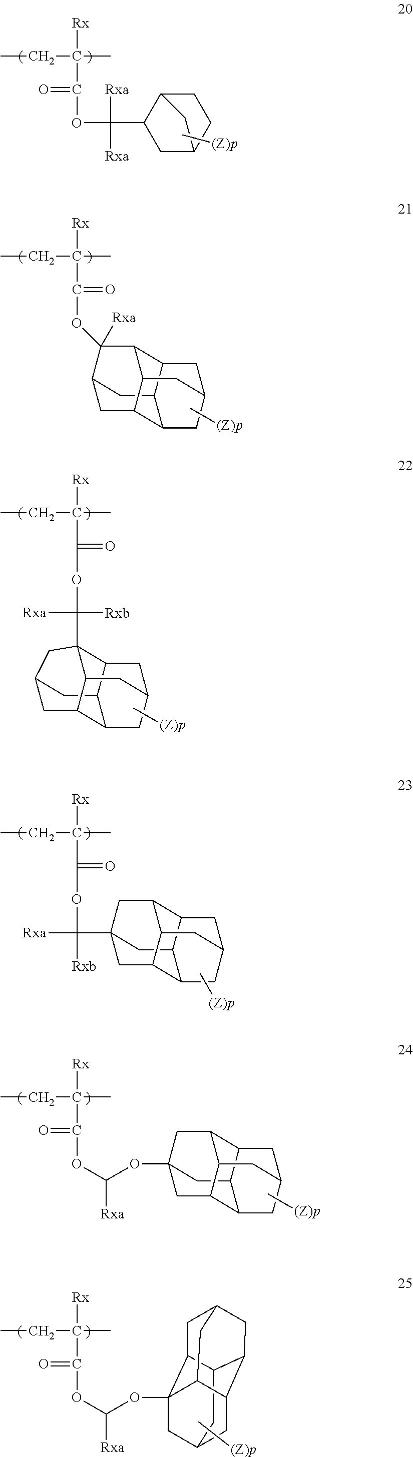

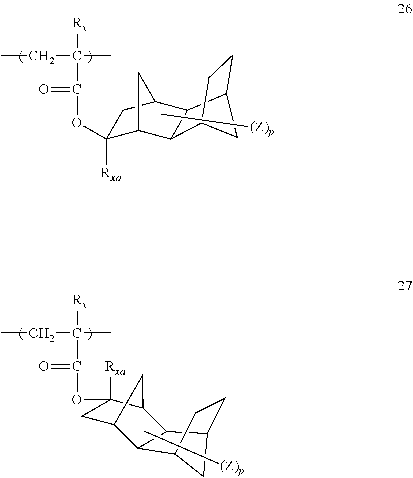

In one aspect of the present invention, the resin (B) preferably has a phenolic hydroxyl group. Here, the phenolic hydroxyl group is a group resulting from substitution of a hydrogen atom of an aromatic ring group with a hydroxy group. The aromatic ring of the aromatic ring group is a monocyclic or polycyclic aromatic ring, and examples thereof include a benzene ring and a naphthalene ring.

In a case where the resin (B) of the present invention is a resin having a phenolic hydroxyl group, the resin is preferably a resin having a repeating unit containing a phenolic hydroxyl group, and specific examples and preferred examples of the repeating unit containing a phenolic hydroxyl group include those described for the resin (C) having a phenolic hydroxyl group in the first embodiment.

The content of the repeating unit containing a phenolic hydroxyl group is preferably 10% to 98% by mole, more preferably 20% to 95% by mole, and still more preferably 20% to 90% by mole, with respect to all the repeating units in the resin (B).

Furthermore, in the same manner as in the resin (C) described in the first embodiment, the resin (B) is a group having a non-acid-decomposable polycyclic alicyclic hydrocarbon structure, and it preferably has a structure in which a hydrogen atom in the phenolic hydroxyl group is substituted in a view of obtaining a high glass transition temperature (Tg) and higher dry etching resistance. The details of this structure, the preferred content ranges of the repeating units having the structure with respect to all the repeating units of the resin, and the like are the same as those described for the resin (C) in the first embodiment.

The resin (B) preferably further includes the repeating units as described below (hereinafter also referred to as “other repeating units”) as a repeating unit other than the above repeating units.

Examples of a polymerizable monomer for forming these other repeating units include styrene, an alkyl-substituted styrene, an alkoxy-substituted styrene, a halogen-substituted styrene, an O-alkylated styrene, an O-acylated styrene, hydrogenated hydroxystyrene, maleic acid anhydride, an acrylic acid derivative (acrylic acid, an acrylic acid ester, or the like), a methacrylic acid derivative (methacrylic acid, a methacrylic acid ester, or the like), an N-substituted maleimide, acrylonitrile, methacrylonitrile, vinylnaphthalene, vinylanthracene, and indene which may has a substituent.

The resin (B) may or may not contain these other repeating units; however, in a case where contained, the content of these other repeating units in the resin (B) with respect to all the repeating units constituting the resin (B) is generally 1% to 30% by mole, preferably 1% to 20% by mole, and more preferably 2% to 10% by mole.

The resin (B) can be synthesized by a known radical polymerization method, anion polymerization method or a living radical polymerization method (iniferter method or the like). For example, in the anion polymerization method, a polymer can be obtained by dissolving a vinyl monomer in an appropriate organic solvent, and causing the vinyl monomer to react, usually under cooling conditions, by using a metal compound (butyllithium or the like) as an initiator.

As the resin (B), a polyphenol compound produced by a condensation reaction between an aromatic ketone or an aromatic aldehyde, and a compound containing 1 to 3 phenolic hydroxyl groups (for example, JP2008-145539A), a calixarene derivative (for example, JP2004-18421A), a Noria derivative (for example, JP2009-222920A), a polyphenol derivative (for example, JP2008-94782A) can also be applied, and the resin (B) may also be synthesized by modifying these compounds by polymer reactions.

The content of the repeating unit having an acid-decomposable group in the acid-decomposable resin (a total content when a plurality of kinds thereof are include) is in a range of preferably 3% to 90% by mole, more preferably 5% to 80% by mole, and particularly preferably 7% to 70% by mole, with respect to all the repeating units in the acid-decomposable resin.

Moreover, it is also preferable that the resin (B) contains the repeating unit having a silicon atom in the side chain, described in the resin (C).

The resin (B) may have the repeating unit having a silicon atom in the side chain singly or in combination of two or more kinds thereof.

The content of the repeating unit having a silicon atom in the side chain is preferably 1% to 30% by mole, more preferably 1% to 20% by mole, and still more preferably 1% to 10% by mole, with respect to all the repeating units in the resin (B).

Moreover, in the present specification, the repeating unit having a silicon atom and an acid-decomposable group also corresponds to a repeating unit having a silicon atom as well as a repeating unit having an acid-decomposable group.

The resin (B) may have a repeating unit including an ionic structural site that decomposes upon irradiation with actinic rays or radiation to generate an acid in the side chain of the resin. Examples of such a repeating unit include a repeating unit represented by General Formula (4).

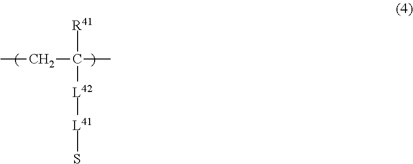

R⁴¹ represents a hydrogen atom or a methyl group. L⁴¹ represents a single bond or a divalent linking group. L⁴² represents a divalent linking group. S represents an ionic structural site that decomposes upon irradiation with actinic rays or radiation to generate an acid in the side chain.

Specific examples of the resin (B) as the acid-decomposable resin, described above, are shown below, but the present invention is not limited thereto.

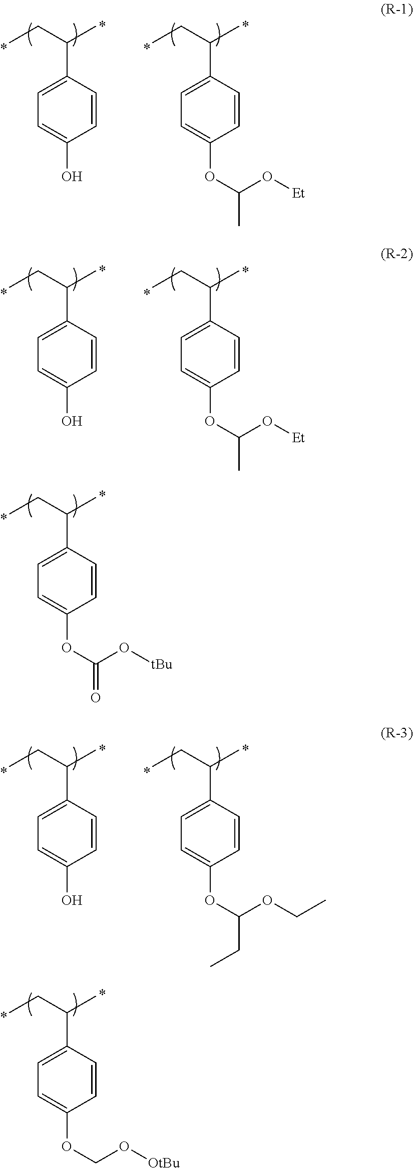

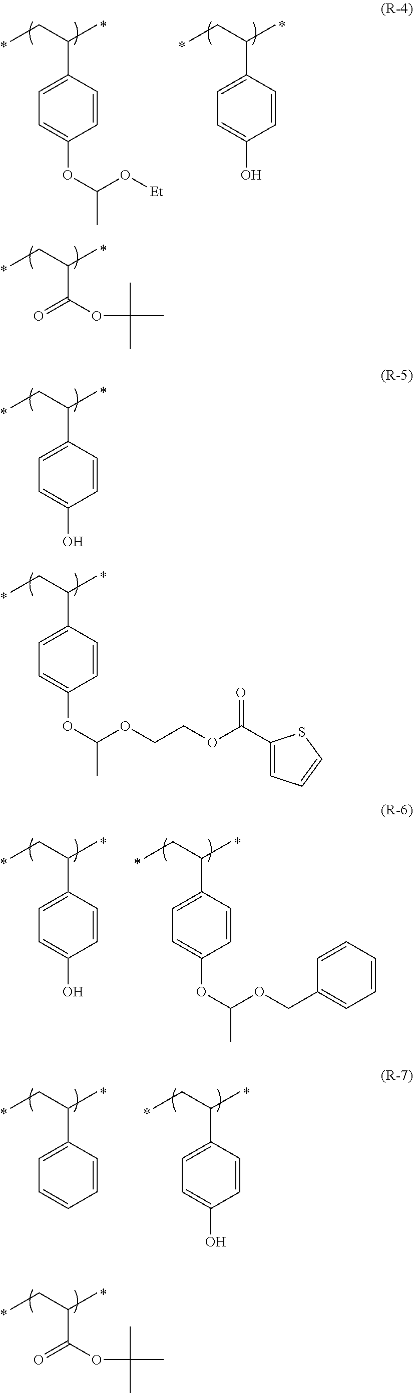

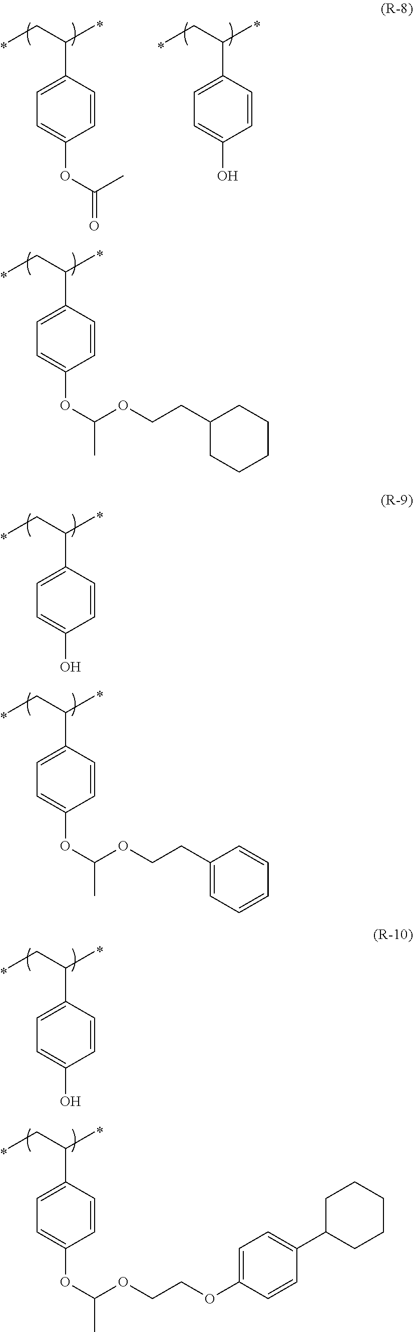

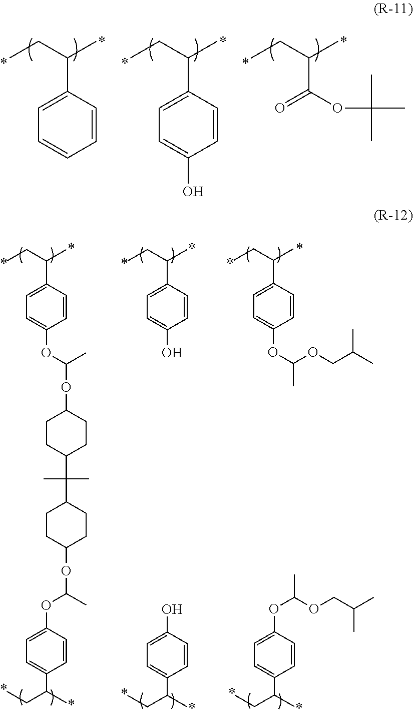

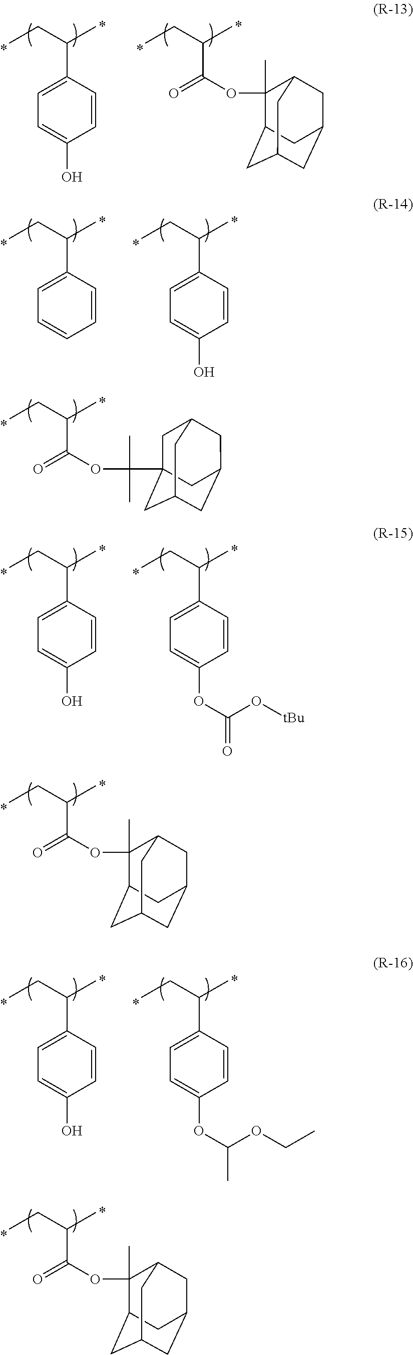

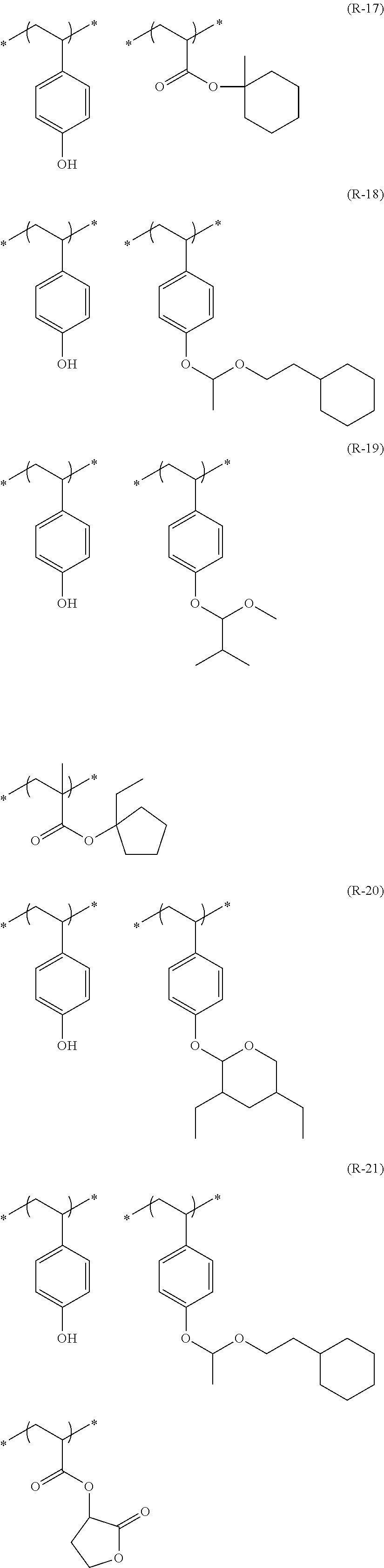

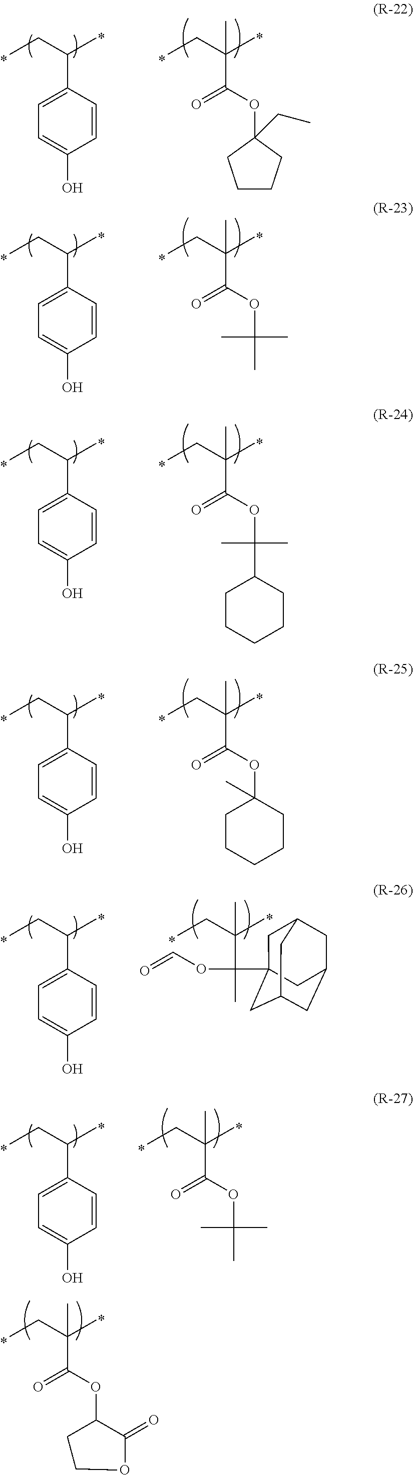

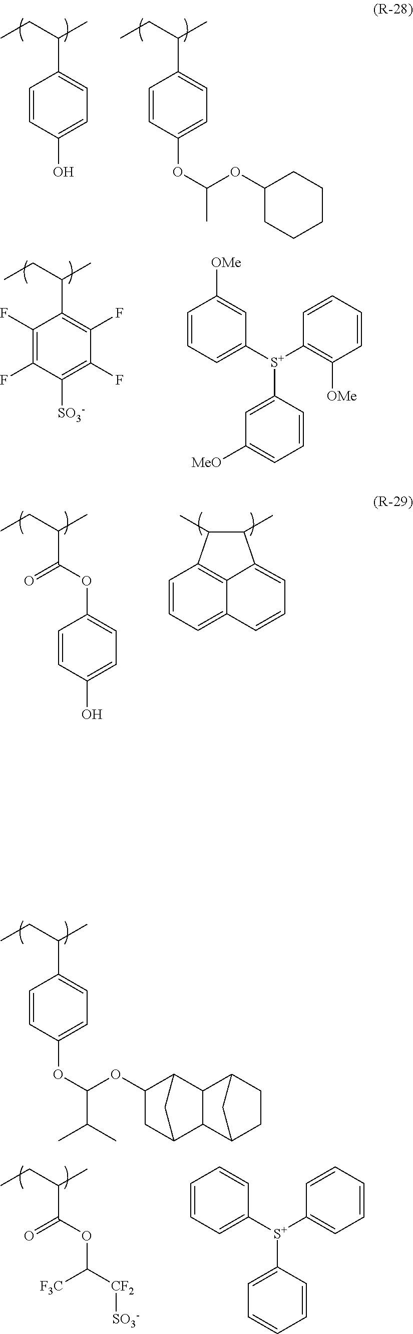

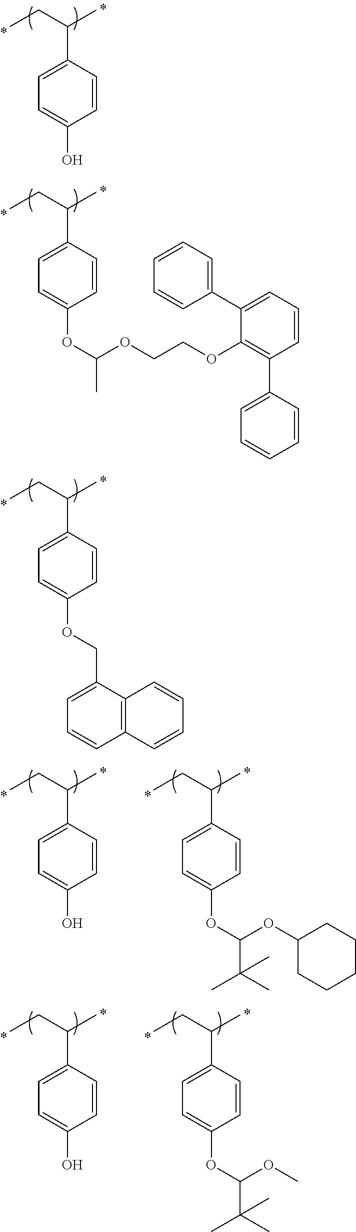

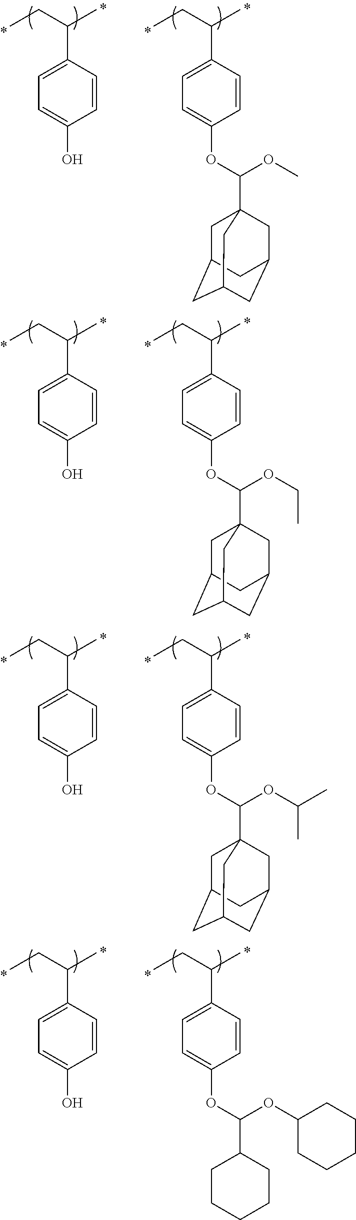

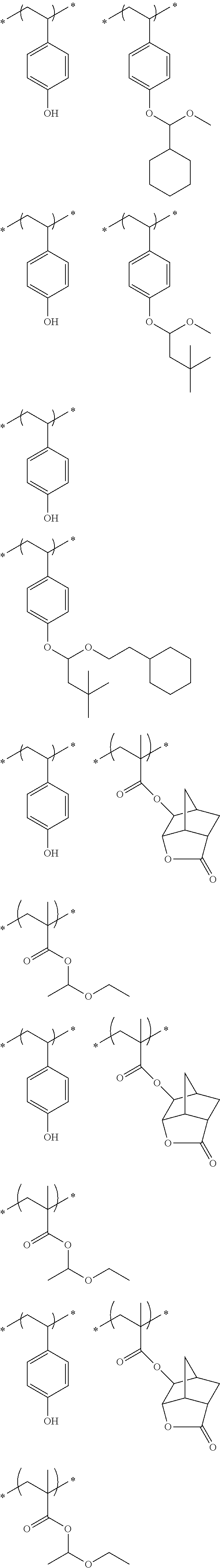

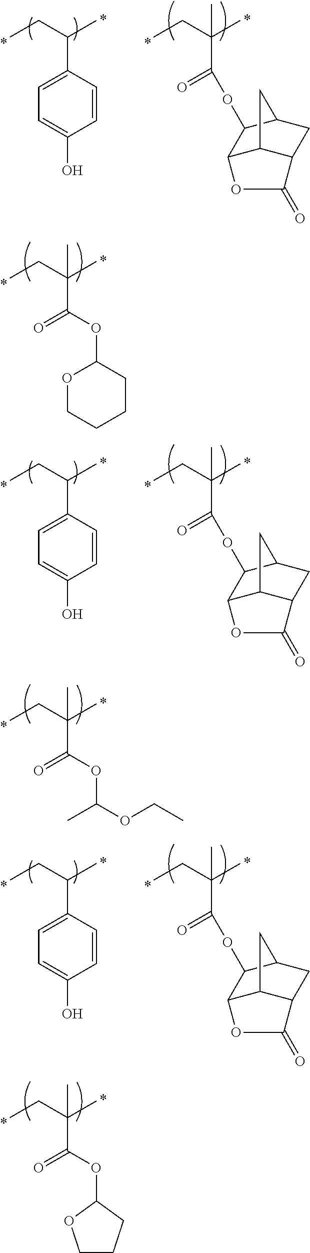

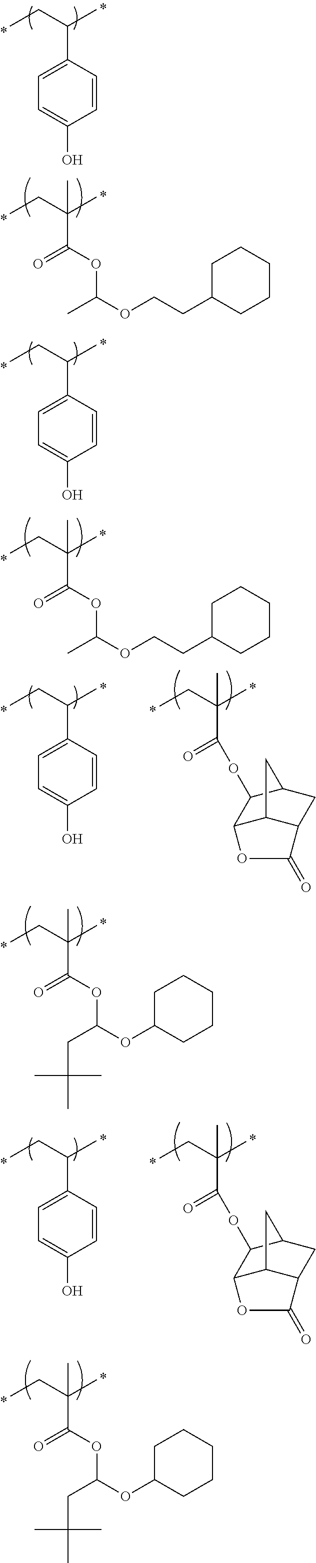

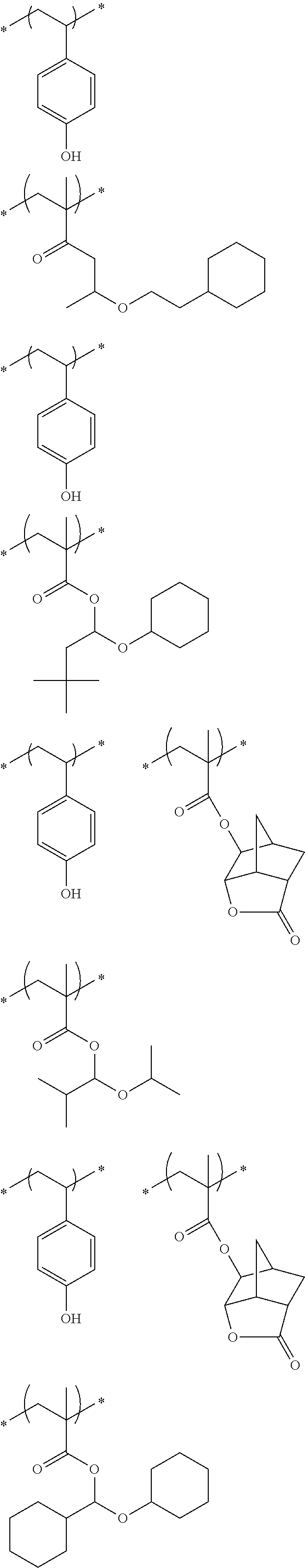

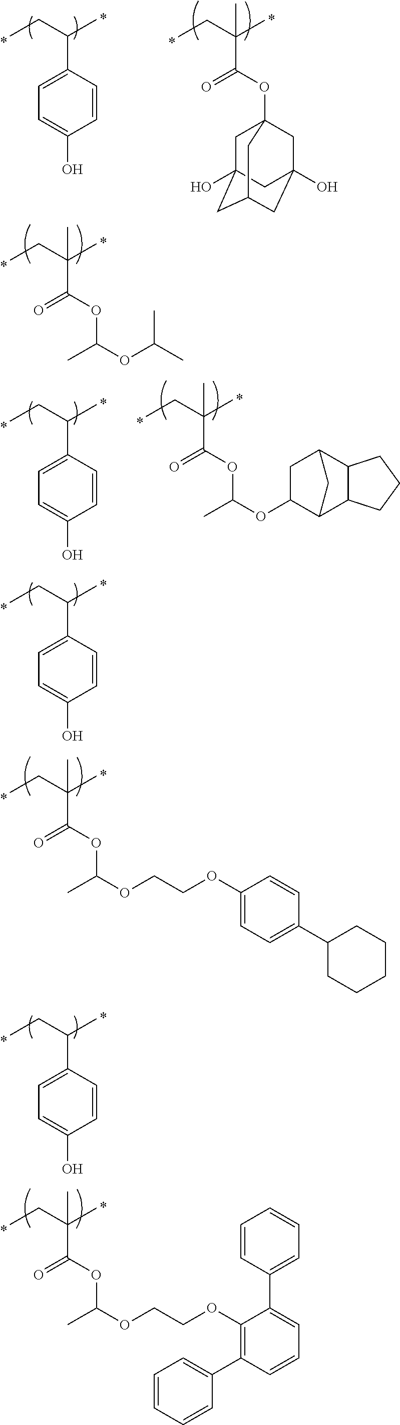

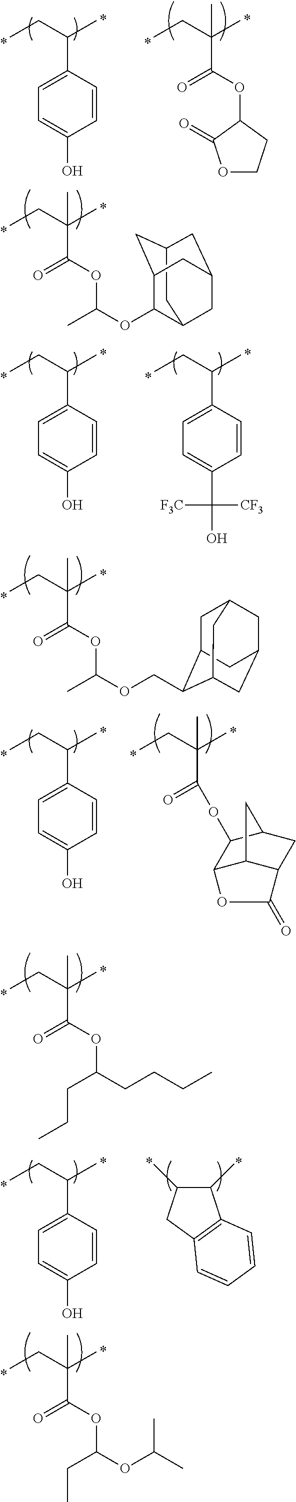

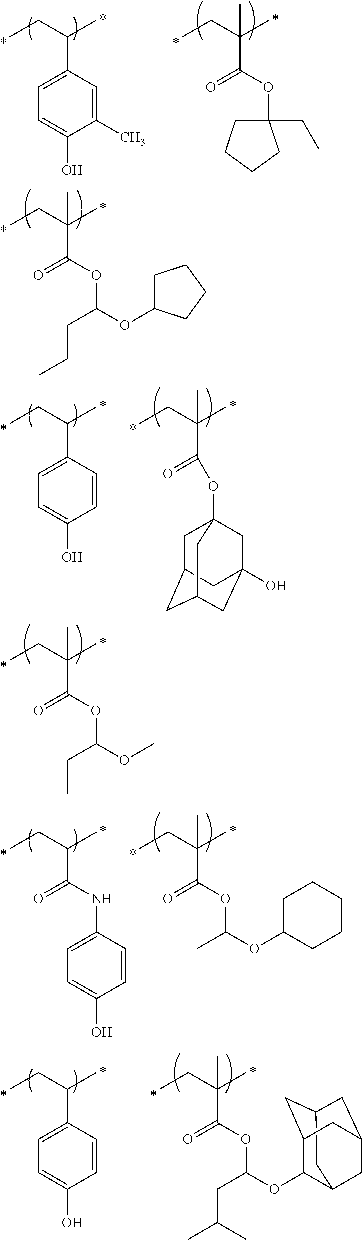

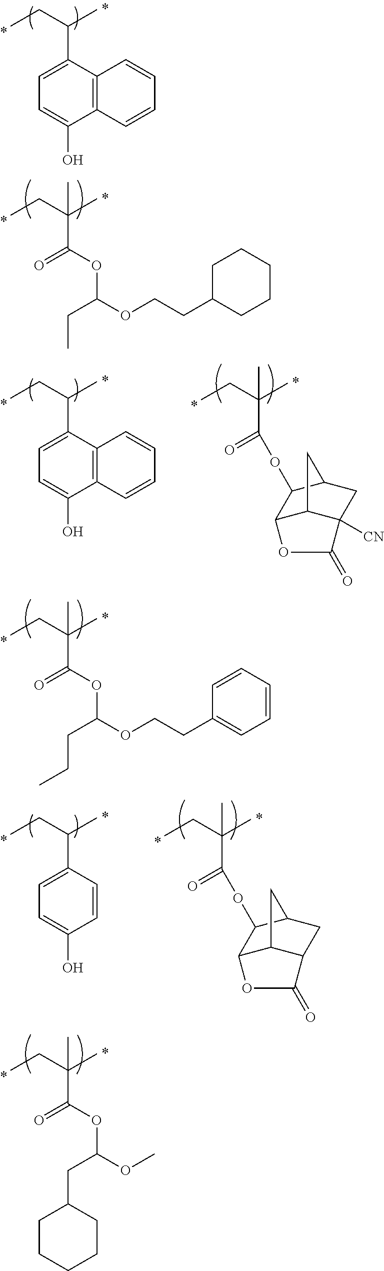

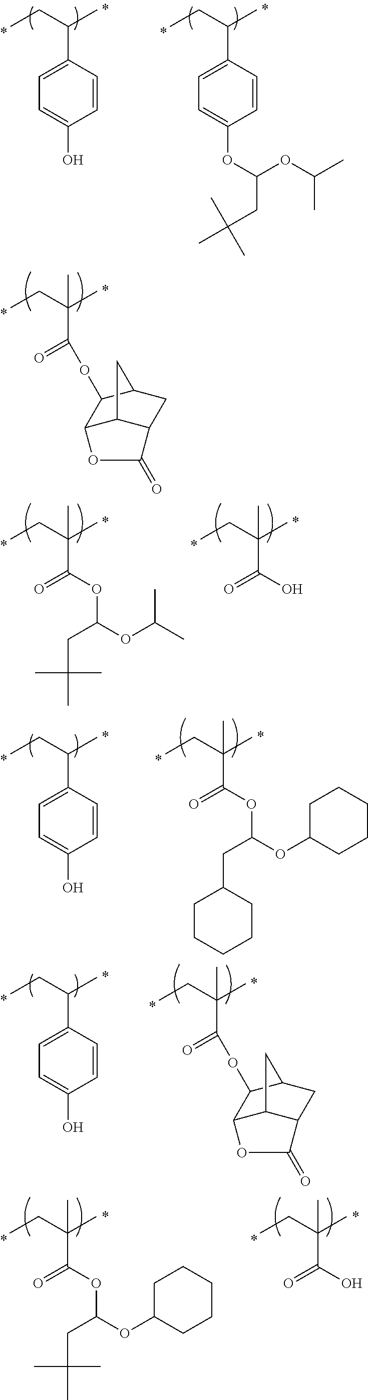

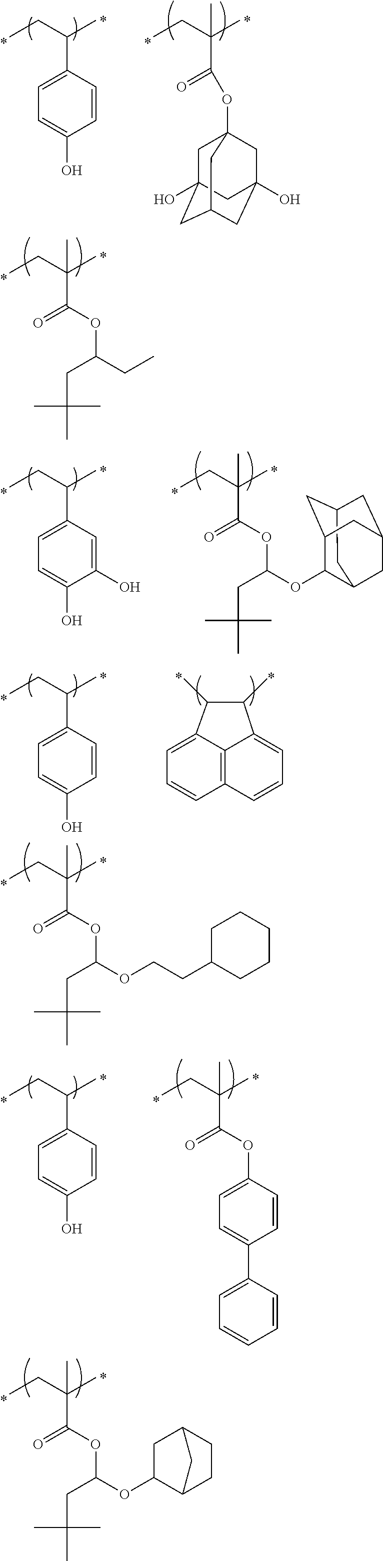

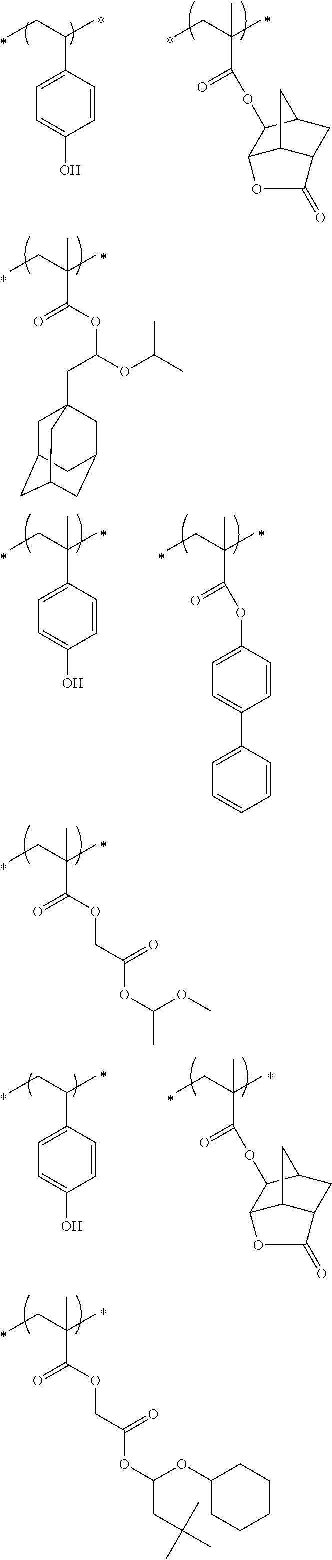

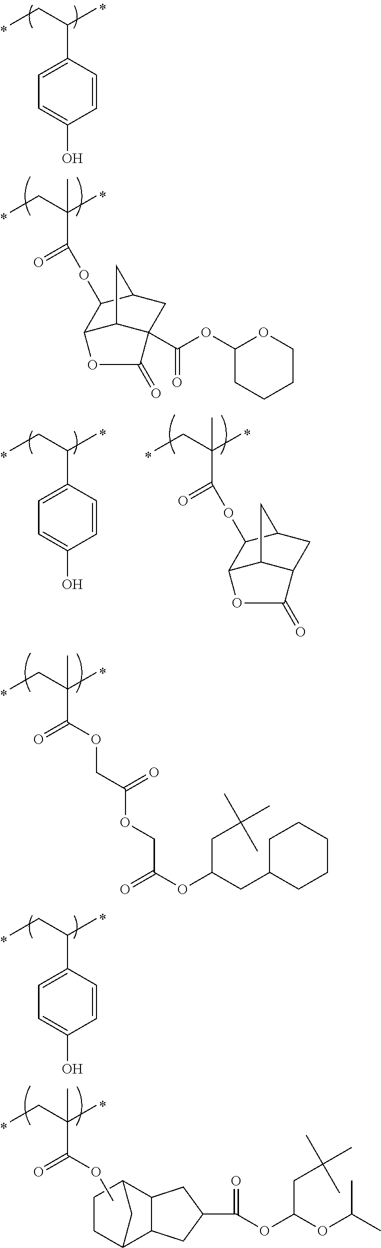

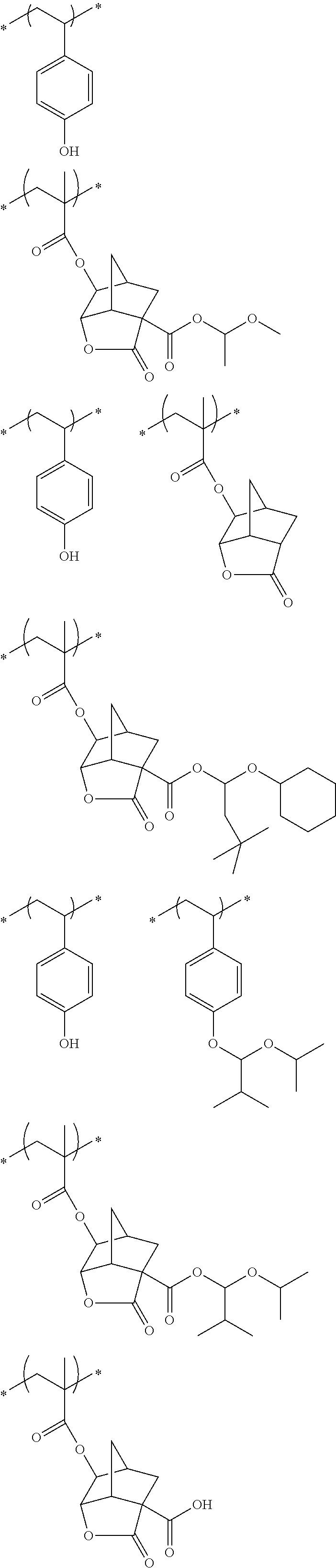

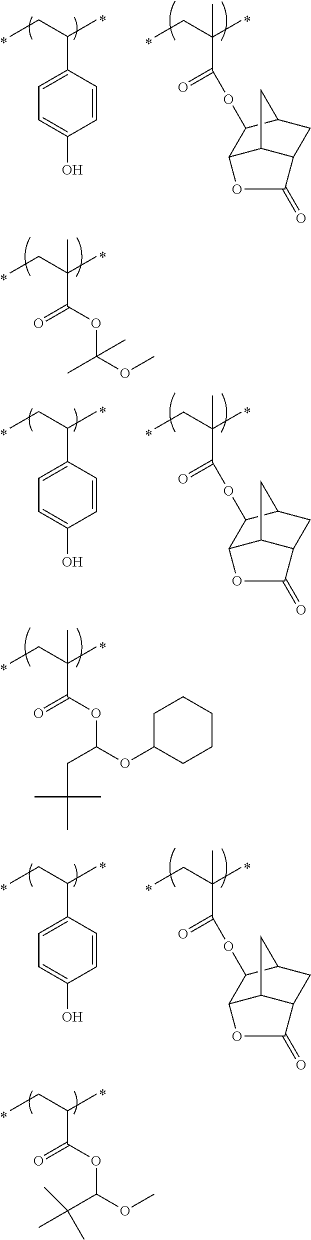

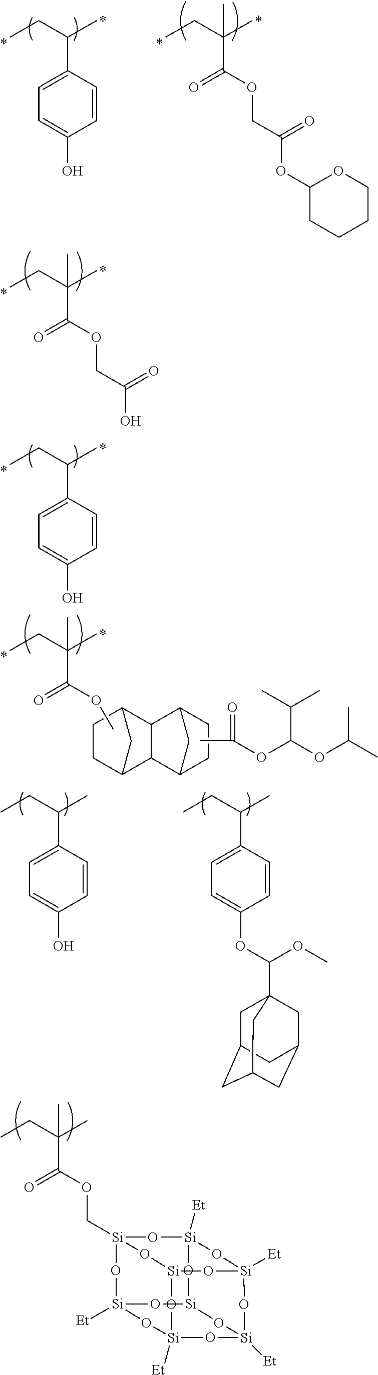

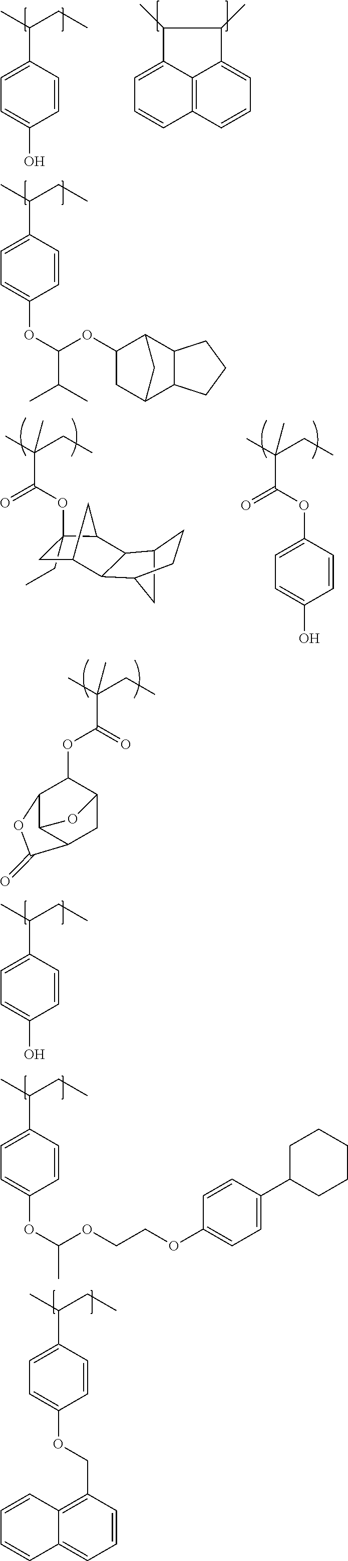

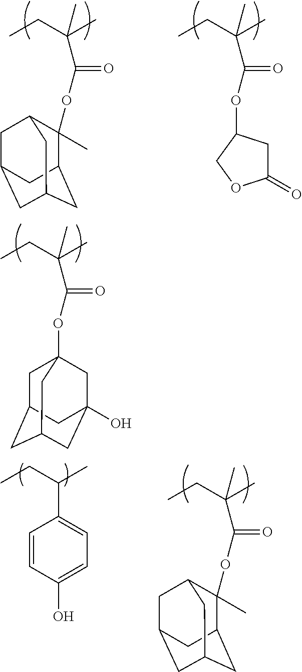

In the specific examples, tBu represents a t-butyl group. The content ratio of the group decomposable by an acid is calculated by Formula B/(B+S) according to the number (B) of groups decomposable by an acid in the resin and the number (S) of alkali-soluble groups not protected by a group leaving by an acid. This content ratio is preferably 0.01 to 0.7, more preferably 0.05 to 0.50, and still more preferably 0.05 to 0.40.

The resin (B) may include a monocyclic or polycyclic alicyclic hydrocarbon structure. In particular, in a case where the composition of the present invention is irradiated with ArF excimer laser light, it is preferable that the composition includes such an alicyclic hydrocarbon structure is preferable.

The resin (B) may include a repeating unit including at least one selected from a lactone group and a sultone group. In particular, in a case where the composition of the present invention is irradiated with ArF excimer laser light, including a repeating unit including at least one selected from a lactone group and a sultone group is preferable. The lactone group is preferably a group including a 5- to 7-membered ring lactone structure, and in particular, another ring structure is fused in the form of forming a bicyclo structure or a spiro structure in a 5- to 7-membered ring lactone structure.

Moreover, in the repeating unit including a lactone structure, an optical isomer is usually present, but any optical isomer may be used. In addition, one optical isomer may be used singly or a mixture of a plurality of optical isomers may be used. In a case where one optical isomer is mainly used, the optical purity thereof is preferably 90% ee or more, and more preferably 95% ee or more.

Particularly preferred examples of the repeating unit including a lactone group include the following repeating units. By selecting the optimal lactone group, the pattern profile and density dependency are improved. In the Formulae, Rx and R represent H, CH₃, CH₂OH, or CF₃.

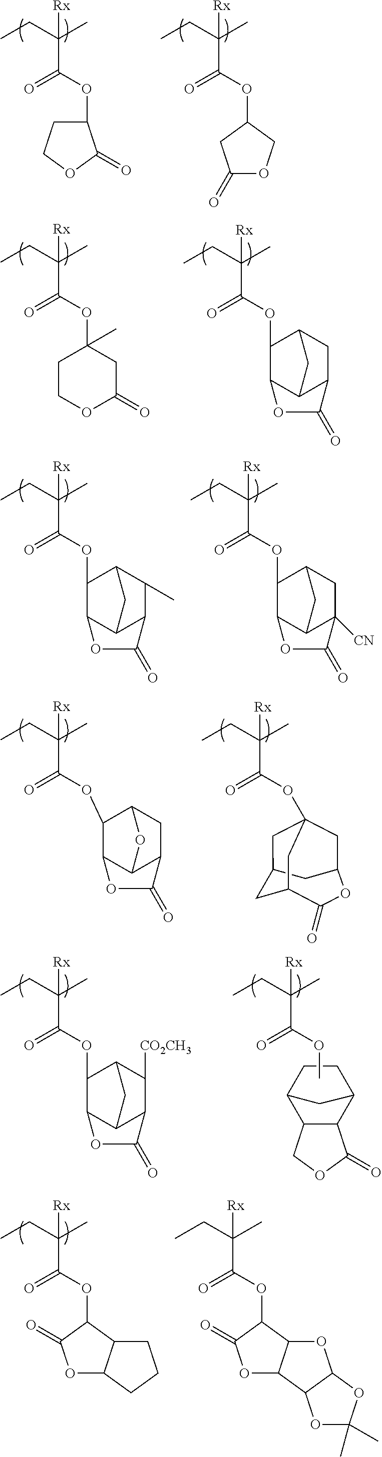

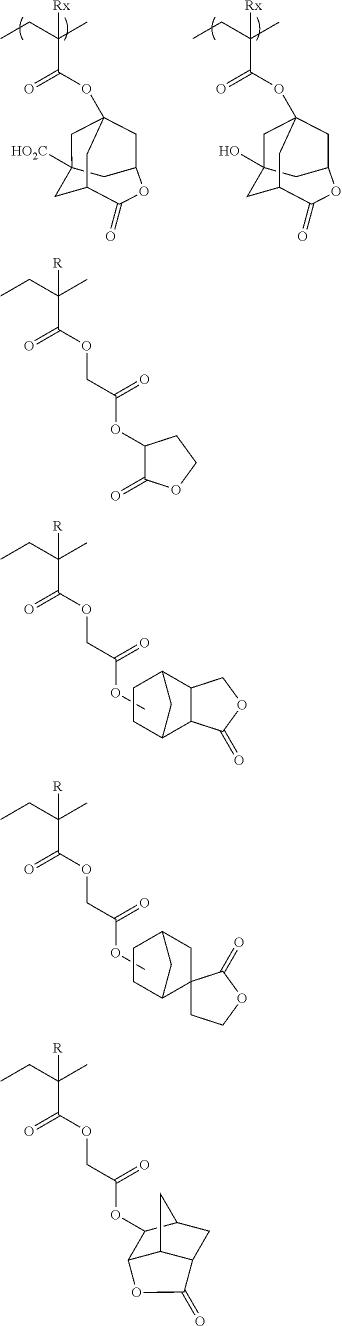

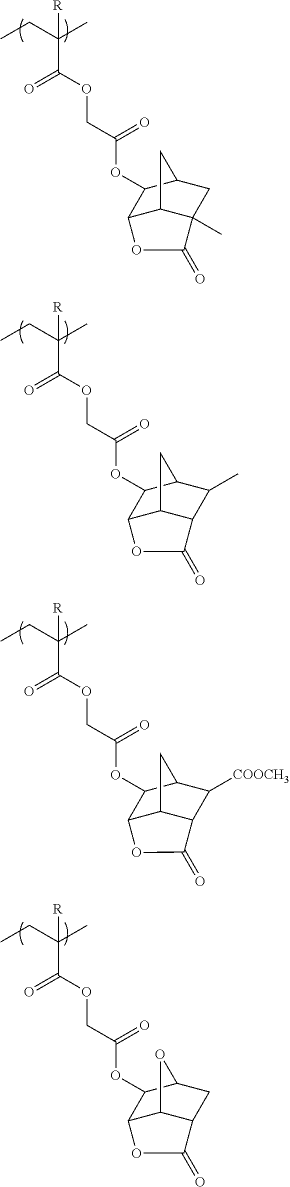

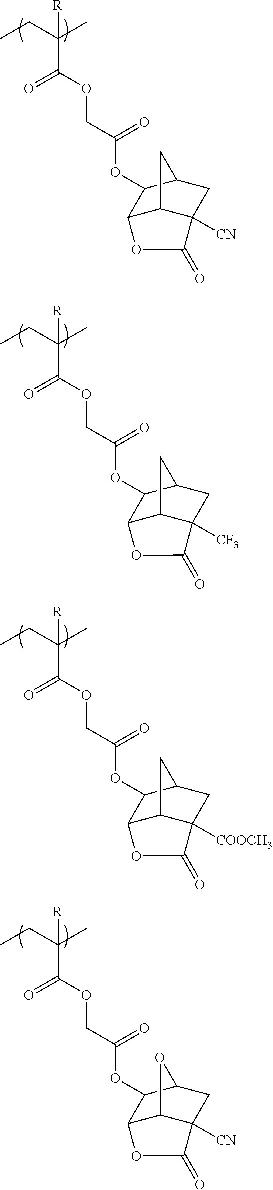

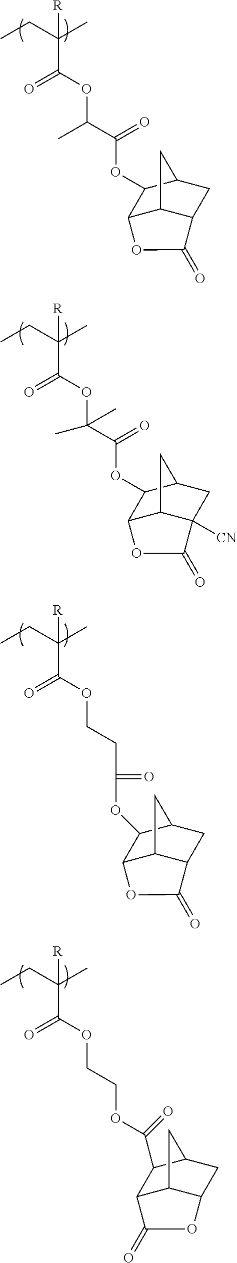

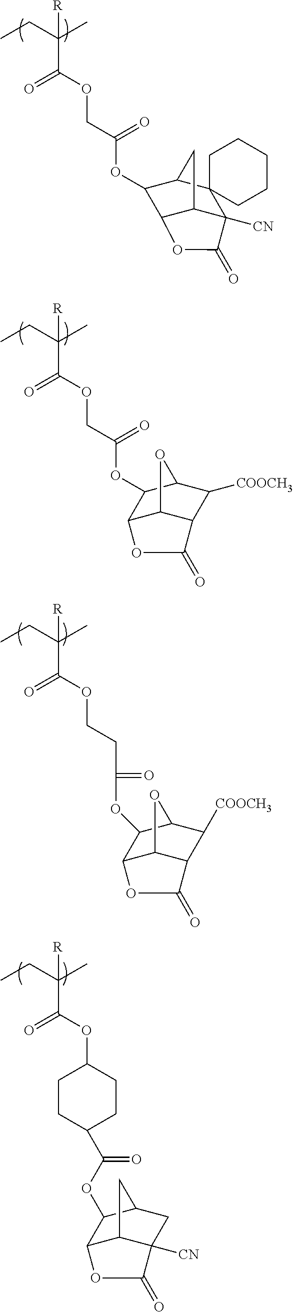

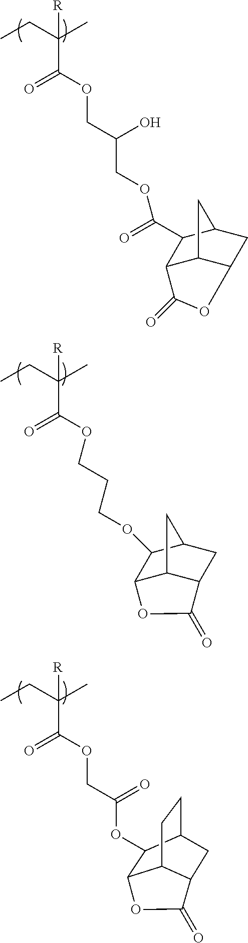

Examples of the repeating unit included in the resin (B) preferably include a repeating unit in which a lactone group is substituted with a sultone group in the above-mentioned repeating unit containing a lactone group.

The weight-average molecular weight of the resin (B) is preferably within a range of 2,000 to 200,000, as a value in terms of polystyrene, determined by a GPC method. By setting the weight-average molecular weight to 2,000 or more, the heat resistance and the dry etching resistance can be particularly improved. By setting the weight-average molecular weight to 200,000 or less, the film forming properties thereof can also be improved by causing a reduction in the viscosity of the composition, along with a particular improvement in the developability.

A more preferable molecular weight thereof is within a range of 1,000 to 200,000, more preferably within a range of 2,000 to 50,000, and still more preferably 2,000 to 10,000. In addition, in the formation of a fine pattern in which electron beams, X-rays, or high-energy beams at a wavelength of 50 nm or less (for example, EUV) is used, the weight-average molecular weight is most preferably set within a range of 3,000 to 6,000. By adjusting the average molecular weight, the heat resistance and the resolving power of the composition may be improved, and a reduction of developing defects or the like can be achieved at the same time.

The dispersity (Mw/Mn) of the resin (B) is preferably 1.0 to 3.0, more preferably 1.0 to 2.5, and still more preferably 1.0 to 1.6. By adjusting the dispersity, for example, the line edge roughness performance can be improved.

In the composition of the present invention, two or more kinds of the resin (B) may be used in combination.

The combination ratio accounted for by the resin (B) in the composition of the present invention is preferably 30% to 99.9% by mass, more preferably 50% to 99% by mass, and still more preferably 60% to 99% by mass, based on the total solid contents.

The actinic ray-sensitive or radiation-sensitive composition according to the second embodiment of the present invention preferably contains the above-mentioned compound (D) (acid generator) that generates an acid upon irradiation with actinic rays or radiation, as described in the first embodiment.

The preferred range of the content of the compound (D) in the composition is the same as the range described in the first embodiment.

Furthermore, the actinic ray-sensitive or radiation-sensitive composition according to the second embodiment of the present invention preferably contains the basic compound (E) described in the first embodiment.

The preferred range of the content of the basic compound (E) in the composition is the same as the range described in the first embodiment.

Moreover, the actinic ray-sensitive or radiation-sensitive composition according to the second embodiment of the present invention may contain the betaine compound, the hydrophobic resin, the surfactant, the organic acid, the compound having two or more functional groups which forms a hydrogen bond with a phenolic hydroxyl group, the onium carboxylate onium salt, and the acid proliferation agent, each described in the first embodiment. The preferred range of the content of each component of the betaine compound, the hydrophobic resin, the surfactant, the onium carboxylate salt, and the acid proliferation agent is the same as the range described in the first embodiment.

In addition, the actinic ray-sensitive or radiation-sensitive composition according to the second embodiment of the present invention preferably contains the solvent described in the first embodiment, and the preferred range of the concentration of the solid contents of the composition is the same as the range described in the first embodiment.

### EXAMPLES

Hereinafter, the present invention will be described in detail with reference to Examples, but the contents of the present invention are not limited thereto.

### Evaluation of Electron Beam (EB) Lithography

### Examples 1 to 8 and Comparative Examples 1 to 4

(1) Preparation of Support

A 6-inch wafer (which had been subjected to a shielding film treatment for use in an ordinary photomask blank) on which a film of chromium oxychloride had been formed was prepared. Here, 1 inch corresponds to 25.4 mm.

(2) Pre-Rinsing Treatment

A pre-rinsing liquid was ejected for 15 seconds onto the 6-inch wafer while rotating the 6-inch wafer at 500 rpm, using a spin coater Mark 8 manufactured by Tokyo Electron, Ltd., and the wafer was subjected to a pre-rinsing treatment, using each of the pre-rinsing liquids described in Table 2, across the entire surface of the substrate. Then, the wafer was rotated at 1,200 rpm for 15 seconds, and the pre-rinsing liquid was sprayed thereonto, followed by drying. Thereinafter, the wafer was heated on a hot plate at 140° C. for 600 seconds.

TABLE 2

| | | | | Amount |
|---|---|---|---|---|
| | | | | (% by |
| | | | | mass) of |
| | | Amount | | acid or |
| | | (% by | | thermal |
| | | mass) of | | acid |
| | | solvent | | generator |
| | | with | | with |
| | | respect | | respect |
| | | to total | | to total |
| | | amount | Acid or | amount |
| Pre- | | of pre- | thermal | of pre- |
| rinsing | | rinsing | acid | rinsing |
| liquid | Solvent or water | liquid | generator | liquid |
| R-1 | PGMEA | 100.00 | — | — |
| R-2 | PGME | 100.00 | — | — |
| R-3 | Ethyl lactate | 100.00 | — | — |
| R-4 | PGMEA | 99.50 | Benzoic acid | 0.50 |
| R-5 | PGMEA | 99.00 | Benzoic acid | 1.00 |
| R-6 | PGMEA | 66.00 | Benzoic acid | 1.00 |
| | PGME | 33.00 | | |
| R-7 | PGMEA | 66.00 | Benzoic acid | 1.00 |
| | Cyclohexanone | 33.00 | | |
| R-8 | PGMEA | 98.10 | 10- | 1.90 |
| | | | Camphorsulfonic | |
| | | | acid | |
| RR-1 | N-Methyl-2- | 100.00 | — | — |
| | pyrrolidone | | | |
| RR-2 | PGMEA | 60.00 | — | — |
| | water | 40.00 | | |
| RR-3 | PGMEA | 75.00 | Benzoic acid | 25.00 |

Here, the CLogP of each of the solvents used in the pre-rinsing liquid is as shown in Table 3.

TABLE 3

| Solvent | CLogP value |
|---|---|
| PGMEA | 0.599 |
| PGME | −0.297 |
| Ethyl lactate | 0.331 |
| Cyclohexane | 0.865 |
| N-Methyl-2-pyrrolidone | −0.397 |

Moreover, the pKa and the molecular weight of the acid or the acid produced from the thermal acid generator, used in the pre-rinsing liquid, are as shown in Table 4, respectively.

TABLE 4

| | pKa of acid, | Molecular |
|---|---|---|
| | or acid | weight of acid, |
| Acid or | produced from | or acid produced |
| thermal acid | thermal acid | from thermal |
| generator | generator | acid generator |
| Benzoic acid | 4.20 | 122.12 |
| 10-Camphorsulfonic acid | −1.64 | 232.3 |

With regard to the surface of the substrate in each of Examples and Comparative Examples, which was subjected to the pre-rinsing treatment and the surface of the substrate in Comparative Example 1, which was not subjected to the pre-rinsing treatment, the contact angle and the secondary ion strength of the amine component C₄H₁₂N⁺ were measured in the following manner. The results are shown in Table 6.

[Contact Angle]

One drop of pure water was dropped onto the surface of a substrate after the pre-rinsing treatment, and then a static contact angle at a time when 5 seconds has passed was automatically measured in a θ/2 method, using an automatic contact angle meter (CA-V Type manufactured by Kyowa Interface Chemical Co., Ltd.), thereby obtaining a static contact angle of the resist film.

[Secondary Ion Strength of Amine Component C₄H₁₂N⁺]

Using TOF-SIMS, the secondary ion strength of the surface of the substrate was acquired in the following conditions.

Device: ION-TOF-made TOF-SIMS V

Primary ion: Bi₃⁺

Ion current: 0.2 pA

Measurement mode: Bunching Mode (high-mass decomposability mode)

Measurement region: 100 μm²

Polarity: Positive

(3) Preparation of Resist Film

Subsequently, a negative tone resist composition NR-1 having the composition shown in the following table was applied, and dried on a hot plate at 100° C. for 600 seconds, thereby obtaining a resist film having a film thickness of 50 nm. That is, a resist-applied wafer was obtained.

TABLE 5

| | | Crosslinking | Photoacid | Basic | |
|---|---|---|---|---|---|
| | Resin | agent | generator | compound | Solvent |
| Negative | P-1 | CL-1/CL-2 | A-1 | B-1 | PGMEA/ |
| tone resist | | | | | PGME |
| composition | 1.058 g | 0.191 g/ | 0.288 g | 0.019 g | 78.702 g/ |
| NR-1 | | 0.066 g | | | 19.676 g |

The respective components shown in Table 5 are as shown below.

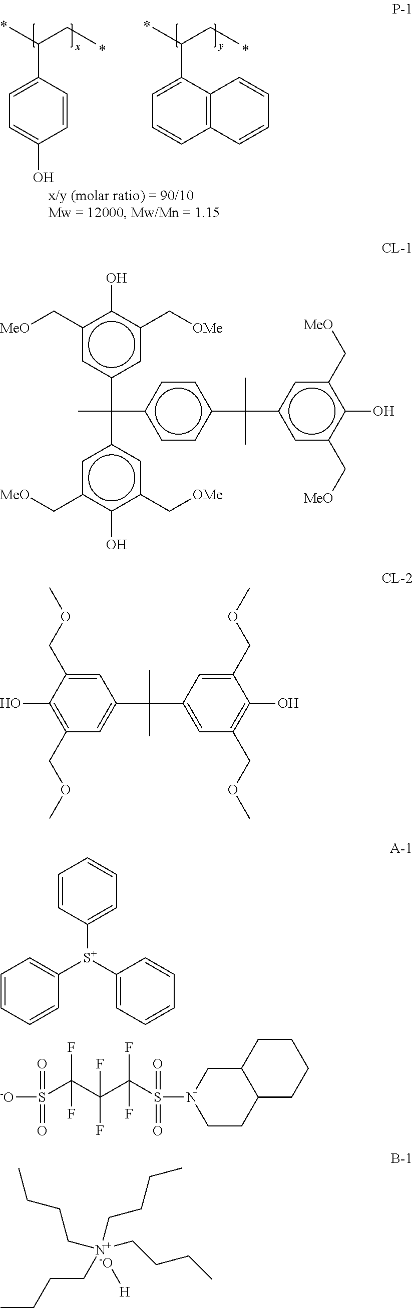

(4) Preparation of Negative Tone Resist Pattern

This resist film was subjected to patternwise irradiation using an electron beam lithographic apparatus (manufactured by Elionix, Inc.; ELS-7500, acceleration voltage: 50 KeV). After irradiation, the film was heated on a hot plate at 120° C. for 600 seconds, immersed for 120 seconds using a 2.38%-by-mass aqueous tetramethylammonium hydroxide (TMAH) solution, and then rinsed for 30 seconds with water and dried, thereby forming a resist pattern having a 1:1 line-and-space with a line width ranging from 400 nm to 15 nm.

(5) Evaluation of Resist Pattern

For the obtained pattern, a sensitivity (LS sensitivity), a line-and-space resolution (LS resolution), and the taper angle (LS pattern taper angle) of a line-and-space pattern by the following methods were evaluated. The results are shown in Table 6.

[LS Sensitivity]

The obtained pattern was observed using a scanning electron microscope (S-4800 manufactured by Hitachi, Ltd.). The exposure dose (electron beam irradiation dose) when resolving a 1:1 line-and-space resist pattern with a line width of 50 nm was defined as the sensitivity. A smaller value of this exposure dose indicates better performance.

[Evaluation of LS Resolution]

The limiting resolving power (minimum line width for separating and resolving the line and the space) at the exposure dose (electron beam irradiation dose) exhibiting the above-mentioned sensitivity was defined as an LS resolution (nm).

[LS Pattern Taper Angle]

The cross-sectional shape of the obtained 1:1 line-and-space resist pattern with a line width of 50 nm was observed using a scanning electron microscope (S-4800 manufactured by Hitachi, Ltd.). The cross-section in the direction crossing perpendicularly to the line pattern was observed. Here, the tilt angle was set to 100 (inclination angle at the time of observing the pattern in the vertical direction). From the observed image, the angle between the side wall of the line pattern and the surface of the substrate was measured. The angle at which the pattern was forward tapered was set to 900 or less, and the angle at which the pattern was reversely tapered was set to 900 or more. The left and right taper angles often line patterns in total were measured, and an average value thereof was used for evaluation of an “LS pattern taper angle”. This value which is nearer to 900 indicates a better cross-sectional shape of a pattern.

TABLE 6

| | | Contact angle | Secondary ion strength | | | | LS |
|---|---|---|---|---|---|---|---|
| | | (water) after | (normalized to entire | Negative | LS | LS | pattern |
| | Pre-rinsing | pre-rinsing | ion strength) of amine | tone resist | sensitivity | resolution | taper |
| | liquid | treatment | component C₄H₁₂N⁺ | composition | (μC/cm²) | (nm) | angle (°) |
| Example 1 | R-1 | 41.5° | 0.09 | NR-1 | 24.3 | 30 | 94 |
| Example 2 | R-2 | 32.5° | 0.10 | NR-1 | 23.1 | 35 | 95 |
| Example 3 | R-3 | 37.8° | 0.09 | NR-1 | 23.8 | 35 | 94 |
| Example 4 | R-4 | 42.2° | 0.04 | NR-1 | 23.8 | 25 | 92 |
| Example 5 | R-5 | 41.9° | 0.01 | NR-1 | 23.5 | 20 | 91 |
| Example 6 | R-6 | 37.0° | 0.02 | NR-1 | 23.5 | 20 | 91 |
| Example 7 | R-7 | 44.1° | 0.01 | NR-1 | 23.3 | 20 | 90 |
| Example 8 | R-8 | 41.4° | 0.01 | NR-1 | 23.4 | 25 | 88 |
| Comparative | No pre-rinsing | 4.8° | 0.21 | NR-1 | 24.5 | 45 | 99 |
| Example 1 | treatment | | | | | | |
| Comparative | RR-1 | 28.6° | 0.15 | NR-1 | 26.9 | 45 | 98 |
| Example 2 | | | | | | | |
| Comparative | RR-2 | 15.3° | 0.17 | NR-1 | 24.8 | 40 | 98 |
| Example 3 | | | | | | | |
| Comparative | RR-3 | 43.1° | 0.03 | NR-1 | 24.1 | 45 | 79 |
| Example 4 | | | | | | | |

### Examples 9 to 13 and Comparative Example 5

In the same manner as in Example 4 except that the negative tone resist composition NR-1 was replaced with each of the negative tone resist compositions NR-2 to NR-6 in Table 7 in the “(3) Preparation of Resist Film”, a negative tone resist pattern was prepared and evaluated. The developing defects were measured, based on the following method.

[Residue Defects]

The cross-sectional shape of the obtained 1:1 line-and-space resist pattern with a line width of 100 nm was observed using a scanning electron microscope (S-4800 manufactured by Hitachi, Ltd.). In the observed image (1 μm²), the extent of the residue defects was observed with the naked eyes, and evaluated as follows.

A: No residue defects

B: Case where less than 20% of the surface of the substrate (bottom section) is covered with residues in the space section

C: Case where 20% or more of the surface of the substrate (bottom section) is covered with residues in the space section

The results are shown in Table 8.

TABLE 7

| | | | | | | | | | | | | | | | Concen- |
|---|---|---|---|---|---|---|---|---|---|---|---|---|---|---|---|
| | | | | | | | | | | | | | | | tration |
| | | | | | | | | | | | | | | | [% by |
| Resist | | | Hydro- | | | | | | Cross- | | | | | | weight] |
| compo- | | % by | phobic | % by | Acid | % by | Basic | % by | linking | % by | | % by | | Mass | of solid |
| sition | Resin | mass | resin | mass | generator | mass | compound | mass | agent | mass | Additive | mass | Solvent | ratio | content |
| NR-2 | Poly-3 | 69.9 | C-1 | 3 | A-4 | 10 | B-4 | 1.8 | CL-2 | 15 | E-1 | 0.3 | SL-1/SL-2 | 20/80 | 2.5 |
| NR-3 | Poly-2 | 70.4 | C-1 | 3 | A-5 | 10 | B-3 | 1.3 | CL-1 | 15 | E-2 | 0.3 | SL-1/SL-2 | 20/80 | 2.5 |
| NR-4 | Poly-2 | 62.8 | C-1 | 3 | A-1 | 10 | B-9 | 4.2 | CL-3 | 20 | — | — | SL-1/SL-2 | 20/80 | 2.5 |
| NR-5 | Poly-2 | 63.1 | C-1 | 3 | A-1 | 10 | B-8 | 3.9 | CL-3 | 20 | — | — | SL-1/SL-2 | 20/80 | 2.5 |
| NR-6 | Poly-2 | 68.5 | — | — | A-8 | 10 | B-5 | 1.5 | CL-4 | 20 | — | — | SL-1/SL-2 | 20/80 | 2.5 |

TABLE 8

| | | | Secondary | | | | | |
|---|---|---|---|---|---|---|---|---|
| | | | ion strength | | | | | |
| | | Contact | (normalized | | | | | |
| | | angle | to entire ion | | | | LS | |
| | | (water) | strength) of | Negative | | | pattern | |
| | | after | amine | tone | LS | LS | taper | |
| | Pre-rinsing | pre-rinsing | component | resist | sensitivity | resolution | angle | Residue |
| | liquid | treatment | C₄H₁₂N⁺ | composition | (μC/cm²) | (nm) | (°) | defects |
| Example 9 | R-4 | 42.2° | 0.04 | NR-2 | 23.3 | 35 | 90 | A |
| Example 10 | R-4 | 42.2° | 0.04 | NR-3 | 24.8 | 30 | 92 | A |
| Example 11 | R-4 | 42.2° | 0.04 | NR-4 | 23.9 | 25 | 91 | A |
| Example 12 | R-4 | 42.2° | 0.04 | NR-5 | 24.5 | 25 | 93 | A |
| Example 13 | R-4 | 42.2° | 0.04 | NR-6 | 25.2 | 30 | 92 | A |
| Comparative | No pre-rinsing | 4.8° | 0.21 | NR-2 | 25.1 | 50 | 99 | B |
| Example 5 | treatment | | | | | | | |

Among the components used in the negative tone resist compositions NR-2 to NR-6, and the positive tone resist compositions PR-2 to PR-12 which will be described later, the components which have not been described above will be shown below.

[Resin]

The structures, the compositional ratios (molar ratios), the weight-average molecular weights (Mw), the dispersities (Mw/Mn), and the like of the resin will be shown below.

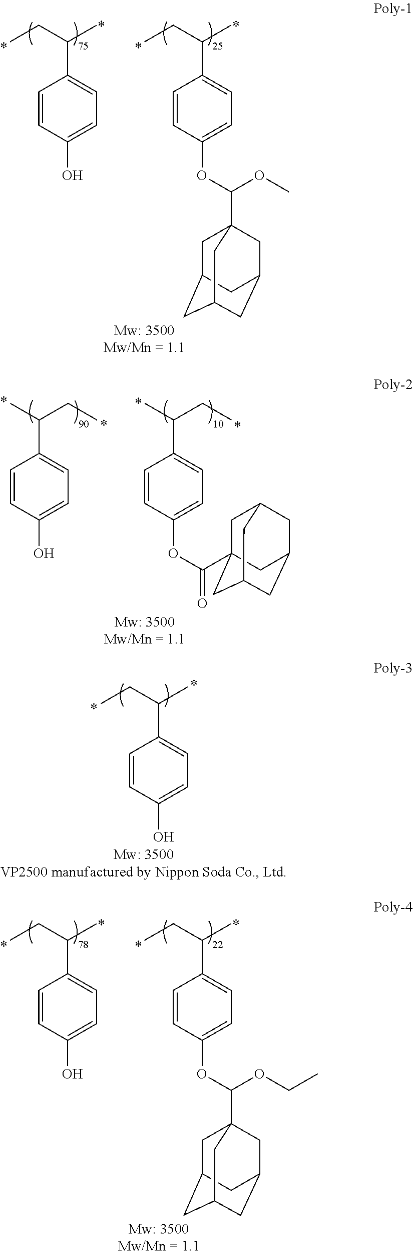

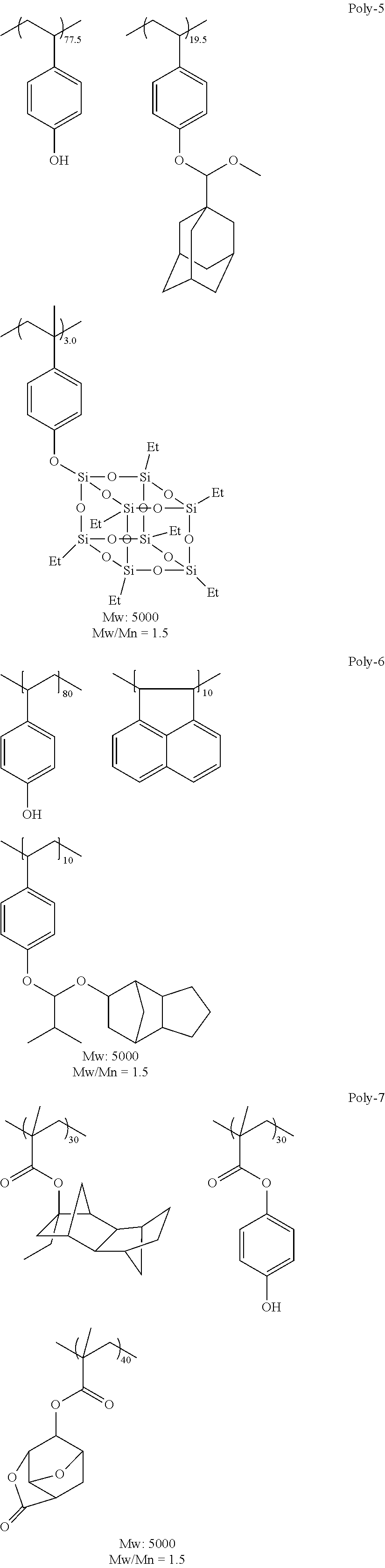

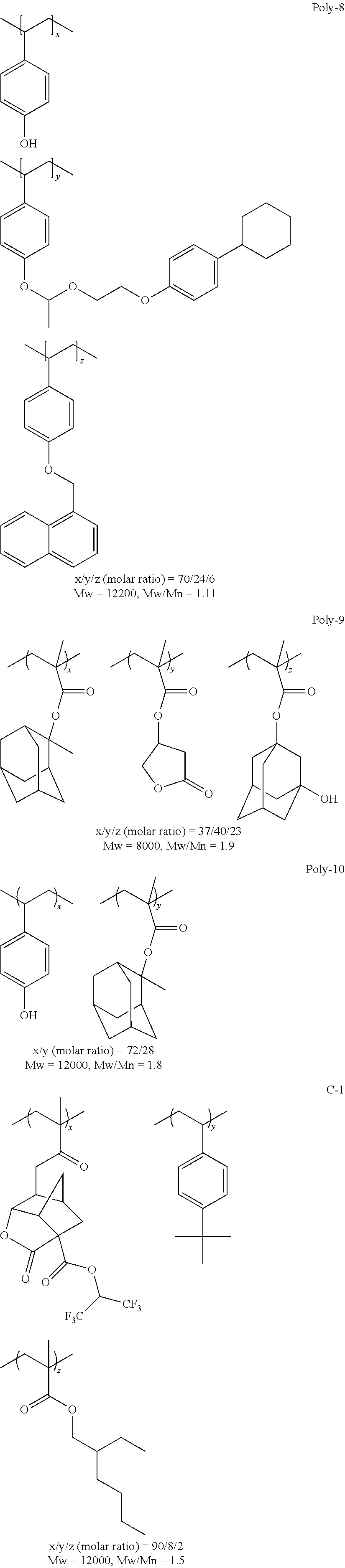

[Basic Compound]

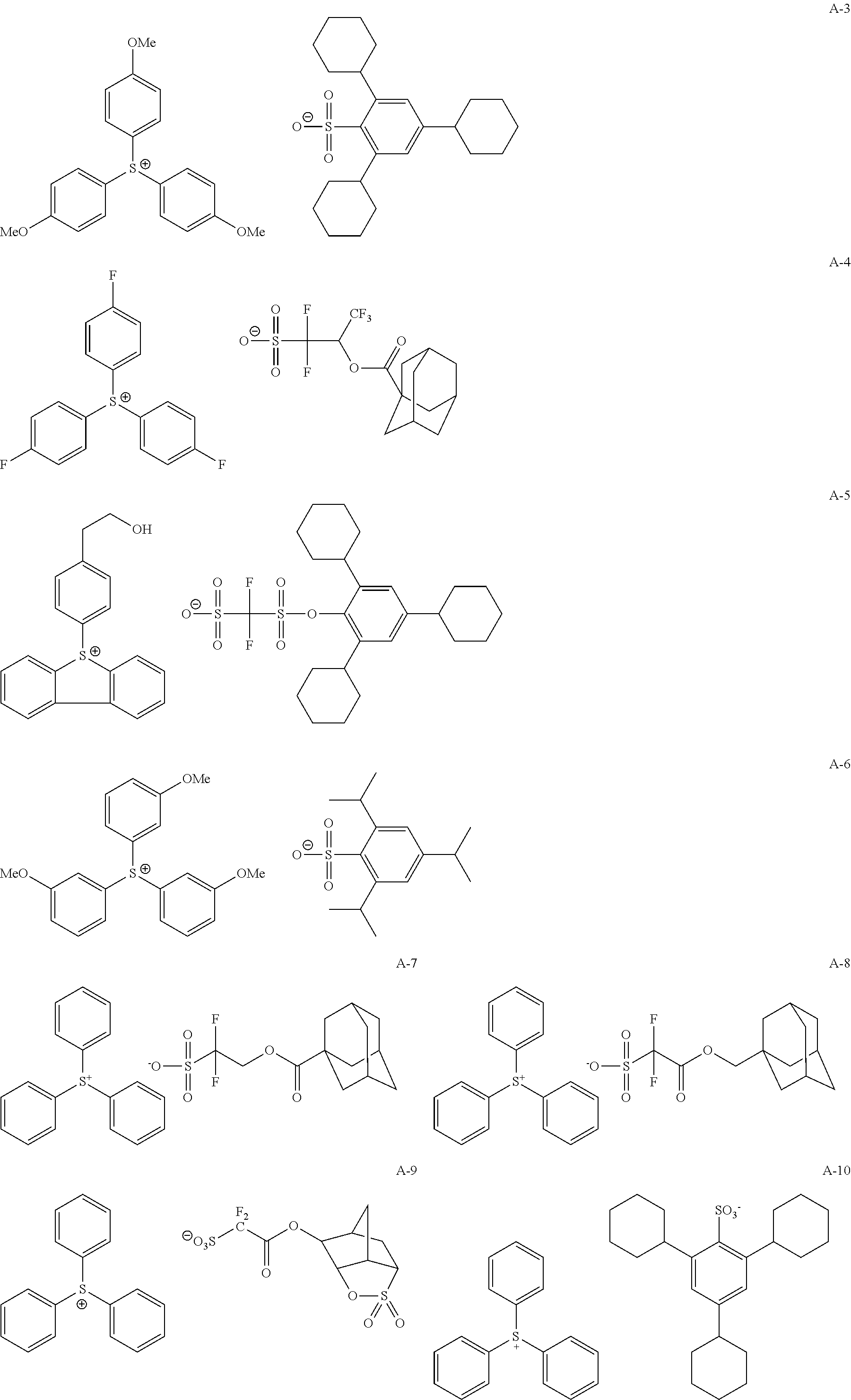

[Basic Compound]

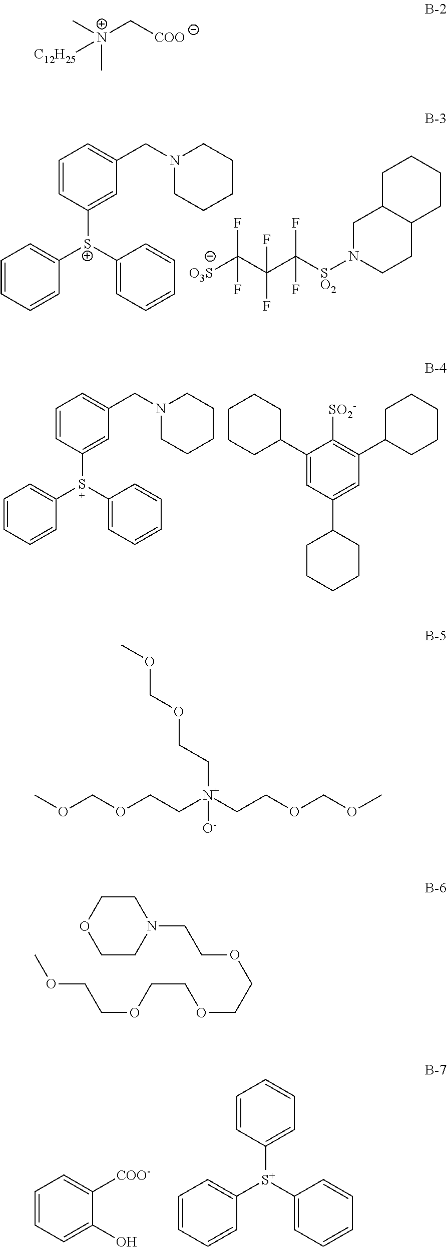

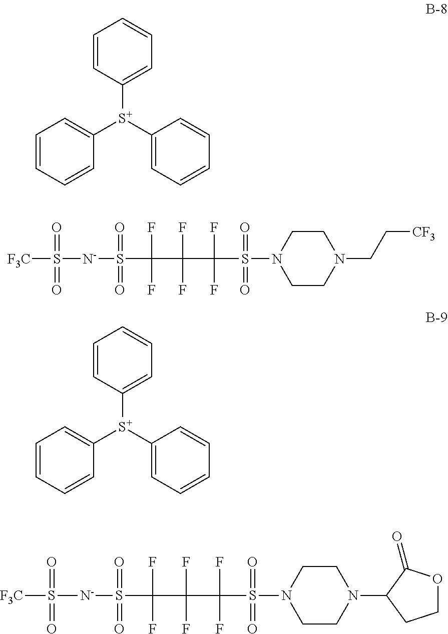 [SMILES: c1ccc([S+](c2ccccc2)c2ccccc2)cc1 ; O=S(=O)([N-]S(=O)(=O)C(F)(F)C(F)(F)C(F)(F)S(=O)(=O)N1CCN(CCC(F)(F)F)CC1)C(F)(F)F ; c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1]

[Crosslinking Agent]

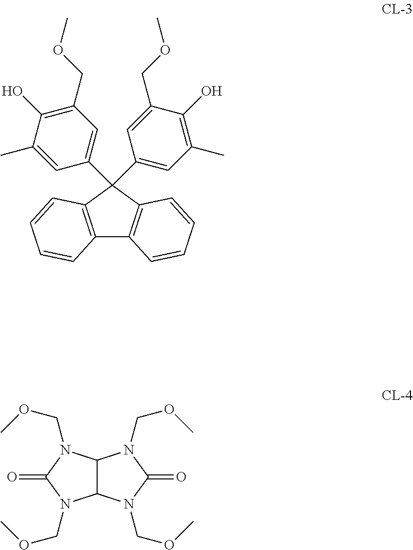

[Additive]

E-1: Benzoic acid

E-2: Salicylic acid

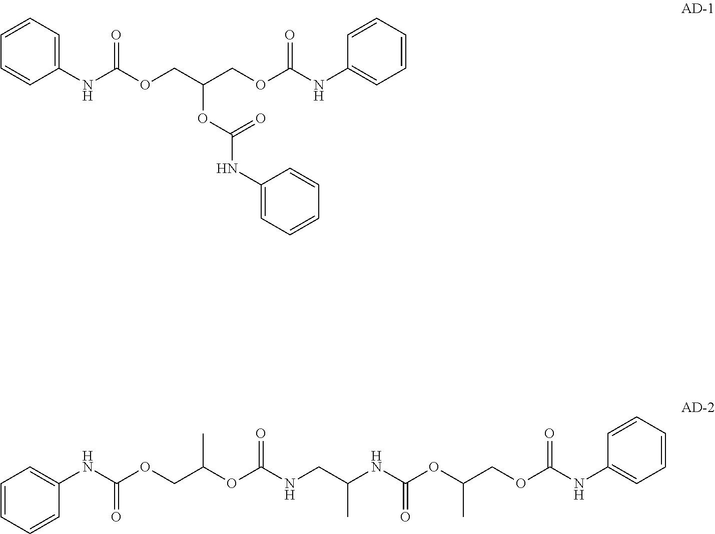 [SMILES: O=C(Nc1ccccc1)OCC(COC(=O)Nc1ccccc1)OC(=O)Nc1ccccc1 ; CC(CNC(=O)OC(C)COC(=O)Nc1ccccc1)NC(=O)OC(C)COC(=O)Nc1ccccc1]

[Surfactant]

W-1: PF6320 (manufactured by OMNOVA Solutions Inc.)

W-2: MEGAFACE F176 (manufactured by Dainippon Ink & Chemicals, Inc.; fluorine-based)

[Solvent]

SL-1: Propylene glycol monomethyl ether (1-methoxy-2-propanol)

SL-2: Propylene glycol monomethyl ether acetate (1-methoxy-2-acetoxypropane)

SL-3: Ethyl lactate

SL-4: Cyclohexanone

From the results shown in Tables 6 and 8, it could be seen that in Examples 1 to 13 in which the pre-rinsing treatment was carried out with the pre-rinsing liquid of the present invention, it was possible to form a pattern excellent in a sensitivity, the cross-sectional shape of a pattern, a resolution, and residue defect performance in the formation of an ultrafine pattern (for example, a pattern with a line width of 50 nm or less), as compared with Comparative Examples 1 and 5 in which the pre-rinsing treatment was not carried out, and Comparative Examples 2 to 4 in which even though the pre-rinsing treatment was carried out, the pre-rinsing liquid did not satisfy the requirements in the present invention.

In addition, in Examples 4 to 8 in which the pre-rinsing liquid containing an acid was used, a result in which the effect of the present invention was further expressed was obtained.

### Examples 14 to 20 and Comparative Examples 6 to 9

In the same manner as in Examples 1 to 7, (1) Preparation of Support and (2) Pre-Rinsing Treatment (provided that each of the pre-rinsing liquids used was the same as in Table 2) were carried out.

For the surface of the substrate in each of Examples and Comparative Examples, which was subjected to the pre-rinsing treatment, and the surface of the substrate in Comparative Example 6, which was not subjected to the pre-rinsing treatment, the contact angle and the secondary ion strength of the amine component C₄H₁₂N⁺ were measured by the above-described methods. The results are shown in Table 10.

Subsequently, the positive tone resist composition PR-1 shown in the following table was applied, and dried on a hot plate at 130° C. for 600 seconds, thereby obtaining a resist film having a film thickness of 50 nm. That is, a resist-applied wafer was obtained.

TABLE 9

| | | Photoacid | Basic | |
|---|---|---|---|---|
| | Resin | generator | compound | Solvent |
| Positive | P-2 | A-2 | B-1 | PGMEA/ |
| tone resist | | | | PGME |
| composition | 1.455 g | 0.176 g | 0.015 g | 80.481 g/ |
| PR-1 | | | | 17.873 g |

The resin and the photoacid generator in Table 9 are as follows below. The other components are as mentioned above.

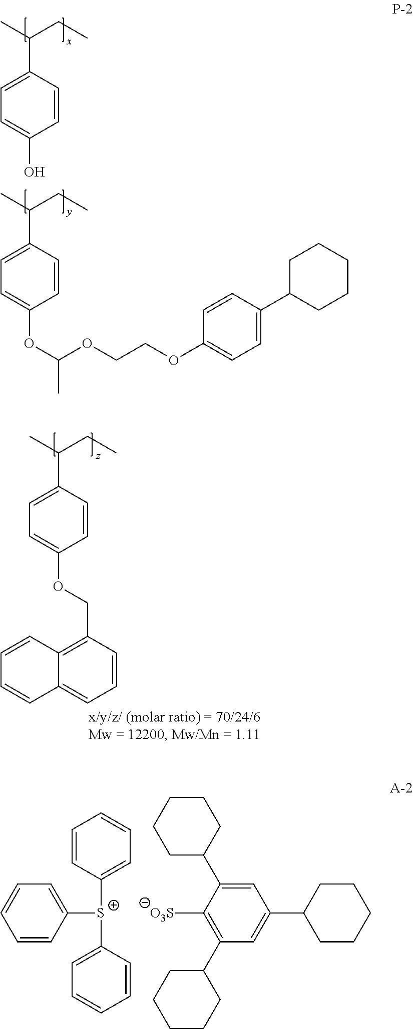

With regard to this resist film, 1:1 line-and-space positive tone resist patterns ranging from a line width of 400 nm to a line width of 15 nm were formed by the same method as for (4) Preparation of Negative Tone Resist Pattern in Example 1 except that the heating condition after irradiation was set to 110° C. for 600 seconds.

For the obtained patterns, a sensitivity (LS sensitivity), a line-and-space resolution (LS resolution), the taper angle (LS pattern taper angle) of a line-and-space pattern, and the developing defects were evaluated.

The sensitivity (LS sensitivity), the line-and-space resolution (LS resolution), the taper angle (LS pattern taper angle) of the line-and-space pattern, and the residue defects were measured, based on the above-mentioned methods.

The results are shown in Table 10.

TABLE 10

| | | | Secondary | | | | | |
|---|---|---|---|---|---|---|---|---|
| | | | ion strength | | | | | |
| | | | (normalized | | | | | |
| | | | to entire ion | | | | | |
| | | Contact angle | strength) of | Positive | | | LS | |
| | | (water) after | amine | tone | LS | LS | pattern | |
| | Pre-rinsing | pre-rinsing | component | resist | sensitivity | resolution | taper | Residue |
| | liquid | treatment | C₄H₁₂N⁺ | composition | (μC/cm²) | (nm) | angle (°) | defects |
| Example 14 | R-1 | 41.5° | 0.09 | PR-1 | 23.8 | 30 | 88 | A |
| Example 15 | R-2 | 32.5° | 0.10 | PR-1 | 24.3 | 35 | 86 | B |
| Example 16 | R-3 | 37.8° | 0.09 | PR-1 | 23.6 | 30 | 88 | A |
| Example 17 | R-4 | 42.2° | 0.04 | PR-1 | 23.5 | 25 | 89 | A |
| Example 18 | R-5 | 41.9° | 0.01 | PR-1 | 23.3 | 18 | 90 | A |
| Example 19 | R-6 | 37.0° | 0.02 | PR-1 | 23.3 | 20 | 89 | A |
| Example 20 | R-7 | 44.1° | 0.01 | PR-1 | 23.4 | 20 | 91 | A |
| Comparative | No pre-rinsing | 4.8° | 0.21 | PR-1 | 25.1 | 45 | 83 | C |
| Example 6 | treatment | | | | | | | |
| Comparative | RR-1 | 28.6° | 0.15 | PR-1 | 25.9 | 50 | 80 | C |
| Example 7 | | | | | | | | |
| Comparative | RR-2 | 15.3° | 0.17 | PR-1 | 24.5 | 40 | 84 | B |
| Example 8 | | | | | | | | |
| Comparative | RR-3 | 43.1° | 0.03 | PR-1 | 23.5 | 45 | 99 | B |
| Example 9 | | | | | | | | |

### Examples 21 to 31 and Comparative Example 10

In the same manner as in Example 14 except that the positive tone resist composition PR-1 was replaced with each of the positive tone resist compositions PR-2 to PR-12 in Table 11 in the preparation of the resist film, a positive tone resist pattern was prepared and evaluated. The components used in the positive tone resist compositions PR-2 to PR-12 are as described above.

The results are shown as Table 12.

TABLE 11

| | | | | | | | | | | | | | | | Concen- |
|---|---|---|---|---|---|---|---|---|---|---|---|---|---|---|---|
| | | | | | | | | | | | | | | | tration |
| | | | | | | | | | | | | | | | [% by |
| Resist | | | Hydro- | | | | | | | | | | | | weight] |
| compo- | | % by | phobic | % by | Acid | % by | Basic | % by | | % by | Surfac- | % by | | Mass | of solid |
| sition | Resin | mass | resin | mass | generator | mass | compound | mass | Additive | mass | tant | mass | Solvent | ratio | content |
| PR-2 | Poly-8 | 86.7 | — | — | A-6 | 12 | B-1 | 1.2 | — | — | W-1 | 0.1 | SL-1/SL-2 | 20/80 | 2.5 |
| PR-3 | Poly-1 | 80.2 | C-1 | 4 | A-3 | 12 | B-8 | 3.5 | E-1 | 0.3 | — | — | SL-1/SL-2 | 20/80 | 2.5 |
| PR-4 | Poly-1 | 80.4 | C-1 | 4 | A-3 | 12 | B-8 | 3.3 | E-2 | 0.3 | — | — | SL-1/SL-2/SL-3 | 20/60/20 | 2.5 |
| PR-5 | Poly-4 | 80.3 | C-1 | 4 | A-3 | 12 | B-9 | 3.4 | E-2 | 0.3 | — | — | SL-1/SL-2/SL-3 | 20/60/20 | 2.5 |
| PR-6 | Poly-5 | 86.9 | — | — | A-10 | 12 | B-2 | 1.1 | — | — | — | — | SL-1/SL-2/SL-3 | 20/20/60 | 2.4 |
| PR-7 | Poly-1 | 76.9 | — | — | A-10 | 12 | B-2 | 1.0 | AD-1 | 10 | W-2 | 0.1 | SL-1/SL-2/SL-3 | 20/20/60 | 2.4 |
| PR-8 | Poly-1 | 77.1 | — | — | A-10 | 12 | B-2 | 0.8 | AD-2 | 10 | W-2 | 0.1 | SL-1/SL-2/SL-3 | 20/20/60 | 2.4 |
| PR-9 | Poly-6 | 84.6 | C-1 | 4 | A-6 | 10 | B-5 | 1.1 | E-2 | 0.3 | — | — | SL-1/SL-2/SL-4 | 20/60/20 | 2.6 |
| PR-10 | Poly-7 | 83.4 | C-1 | 4 | A-4 | 11 | B-6 | 1.3 | E-2 | 0.3 | — | — | SL-1/SL-2/SL-4 | 20/60/20 | 2.6 |
| PR-11 | Poly-9 | 80.5 | C-1 | 4 | A-9 | 14 | B-5 | 1.2 | E-2 | 0.3 | — | — | SL-1/SL-2/SL-3 | 20/60/20 | 2.5 |
| PR-12 | Poly-10 | 79.3 | C-1 | 4 | A-7 | 15 | B-7 | 1.4 | E-2 | 0.3 | — | — | SL-1/SL-2/SL-3 | 20/60/20 | 2.5 |

TABLE 12

| | | Contact angle | Secondary ion strength | | | | LS | |
|---|---|---|---|---|---|---|---|---|
| | | (water) after | (normalized to entire | Positive | LS | LS | pattern | |
| | Pre-rinsing | pre-rinsing | ion strength) of amine | tone resist | sensitivity | resolution | taper | Residue |
| | liquid | treatment | component C₄H₁₂N⁺ | composition | (μC/cm²) | (nm) | angle (°) | defect |
| Example 21 | R-1 | 41.5° | 0.09 | PR-2 | 25.2 | 40 | 89 | B |
| Example 22 | R-1 | 41.5° | 0.09 | PR-3 | 24.9 | 35 | 90 | A |
| Example 23 | R-1 | 41.5° | 0.09 | PR-4 | 23.6 | 35 | 88 | A |
| Example 24 | R-1 | 41.5° | 0.09 | PR-5 | 24.4 | 30 | 91 | A |
| Example 25 | R-1 | 41.5° | 0.09 | PR-6 | 24.5 | 25 | 87 | B |
| Example 26 | R-1 | 41.5° | 0.09 | PR-7 | 25.3 | 25 | 89 | B |
| Example 27 | R-1 | 41.5° | 0.09 | PR-8 | 24.8 | 25 | 90 | B |
| Example 28 | R-1 | 41.5° | 0.09 | PR-9 | 24.7 | 30 | 88 | A |
| Example 29 | R-1 | 41.5° | 0.09 | PR-10 | 23.9 | 35 | 91 | A |
| Example 30 | R-1 | 41.5° | 0.09 | PR-11 | 24.5 | 35 | 90 | A |
| Example 31 | R-1 | 41.5° | 0.09 | PR-12 | 24.1 | 30 | 89 | A |
| Comparative | No pre-rinsing | 4.8° | 0.21 | PR-2 | 25.1 | 50 | 83 | C |
| Example 10 | treatment | | | | | | | |

From the results shown in Tables 10 and 12, it could be seen that in Examples 14 to 31 in which the pre-rinsing treatment was carried out with the pre-rinsing liquid of the present invention, it was possible to form a pattern excellent in a sensitivity, the cross-sectional shape of a pattern, a resolution, and residue defect performance in the formation of an ultrafine pattern (for example, a pattern with a line width of 50 nm or less), as compared with Comparative Examples 6 and 10 in which the pre-rinsing treatment was not carried out, and Comparative Examples 7 to 9 in which even though the pre-rinsing treatment was carried out, the pre-rinsing liquid did not satisfy the requirements in the present invention.

In addition, in Examples 17 to 20 in which the pre-rinsing liquid containing an acid was used, a result in which the effect of the present invention was further expressed was obtained.

Moreover, in Examples described above, even with the use of further incorporation of 0.05 g of B-29 as the hydrophobic resin into the resist compositions NR-1 and PR-1, the same evaluation as in Examples described above can be obtained.

Furthermore, in Examples above, even with changes in the resin, the photoacid generator, the basic compound, the crosslinking agent, the additive, the surfactant, the hydrophobic resin, or the solvent within the above-mentioned preferred range, the same performance is exhibited.

According to the present invention, it is possible to provide a pre-rinsing liquid capable of forming a pattern excellent in a sensitivity, the cross-sectional shape of a pattern, a resolution, and residue defect performance, particularly in the formation of an ultrafine pattern (for example, a pattern with a line width of 50 nm or less); and a pre-rinsing treatment method and a pattern forming method, each using the same.

While the present invention has been described in detail and with reference to specific embodiments thereof, it will be apparent to one skilled in the art that various changes and modifications can be made therein without departing from the spirit and scope of the invention.

The present application is based on Japanese Patent Application (Patent Application No. 2015-098494) filed on May 13, 2015 and Japanese Patent Application (Patent Application No. 2016-061892) filed on Mar. 25, 2016, the contents of which are incorporated herein by reference.

What is claimed is:

1. A pre-rinsing liquid used in a method including forming a resist film including an actinic ray-sensitive or radiation-sensitive composition on a substrate, and irradiating the resist film with actinic rays or radiation to form a pattern on the substrate, and used for subjecting the substrate to a pre-rinsing treatment before applying the actinic ray-sensitive or radiation-sensitive composition onto the substrate,
wherein the pre-rinsing liquid satisfies the following conditions (1) and (2):
(1) the pre-rinsing liquid includes 80% by mass or more of an organic solvent with respect to the total mass of the pre-rinsing liquid, and
(2) the organic solvent is at least one organic solvent selected from the group consisting of alcohols, cyclic ethers, glycol ethers, glycol ether acetates, hydrocarbons, ketones, lactones, and esters.

2. The pre-rinsing liquid according to claim 1, for manufacturing a mask blank, wherein the substrate is a mask blank.

3. The pre-rinsing liquid according to claim 1, comprising:
an organic solvent having a CLogP of −0.2 or more as the organic solvent.

4. The pre-rinsing liquid according to claim 1, comprising:
an acid or a compound that produces an acid by heat.

5. The pre-rinsing liquid according to claim 4,
wherein the pKa of the acid, or an acid produced from the compound by heat is −5 or more.

6. The pre-rinsing liquid according to claim 4,
wherein the molecular weight of the acid, or an acid produced from the compound by heat is 1,000 or less.

7. The pre-rinsing liquid according to claim 4,
wherein the content of the acid, or the compound that produces an acid by heat is from 0.01% by mass to 19.99% by mass with respect to the total mass of the pre-rinsing liquid.

8. The pre-rinsing liquid according to claim 1,
wherein the pattern is a negative tone pattern.

9. The pre-rinsing liquid according to claim 1,
wherein the pattern is a positive tone pattern.

10. A pre-rinsing treatment method comprising:
washing and hydrophobizing the surface of a substrate before applying an actinic ray-sensitive or radiation-sensitive composition thereonto with the pre-rinsing liquid according to claim 1.

11. A pattern forming method comprising:
the pre-rinsing treatment method according to claim 10.

12. The pattern forming method according to claim 11,
wherein the substrate is a mask blank, and a pattern is formed on the mask blank.

13. The pattern forming method according to claim 11, further comprising
forming a negative tone pattern after carrying out the pre-rinsing treatment method.

14. The pattern forming method according to claim 11, further comprising
forming a positive tone pattern after carrying out the pre-rinsing treatment method.
